(19) United States
(12) Patent Application Publication
(10) Pub. No.: US 2014/0221664 A1
(43) Pub. Date: Aug. 7, 2014

(54) COUPLED HETEROARYL COMPOUNDS VIA REARRANGEMENT OF HALOGENATED HETEROAROMATICS FOLLOWED BY OXIDATIVE COUPLING (ELECTRON WITHDRAWING GROUPS)

(71) Applicants: Yulia A. Getmanenko, Atlanta, GA (US); Seth Marder, Atlanta, GA (US); Do Kyung Hwang, Duluth, GA (US); Bernard Kippelen, Decatur, GA (US)

(72) Inventors: Yulia A. Getmanenko, Atlanta, GA (US); Seth Marder, Atlanta, GA (US); Do Kyung Hwang, Duluth, GA (US); Bernard Kippelen, Decatur, GA (US)

(73) Assignee: GEORGIA TECH RESEARCH CORPORATION, Atlanta, GA (US)

(21) Appl. No.: 14/237,437

(22) PCT Filed: Aug. 9, 2012
(86) PCT No.: PCT/US2012/050215

§ 371 Date: Apr. 15, 2014

Related U.S. Application Data
(60) Provisional application No. 61/522,188, filed on Aug. 10, 2011.

(51) Int. Cl. H01L 51/00

(52) U.S. Cl. CPC H01L 51/0068; H01L 51/0074; H01L 51/0071
USPC 548/147; 549/44; 548/430; 549/48; 548/151; 549/41

(57) ABSTRACT

The inventions disclosed and described herein relate to new and efficient generic methods for making a wide variety of compounds having HAr—Z-Har tricyclic cores, wherein HAr is an optionally substituted five or six membered heteroaryl ring, and Hal is a halogen, and Z is a bridging radical, such as S, Sc, NR⁵, C(O), C(O)C(O), Si(R⁵)₂, SO, SO₂, PR⁵, BR⁵, C(R⁵)₂ or P(O)R⁵ and both HAr are covalently bound to one another. The synthetic methods employ a “Base-Catalyzed Halogen Dance” reaction to prepare a metallated compound comprising a five or six membered heteroaryl ring comprising a halogen atom, and then oxidatively coupling the reactive intermediate compound. The compounds of Formula (II) and/or oligomer or polymers comprising repeat units having Formula (II) can be useful for making semi-conducting materials, and/or electronic devices comprising those materials. Acyl compounds can be prepared. Heteroarylene substituents can be used. The core tricyclic core can be coupled to itself. The Z group also can be strong electron-withdrawing groups such as C═C(CN)₂ or [C═C(CN)_{2]2}. Organic electronic devices can be made including field-effect transistors. Formula (II).

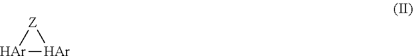

### RELATED APPLICATIONS

This application claims priority to U.S. provisional application Ser. No. 61/522,188 filed Aug. 10, 2011, the complete disclosure of which is hereby incorporated by reference in its entirety.

### BACKGROUND OF THE INVENTION

In recent years there has been a good deal of interest in the art in creating new semiconducting organic materials (monomeric, oligomeric, or polymeric) that comprise conjugated aromatic and/or heteroaromatic rings, and are capable of conducting electrical charge carriers (holes and/or electrons) for use in making various electronic devices, such as for example transistors, solar cells, and light emitting diodes.

Aryl and heteroaryl halides, especially bromide and iodides, are well known as polymerizable precursors of such semiconducting small molecules, oligomers, polymers and copolymers, and are also well known to be convertible to aryl or heteroaryl boronic ester or trialkyl tin derivatives that are also polymerizable or can be reacted to make small molecules and oligomers (typically in the presence of transition metal polymerization catalysis such as palladium or nickel complexes). Synthetic methods for making many such aryl or heteroaryl halide compounds are known, but the synthesis of particular desirable isomers of many aryl or heteroaryl halides remain difficult or expensive.

It is known in the art that aryl or heteroaryl halides can sometimes be isomerized to move the halogen to a different position on the aryl or heteroaryl ring if they are treated with very strong bases, such as for example organo-lithium or organo-magnesium reagents, or lithium dialkylamides. This base catalyzed rearrangement of aryl and heteroaryl halides, may be called the “Base-Catalyzed Halogen Dance” (“BCHD”) rearrangement (see, for example Schnurich et al, Chem. Soc. Rev., 2007, 36, 1046-1057, and de Souza, Curr. Org. Chem. 2007, 11, 637-646) both hereby incorporated by reference for their teachings regarding the methodology of the Halogen Dance reaction and its known synthetic applications).

The rearranged and metallated halogenated intermediate heteroaryl compounds formed via the Halogen Dance rearrangement have then been further utilized in a variety of ways in the prior art, especially by reactions with electrophiles, but those prior uses are believed to be significantly different in kind than the uses of those halogenated and metallated heteroaryl intermediates for oxidative couplings described and claimed hereinbelow.

It is known in the art that the rings of some metallated (typically lithiated) aryl or heteroaryl compounds can be oxidatively coupled with certain oxidizing agents such as copper salts or thionyl chloride, as schematically indicated in the idealized drawing below (see for example, Gronowitz, S. Acta Chem. Scand. 15, 1393-1395 (1961); Whitesides et al, J. Amer. Chem. Soc. 89(20) 5302-5303 (1967); Surry et al, Angew Chem. Int. Ed., 44, 1870-1873 (2005), and Oae et al, Phosphorus, Sulfur, and Silicon, Vol. 103, 101-110 (1995), hereby incorporated by reference for their various teachings regarding relevant oxidative coupling reactions).

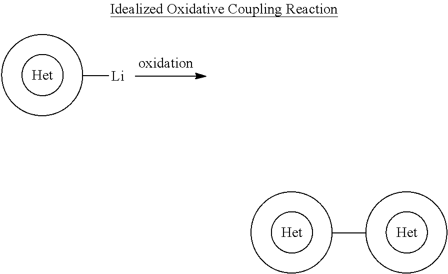

Lastly, it has long been known in the art, such as for example as recently disclosed in PCT Publication WO 2009/115413 (hereby incorporated by reference herein) that certain bishalogenated bisthiophene compounds could be coupled with various regents to form a class of fused ring bisthiophene heteroaryls as indicated in the reaction scheme below:

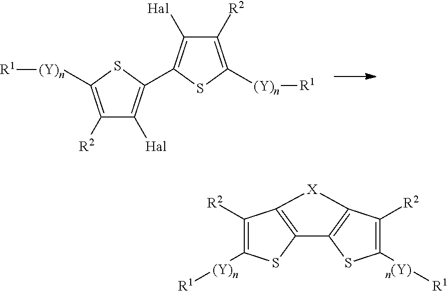

wherein Hal stands for hydrogen or halogen, especially Br, R¹ is hydrogen or a substituent, n ranges from 0 to 6, preferably being 0; Y, if present, is substituted or unsubstituted phenylene, thiene, 1,2-ethylene, or is 1,2-ethinylene; R² is hydrogen or certain aryls and alkyls, and X is certain bridging groups. WO 2009/115413 taught that its compounds and/or certain copolymers derived therefrom could be useful as semiconductors for making electronic devices. WO 2009/115413 did not however teach or suggest that a combination of the halogen dance reaction and an oxidative coupling reaction could be used to prepare its bishalogenated bisthiophene starting materials, or that fused ring heterocycle that do not comprise at least two thiophene rings could be prepared by the methods disclosed.

A need exists for reactions that can be used to conveniently and economically prepare a very wide variety of both known and new dihalo-aryl and/or heteroaryl intermediates, which serve as precursors for the preparation of reactive small molecules that can be used as precursors for the synthesis of new small molecules, oligomers, polymers, and co-polymers that can be useful for making organic electronic devices. In particular, for example, electron withdrawing group compounds are an important class of organic semiconductor compounds useful for organic and printed electronics.

### SUMMARY OF THE INVENTION

The various inventions and/or their embodiments disclosed herein relate to new methods for making heteroaryl compounds having at least two coupled heteroaryl rings and two halogens that employ a sequence of reactions that involve the use of the Base-Catalyzed Halogen Dance (BCHD) reaction to prepare optionally substituted heteroaryl intermediates that are then oxidatively coupled, to prepare a very wide variety of heteroaryl small molecule, oligomer, polymer, and co-polymer compounds having at least two coupled heteroaryl rings.

One embodiment provides a method for synthesizing a fused tricyclic compound comprising the structure

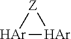

wherein
HAr a five or six membered heteroaryl group,
Z is C═C(CN)₂, or [C═C(CN₂)]₂,

the method comprising:
providing an optionally substituted precursor compound comprising a halo-heteroaryl ring having an Hal substituent at a first position on the HAr ring;
treating the precursor compound with a strongly basic compound to induce the isomerization of the precursor compound to produce an intermediate compound wherein the Hal atom is bound to a different position on the HAr ring;
treating the intermediate compound with an oxidizing agent so as to form a carbon-carbon bond between two intermediate compounds and thereby form the bishalo-bisheteroaryl compound.
optionally treating the bishalo-bisheteroaryl compound with an organometallic compound to exchange a metal for the Hal substituents, and form a bismetallo-bisheteroaryl compound, and
reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

Another embodiment provides a composition represented by at least one of:

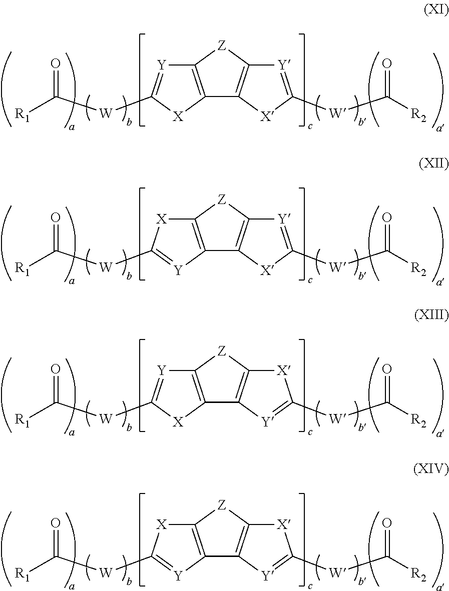

wherein independently a is 0 or 1, and a′ is 0 or 1;
wherein R₁ and R₂ independently are alkyl, fluoroalkyl, aryl, fluoroaryl, heteroaryl, arylalkyl, or heteroarylalkyl;
wherein W and W′ independently comprise at least one heteroarylene group;
wherein b and b′ independently are 0, 1, 2, 3, or 4;
wherein c is 1, 2, 3, or 4;
wherein X and X′ independently are O, S, Se, NR³, PR³, or Si(R³)₂, wherein R³ is alkyl, heteroalkyl, or alkylaryl;
wherein Y and Y′ independently are N, P, CH, CR⁴, or SiR⁴. wherein R⁴ is H, alkyl, fluorinated alkyl, aryl, fluorinated aryl, or heteroaryl;
wherein Z is C═C(CN)₂, or [C═C(CN₂)]₂.

Additional embodiment provide for compounds, compositions and devices as further elaborated in detail below.

The various genera and subgenera of compounds of Formula (II) or (IIa), prepared by the methods of the invention, can be readily further functionalized and/or elaborated to produce a wide variety of known and new downstream compounds, oligomers, or polymers that are useful for many purposes, including for the preparation of compounds and compositions for making electronic devices, such as transistors, solar cells, light emitting diodes, and the like.

Further detailed description of preferred embodiments of the various inventions broadly outlined above will be provided below in the Detailed Description section provided below.

### BRIEF DESCRIPTION OF THE FIGURES

FIG. 1 discloses the cyclic voltammogram of 2,7-bis-(5-n-nonyl-thiophen-2-yl)-benzo[1,2-b:6,5-b′]dithiophene-4,5-di-(1,3-dioxolane) disclosed in Example 30, Step 1.

FIG. 2 discloses the cyclic voltammogram and DPV of 2,7-bis-(5-pentafluorobenzoyl-thiophene-2-yl)-benzo[2,1-b:3,4-b′]dithiazole-4,5-di-(1,3-dioxolane) as embodied in Example 31, Step 5.

FIG. 3 discloses the cyclic voltammogram of 2-(5-pentafluorobenzoyl-thiophen-2-yl)-7-(thiophen-2-yl)-benzo[1,2-b:6,5-b′]dithiophene-4,5-bis(ethyleneoxolane) as embodied in Example 34, Step 1.

FIG. 4 discloses the cyclic voltammogram and DPV of 2-(5-pentafluorobenzoyl-thiophen-2-yl)-7-(thiophen-2-yl)-benzo[1,2-b:6,5-b′]dithiophene-4,5-dione as embodied in Example 34, Step 2.

FIG. 5 discloses the cyclic voltammogram of 7,7′-bis-pentafluorobenzoyl-2,2′-bis-benzo[1,2-b:6,5-b′]dithiophene-4,5-bis(ethyleneoxolane) as embodied in Example 33, Step 2.

FIG. 6 discloses differential pulse voltammetry (DPV) of 7,7′-bis-pentafluorobenzoyl-2,2′-bis-benzo[1,2-b:6,5-b′]dithiophene-4,5-dione as embodied in Example 33, Step 3.

FIG. 7 discloses OFET results for an acyl compound as described in Example 40.

FIG. 8 discloses OFET results for a thiazole compound also as described in Example 40.

FIG. 9 illustrates FET device architecture.

FIG. 10 discloses OFET results for a compound as described in Example 41.

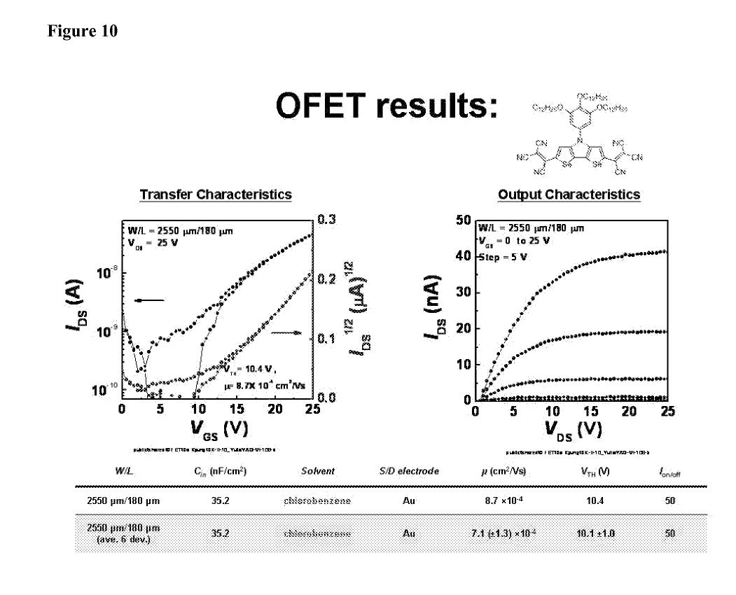

FIG. 11 discloses OFET results for another compound as described in Example 41.

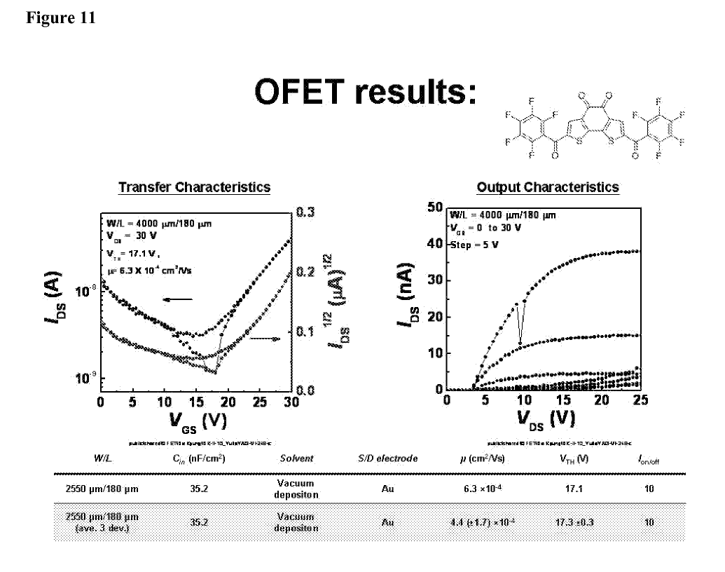

FIG. 12 discloses OFET results for an additional compound as described in Example 41.

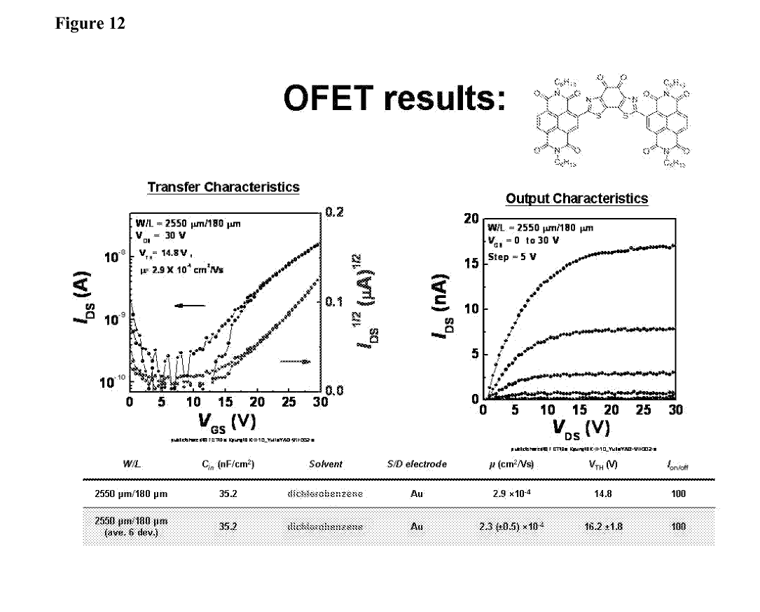

FIG. 13. discloses cyclic voltammogram of 2,7-bis-(3,4,5-trifluorobenzoyl)-benzo[1,2-b:6,5-b′]dithiophene-4,5-bis-(1,3-dioxolane) of Example 44.

FIG. 14 discloses CV analyses of (a) 6,9-bis(trimethylsilyl)dithieno[3,2-f:2′,3′-h]quinoxaline-2,3-dicarbonitrile (S3): E_{1/2}^{0/1-}=−1.43 V (partially reversible) and (b) 2,5,9,12-tetrakis(trimethylsilyl)tetrathieno[3,2-a:2′,3′-c:3″,2″-h:2′″,3′″-j]phenazin.

### DETAILED DESCRIPTION OF THE INVENTION

The various inventions and/or their embodiments disclosed herein relate to new methods for making heteroaryl compounds of Formula (I) having at least two coupled heteroaryl rings and two halogens, which employ a sequence of reactions that involve the use of the Base-Catalyzed Halogen Dance (BCHD) reaction to prepare optionally substituted heteroaryl intermediates (in-situ), which are then oxidatively coupled, to prepare a very wide variety of bishalo-bisheteroaryl compounds having at least two coupled heteroaryl rings. Many of the bishalo-bisheteroaryl compounds can then be used to prepare a wide variety of fused tricyclic compounds of Formula (II) as shown above and below, and oligomers, polymers, and copolymers derived therefrom. Such compounds can be used to prepare chemical compositions for making electronic devices, such as transistors, solar cells, light emitting diodes, and the like. In addition they can be used to make various light absorbing materials that could have applications in the fields of sensing, nonlinear optics, optical limiting, as well.

Nevertheless, before describing the many possible embodiments of the inventions described herein, it is desirable to set forth certain relevant definitions.

### DEFINITIONS

Throughout the application, where compositions are described as having, including, or comprising specific components, or where processes are described as having, including, or comprising specific process steps, it is contemplated that compositions of the present teachings also consist essentially of, or consist of, the recited components, and that the processes of the present teachings also consist essentially of, or consist of, the recited process steps.

In the application, where an element or component is said to be included in and/or selected from a list of recited elements or components, it should be understood that the element or component can be any one of the recited elements or components and can be individually selected from a group consisting of two or more of the recited elements or components.

In addition, where the use of the term “about” is presented before a quantitative value, the present teachings also include the specific quantitative value itself, unless specifically stated otherwise. In some embodiments, the term “about” can refer to a +−10% variation from the nominal value stated.

It should be understood that the order of steps or order for performing certain actions can be immaterial so long as the methods disclosed herein remain operable. Moreover, two or more steps or actions may also be conducted simultaneously, so long as the methods disclosed herein remain operable.

As used herein, a “polymer” or “polymeric compound” refers to a molecule (e.g., a macromolecule) including a plurality of one or more repeating units connected by covalent chemical bonds. A polymer can be represented by the general formula:

Mₙ

wherein M is the repeating unit or monomer, and n is the number of M's in the polymer. For example, if n is 3, the polymer shown above is understood to be:

M-M-M.

The polymer or polymeric compound can have only one type of repeating unit as well as two or more types of different repeating units. In the former case, the polymer can be referred to as a homopolymer. In the latter case, the term “copolymer” or “copolymeric compound” can be used instead, especially when the polymer includes chemically significantly different repeating units. The polymer or polymeric compound can be linear or branched. Unless specified otherwise, the assembly of the repeating units in the copolymer can be head-to-tail, head-to-head, or tail-to-tail. In addition, unless specified otherwise, the copolymer can be a random copolymer, an alternating copolymer, or a block copolymer.

As used herein, “halo” or “halogen” refers to fluoro, chloro, bromo, and iodo.

As used herein, “oxo” refers to a double-bonded oxygen (i.e., ═O).

As used herein, “alkyl” refers to a straight-chain or branched saturated hydrocarbon group. Examples of alkyl groups include methyl (Me), ethyl (Et), propyl (e.g., -propyl and /iso-propyl), butyl (e.g., n-butyl, iso-butyl, sec-butyl, tert-butyl), pentyl groups (e.g., n-pentyl, neopentyl), hexyl groups, and the like. In various embodiments, an alkyl group can have 1 to 40 carbon atoms (i.e., C₁₋₄₀ alkyl group), or, 1-20 carbon atoms (i.e., C₁₋₂₀ alkyl group). In some embodiments, an alkyl group can have 1 to 6 carbon atoms, and can be referred to as a “lower alkyl group”. Examples of lower alkyl groups include methyl, ethyl, propyl (e.g., n-propyl and iso-propyl), and butyl groups (e.g., n-butyl, sec-butyl, tert-butyl). In some embodiments, alkyl groups can be substituted as described herein. An alkyl group is generally not substituted with another alkyl group, an alkenyl group, or an alkynyl group.

As used herein, “haloalkyl” refers to an alkyl group having one or more halogen substituents. At various embodiments, a haloalkyl group can have 1 to 40 carbon atoms (i.e., C₁₋₄₀ haloalkyl group), for example, 1 to 20 carbon atoms (i.e., C₁₋₂₀ haloalkyl group). Examples of haloalkyl groups include CF₃, C₂F₅, CHF₂, CH₂F, CCl₃, CHCl₂, CH₂Cl, C₂Cl₅, and the like. Perhaloalkyl groups, i.e., alkyl groups where all of the hydrogen atoms are replaced with halogen atoms (e.g., CF₃ and C₂F₅), are included within the definition of “haloalkyl.”

As used herein, “alkoxy” refers to —O-alkyl group. Examples of alkoxy groups include, but are not limited to, methoxy, ethoxy, propoxy (e.g., n-propoxy and iso-propoxy), t-butoxy, pentoxy, hexoxy groups, and the like. The alkyl group in the —O-alkyl group can be substituted as described herein.

As used herein, “cycloalkyl” refers to a non-aromatic carbocyclic group including cyclized alkyl, alkenyl, and alkynyl groups. In various embodiments, a cycloalkyl group can have 3 to 22 carbon atoms, for example, 3 to 20 carbon atoms (e.g., C₃₋₁₄ cycloalkyl group). A cycloalkyl group can be monocyclic (e.g., cyclohexyl) or polycyclic (e.g., containing fused, bridged, and/or spiro ring systems), where the carbon atoms are located inside or outside of the ring system. Any suitable ring position of the cycloalkyl group can be covalently linked to the defined chemical structure. Examples of cycloalkyl groups include cyclopropyl, cyclobutyl, cyclopentyl, cyclohexyl, cycloheptyl, cyclopentenyl, cyclohexenyl, cyclohexadienyl, cycloheptatrienyl, norbornyl, norpinyl, norcaryl, adamantyl, and spiro[4.5]decanyl groups, as well as their homologs, isomers, and the like. In some embodiments, cycloalkyl groups can be substituted as described herein.

As used herein, “heteroatom” refers to an atom of any element other than carbon or hydrogen and includes, for example, nitrogen, oxygen, silicon, sulfur, phosphorus, and selenium.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have 6 to 24 carbon atoms in its ring system (e.g., C₆₋₂₀ aryl group), which can include multiple fused rings. In some embodiments, a polycyclic aryl group can have 8 to 24 carbon atoms. Any suitable ring position of the aryl group can be covalently linked to the defined chemical structure. Examples of aryl groups having only aromatic carbocyclic ring(s) include phenyl, 1-naphthyl (bicyclic), 2-naphthyl (bicyclic), anthracenyl (tricyclic), phenanthrenyl (tricyclic), pentacenyl (pentacyclic), and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system).

As used herein, “heteroaryl” refers to an aromatic ring system containing at least one ring heteroatom selected from, for example, oxygen (O), nitrogen (N), sulfur (S), silicon (Si), and selenium (Se). The heteroaryl rings typically comprise a five or six membered aromatic ring, which may however be bonded to additional rings, so as to form a polycyclic ring system where at least one of the rings present in the ring system is aromatic and contains at least one ring heteroatom. Polycyclic heteroaryl groups include those having two or more heteroaryl rings fused together, as well as those having at least one monocyclic heteroaryl ring fused to one or more aromatic carbocyclic rings, non-aromatic carbocyclic rings, and/or non-aromatic cycloheteroalkyl rings. A heteroaryl group, as a whole, can have, for example, 5 to 24 ring atoms and contain 1-5 ring heteroatoms (i.e., 5-20 membered heteroaryl group). The heteroaryl group can be attached to the defined chemical structure at any heteroatom or carbon atom that results in a stable structure. Generally, heteroaryl rings do not contain O—O, S—S, or S—O bonds. However, one or more N or S atoms in a heteroaryl group can be oxidized (e.g., pyridine N-oxide, thiophene S-oxide, thiophene S,S-dioxide). Examples of heteroaryl groups include, for example, the 5- or 6-membered monocyclic and 5-6 bicyclic ring systems shown below:

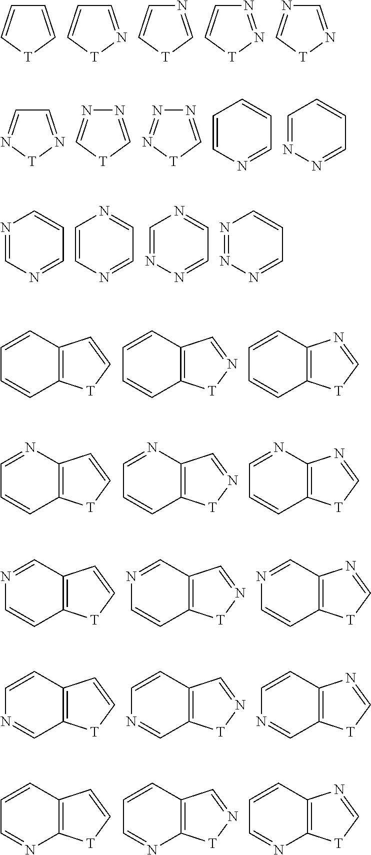

where T is O, S, NH, N-alkyl, N-aryl, N-(arylalkyl) (e.g., N-benzyl), SiH₂, SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzotbiazolyl, benzisothiazolyl, benzisoxazolyl, benzoxadiazolyl, benzoxazolyl, cinnolinyl, 1H-indazolyl, 2H-indazolyl, indolizinyl, isobenzofuryl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be substituted as described herein.

Heteroaryl groups are not limited to those described above, and may be further described within the present specification or claims.

As used herein, a “p-type semiconductor material” or a “p-type semiconductor” refers to a semiconductor material having holes as the majority current carriers. In some embodiments, when a p-type semiconductor material is deposited on a substrate, it can provide a hole mobility in excess of about 10⁻⁵ cm²/Vs. In the case of field-effect devices, a p-type semiconductor can also exhibit a current on/off ratio of greater than about 10, or preferably greater than about 10⁵.

As used herein, an “n-type semiconductor material” or an “n-type semiconductor” refers to a semiconductor material having electrons as the majority current carriers. In some embodiments, when an n-type semiconductor material is deposited on a substrate, it can provide an electron mobility in excess of about 10⁻⁵ cm²/Vs. In the case of field-effect devices, an n-type semiconductor can also exhibit a current on/off ratio of greater than about 10, or preferably greater than about 10⁵.

As used herein, “solution-processable” refers to compounds (e.g., polymers), materials, or compositions that can be used in various solution-phase processes including spin-coating, printing (e.g., inkjet printing, screen printing, pad printing, offset printing, gravure printing, flexographic printing, lithographic printing, mass-printing and the like), spray coating, electrospray coating, drop casting, dip coating, and blade coating.

Methods for Synthesizing Bishalo-Bisheteroaryl Compounds

The various inventions and/or their embodiments disclosed herein relate to new methods for making heteroaryl compounds having at least two coupled heteroaryl rings and two halogens, via a sequence of reactions that involve the use of the Base-Catalyzed Halogen Dance (BCHD) reaction to prepare optionally substituted heteroaryl intermediates that have a halogen (especially Br or I) bonded to the heteroaryl ring, and also typically have a main group metal (such as Li or Mg) bonded to the ring. The highly reactive metallated and halogenated heteroaryl rings produced by a BCHD reaction are then oxidatively coupled, to prepare a very wide variety of heteroaryl compounds having at least two coupled heteroaryl rings and two halogens.

In many embodiments, the inventions relate to various methods for synthesizing a bishalo-bisheteroaryl compound of Formula (I)

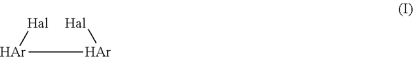

wherein HAr is an optionally substituted five or six membered heteroaryl ring, which comprises at least one ring carbon atom and at least one ring heteroatom, and Hal is a halogen, especially Br or I. In many embodiments of the methods, HAr is a five membered heteroaryl ring that may optionally be substituted with additional organic or inorganic substituent groups, including additional aryl or heteroaryl rings. In various embodiments, the HAr ring and its optional substituents together comprise between 1 to 50, or 2 to 40, or 3 to 30 carbon atoms.

The method for synthesizing the compounds of Formula (I) comprise at least the following steps:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate halo-heteroaryl compound with an oxidizing agent so as to form a carbon-carbon bond between two intermediate halo-heteroaryl compounds and thereby form the bishalo-bisheteroaryl compound.

The optionally substituted precursor compound comprises at least one halo-heteroaryl ring having the Hal substituent (typically Br or I) at a first position on the HAr ring, but may also have other organic or inorganic ring substituents, including additional halides, and other aryl or heteroaryl ring at other positions of the HAr heteroaryl ring. A preferred group of ring substituents for HAr include aryl or heteroaryl rings, fluoride, cyano, alkyl, alkynyl, alkoxy, perfluoroalkyl, and perfluoroalkoxy groups that can significantly modulate the electronic properties of the HAr ring, modify the solubilities or other physical properties, and/or are substantially chemically stable after oxidation by holes or reduction by the electrons used as current carriers in electronic devices. The ring substituents for HAr can also be certain functional groups such as trialkyltin, trialkylsilicon, trialkoxysilicon, or organoborate ester groups that are well known as useful for subsequent cross-coupling with or polymerization of the compounds of Formula (I) or (II).

In many embodiments, the precursor compound for the methods of synthesis is also the precursor for the HAr rings, and have the structure

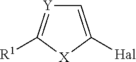

wherein

R¹ is a halide, or an optionally substituted organic radical;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

Preferred R¹ organic radicals, which can be attached to the five-membered heteroaryl ring at the position indicated in the drawing either before or after the halogen dance/oxidative coupling reaction steps, can be an C₁-C₃₀ organic radical, such as for example an alkyl, alkynyl, aryl, heteroaryl, —Sn(R²)₃ (triorganotin), —Si(R²)₃ (triorganosilyl), Si(OR²)₃ (trialkoxysilyl) or —B(—OR²¹)₂ (organoborate ester) group wherein each R² is an independently selected alkyl or aryl, and each R²¹ is an independently selected alkyl or aryl, or the R²¹ groups together form an optionally substituted alkylene group bridging the oxygen atoms.

Preferred triorganotin radicals include trialkyltin radicals, especially tributyltin and trimethyltin radicals, which are well known for their use in palladium-catalyzed Stille coupling and/or polymerization reactions with organic halides, especially aryl or heteroaryl bromides or iodides. Preferred triorganosilyl radicals include trialkylsilyl radicals, especially trimethylsilyl (TMS) radicals or triisopropylsilyl (TIPS) radicals, which can be easily converted to halides such as bromides and iodides, or directly react in the Hiyama coupling (for activated TMS groups). Preferred trialkoxysilyl radicals include trimethoxysilyl, or triethoxylsilyl, or tripropoxysilyl radicals. Preferred organoborate ester groups comprise alkyl groups at R², or are pinnacol borate radicals (ie. 4,4,5,5-tetramethyl-1,3,2-dioxaborolane groups having the structure shown below, which are well known for their reactivity in palladium catalyzed Suzuki coupling reactions with other organic halides, especially aryl or heteroaryl halides:

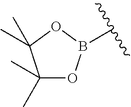 [SMILES: *B1OC(C)(C)C(C)(C)O1]

In many embodiments, the R¹ radicals are aryl or heteroaryl radicals that can themselves be optionally substituted. For example, R¹ can be a C₁-C₃₀ aryl (such as phenyl, napthyl, biphenyl, and the like as described elsewhere herein), or heteroaryl (such as thiophene, pyrrole, thiazole, or the like as described elsewhere herein), optionally substituted by one to four ring substituents independently selected from halides, alkyl, alkynyl, cyano, perfluoroalkyl, alkoxide, perfluoroalkoxide, —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In some embodiments, R¹ can be an optionally substituted C₁-C₃₀ alkynyl radical, such as those having the structure —C≡C—R², wherein R² can be hydrogen, —Si(R²)₃, wherein each R² is an independently selected alkyl or aryl, or an optionally substituted alkyl, aryl, or heteroaryl.

In some preferred embodiments, the R¹ radicals can be either optionally substituted aryl or heteroaryls having a relatively electron-rich conjugated π electron system that can function as “electron donor” “co-monomer”, or a relatively electron-poor conjugated π electron system that can function as “electron acceptor” “co-monomer”, for the preparation of oligomeric compounds that are useful for making downstream “low bandgap” copolymers capable of efficiently conducting holes or electrons. Non-limiting examples of desirable electron rich R¹ radicals include the various heteroaryls shown below:

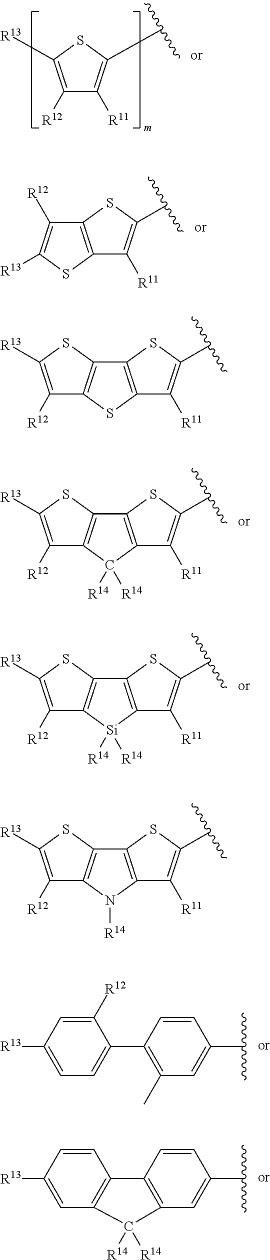

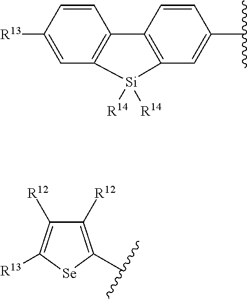

R¹ can also be a relatively electron poor heteroaryl radical, such as for example one of the formulas shown below:

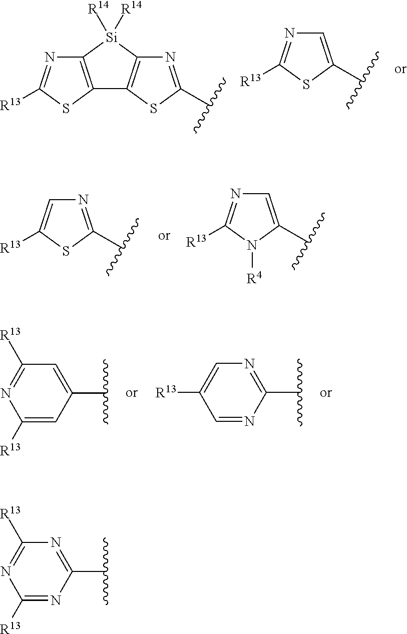

In connection with substituents for the R¹ aryl or heteroaryl groups described above, R¹¹, R¹², R¹⁴ can be any C₁-C₃₀ organic radical, such as but not limited to a C₁-C₁₈ alkyl, perfluoroalkyl, or alkoxy group, and R¹³ can be hydrogen, halide, any C₁-C₃₀ organic radical, such as but not limited to a C₁-C₁₈ alkyl, perfluoroalkyl, or alkoxy group, including Si(R²)₃, Si(OR²)₃, —B(—OR²¹)₂, or Sn(R²)₃.

In many embodiments, the R¹ radicals are “terminal” aryl or heteroaryl radicals, such as the electron poor radicals shown below:

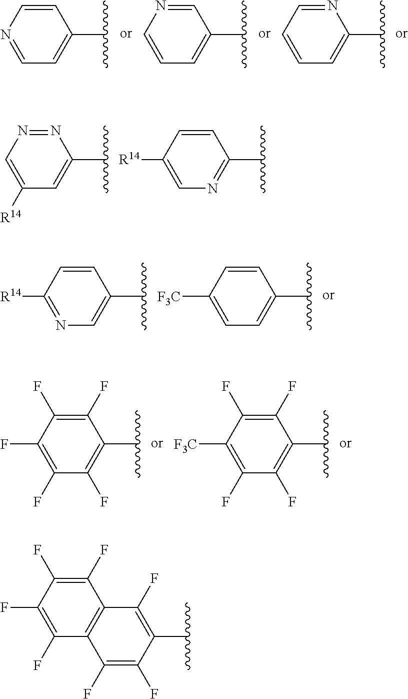

In additional related embodiments, the precursor compounds used for the synthesis of compounds of Formula (I) can have the structure shown below:

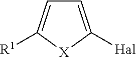

wherein

R¹ and Hal can be defined in any of the ways described above; and

X is S, Se or NR³ wherein R³ is a C₁-C₁₈ alkyl, perfluoroalkyl, aryl, or heteroaryl. In some embodiments, R³ is CF₃.

In additional related embodiments, the precursor compounds used for the synthesis of compounds of Formula (I) can be the thiazole or imidazole derivatives shown below:

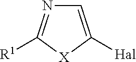

wherein

R¹ and Hal can be defined in any of the ways described above; and

X is S or NR³ wherein R³ is a C₁-C₁₈ alkyl, perfluoroalkyl, aryl, or heteroaryl. In some embodiments, R³ is CF₃.

In additional related embodiments, the precursor compounds used for the synthesis of compounds of Formula (I) can be the thiazoles shown below:

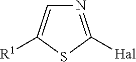

wherein

R¹ and Hal can be defined in any of the ways described above.

It will be appreciated that many methods for synthesizing many of the various precursor compounds described above are known to those of ordinary skill in the art, or are commercially available from well known suppliers. Exemplary methods for synthesizing some of the precursor compounds are provided below. It should also be noted that one kind of R¹ substituent (such as —SiR₃ groups) may be initially present before the Halogen Dance/oxidative coupling reaction sequences are employed, but that the initial R¹ group (such as halide or —SiR₃ groups) could then be optionally removed and replaced with a different R¹ group, such as an aryl or heteroaryl, or SnR₃ or organoborate ester group.

The method for synthesizing the bishalo-bisheteroaryl compounds of Formula (I) described and claimed herein typically comprise at least the following steps, which relates to performance of the Base-Catalyzed Halogen Dance portion of the reaction sequence:

treating the precursor compound with a strongly basic compound to induce the isomerization of the precursor compound to produce an intermediate compound wherein the Hal atom is bound to a different position on the HAr ring;

The strongly basic compounds used to initiate the “Base-Catalyzed Halogen Dance” reaction can be any compound that is sufficiently strongly basic to deprotonate one of the ring hydrogens of the precursor compound, to form the reactive equivalent of an organic anion on the deprotonated carbon in the ring of the precursor compound. In practice, the strongly basic compounds employed are typically organometallic compounds of Group I or Group II metals, especially organolithium or organomagnesium compounds. In many embodiments, the strongly basic compound employed can be a lithium dialkylamide (such as for example lithium diisopropyl amide).

Typically, the “Base-Catalyzed Halogen Dance” rearrangement reaction corresponding to step b recited above is initiated by addition of a small molar excess (for example about 1.1 equivalents) of the strongly basic compound to a solution of the precursor compound. Without wishing to be bound by theory, it is believed that this practice typically results in the deprotonation of a hydrogen atom of the precursor compound and concurrent formation of an organometallic (usually lithium) salt of the precursor compound as a highly reactive “in-situ” intermediate, which undergoes isomerization to form thermodynamically more stable species. During the reaction, the base present also initiates a sequence of lithium-halogen exchange reactions, which can have the effect of moving/isomerizing the halogen atom of the precursor compound (Hal) to a more thermodynamically stable position on the ring of the precursor compound. This “Base-Catalyzed Halogen Dance” reaction sequence, which produces a highly reactive organometallic intermediate compound wherein the Hal atom is bound to a different position on the HAr ring” can be conceptually illustrated by the diagram below:

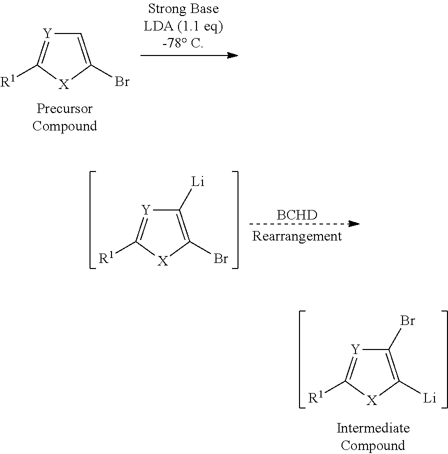

In some of the methods embodied herein, the rearranged and often highly reactive intermediate compound is then subjected to an oxidative coupling step, as recited below.

treating the intermediate compound with an oxidizing agent so as to form a carbon-carbon bond between two intermediate compounds and thereby form the bishalo-bisheteroaryl compound.

A wide variety of oxidizing agents can be used to treat the intermediate compound and form the bishalo-bisheteroaryl compound. For example, thionyl chloride and a variety of copper (II) salts can be employed. CuCl₂ is employed as an oxidizing agent in many embodiments of the methods of the invention. A schematic diagram illustrating the oxidation reaction and formation of the bishalo-bisheteroaryl compound is shown below.

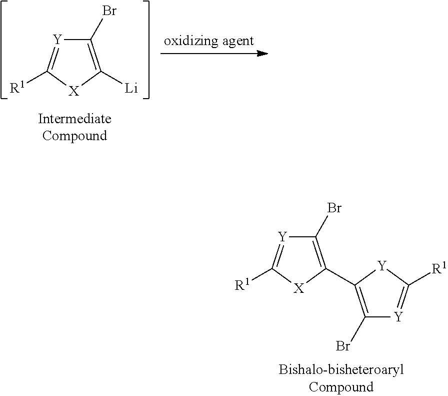

The product bishalo-bisheteroaryl compounds can be readily purified and isolated by many of the methods well known in the art, including extraction, distillation, crystallization, sublimation, or chromatography.

A general synthetic procedure for carrying out some of the synthetic methods described above and claimed below is as follows: A heteroaryl bromide is dissolved in anhydrous THF and the solution cooled in acetone/dry ice bath under nitrogen atmosphere. Lithium diisopropyl amide (LDA) (1.1 eq.) is added dropwise and the progress of the BCHD reaction monitored by GC/MS and/or ¹H NMR. After BCHD reaction completion, CuCl₂ (1.1 eq.) is added in one portion, the mixture stirred at −78° C. for a few hours and then warmed to room temperature. The reaction mixture is diluted with hexanes and water, the organic phase is removed and the aqueous phase is extracted with hexanes several times. The combined organic phases are dried over MgSO₄, the solvents were removed by rotary evaporation, the residue is dissolved in hexanes or other suitable solvent and the solution is filtered through a plug of silica gel. The product can be further purified by crystallization, sublimation, column chromatography, Kugelrohr distillation, or many other techniques well known to those of ordinary skill in the art.

Examples of sub-generic classes of bishalo-bisheteroaryl compounds that can be synthesized via the methods of the invention have Formula (Ia) shown below:

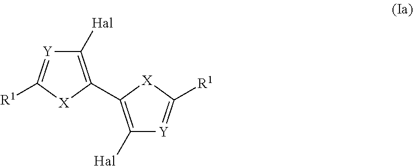

wherein R¹, X, Y, and Hal can be defined in any of the ways already detailed above, or as follows:

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃, or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl;

In Formulas I, Ia, and their various subgenera described herein, Hal can be a halogen, including F, Cl, Br, or I. In many embodiments Hal is Br or I, or in many cases Br.

Examples of other sub-generic classes of bishalo-bisheteroaryl compounds that can be synthesized via the methods of the invention are shown below:

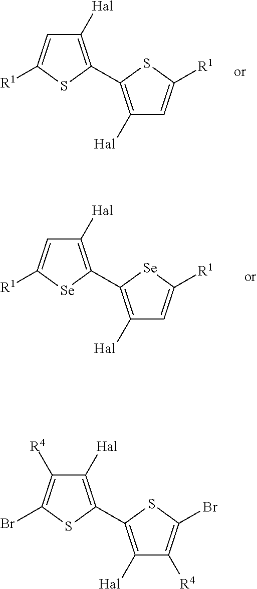

wherein R¹, X, Y, and Hal can be defined in any of the ways already detailed above, especially wherein Hal is Br, or as follows:

R¹ is a halide, or a C₁-C₃₀ organic radical selected from optionally substituted alkyl, alkynyl, aryl, heteroaryl, or —Sn(R²)₃, —Si(R²)₃, —Si(OR²)₃, or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R⁴ is a C₁-C₁₈ alkyl, aryl, or heteroaryl.

Additional examples of sub-generic classes of bishalo-bisheteroaryl compounds that can be synthesized via the methods of the invention are shown below:

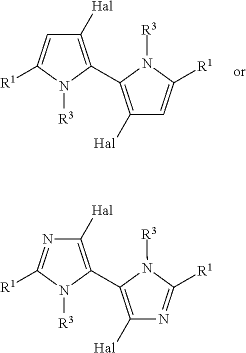

wherein R¹, X, Y, and Hal can be defined in any of the ways already detailed above, or as follows:

R¹ is a halide, or a C₁-C₃₀ organic radical selected from optionally substituted alkyl, alkynyl, aryl, heteroaryl, or —Sn(R²)₃, —Si(R²)₃, Si(OR²)₃, or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R³ is a C₁-C₁₈ alkyl, perfluoroalkyl, aryl, or heteroaryl.

Yet further examples of sub-generic classes of bishalo-bisheteroaryl compounds that can be synthesized via the methods of the invention are shown below:

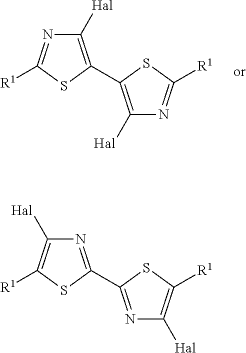

wherein R¹, X, Y, and Hal can be defined in any of the ways already detailed above, or wherein R¹ or a C₁-C₃₀ organic radical selected from optionally substituted alkyl, alkynyl, aryl, heteroaryl, or —Sn(R²)₃, —Si(R²)₃, Si(OR²)₃, or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

It should also be noted that for any of the sub-generic classes of bishalo-bisheteroaryl compounds described above, in some embodiments R¹ can have the structures shown below:

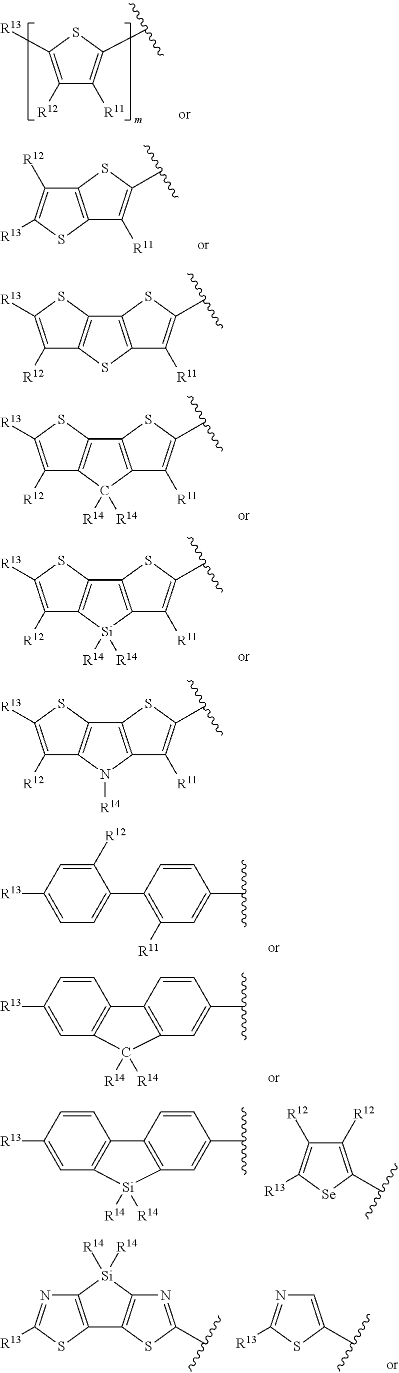

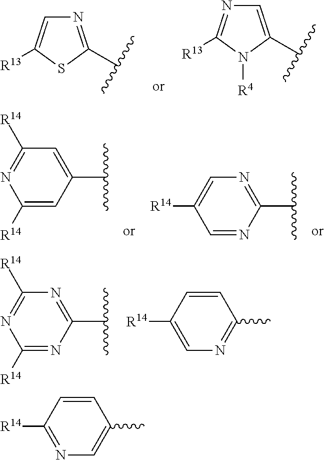

wherein m is 1, 2, 3, or 4, and R¹¹, R¹², R¹⁴ are hydrogen or a C₁-C₁₈ alkyl, perfluoroalkyl, alkoxy, or perfluoroalkoxy group, and R¹³ is hydrogen, —B(—OR²¹)₂, Si(R²)₃, or Sn(R²)₃, wherein each R² is an independently selected alkyl or aryl, and each R²¹ is an independently selected alkyl or aryl, or the R²¹ groups together form an optionally substituted alkylene group to form a ring bridging the oxygen atoms.

Suitable starting materials for preparing compounds of Formula (I) having two thiazole rings and having a variety of aryl or heteroaryl substituents at R¹ can often be prepared by the generic synthetic procedure illustrated in the diagram below:

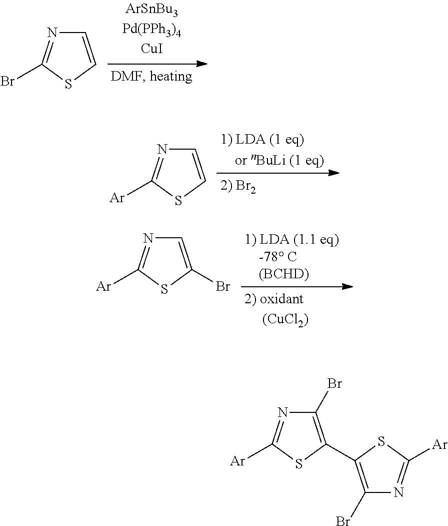

Specific examples of bishalo-bisheteroaryl compounds that have been synthesized by the methods of the invention are shown in Table 1 shown below, and further examples provided in the Examples Section below.

TABLE 1
Examples of compounds synthesized via the sequence of BCHD rearrangement-CuCl₂ oxidative coupling.

| Entry | Substrate | Product | Isolated Yield, % |
|---|---|---|---|
| 1 | 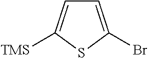 | 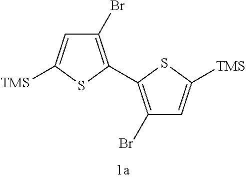 [SMILES: C[Si](C)(C)c1cc(Br)c(-c2sc([Si](C)(C)C)cc2Br)s1] | 60-84 |
| 2 | 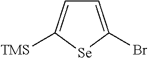 | 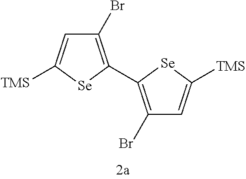 [SMILES: C[Si](C)(C)c1cc(Br)c(-c2[se]c([Si](C)(C)C)cc2Br)[se]1] | 50-66 |
| 3 | 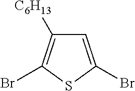 | 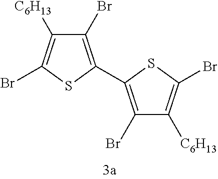 | 81-87 |
| 4 | 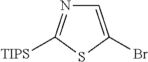 | 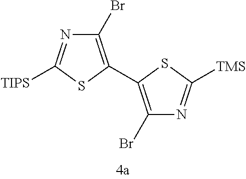 | 60-82 |
| 5 | 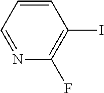 | 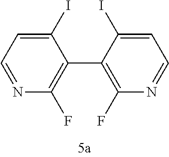 [SMILES: Fc1nccc(I)c1-c1c(I)ccnc1F] | 60 |
| 6 | 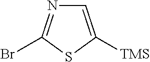 | 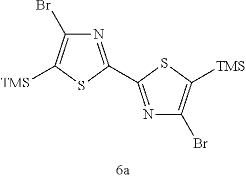 [SMILES: C[Si](C)(C)c1sc(-c2nc(Br)c([Si](C)(C)C)s2)nc1Br] | 35-68 |
| 7 | 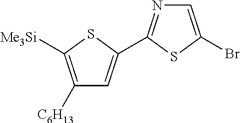 | 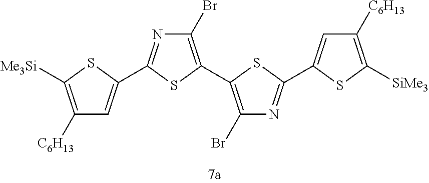 | 67% (after 1^{st} column) |

Methods for Synthesizing Fused Tricyclic Compounds

The ready availability of a wide variety of bishalo-bisheteroaryl compounds of Formula (I) via the synthetic methods described above provides a wide variety of starting materials for the synthesis of a wide variety of fused tricyclic compounds of Formula (II), as shown below:

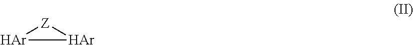

wherein

HAr can be any of the optionally substituted heteroaryl ring radicals disclosed elsewhere herein, and

Z is a bridging group, such as S, Se, NR⁵, C(O), C(O)C(O), Si(R⁵)₂, SO, SO₂, PR⁵, P(O)R⁵, BR⁵, C(R⁵)₂, C(C(CN)₂)C(C(CN)₂), or C(C(CN)₂) wherein R⁵ is an organic radical.

Many fused tricyclic compounds of Formula (II) can be prepared by additionally

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

Restating the method steps above, in some embodiments, the invention relates to multi-step methods of making fused tricyclic compounds of Formula (II), comprising the structure

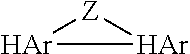

wherein

HAr is an optionally substituted five or six membered heteroaryl ring comprising at least one ring carbon atom and at least one ring heteroatom,

Z is S, Se, NR⁵, C(O), C(O)C(O), Si(R⁵)₂, SO, SO₂, PR⁵, P(O)R⁵, BR⁵, C(R⁵)₂, C(C(CN)₂)C(C(CN)₂), or C(C(CN)₂) wherein R⁵ is a C₁-C₅₀ organic radical selected from optionally substituted alkyl, perfluoroalkyl, aryl, and heteroaryl,

wherein the method comprises the steps of

providing an optionally substituted precursor compound comprising a halo-heteroaryl ring having an Hal substituent at a first position on the HAr ring, and Hal is a halogen, and

treating the precursor compound with a strongly basic compound to induce the isomerization of the precursor compound to produce an intermediate compound wherein the Hal atom is bound to a different position on the HAr ring; and

treating the intermediate compound with an oxidizing agent so as to form a carbon-carbon bond between two intermediate compounds and thereby form the bishalo-bisheteroaryl compound having the structure

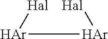

and

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or
reacting the bishalo-bisheteroaryl compound or bismetallo-bisheteroaryl compound with a nucleophile, to introduce the Z group, or a precursor thereof suitable for forming the fused tricyclic compound.

In some embodiments of such methods of making the fused tricyclic compounds of Formula (I), the halogenated positions of the bishalo-bisheteroaryl compounds of Formula (I) can condensed with nucleophilic reagents that comprise the Z group. Consider for example the following exemplary condensation reaction of a bishalo-bisheteroaryl compound with a nucleophilic amine compound in the presence of a palladium catalyst, whose details are presented below in Example 10. or a similar novel selenium derivative:

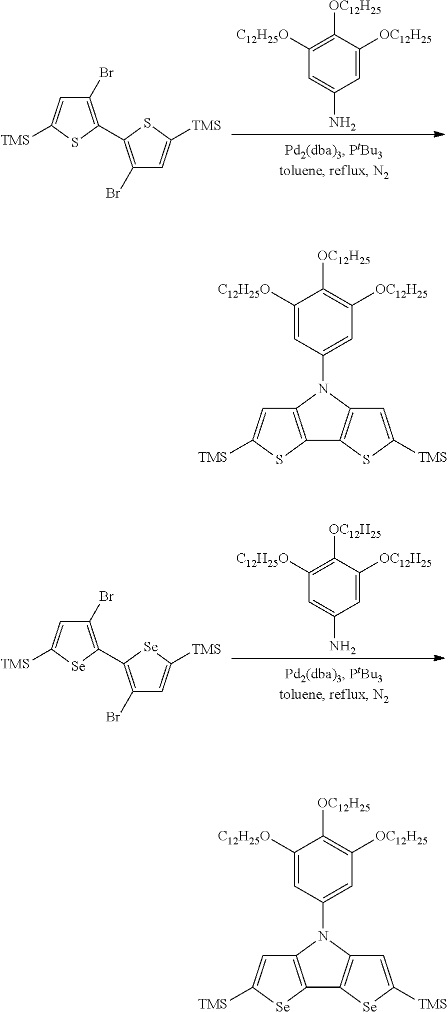

In other embodiments of the methods of making the fused tricyclic compounds, the bishalo-bisheteroaryl compound is first reacted with an organometallic compound to exchange a metal for the Hal substituents, and thereby form a nucleophilic bismetallo-bisheteroaryl compound, which is then condensed with an electrophilic source of the Z radical, to form a subclass of fused tricyclic compounds of Formula (IIa), as shown below:

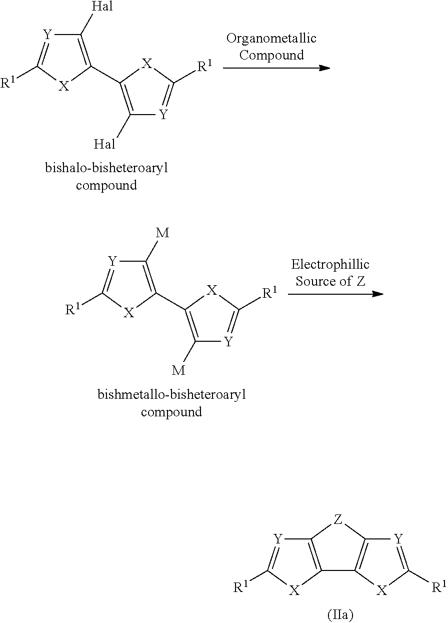

As indicated in the diagram above, the organometallic compound used to react with and activate the bishalo-bisheteroaryl compound and form a bismetallo-bisheteroaryl compound, which is then reacted with a suitable source of the Z radical. Suitable organometallic compounds for activating the bishalo-bisheteroaryl compound include highly basic and/or nucleophilic main group organometallic compounds such as organolithium compounds (such as n-butyl lithium), or organomagnesium compounds. Other suitable organometallic compounds for activating the bishalo-bisheteroaryl compound include various transition metal catalyst compounds, especially late transition metals from Groups VIII, IB, or IIB.

In many embodiments of the methods, the electrophilic source of the Z radical can be a compound V—R⁶—V′, where R⁶ is selected from S, Se, NR⁵, C(O), C(O)C(O), Si(R⁵)₂, SO, SO₂, PR⁵, P(O)R⁵, BR⁵, C(R⁵)₂, C(C(CN)₂)C(C(CN)₂), or C(C(CN)₂) and V and V′ are leaving groups, or V and V′ together form a leaving group suitable for a condensation reaction with the bismetallo-bisheteroaryl compound, to form the fused tricyclic compound. In many embodiments, R⁵ is an optionally substituted organic radical selected from alkyl, perfluoroalkyl, alkoxide, aryl, heteroaryl, or the like. R⁵ has between one and 50 carbon atoms, or between 2 and 30 carbon atoms. In many embodiments, V and/or V′ are halides such as Cl, Br or I, or other similar anionic leaving groups.

Specific examples of suitable V—R⁶—V′ reagents for introducing the Z radicals include but are not limited to dimethylcarbamoyl chloride (for introducing a CO group), diethyl oxalate (for introducing α-dicarbonyl groups), Cl₂SiR₂ (for introducing SiR₂ groups), SCl₂ or (PhSO₂)₂S (for introducing S bridges, which can be oxidized to SO or SO₂ groups), RB(OMe)₂ (for introducing BR bridges); Cl₂PR (for introducing PR bridges, which can be oxidized to phosphine oxides); and (PhSO₂)₂Se (for introducing Se bridges).

In other embodiments, V and/or V′ can be organic leaving groups, such as perfluoroalkoxides, or amines such as the N,N-dimethylethylenediamine radical of N,N-dimethyl-piperazine-2,3-dione, which is an effective source of alpha-dicarbonyl “Z” groups, as illustrated by the drawing and Example 16 below.

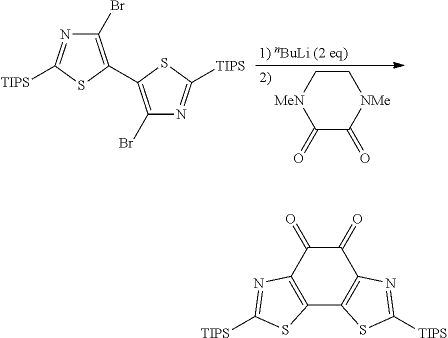

Overall, the various inventions described herein relate to general three step method for synthesizing a very wide variety of fused tricyclic compounds, as shown in the reaction scheme diagram below:

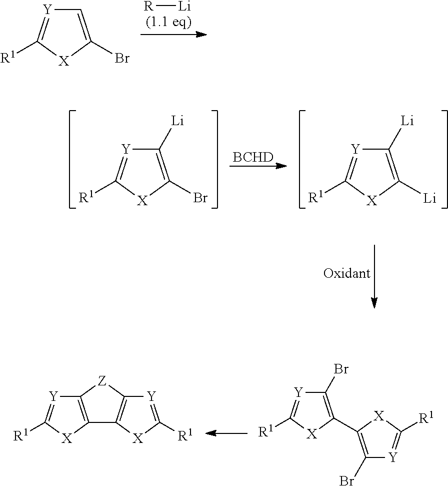

wherein R¹, X, Y, and Z can be defined in any of the ways disclosed hereinabove.

The Fused Tricyclic Compounds

As disclosed and described above, the various embodiments of the methods of the inventions provide unexpectedly short, efficient and inexpensive methods for making a wide variety of fused tricyclic compounds, many of which can be used as semiconducting materials for making electronic devices, or they may be used as synthetic intermediates and further elaborated or polymerized to produce other semiconducting materials useful for making electronic devices.

The fused tricyclic compounds that can be made by the methods described herein include some have the general structure of Formula (II) shown below:

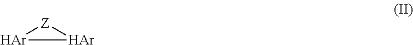

wherein

HAr can be defined in any manner described above, and

Z is an organic or inorganic group bridging the two HAr radicals to form the tricyclic compound. For example, Z can be S, Se, NR⁵, C(O), C(O)C(O), Si(R⁵)₂, SO, SO₂, PR⁵, P(O)R⁵, BR⁵, C(R⁵)₂, C(C(CN)₂)C(C(CN)₂), or C(C(CN)₂) wherein R⁵ is an optionally substituted organic radical selected from alkyl, perfluoroalkyl, alkoxide, aryl, heteroaryl, or the like. It should also be noted that when Z is C(O) or C(O)C(O) (i.e. one or more carbonyl groups, the corresponding ketals can also be readily synthesized, as disclosed below, and such ketals can be very valuable synthetic intermediates that facilitate additional functionalization of the HAr groups, as will also described below.,

In many embodiments of the fused tricyclic compounds, HAr is an optionally substituted five membered heterocycle. Examples of the such fused tricyclic compounds can have the generic structure shown in Formula (IIa) shown below

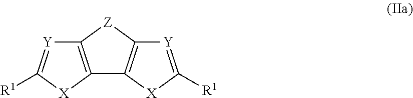

wherein R¹, X, Y, and Z can be defined in any of the ways disclosed herein.

In some such embodiments of the compounds of Formula (IIa), R¹ can be hydrogen, a halide, or a C₁-C₃₀ organic radical. Such R¹ organic radicals can be selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms. Such R¹ organic radicals can be selected from an organic acyl compound having the formula

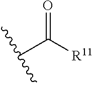

wherein R¹¹ is an aryl or heteroaryl optionally substituted with 1-10 independently selected halide, cyano, alkyl, perfluoroalkyl, acyl, alkoxy, or perfluoroalkoxy groups.

In the compounds of Formula (IIa),

X can be O, S, Se, or NR³ wherein R³ is a C₁-C₁₈ alkyl, perfluoroalkyl, aryl, or heteroaryl; and

Y can be CH, CR⁴, or N, wherein R⁴ is a C₁-C₁₈ alkyl, aryl, or heteroaryl; and

Z can be S, Se, NR⁵, C(O), C(O)C(O), Si(R⁵)₂, SO, SO₂, PR⁵, P(O)R⁵, BR⁵, or C(R⁵)₂, wherein R⁵ is a C₁-C₅₀ organic radical selected from optionally substituted alkyl, perfluoroalkyl, aryl, and heteroaryl.

In some preferred embodiments the compounds of Formula (IIa), Z is C(O), C(O)C(O), to give mono or bis keto derivatives of Formula (IIb) or Formula (IIb), or ketal protected derivatives thereof, having Formulas (IId), (IIe), (IIf) or (IIg) shown below, where n is 2 or 3.

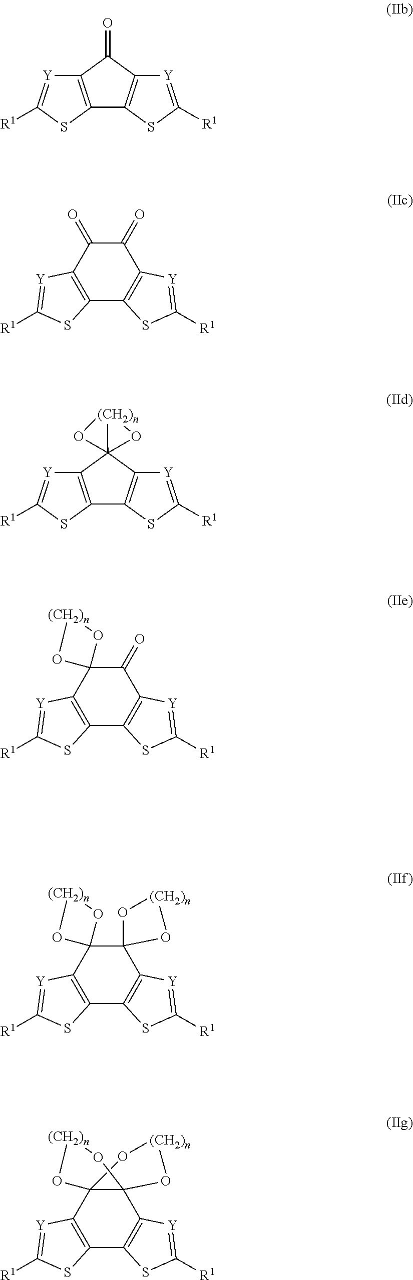

wherein X, Y, and R¹ can be any of the groups identified elsewhere herein.

It is understood in the art that, in some instances, bis ketals, such as those exemplified in Formulas (IIf) and (IIg) may be difficult to distinguish using standard characterization techniques (e.g. NMR). Thus, for the purposes of this disclosure a representation of a bis ketal like those exemplified in (IIf) and (IIg) may be treated as interchangeable. That is, a bis ketal as exemplified by (IIf) may be actually be a bis ketal exemplified by (IIg) or visa versa. In another embodiment, a bis ketal as exemplified by (IIf) is a mixture ofbis ketals as exemplified by (IIf) and (IIg). In some instances bis ketals are distinguishable through techniques. It is understood that Forumlas II are used merely as exemplifications, and the statements are not limited to those tricyclic structures.

The ketal protected derivatives having Formulas (IId), (IIe), (IIf) or (IIg) are especially useful as synthetic intermediates that allow easy further functionalizations at R¹, followed by deprotection to liberate the functionalized parent carbonyl compounds. Specific examples of such ketal protected compounds include the bis-thiophene and bisthiazole ketal compounds whose structures are shown below;

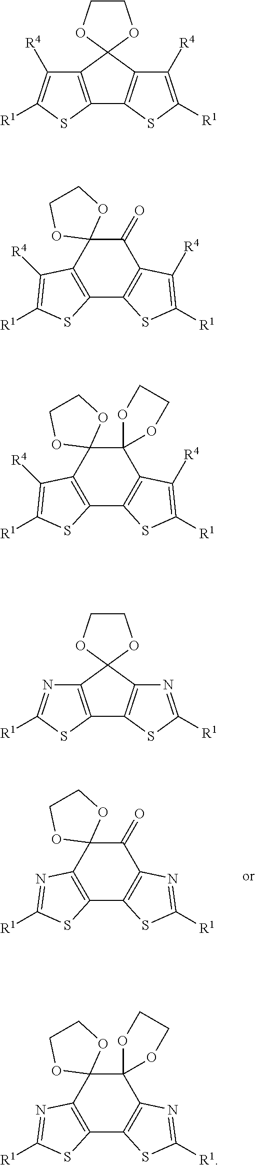

Some subgenera of the compounds of Formulas (IIa), (IIb), and (IIc) include the bis-thiophenes having the structure

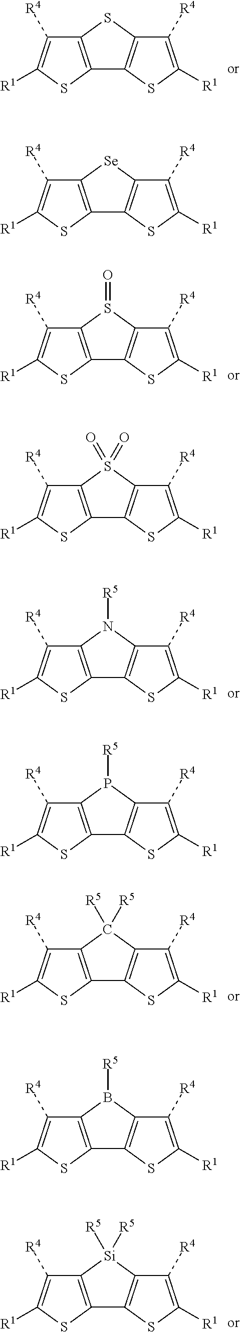

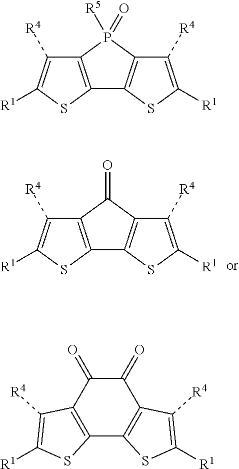

wherein R¹ can be hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² can be an independently selected alkyl or aryl, and each R²¹ can be an independently selected alkyl or aryl, or the R²¹ groups together form an optionally substituted alkylene group bridging the oxygen atoms, R⁴ can be hydrogen or optionally a C₁-C₁₈ alkyl group, and R⁵ can be a C₁-C₅₀ organic radical selected from alkyl, aryl, heteroaryl.

Related subgenera of the compounds of Formula (IIa) include the bis-selenophenes having the structure

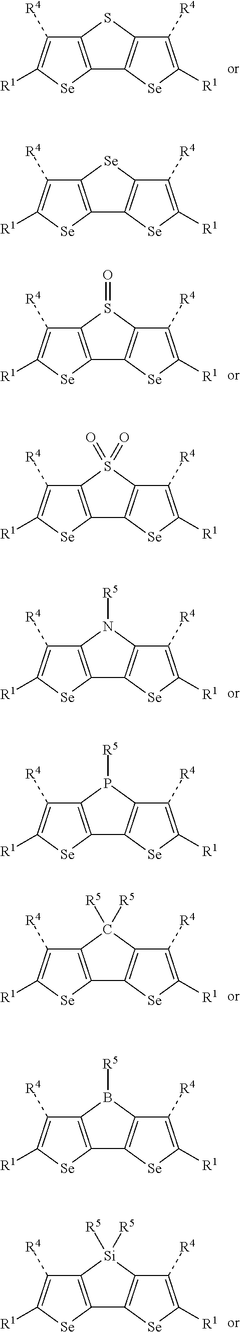

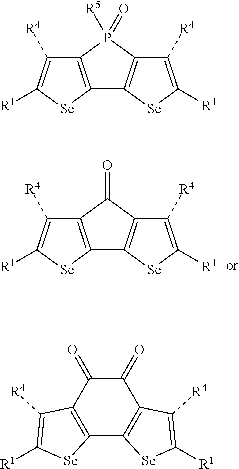

wherein R¹ can be hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² can be an independently selected alkyl or aryl, and each R²¹ can be an independently selected alkyl or aryl, or the R²¹ groups together form an optionally substituted alkylene group bridging the oxygen atoms, R⁴ can be hydrogen or optionally a C₁-C₁₈ alkyl group, and R⁵ can be a C₁-C₅₀ organic radical selected from alkyl, aryl, heteroaryl.

Other related embodiments of the compounds of Formula (IIa) include the bispyrroles shown below:

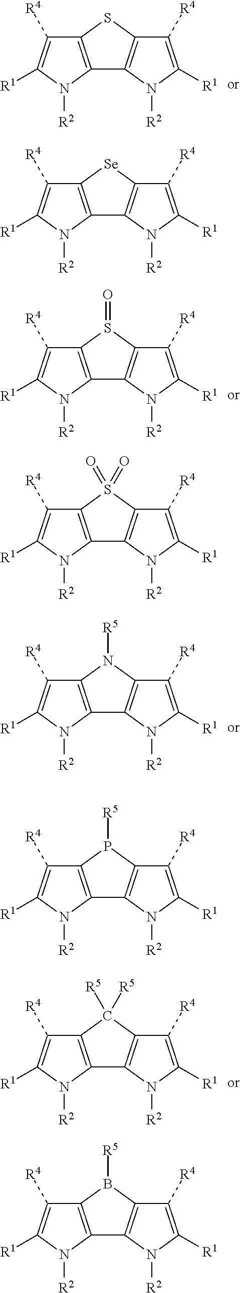

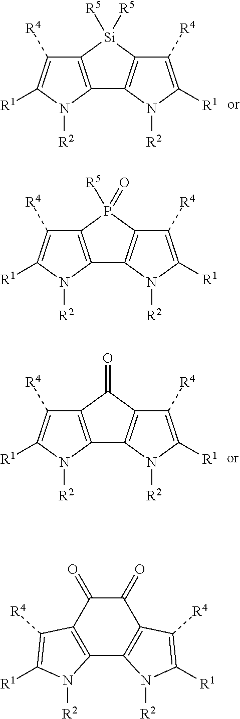

wherein R¹ is hydrogen or a halide, or a C₁-C₃₀ organic radical selected from alkyl, alkynyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen, cyano, or optionally a C₁-C₁₈ alkyl group, and R⁵ is a C₁-C₅₀ organic radical selected from alkyl, aryl, heteroaryl. In some embodiments, R² is a CF₃ group.

Other related embodiments of the compounds of Formula (IIa) include the bisthiazoles shown below:

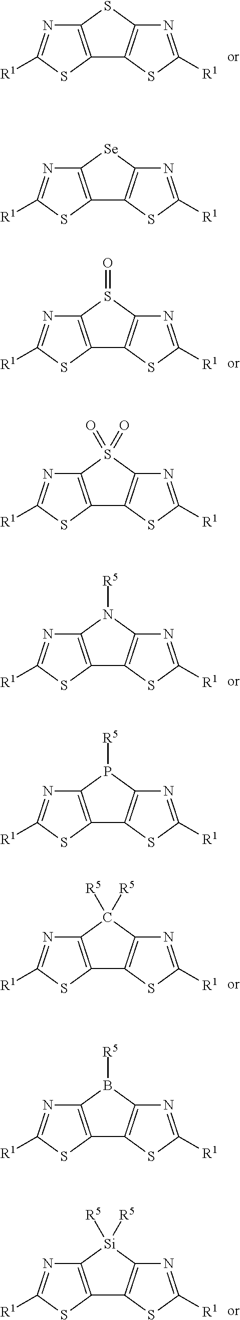

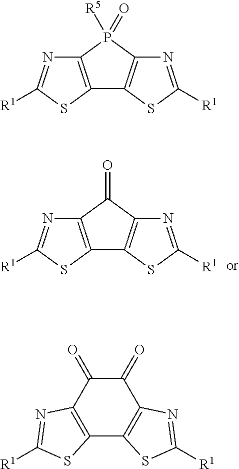

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl and each R²¹ is an independently selected alkyl or aryl, or the R²¹ groups together form an optionally substituted alkylene group bridging the oxygen atoms, and R⁵ is a C₁-C₅₀ organic radical selected from alkyl, aryl, heteroaryl.

Of particular interest are bisthiazole-biscarbonyl compounds having the structure:

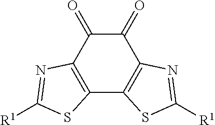

wherein R¹ can be hydrogen, a halide, an optionally substituted C₁-C₃₀ aryl or heteroaryl, alkynyl, Si(R²)₃, Si(OR²)₃, Sn(R²)₃, or B(OR²)₂ wherein each R² is an independently selected C₁-C₁₈ alkyl or aryl, or the R² groups together form a cyclic alkylene.

Such bisthiazole-biscarbonyl compounds have fused tricyclic cores that are highly electron deficient, and are useful for making polymers and/or compositions that can conduct electrons, and hence are very useful for making electronic devices. In addition they can be useful as optical absorbing materials, nonlinear optical materials, sensing materials and optical limiting materials.

Yet other related embodiments of the compounds of Formula (IIa) include the bisimidazoles shown below:

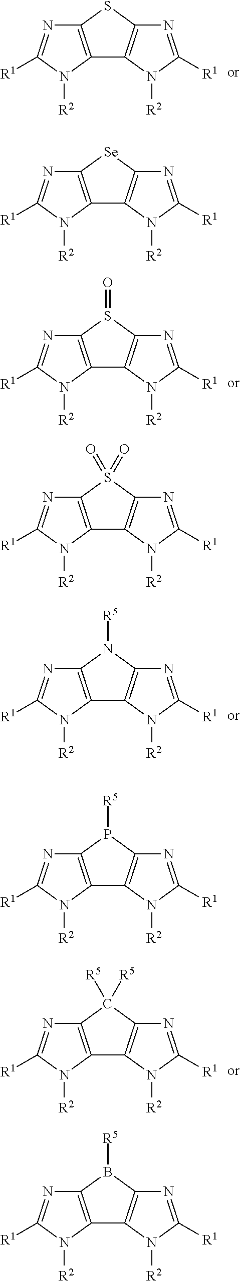

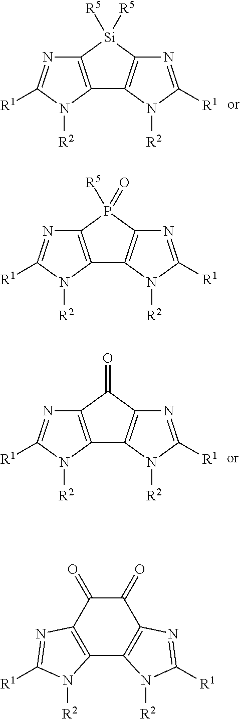

wherein R¹ is hydrogen or a halide, or a C₁-C₃₀ organic radical selected from optionally substituted alkyl, alkynyl, aryl, heteroaryl, or —Sn(R²)₃, —Si(R²)₃, or —B(—OR²)₂ wherein each R² is an independently selected alkyl or aryl and each R²¹ is an independently selected alkyl or aryl, or the R²¹ groups together form an optionally substituted alkylene group to form a ring bridging the oxygen atoms, and R⁵ is a C₁-C₅₀ organic radical selected from alkyl, perfluoroalkyl, aryl, or heteroaryl.

In many embodiments of the compounds of Formula (IIa) and its several subgenera shown above, R¹ can be an optionally substituted aryl, or heteroaryl. For example, R¹ can be a relatively electron rich radical having one of the formulas shown below:

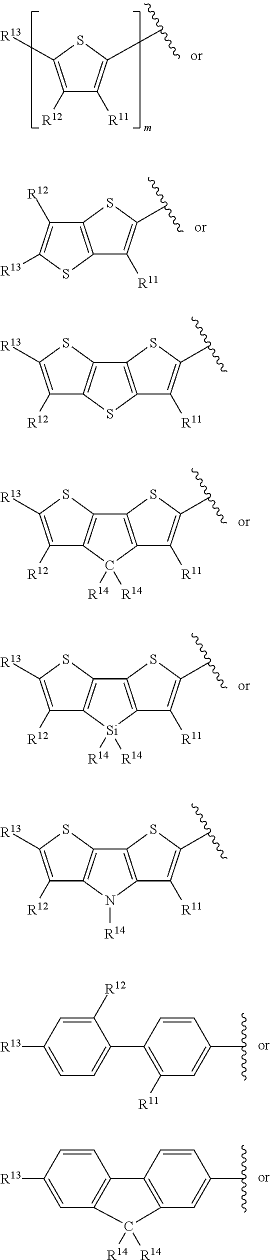

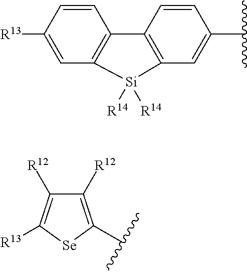

wherein m is 1, 2, 3, or 4, and R⁴, R¹¹, R¹², R¹⁴ are a C₁-C₁₈ alkyl, perfluoroalkyl, or alkoxy group, and R¹³ is hydrogen, halide, Si(R²)₃, Si(OR²)₃ or Sn(R²)₃.

In other embodiments of the fused tricyclic compounds of Formula (IIa) or its subgenera, R¹ can be a relatively electron poor heteroaryl radical, such as for example one of the formulas shown below:

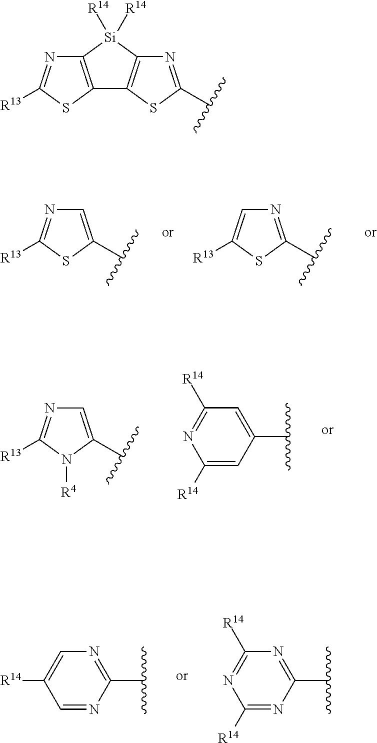

wherein m is 1, 2, 3, or 4, and R⁴, and R¹⁴ are a C₁-C₁₈ alkyl, perfluoroalkyl, or alkoxy group, and R¹³ is hydrogen, halide, Si(R²)₃, or Sn(R²)₃.

Moreover, in some embodiments of the compounds of Formula (IIa), R¹ can be a relatively electron poor terminal aryl or heteroaryl, such as those having the structures:

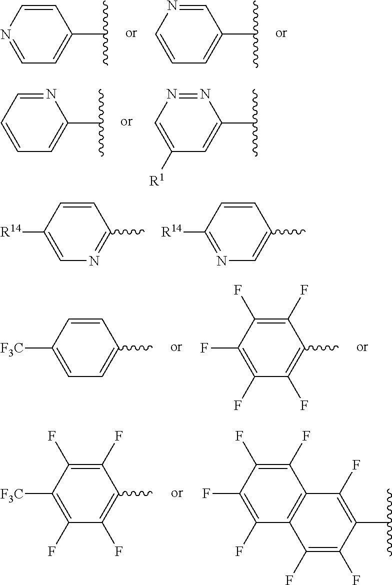

Examples of specific compounds of Formula (IIa) that have been experimentally synthesized in the lab include the compounds illustrated in Table 2.

TABLE 2
Summary of the tricyclic cores obtained from the aryl dibromides synthesized by the sequence of BCHD reaction and
CuCl₂ oxidative coupling.

| Entry | Bis heteroaryl Halide | Product | Isolated Yield, % |
|---|---|---|---|
| 1 | 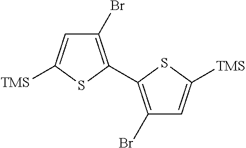 [SMILES: C[Si](C)(C)c1cc(Br)c(-c2sc([Si](C)(C)C)cc2Br)s1] | 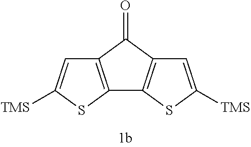 [SMILES: C[Si](C)(C)c1cc2c(s1)-c1sc([Si](C)(C)C)cc1C2=O] | 56-85 |
| 2 | 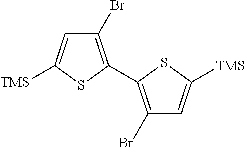 [SMILES: C[Si](C)(C)c1cc(Br)c(-c2sc([Si](C)(C)C)cc2Br)s1] | 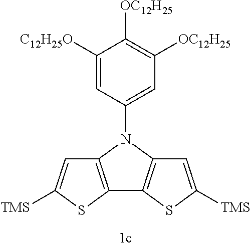 | 53 |
| 3 | 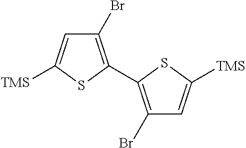 [SMILES: C[Si](C)(C)c1cc(Br)c(-c2sc([Si](C)(C)C)cc2Br)s1] | 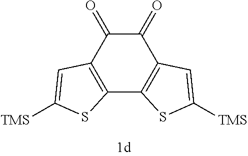 [SMILES: C[Si](C)(C)c1cc2c(s1)-c1sc([Si](C)(C)C)cc1C(=O)C2=O] | 27-80 |
| 4 | 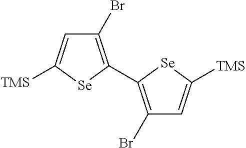 [SMILES: C[Si](C)(C)c1cc(Br)c(-c2[se]c([Si](C)(C)C)cc2Br)[se]1] | 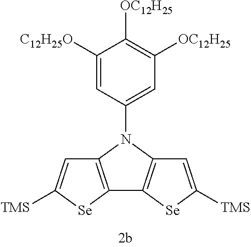 | 51-81 |
| 5 | 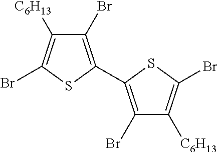 | 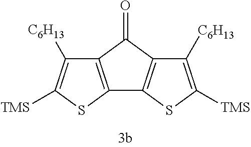 | 52-54 |
| 6 | 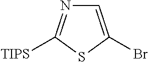 | 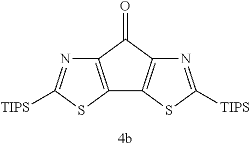 | 39 |
| 7 | 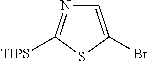 | 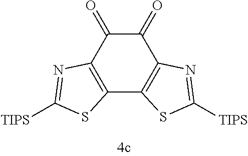 | 38 |
| 8 | 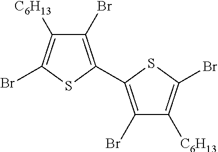 | 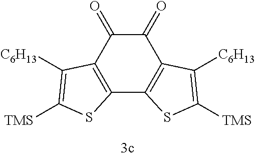 | 34 |
| 9 | 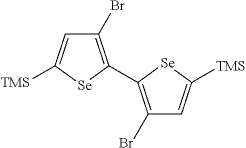 [SMILES: C[Si](C)(C)c1cc(Br)c(-c2[se]c([Si](C)(C)C)cc2Br)[se]1] | 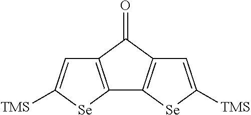 [SMILES: C[Si](C)(C)c1cc2c([se]1)-c1[se]c([Si](C)(C)C)cc1C2=O] | |
| 10 | 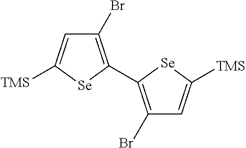 [SMILES: C[Si](C)(C)c1cc(Br)c(-c2[se]c([Si](C)(C)C)cc2Br)[se]1] | 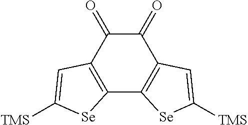 [SMILES: C[Si](C)(C)c1cc2c([se]1)-c1[se]c([Si](C)(C)C)cc1C(=O)C2=O] | <5% |

Compounds of Formula (IIa) as Synthetic Intermediates

The various subgenera of compounds of Formula (II) or (IIa), available by the methods of the invention, can also be readily further functionalized and/or elaborated to produce a wide variety of known and new downstream compounds, oligomers, polymers, or copolymers that are useful for many purposes, including for the preparation of compounds and compositions for making electronic devices, such as transistors, solar cells, light emitting diodes, and the like.

For example, it has been discovered that the compounds of Formula (IIa) wherein R¹ is a triorganosilane can be readily converted to the corresponding iodides or bromides, as shown in the diagram below and in Table 3.

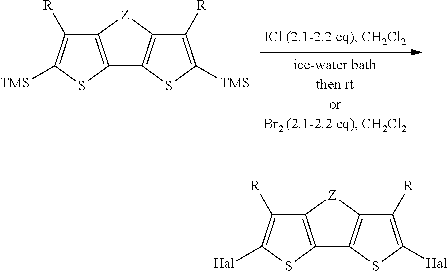

TABLE 3
Summary of Synthesized Fused Tricyclic Dihalides

| | | E_{1/2}^{0/1-}, | E_{1/2}^{1-/2-}, , |
|---|---|---|---|
| En- | | V | V |
| try | Aryl Dihalide | (solvent) | (solvent) |
| 1 | 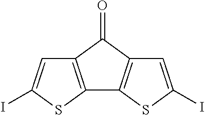 [SMILES: O=C1c2cc(I)sc2-c2sc(I)cc21] | −1.49 | n/a |
| 2 | 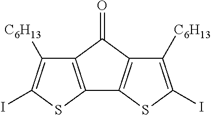 | −1.61 (CH₂Cl₂) | n/a |
| 3 | 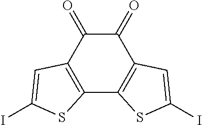 [SMILES: O=C1C(=O)c2cc(I)sc2-c2sc(I)cc21] | −0.94 (THF) | −1.60 (THF) |
| 4 | 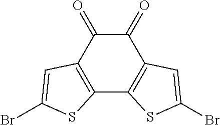 [SMILES: O=C1C(=O)c2cc(Br)sc2-c2sc(Br)cc21] | −0.90 (THF) | −1.64 (THF) |
| 5 | 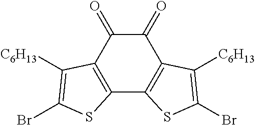 | −1.01 (CH₂Cl₂) | −1.62 (CH₂Cl₂) |
| 6 | 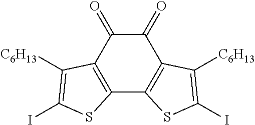 | −1.02 (CH₂Cl₂) | −1.62 (CH₂Cl₂) |
| 7 | 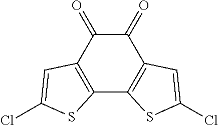 [SMILES: O=C1C(=O)c2cc(Cl)sc2-c2sc(Cl)cc21] | −0.88 (THF) | −1.68 (THF) |
| 8 | 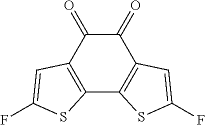 [SMILES: O=C1C(=O)c2cc(F)sc2-c2sc(F)cc21] | −0.91 (THF) | −1.73 (THF) |
| 9 | 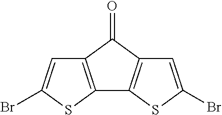 [SMILES: O=C1c2cc(Br)sc2-c2sc(Br)cc21] | −1.48 (CH₂Cl₂) | |
| 10 | 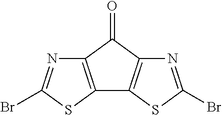 [SMILES: O=C1c2nc(Br)sc2-c2sc(Br)nc21] | | |
| 11 | 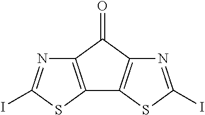 [SMILES: O=C1c2nc(I)sc2-c2sc(I)nc21] | | |

R = H, C₆H₁₃; Z = C(O), C(O)—C(O); Hal = Br, I
CV experiment: 0.1 M ⁿBu₄NPF₆ in THF or CH₂Cl₂ vs Cp₂Fe at 0 V

Such fused tricyclic dihalides can be coupled at the R¹ halides with a wide variety of other aryl or heteroaryl compounds, via the well known Stille, Sonogashira or Suzuki coupling procedures (see Hassan et al. Chem. Rev., 2002, 102, 1359-1469, and Sonogashira et al., Tetrahedron Lett., 1975, 50, 4467-4470, both hereby incorporated herein by reference), to produce a wide variety of oligomers, or polymerizable oligomeric materials that can be used to prepare copolymers comprising those repeat units.

Alternatively, fused tricyclic compounds comprising Si(OR)₃ or SnR₃ radicals suitable for Hiyama or Stille couplings or polymerizations with other corresponding aryl or heteroaryl radicals can be prepare as indicated in the reaction diagrams shown below:

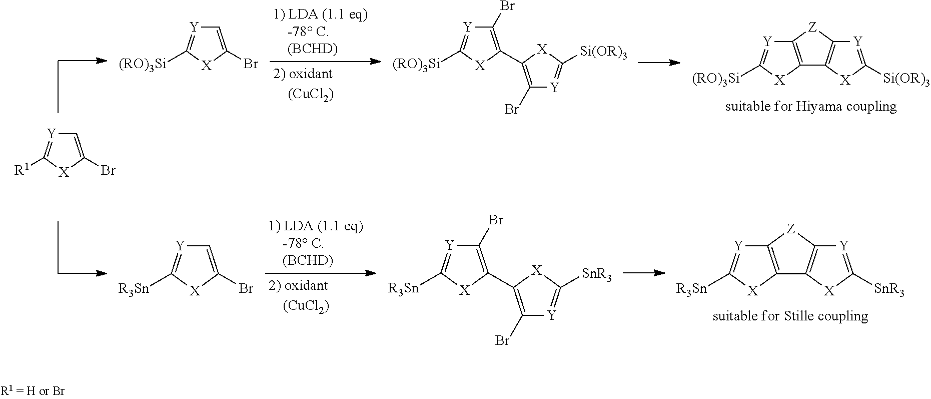

Polymers Comprising the Fused Tricyclic Compounds as Repeat Units

Some aspects of the present inventions relate to new polymers comprising one or more of the fused tricyclic compounds disclosed herein as repeat units for copolymers. For example, some embodiments of the inventions herein relate to a polymer or copolymer comprising a repeat unit having the structure

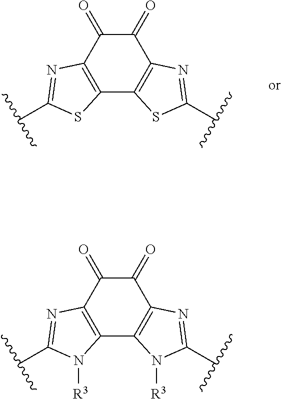

wherein R³ is a C₁-C₁₈ alkyl, perfluoroalkyl, aryl, or heteroaryl. In some embodiments, R³ is CF₃.

In other embodiments, the invention relates to polymers or copolymer comprising a repeat unit having the structure

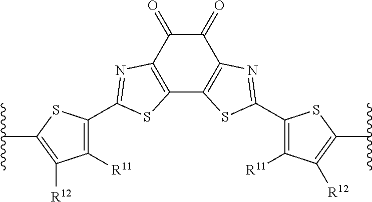

wherein R¹¹ and R¹² are hydrogen or a C₁-C₁₈ alkyl.

Many such polymers or copolymers can be unexpectedly superior organic semiconductors capable of transporting holes and/or electrons, and can be solution processed, so as to be useful in the synthesis of electronic devices, such as transistors, solar cells, and/or organic light emitting diodes.

### Applications

The compounds described herein can be used in, for example, organic electronics and printed electronics applications including, for example, transistors, TFTs, field-effect transistory, photodetectors and photovoltaics, solar cells, light emitting diodes, organic light emitting diodes, sensors, displays, flat panel displays, RFID, electronic paper, artificial skin, and the like.

The compounds can be also, if desired, subjected to oligomerization or polymerization processes for further use in applications.

Patterning methods can be carried out including, for example, ink jet printing and soft lithography. Film formation methods can be carried out including, for example, spin coating, dip coating, and the like.

Flexible substrates such as polymeric materials and rigid substrates such as glasses can be used.

Field-effect transistors are described in, for example, Bao, Locklin, Organic Field-Effect Transistors, CRC Press, 2007. Organic photovoltaics and solar cells are described in, for example, Sun, Sariciftci, Organic Photovoltaics, Taylor, 2005. OLEDs are described in, for example, Li, Meng, Organic Light-Emitting Materials and Devices, CRC, 2007.

The field-effect transistor can be fabricated with a top gate or bottom gate configuration. Substrates, source and drain electrodes, dielectric layers, and gate electrodes can be fabricated as known in the art. The active organic semiconducting layer can be solution processed or vacuum processed. Solution processing can be carried out with use of organic solvents such as chlorobenzene or dichlorobenzene. Solid concentration can be, for example, 0.1 mg/mL, or at least 1 mg/mL, or at least 10 mg/mL. The working examples below provide embodiments and methods of making which allow for demonstration of the field effect. One can provide the compounds with, for example, electron-withdrawing substituents or with larger naphthalene imide substituents (see, for example, working example 41).

In one embodiment, for example, a device is provided comprising one or more of the compositions or compounds described herein, wherein the device is, for example, a field effect transistor in which the active semiconducting layer comprises one or more of the compositions or compounds described herein and has a mobility of at least 1×10⁻⁵ cm²/Vs, or at least 1×10⁻⁴ cm²/Vs, or at least 1×10⁻³ cm²/Vs.

The I_{on/off} ratio can be, for example, at least 10, or at least 50, or at least 100.

Synthesis, device fabrication and FET measurements are illustrated in the following additional, non-limiting working examples.

### WORKING EXAMPLES

The various inventions described above are further illustrated by the following specific examples, which are not intended to be construed in any way as imposing limitations upon the scope of the invention disclosures or claims attached herewith. On the contrary, it is to be clearly understood that resort may be had to various other embodiments, modifications, and equivalents thereof which, after reading the description herein, may suggest themselves to one of ordinary skill in the art without departing from the spirit of the present invention or the scope of the appended claims.

General—All experiments with air- and moisture-sensitive intermediates and compounds were carried out under an inert atmosphere using standard Schlenk techniques.

NMR spectra were recorded on 400 MHz Bruker AMX 400 and referenced to residual proton solvent or internal tetramethylsilane standard. UV-vis absorption spectra were recorded on a Varian Cary 5E UV-vis-NIR spectrophotometer. Cyclic voltammograms were obtained on a computer controlled BAS 100B electrochemical analyzer, and measurements were carried out under a nitrogen flow in deoxygenated anhydrous CH₂Cl₂ or THF solutions oftetra-n-butylammonium hexafluorophosphate (0.1 M). Glassy carbon was used as the working electrode, a Pt wire as the counter electrode, and an Ag wire anodized with AgCl as the pseudo-reference electrode. Potentials were referenced to the ferrocenium/ferrocene (Cp₂Fe^{+/0}) couple by using ferrocene as an internal standard. Abbreviations used include singlet (s), doublet (d), doublet of doublets (dd), triplet (t), triplet of doublets (td) and unresolved multiplet (m). Mass spectral analyses were provided by the Georgia Tech Mass Spectrometry Facility. Elemental analyses were provided by Atlantic Microlab, Inc.

Unless otherwise noted, cited reagents and solvents were purchased from well-known commercial sources (such as Sigma-Aldrich of Milwaukee Wis. or Acros Organics of Geel Belgium), and were used as received without further purification.

### Example 1

### 3,3′-Dibromo-5,5′-bis-trimethylsilanyl-2,2′-bithiophene (1a)

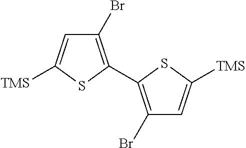 [SMILES: C[Si](C)(C)c1cc(Br)c(-c2sc([Si](C)(C)C)cc2Br)s1]

2-Bromothiophene (0.10 mol, 16.3 g) was dissolved in 200 ml of anhydrous THF and the colorless solution was cooled in acetone/dry ice bath. LDA (1.2 M in hexanes-THF, 0.10 mol, 83.3 ml) was added dropwise and clear yellow-orange solution was stirred for 1 h. Chlorotrimethylsilane (1.0 eq., 0.10 mol, 10.86 g) was added dropwise, the mixture was stirred for 1 h and clean formation of 2-bromo-5-trimethylsilylthiophene was confirmed by GC/MS analysis. LDA (1.2 M in hexanes-THF, 1.1 eq., 0.11 mol, 91.7 ml) was added dropwise, and after stirring for 0.5 h thick suspension formed. Completion of the BCHD reaction was confirmed by GC/MS analysis and CuCl₂ (1.1 eq., 0.11 mol, 14.79 g) was added in one portion. Dark green mixture was allowed to slowly warm to room temperature overnight. Hexanes and water were added (copper salts partially precipitated out) and the organic phase was carefully removed. The aqueous phase was extracted with hexanes several times and combined organic phases were dried over MgSO₄. The solvents were removed by rotary evaporation and the residue (oil with some green copper salts) was dissolved in hexanes. This solution was filtered through silica gel plug (hexanes as eluant), the solvent was removed from brownish solution and the crude product was obtained as oil, which partially solidified overnight. This crude material was purified by Kugelrohr distillation and the product was obtained as yellow oil at 175-180° C./1.0-1.2 mm Hg (this oil solidified on standing, 19.80 g, 84.5% yield). UV-vis (CH₂Cl₂) λₘₐₓ, nm 226, 266. ¹H NMR (400 MHz, CDCl₃): δ 7.20-7.10 (s, 2H); 0.40-0.30 (s, 18H); ¹³C{¹H} NMR (100 MHz, CDCl₃): δ 142.76, 136.86, 133.78, 112.78, −0.52.

### Example 1a

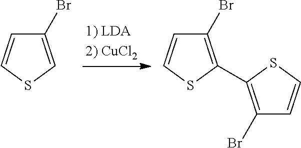 [SMILES: Brc1ccsc1 ; Brc1ccsc1-c1sccc1Br]

Lithium diisopropylamide (LDA) was prepared by the addition of n-BuLi (2.5 M in hexanes, 0.210 mol, 84 mL) to a solution of diisopropylamine (0.231 mol, 23.37 g) in 25 mL of anhydrous THF (−78° C. to room temperature). This LDA solution was added dropwise to a solution of 3-bromothiophene (0.200 mol, 32.607 g) in 200 mL of anhydrous THF cooled in acetone/dry ice bath. After stirring for 5 minutes precipitation was observed. The reaction mixture was stirred for 1 h and CuCl₂ (1.1 eq., 0.210 mol, 28.23 g) was added in three portions (exothermic reaction). The mixture became blue-black, and then orange-brown with precipitate. The cooling bath was removed and the mixture was transferred into a round bottom flask. The solvents were removed by rotary evaporation and the residue (greenish-brownish oil) was applied to the silica gel pad. The product was eluted with hexanes (˜1.5 L), and then CH₂Cl₂ (500 mL). The solvents were removed from the filtrate, and the part of the residue (7 g, brown solid) was transferred into a pear-shaped 50 mL flask, and the material was purified by Kugelrohr distillation and the product was collected as off-white solid at 190-200° C./(<0.7-0.8 mm Hg) (4.0 g). The rest of the brown soft matter was purified by Kugelrohr distillation (several times), and off-white material was obtained (13.0 g; total yield of the product (17.0 g, 52.5% yield). This material was recrystallized from 250 mL of hexanes and off-white solid was obtained (8.18 g, 63% recovery). The mother liquor was concentrated and additional amount of product crystallized. GC/MS analysis: 324 (molecular ion) @ 11.6 min.

### Example 2

### 3,3′-Dibromo-5,5′-bis-trimethylsilanyl-2,2′-biselenophene (2a)

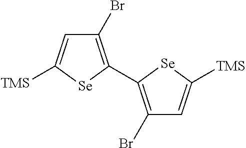 [SMILES: C[Si](C)(C)c1cc(Br)c(-c2[se]c([Si](C)(C)C)cc2Br)[se]1]

A solution of diisopropylamine (distilled from CaH₂, 48.4 mmol, 4.90 g) in anhydrous THF (20 ml) was cooled in acetone/dry ice bath and n-butyllithium (2.5 M in hexanes, 44.0 mmol, 17.6 ml) was added dropwise. The cooling bath was removed and the mixture was stirred for 0.5 h. Portion of this freshly prepared LDA (1.0 M, 20.0 mmol, 20 ml) was added dropwise to a colorless solution of 2-bromoselenophene (20.0 mmol, 4.20 g) in 100 ml of anhydrous THF (acetone/CO₂ bath). During the addition of LDA the reaction mixture changed color from colorless to yellow. The reaction mixture was stirred for 0.5 h and chlorotrimethylsilane (20.0 mmol, 2.17 g) was added dropwise. The mixture was stirred for 20 minutes and clean formation of 2-bromo-5-trimethylsilyl-selenophene was confirmed by GC/MS analysis. LDA (1.0 M, 24.0 mmol, 24 ml) was added dropwise, the reaction mixture was stirred for 0.5 min and completion of BCHD reaction was confirmed by GC/MS analysis. CuCl₂ (20.0 mmol, 2.69 g) was added in one portion, the resulting mixture was stirred for 2 hours and the cooling bath was removed. The dark yellow-brownish reaction mixture was poured into ˜50 ml of brine, diluted with ˜50 ml of hexanes and copper salts partially precipitated out. The organic phase was removed, the aqueous phase was extracted with hexanes (3×20 ml) and the combined organic phases were dried over MgSO₄. The solvents were removed by rotary evaporation, the residue was dissolved in hexanes and filtered through silica gel plug (200 ml of hexanes, then hexanes:EtOAc (50:1, 200 ml) as eluants). The solvents were removed from bright yellow solution and orange oil was purified by column chromatography to give product as a yellow solid (3.74 g, 66.6% yield). HRMS (EI) calculated for C₁₄H₂₀Br₂Se₂Si₂ 561.7801; found 561.7797. ¹H NMR (CDCl₃, 400 MHz): δ 7.46 (s, 2H), 0.33 (s, 18H); ¹³C{¹H} NMR (CDCl₃, 100 MHz): δ 145.0, 139.5 (CH), 139.4, 113.3, −0.1. Anal. Calc. for C₁₄H₂₀Br₂Se₂Si₂: C, 29.91; H, 3.59. Found: C, 30.15; H, 3.53.

### Example 3

### 3,3′5,5′-Tetrabromo-4,4′-di-n-hexyl-2,2′-bithiophene (3a)

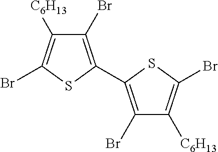

Diisopropylamine (distilled from CaH₂, 90.0 mmol, 9.11 g) was dissolved in anhydrous THF (160 ml) under nitrogen atmosphere and the resulting solution was cooled (acetone/dry ice bath). n-Butyllithium (2.5 M in hexanes, 82.5 mmol, 33.0 ml) was added dropwise, the cooling bath was removed and the mixture was stirred for half an hour. This freshly prepared solution of LDA was cooled (acetone/dry ice bath) and 2,5-dibromo-3-n-hexylthiophene (75.0 mmol, 24.46 g) was added dropwise. The bright yellow reaction mixture was stirred for 1 h and CuCl₂ (82.5 mmol, 11.09 g) was added in one portion. The mixture from yellow-orange became blue. The reaction mixture was allowed to warm slowly to room temperature overnight (without cooling bath removal). The reaction mixture was treated with water (˜70 ml) and hexanes (copper salts precipitated out). The organic phase was removed, the aqueous phase was extracted with hexanes two times and the combined organic phases were dried over MgSO₄. The solvents were removed by rotary evaporation and the crude product was obtained as brownish oil. The crude product was dissolved in hexanes and filtered through silica gel plug (˜400 ml of hexanes as eluant was used). Barely yellowish solution was collected (brown and green matter got stuck on the silica gel), the solvent was removed and the yellowish oil was dried under vacuum. Yellowish oil solidified on scratching and yellowish solid was obtained (19.74 g, 81.0%). HRMS (EI) calculated for C₂₀H₂₆Br₄S₂ 645.8209; found 645.8171. ¹H NMR (CDCl₃, 400 MHz): δ 2.64 (t, J=7.9 Hz, 2H), 1.53 (m, 2H), 1.43-1.20 (m, 6H), 0.88 (t, J=6.8 Hz, 3H); ¹³C{¹H} NMR (CDCl₃, 100 MHz): δ 141.5, 128.5, 114.6, 111.0, 31.5, 30.3, 29.0, 28.5, 22.6, 14.1. Anal. Calc. for C₂₀H₂₆Br₄S₂: C, 36.95; H, 4.03. Found: C, 37.23; H, 4.03.

### Example 4

### 4,4′-Dibromo-2,2′-bis(triisopropylsilyl)-5,5′-bithiazole (4a)

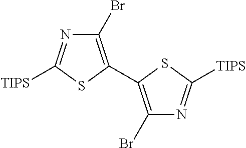

2-Triisopropylsilyl-5-bromothiazole (6.71 mmol, 2.15 g) was dissolved in 70 ml of anhydrous THF under nitrogen atmosphere and the resulting colorless solution was cooled in acetone/dry ice bath. LDA (1.5 M in hexanes-THF, 1.1 eq., 7.38 mmol, 4.9 ml) was added dropwise and the reaction mixture became bright yellow. The mixture was stirred for 15 minutes, a small aliquot was treated with hexanes-MeOH, the solvent was removed and the residue was analyzed by ¹H NMR. The completion of the BCHD reaction was confirmed and CuCl₂ (1.1 eq., 7.38 mmol, 0.99 g) was added in one portion. The reaction mixture became dark green in color. After stirring for 2 h the cooling bath was removed, the mixture was warmed to room temperature, treated with hexanes (˜70 ml) and water and copper salts precipitated out. The organic phase was removed, the aqueous phase was extracted with hexanes (3×20 ml) and combined organic phases were dried over MgSO₄. The solvent was removed by rotary evaporation and the crude product was obtained as brownish solid. This material was purified by column chromatography (200 ml of silica gel, hexanes:CH₂Cl₂ (2:1) as eluant). First several fractions containing slightly contaminated material were combined separately, the solvent was removed and yellowish solid (0.514 g) was further purified by recrystallization from ˜45 ml of EtOH. Off white crystalline material was obtained after vacuum filtration (0.412 g, 80.2% recovery). Fractions with pure material were combined separately, the solvents were removed by rotary evaporation and the yellowish solid (1.24 g) was recrystallized from ˜80 ml EtOH. Off white shiny solid was obtained after vacuum filtration (1.09 g, 87.9% recovery). Total yield of the product before recrystallization was 81.8% (1.75 g), the recovery after recrystallization was 85.6% (1.50 g). UV-vis (CH₂Cl₂) λₘₐₓ: 225, 314. HRMS (EI) calculated for C₂₄H₄₂Br₂N₂S₂Si₂ 636.0695; found 636.0669. ¹H NMR (CDCl₃, 400 MHz): δ 1.48 (septet, 6H), 1.75 (d, J=7.6 Hz, 36H); ¹³C{¹H} NMR (CDCl₃, 100 MHz): δ 172.5, 130.3, 125.0, 18.4, 11.5. Anal. Calc. for C₂₄H₄₂Br₂N₂S₂Si₂ C, 45.13; H, 6.63; N, 4.39. Found: C, 44.86; H, 6.53; N, 4.36.

### Example 5

### 2,2′-Difluoro-4,4′-diiodo-3,3′-bipyridine (5a)

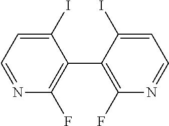 [SMILES: Fc1nccc(I)c1-c1c(I)ccnc1F]

2-Fluoro-3-iodopyridine (7.80 mmol, 1.74 g) was dissolved in 40 ml of anhydrous THF under nitrogen atmosphere and the solution was cooled in acetone/CO₂ bath. LDA (1.1 eq., 1.2 M in hexanes-THF, 8.58 mmol, 7.15 ml) was added dropwise. The reaction mixture became yellowish and after stirring for 0.5 h it was analyzed by GC/MS. A clean BCHD reaction was confirmed, the mixture was stirred for additional 0.5 h and CuCl₂ (1.1 eq., 8.58 mmol, 1.15 g) was added in one portion. The yellow reaction mixture became dark blue, then brown red (within 1-2 h) and then light greenish after warm up to room temperature. The reaction mixture was treated with hexanes and water, the organic phase was removed, and the aqueous phase was extracted with hexanes (2×˜20 ml). The combined organic phases were dried over MgSO₄ and the solvent was removed by rotary evaporation to give greenish-brownish oil which partially solidified on standing. This crude product was purified by column chromatography (200 ml of silica gel, hexanes:CH₂Cl₂ mixtures (2:1, 1:1: and then 1:2) as eluants). The solvents were removed from combined fractions and the product was obtained as off-white solid (1.04 g, 60.1%). UV-vis (CH₂Cl₂) λₘₐₓ, nm 226, 244, 268. HRMS (EI) calculated for C₁₀H₄F₂I₂N₂ 443.8432; found 443.8417. ¹H NMR (CDCl₃, 400 MHz): δ 8.01 (d, J=5.2 Hz, 2H), 7.82 (d, J=5.2 Hz, 2H); ¹³C{¹H} NMR (CDCl₃, 100 MHz): δ 159.28 (d, J(C—F)=242.8 Hz, quaternary C), 148.5 (d, J(C—F)=15.62 Hz, CH), 132.1 (d, J(C—F)=4.6 Hz, CH), 125.0 (dd, J(C—F)=33.4 Hz, 4.1 Hz), 114.5 (d, J(C—F)=1.7 Hz). Anal. Calc. for C₁₀H₄F₂I₂N₂: C, 27.05; H, 0.91; N, 6.31. Found: C, 27.52; H, 0.84; N, 6.19.

### Example 6

### 4,4′-Dibromo-5,5′-bis(trimethylsilyl)-2,2′-bithiazole (6a)

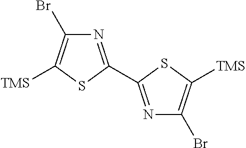 [SMILES: C[Si](C)(C)c1sc(-c2nc(Br)c([Si](C)(C)C)s2)nc1Br]

2-Bromothiazole (40.0 mmol, 6.56 g) was dissolved in 125 ml of anhydrous THF under nitrogen atmosphere, chlorotrimethylsilane (40.0 mmol, 4.34 g) was added and the resulting mixture was cooled (hexanes/N₂ bath). LDA (1.2 M in hexanes-THF, 40.0 mmol, 33.3 ml) was added dropwise and the colorless solution became yellow and then yellow-orange (−90-80° C. internal temperature). GC/MS analysis confirmed a clean formation of 2-bromo-5-trimethylsilylthiazole. The second equivalent of LDA (1.2 M in hexanes-THF, 44.0 mmol, 36.7 ml) was added dropwise (−85° C. internal temperature) and the mixture became green after addition of 5 ml of LDA. After completion of addition of LDA the dark brown reaction mixture was stirred for 10 minutes (−85-80° C. internal temperature) and analyzed by GC/MS. GC/MS analysis showed the presence of rearranged species as a major compound, CuCl₂ (40.0 mmol, 5.38 g) was added in one portion and the mixture was slowly warmed to room temperature without removal of a cooling bath. After 50 minutes the reaction mixture was analyzed by product was detected as a major compound. The reaction mixture was treated with ˜40 ml of water (copper salts partially precipitated out), organic phase was separated and the aqueous phase was extracted with hexanes several times and the dark brown organic phases were dried over MgSO₄. The solvents were removed by rotary evaporation and the crude material was obtained as brown-orange solid. This crude compound was dissolved in hexanes under heating and the cloudy solution was filtered through silica gel plug (hexanes, then hexanes:Et₂O (˜10:1) and slightly impure compound was obtained as orange solid (6.6 g, 68.0% yield). This material was further purified by recrystallization from EtOH and yellow solid was obtained after vacuum filtration (4.3 g, 65% recovery). Additional amount of material can be obtained from the mother liquor. UV-vis (CH₂Cl₂) λₘₐₓ (nm) 339, 347, 251. HRMS (EI) calculated for C₁₂H₁₈Br₂N₂S₂Si₂ 467.8817; found 467.8834. ¹H NMR (CDCl₃, 400 MHz): δ 0.45 (s, 18H); ¹³C {¹H} NMR (CDCl₃, 100 MHz): δ 163.2, 123.1, 132.0, −0.9. Anal. Calc. for C₁₂H₁₈Br₂N₂S₂Si₂: C, 30.64; H, 3.86; N, 5.96. Found: C, 30.85; H, 3.77; H, 5.69.

### Example 7

### 4,4′-Dibromo-2,2′-bis(4-n-hexyl-5-(trimethylsilyl)thiophen-2-yl)-5,5′-bithiazole (7a)

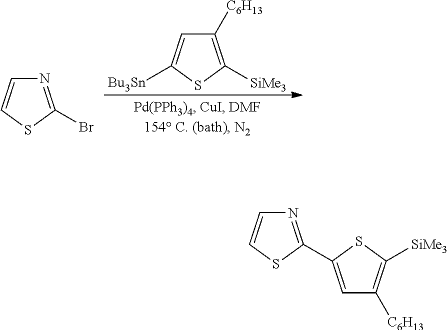

2-Bromothiazole (5.0 mmol, 0.82 g) was mixed with 2-trimethylsilyl-3-n-hexyl-5-tri-n-butylstannylthiophene (1.05 eq., 5.25 mmol, 2.78 g) in an oven-dried Schenk flask. Pd(PPh₃)₄ (0.01 mol %, 0.05 mmol, 0.058 g) and CuI (0.003 mmol, 0.025 mmol, 3.0 mg) and 10 ml of anhydrous DMF were added and the mixture was heated up to 154° C. (bath temperature). The mixture became orange and then after 15 minutes it rapidly changed to brown. TLC analysis (CH₂Cl₂ as eluant) confirmed the complete consumption of 2-bromothiazole and the mixture was cooled to room temperature. Water was added and organic phase was extracted with hexanes. Organic phase was treated with KF_{aq} and syrup-like organic phase was dried over MgSO₄ and filtered through Celite. The solvent was removed from thick solution and the residue was purified by column chromatography (100 ml of silica gel, Hexanes:CH₂Cl₂ (2:1) as eluant; note: the residue was dissolved in dichloromethane and some insoluble white solid (presumably tin salts) was left behind). The solvents were removed from combined fractions and the resulting oil was dried under vacuum (1.12 g, 69.2% yield). GC/MS: 323 at 14.99 min (exact mass calculated for C₁₆H₂₅NS₂Si 323.1198). ¹H NMR (CDCl₃, 400 MHz): δ 7.74 (d, J=3.3 Hz, 1H), 7.45 (s, 1H), 7.21 (d, J=3.3 Hz, 1H), 2.65 (m, 2H), 1.65 (m, 2H), 1.45-1.25 (m, 6H), 1.38 (m, 3H), 0.37 (s, 18H); ¹³C{¹H} NMR (CDCl₃, 100 MHz): δ 161.9 (quaternary C), 151.1 (quaternary C), 143.2 (CH), 140.3 (quaternary C), 136.3 (quaternary C), 129.5 (CH), 117.8 (CH), 31.7 (CH₂), 31.8 (CH₂), 31.6 (CH₂), 31.3 (CH₂), 29.3 (CH₂), 22.5 (CH₂), 14.0 (CH₃), 0.1 (CH₃ of SiMe₃) (assignment of the quaternary, CH, CH₂ and CH₃ signals was made based on the DEPT experiment).

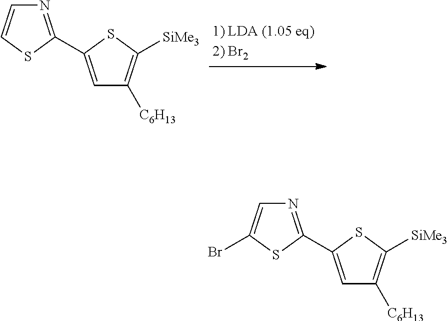

LDA was prepared from diisopropylamine (1.2 eq., 3.6 mmol, 0.36 g), n-butyllithium (2.5 M in hexanes, 3.15 mmol, 1.26 ml) and 10 ml of anhydrous THF. 2-(5-Trimethylsilyl-3-n-hexylthiophen-2-yl)-thiazole (3.0 mmol, 0.97 g) was dissolved in 20 ml of anhydrous THF in a three-necked round bottom flask equipped with magnetic stirbar, nitrogen inlet, thermometer and septum. The colorless solution was cooled in acetone/dry ice bath and freshly prepared LDA was added dropwise (−70 to −65° C. internal temperature). The light purple solution was stirred for 1 h and bromine (1.05 eq., 3.15 mmol, 0.50 g) was added dropwise. The grey reaction mixture became dark in color and then within minutes it became yellow-orange. The mixture was warmed to room temperature, treated with aqueous Na₂S₂O₃ and organic phase was separated. The aqueous phase was extracted with hexanes (3×15 ml) and combined organic phases were dried over MgSO₄. The solvents were removed by rotary evaporation and the crude product was obtained as orange oil, which was purified by column chromatography (100 ml of silica gel, hexanes:CH₂Cl₂ (3:2 as eluant). The solvent was removed from combined fractions and the yellowish oil was dried under vacuum (0.53 g, 43.9% yield). GC/MS: 401 and 403 at 17.08 min (exact mass calculated for C₁₆H₂₄BrNS₂Si 401.0303). ¹H NMR (CDCl₃, 400 MHz): δ 7.62 (s, 1H), 7.37 (s, 1H), 2.64 (t, J=8.0 Hz, 2H), 1.61 (m, 2H), 1.42-1.28 (m, 6H), 0.91 (t, J=6.7 Hz, 3H), 0.36 (s, 9H); ¹³C{¹H} NMR (CDCl₃, 100 MHz): δ 163.1 (quaternary C), 151.1 (quaternary C), 144.4 (CH), 139.7 (quaternary C), 137.1 (quaternary C), 129.6 (CH), 107.3 (quaternary C—Br), 31.7 (CH₂), 31.6 (CH₂), 31.3 (CH₂), 29.3 (CH₂), 22.6 (CH₂), 14.0 (CH₃), 0.1 (CH₃ of SiMe₃) (this material still contained ˜8% of impurity based on NMR analysis).

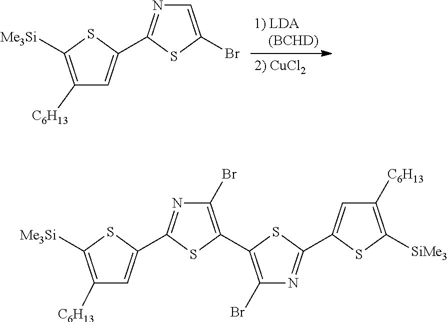

LDA (2.2 eq., 0.37 M, 6 ml) was prepared from diisopropylamine (2.4 mmol, 0.24 g), n-butyllithium (2.5 M in hexanes, 2.2 mmol, 0.9 ml) and 5 ml of anhydrous THF). 2-(5-Trimethylsilyl-3-n-hexyl-thiophen-2-yl)-5-bromothiazole (1.0 mmol, 0.40 g) was dissolved in 20 ml of anhydrous THF and the yellowish solution was cooled in acetone/dry ice bath (nitrogen atmosphere). Freshly prepared LDA (0.37 M in THF, 1.1 eq., 3 ml) was added dropwise to the bromothiazole derivative and the reaction mixture became light purple in color. The reaction mixture was stirred for 20 minutes and a small aliquot was removed for analysis as described immediately below, and treated with hexanes:MeOH. Organic solvents were removed from the analytical sample, and the residue was analyzed by GC/MS analysis and ¹H NMR. The NMR analysis of the analytical sample is shown by the aromatic region of ¹H NMR spectra (400 MHz, CDCl₃) of (a) starting 2-(5-trimethylsilyl-3-n-hexyl-thiophen-2-yl)-5-bromothiazole and (b) its BCHD reaction product, 2-(5-trimethylsilyl-3-n-hexyl-thiophen-2-yl)-4-bromothiazole.which showed a shift from 3048, 3041 and 2949 Hz to 7.473 and 7.102 ppm.

The completion of the BCHD reaction was confirmed by the NMR of the analytical sample, and CuCl₂ (1.1 eq., 0.148 g) was added in one portion to the remaining purple reaction mixture. After stirring for 5 minutes the color changed to yellowish-green and the mixture was slowly warmed to room temperature without cooling bath removal. Hexanes and water were added, the organic phase was removed and the aqueous phase was extracted with Et₂O (3×15-20 ml). The combined organic phases were dried over MgSO₄ and the solvents were removed by rotary evaporation to give crude product as dark yellow solid. This crude product was purified by column chromatography (50 ml of silica gel, hexanes:CH₂Cl₂ (3:2) and bright yellow-orange solid was obtained (0.27 g, 67.3%). Minor impurities were detected by the TLC analysis and material was further purified by the column chromatography (100 ml of silica gel, Hexanes:CH₂Cl₂ (35:15). The solvents were removed from combined fractions and product was obtained as yellow-orange oil which solidified on standing (0.13 g, 48% recovery, 32% yield). HRMS calculated for C₃₂H₄₆Br₂N₂S₄Si₂ 800.0449; found 800.0420. ¹H NMR (CDCl₃, 400 MHz): δ 7.53 (s, 2H), 2.66 (t, J=8.0 Hz, 4H), 1.62 (m, 4H), 1.45-1.30 (m, 12H) 0.98 (t, J=6.9 Hz, 6H), 0.38 (s, 18H); ¹³C{¹H} NMR (CDCl₃, 100 MHz): δ 162.1 (quaternary C), 151.4 (quaternary C), 139.0 (quaternary C), 138.5 (quaternary C), 130.5 (CH), 127.6 (quaternary C), 1210 (quaternary C), 31.7 (CH₂), 31.6 (CH₂), 31.3 (CH₂), 29.3 (CH₂), 22.6 (CH₂), 14.1 (CH₃), 0.1 (CH₃) (assignment of the quaternary, CH, CH₂ and CH₃ signals was made based on the DEPT experiment). Elemental analysis calculated for C₃₂H₄₆Br₂N₂S₄Si₂: C, 47.87; H, 5.77; N, 3.49. Found: C, 47.72; H, 5.77; N, 3.47.

### Example 8

### 2,6-Bis-trimethylsilanyl-cyclopenta[1,2-b:5,4-b′]dithiophen-4-one (1b)

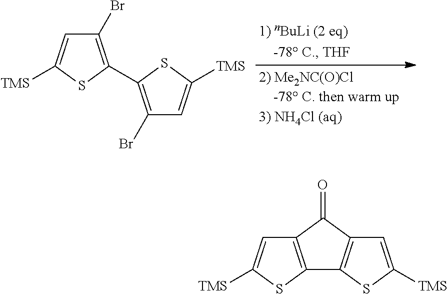 [SMILES: C[Si](C)(C)c1cc(Br)c(-c2sc([Si](C)(C)C)cc2Br)s1 ; C[Si](C)(C)c1cc2c(s1)-c1sc([Si](C)(C)C)cc1C2=O]

3,3′-Dibromo-5,5′-bis-trimethylsilanyl-2,2′-bithiophene (1a) (25.62 mmol, 12.00 g) was dissolved in anhydrous THF (100 ml) under nitrogen atmosphere and the colorless solution was cooled in acetone/dry ice bath. n-Butyllithium (2.5 M in hexanes, 2 eq., 51.24 mmol, 20.5 ml) was added and the colorless reaction mixture became bright yellow in color. After stirring for 15 minutes N,N-dimethylcarbamoyl chloride (1 eq., 25.62 mmol, 2.76 g) in 20 ml of anhydrous THF was added dropwise and the deep-yellow mixture was allowed to warm up. The mixture was stirred for 2.5 h and NH₄Cl (10 g) in water (75 ml) was added carefully, and the dark orange-brown solution became intense red (almost black red). The dark red organic phase was removed, the aqueous phase was extracted with hexanes several times, and the combined organic extracts were dried over MgSO₄. The solvents were removed by rotary evaporation and the crude product (11.0 g) was purified by Kugelrohr distillation. Bright red oil was collected at 190° C./0.25 mm Hg and some brown-orange matter was left in the original distillation flask. The product was obtained as bright red solid in 85.8% yield (7.40 g). Analytically pure compound was obtained after column chromatography purification (silica gel, hexanes as eluant to remove minor impurities, then hexanes:EtOAc (30:1) as eluant for the product). IR (KBr, cm⁻¹): 2955, 2896, 1702, 1466, 1420, 1355, 1248, 1168, 1020, 961, 838, 753, 695, 620, 556, 487. UV-vis (CH₂Cl₂) λₘₐₓ (nm) 273, 282, 494. HRMS (EI) calculated for C₁₅H₂₀OS₂Si₂ 336.0494; found 336.0490. ¹H NMR (400 MHz, CDCl₃): δ 7.07 (s, 2H, two Th—H), 0.32 (s, 18H, two SiMe₃). ¹³C{¹H} NMR (400 MHz, CDCl₃): δ 183.1, 154.3, 144.9, 144.1, 127.9, −0.3. Anal. Calc. for C₁₅H₂₀OS₂Si₂: C, 53.52; H, 5.99. Found: C, 53.39; H, 6.11.

### Example 9

### 2,6-Bis(trimethylsilyl)-4-(3,4,5-tris(dodecyloxy)phenyl)-4H-dithieno[3,2-b:2′,3′-d]pyrrole (1c)

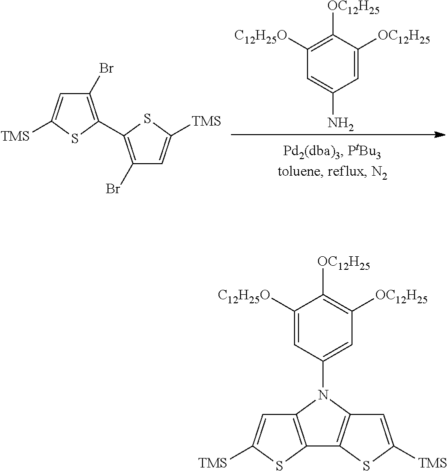

Catalyst Pd₂(dba)₃ (0.125 mmol, 0.115 g, where dba is tris(dibenzylideneacetone)dipalladium(0)), tri-^{t}butylphosphine (10 wt % in hexanes, 0.625 mmol, 1.26 ml) and 25 ml of anhydrous toluene were stirred under nitrogen atmosphere for 20 minutes (dark purple solution) and 3,3′-dibromo-5,5′-bis-trimethylsilanyl-2,2′-bithiophene (1a) (2.5 mmol, 1.17 g), 3,4,5-tris(dodecyloxy)aniline (2.625 mmol, 1.695 g) and ^{t}BuONa (11.5 mmol, 1.09 g) were added (nitrogen atmosphere). The resulting dark brown-orange mixture was refluxed for 0.5 h, analyzed by TLC (hexanes as eluant) and consumption of the starting dibromide 1a was confirmed and a new more polar product was detected. The reaction mixture was cooled to room temperature and treated with ˜15 ml of water. The brown organic phase was separated and the aqueous phase was extracted with hexanes (2×˜15 ml). The combined organic phases were dried over MgSO₄, the solvents were removed by rotary evaporation and the crude product was purified by column chromatography (150 ml of silica gel, hexanes and then hexanes:CH₂Cl₂ (2:1) as eluants). Combined fractions were subjected to rotary evaporation and the residue was dried under vacuum. The product was obtained as very thick yellowish oil (52.9% yield). UV-vis (CH₂Cl₂) λₘₐₓ (nm) 266, 315, 329. MS (MALDI) calculated for C₅₆H₉₇NO₃S₂Si₂ 951.6448; found 951.6. ¹H NMR (400 MHz, CDCl₃): δ 7.21 (s, 2H), 6.78 (s, 2H), 4.02 (m, 6H), 1.84 (m, 6H), 1.51 (m, 6H), 1.45-1.15 (m, 48H), 0.90 (m, 6H), 0.37 (s, 18H); ¹³C{¹H} NMR (400 MHz, CDCl₃): δ 153.7 (quaternary C), 147.0 (quaternary C), 139.3 (quaternary C), 136.5 (quaternary C), 135.4 (quaternary C), 121.6 (quaternary C), 117.9 (CH), 102.2 (CH), 73.7 (CH₂), 69.3 (CH₂), 31.9 (4) (CH₂), 31.9 (2) (CH₂), 30.4 (CH₂), 29.8 (CH₂), 29.8 (CH₂), 29.7 (CH₂), 29.7 (CH₂), 29.4 (CH₂), 29.4 (CH₂), 29.3 (CH₂), 26.2 (CH₂), 26.1 (CH₂), 22.7 (CH₂), 14.1 (CH₃), −0.1 (CH₃) (assignment was made based on DEPT experiment; several CH₂ carbons in the alkyl chains are missing presumably due to overlap). Anal. Calc. for C₅₆H₉₇NO₃S₂Si₂: C, 70.60; H, 10.26; N, 1.47. Found: C, 70.59; H, 10.52; N, 1.55.

### Example 10

### 2,7-Bis-trimethylsilyl-benzo[1,2-b:6,5-b′]dithiophene-4,5-dione (1d)

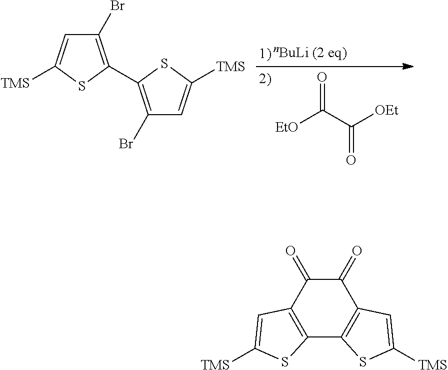 [SMILES: C[Si](C)(C)c1cc(Br)c(-c2sc([Si](C)(C)C)cc2Br)s1 ; CCOC(=O)C(=O)OCC ; C[Si](C)(C)c1cc2c(s1)-c1sc([Si](C)(C)C)cc1C(=O)C2=O]

3,3′-Dibromo-5,5′-bis-trimethylsilyl-2,2′-dithiophene (1a) (60.0 mmol, 28.11 g) was dissolved in anhydrous THF (240 mL), the solution was cooled in acetone/dry ice bath and n-butyllithium (2.87 M in hexanes, 2 eq., 120.0 mmol, 41.8 mL (caution! added in several portions with volume less than 20 mL) was added dropwise. The yellow-orange solution was stirred for 0.5 h and then transferred via cannula into a solution of diethyl oxalate (1.3 eq., 78.0 mmol, 11.40 g) in 200 mL of anhydrous THF (cooled in acetone/dry ice bath). After completion of the addition of the di-lithiated species to the diethyl oxalate, the orange-reddish mixture was stirred for 45 minutes and transferred via cannula into a solution of aqueous NH₄Cl. The dark red organic phase was separated, the aqueous phase was extracted with hexanes, and the combined organic phases were dried over MgSO₄. The solvents were removed by rotary evaporation and the crude product was heated to reflux with ˜500 ml of ethanol, cooled to room temperature, and dark-red needles were separated by the vacuum filtration (16.3 g, 76.7% yield). The mother liquor was subjected to rotary evaporation and the residue was recrystallized from ethanol to give additional amount of product (0.7 g, total yield 17.0 g, 79.9%). ¹H NMR (CDCl₃, 400 MHz): δ 7.60 (s, 2H), 0.36 (s, 18H, 6CH₃); ¹³C {¹H} NMR (CDCl₃, 100 MHz): δ 175.2 (quaternary C), 148.3 (quaternary C), 142.5 (quaternary C), 135.8 (quaternary C), 134.4 (CH), −0.44 (CH₃). HRMS (EI) calculated for C₁₆H₂₀O₂S₂Si₂ 364.0443; found 364.0469. Anal. Calc. for C₁₆H₂₀O₂S₂Si₂: C, 52.70; H, 5.53. Found: C, 52.70; H, 5.36.

Alternatively this compound was prepared using N,N-dimethyl-piperazine-2,3-dione instead of diethyl oxalate. 3,3′-Dibromo-5,5′-bis-trimethylsilanyl-2,2′-bithiophene (6.5 mmol, 3.045 g) was dissolved in anhydrous THF (100 ml), the colorless solution was cooled in acetone/CO₂ bath and n-BuLi (2.5M in hexanes, 13.0 mmol, 5.2 ml) was added dropwise. Bright yellow solution was stirred for 25 minutes and N,N-dimethyl-piperazine-2,3-dione (6.5 mmol, 0.924 g) was added in one portion. The flask was placed into ice-water bath, and the mixture was stirred for 17 h. The orange-yellow mixture was treated with aqueous NH₄Cl and the dark red organic phase was separated. The aqueous phase was extracted with Et₂O (2×15 ml) and combined organic phases were dried over MgSO₄. The solvent was removed by rotary evaporation and the residue was purified by column chromatography (250 ml of silica gel, hexanes:CH₂Cl₂:EtOAc (200:100:3 and then 200:100:6) as eluants. Combined fractions were subjected to rotary evaporation and material was obtained as red tiny needles (0.98 g, 41.4% yield). This material was recrystallized from ˜40 ml of EtOH, and dark red needles were collected by vacuum filtration (0.94 g, 95.9% recovery).

### Example 11

### 2,6-Bis(trimethylsilyl)-4-(3,4,5-tris(dodecyloxy)phenyl)-4H-diselenopheno[3,2-b:2′,3′-d]pyrrole (2b)

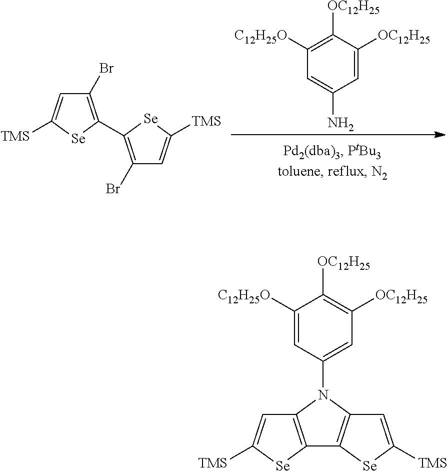

Catalyst Pd₂(dba)₃ (0.319 mmol, 0.292 mg), tri-^{t}butylphosphine (10 wt % in hexanes, 1.60 mmol, 3.23 ml) and 75 ml of anhydrous toluene were stirred for 20 minutes (purple solution) under nitrogen atmosphere and 5,5′-trimethylsilyl-3,3′-dibromo-2,2′-biselenophene (2a) (6.386 mmol, 3.59 g), 3,4,5-tris(dodecyloxy)aniline (6.70 mmol, 4.33 g) and ^{t}BuONa (29.38 mmol, 2.79 g) were added. The resulting dark brown-orange mixture was refluxed for 1 h, analyzed by TLC (hexanes as eluant) and consumption of dibromide 2a was confirmed. The brown mixture was cooled to room temperature, treated with water (˜20 ml) and brown organic phase was removed. The aqueous phase was extracted with hexanes (2×20 ml) and combined organic phases were dried over MgSO₄. The solvents were removed by rotary evaporation and the crude product was obtained as brown oil. This material was purified by the column chromatography (550 ml of silica gel, hexanes (700 ml) and then hexanes:CH₂Cl₂ (2:1) as eluants). The solvent was removed by rotary evaporation and purified material was obtained as yellow oil (it typically solidifies on standing during the storage in refrigerator). MS (MALDI) calculated for C₅₆H₉₇NO₃Se₂Si₂ 1047.5337, found 1047.54. ¹H NMR (CDCl₃, 400 MHz): δ 7.49 (s, 2H), 6.73 (s, 2H), 4.05 (t, J=6.6 Hz, 2H), 3.99 (t, J=6.5 Hz, 4H), 1.84 (m, 6H), 1.49 (m, 6H), 1.28 (m, 48H), 0.89 (m, 9H), 0.35 (s, 18H); ¹³C{¹H} NMR (CDCl₃, 100 MHz): δ 153.6, 147.6, 145.3, 136.9, 135.3, 122.7, 121.2, 103.27, 73.6, 69.3, 32.0, 31.9, 31.6, 30.4, 29.8, 29.7, 29.7, 29.4, 29.4, 29.3, 26.2, 26.1, 22.68, 22.7, 14.1, 0.3 (several CH₂ signals of alkyl groups are missing due to overlap). Anal. Calc. For C₅₆H₉₇NO₃Se₂Si₂: C, 64.27; H, 9.34; N, 1.34. Found: C, 64.38; H, 9.30; N, 1.37.

### Example 12

### 2,6-Bis-trimethylsilanyl-3,5-di-n-hexyl-cyclopenta[1,2-b:5,4-b′]dithiophen-4-one (3b)

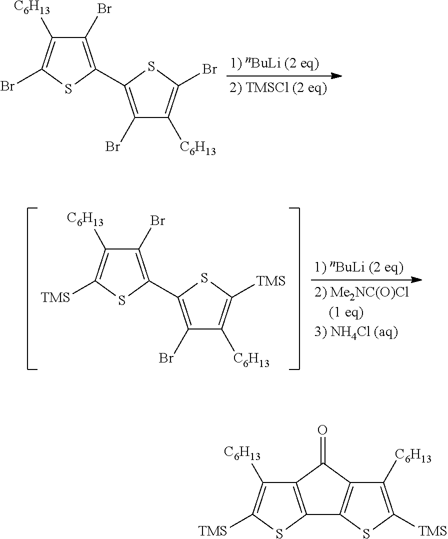

3,3′,5,5′-Tetrabromo-4,4′-di-n-hexyl-2,2′-bithiophene (23.0 mmol, 14.95 g) (3b) was dissolved in 200 ml of anhydrous THF, the solution was cooled in acetone/dry ice bath and n-butyllithium (2.5 M in hexanes, 46.0 mmol, 18.4 ml) was added dropwise (−70-65° C.). During the addition of n-BuLi the light yellowish reaction mixture became darker in color (yellow-orange), but when ˜1.5 ml of n-butyllithium was still in the syringe, the mixture became lighter yellow. The reaction mixture was stirred for 0.5 h and chlorotrimethylsilane (46.0 mmol, 5.00 g) was added dropwise (exothermic reaction), stirred for 20 min and analyzed by GC/MS. Clean formation of 3,3′-dibromo-4,4′-dihexyl-5,5′-bis-trimethylsilyl-2,2′-bithiophene was confirmed and n-butyllithium (2.5 M in hexanes, 46.0 mmol, 18.4 ml) was added dropwise (−70 to −68° C. internal temperature). The reaction mixture was analyzed by GC/MS after 5 minutes of stirring and clean lithiation was confirmed. N,N-Dimethylcarbamoyl chloride (23.0 mmol, 2.47 g) in 10 ml of anhydrous THF was added dropwise and the mixture became darker yellow in color. The reaction flask was partially removed from the cooling bath and the mixture was warmed to −40-30° C. After 40 minutes of stirring the mixture was analyzed by TLC (hexanes:EtOAc (20:1) and the product was detected as a major material. GC/MS analysis showed the presence of three species: de-brominated material (A, 17.4%), desired product (3b, 44.7%) and non-eliminated intermediate (B, 37.9%).

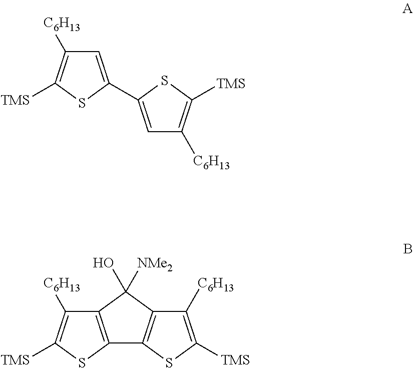

The mixture was stirred for 1.5 h, treated with NH₄Cl (12 g in 50 ml of water) (—30° C. internal temperature), warmed to room temperature and the dark red organic phase was separated. The aqueous phase was extracted with hexanes and combined organic phases were dried over MgSO₄. The solvent was removed by rotary evaporation and the crude product was obtained as thick red oil. This material was purified by column chromatography (200 ml of silica gel, hexanes as eluant). Fractions with a pure material were combined, the solvent was removed and the product was dried under vacuum (3.72 g). Fractions with slightly contaminated material were combined separately and further purified by column chromatography to give dark red oil, which solidified on standing (2.73 g). Total yield of the pure material was 6.45 g (55.6% yield). UV-vis (CH₂Cl₂) λₘₐₓ: 278, 287, 499. HRMS (EI) calculated for C₂₇H₄₄OS₂Si₂ 504.2370; found 504.2362. ¹H NMR (CDCl₃, 400 MHz): δ 2.63 (m, 4H), 1.55 (m, 4H), 1.40-1.25 (m, 12H), 0.87 (t, J=6.8 Hz, 6H), 0.31 (s, 18H); ¹³C{¹H}NMR (CDCl₃, 100 MHz): δ 184.5, 153.1, 147.4, 143.5, 137.1, 31.7, 31.1, 29.7, 29.3, 22.7, 14.1, 0.4. Anal. Calc. for C₂₇H₄₄OS₂Si₂: C, 64.22; H, 8.78. Found: C, 64.22; H, 8.94.

### Example 13

### 2,7-Bis-trimethylsilyl-2,6-di-n-hexyl-benzo[1,2-b:6,5-b′]dithiophene-4,5-dione (1d)

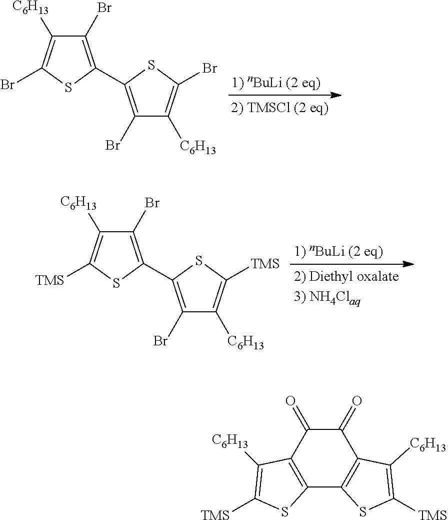

3,3′,5,5′-Tetrabromo-4,4′-di-n-hexyl-2,2′-bithiophene (3.076 mmol, 2.00 g) (3b) was dissolved in 60 ml of anhydrous THF under nitrogen atmosphere, the solution was cooled in acetone/dry ice bath and n-butyllithium (2.5 M in hexanes, 6.15 mmol, 2.5 ml) was added dropwise to the yellowish solution The reaction mixture was stirred for 15 minutes and chlorotrimethylsilane (6.15 mmol, 0.67 g) was added dropwise. The mixture was stirred for 15 minutes and n-butyllithium (2.5 M in hexanes, 6.15 mmol, 2.5 ml) was added dropwise. The reaction mixture was stirred for 0.5 h and the yellow solution was transferred via cannula to a solution of diethyl oxalate (4.24 mmol, 0.62 g) in 60 ml of THF cooled in acetone/dry ice bath. The dark yellow-brown reaction mixture was stirred for 0.5 h and transferred via cannula to an aqueous solution of NH₄Cl (13 g in 50 ml of water). Dark red organic phase was separated, the organic phase was dried over MgSO₄ and the solvents were removed by rotary evaporation to give crude product as red thick oil. This material was purified by column chromatography (250 ml of silica gel, hexanes:CH₂Cl₂ (3:2) to pack the column, hexanes to elute byproducts and then hexanes:CH₂Cl₂ (3:2) to elute the product). Solvents were removed from combined fractions (red) to give dark red oil which was dried under vacuum (oil solidified on standing, 0.56 g, 34.1%). HRMS (EI) calculated for C₂₈H₄₄O₂S₂Si₂ 532.2321; found 532.2325. ¹H NMR (CDCl₃, 400 MHz): δ 2.89 (poorly resolved t, 4H), 1.47 (m, 8H), 1.33 (m, 8H), 0.90 (poorly resolved t, 6H), 0.39 (s, 18H); ¹³C{¹H} NMR (CDCl₃, 100 MHz): δ 175.8 (quaternary C(O), 154.0 (quaternary C), 149.1 (quaternary C), 135.0 (quaternary C), 133.3 (quaternary C), 31.6 (CH₂), 30.9 (CH₂), 30.8 (CH₂), 29.8 (CH₂), 22.7 (CH₂), 14.1 (CH₃), 0.2 (CH₃) (the assignment of the carbon signals was made based on the DEPT experiment). Anal. Calc. for C₂₈H₄₄O₂S₂Si₂: C, 63.10; H, 8.32. Found: C, 62.89; H, 8.40.

### Example 14

### 2,6-Bis-trimethylsilanyl-cyclopenta[2,1-b;3,4-b′]dithiazole-4-one (4b)

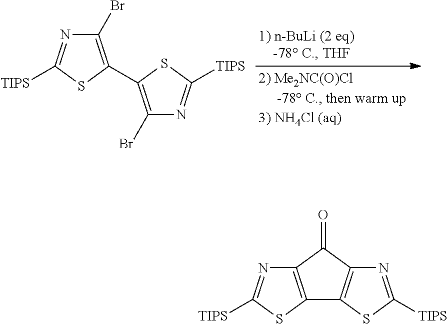

4,4′-Dibromo-2,2′-bis(triisopropylsilyl)-5,5′-bithiazole (4a) (2.0 mmol, 1.277 g) was dissolved in 80 ml of anhydrous THF under nitrogen atmosphere, the resulting colorless solution was cooled in acetone/dry ice bath and n-butyllithium (2.5 M in hexanes, 4.0 mmol, 1.6 ml) was added dropwise. The yellow solution was stirred for 20 minutes, and N,N-dimethylcarbamoyl chloride (2.0 mmol, 0.215 g) in 1 ml of anhydrous THF was added dropwise. The reaction flask was partially removed from the cooling bath, the yellow-orange mixture was stirred for 1 h, and treated with aqueous NH₄Cl. The red organic phase was removed, the aqueous phase was extracted with hexanes and combined organic phases were dried over MgSO₄. The solvents were removed by rotary evaporation and the red residue was purified by column chromatography (150 ml of silica gel, CH₂Cl₂ as eluant). The solvent was removed from combined fractions and red solid was obtained (0.392 g, 38.8% yield). UV-vis (CH₂Cl₂) λₘₐₓ: 267, 309, 492. HRMS (EI) calculated for C₂₅H₄₂N₂₀S₂Si₂ 506.2277; found 506.2239. ¹H NMR (CDCl₃, 400 MHz): δ 1.46 (septet, J=7.4 Hz, 6H), 1.15 (d, J=7.5 Hz, 36H); ¹³C{¹H} NMR (CDCl₃, 100 MHz): δ 179.0, 174.0, 158.2, 145.3, 18.4, 11.6. Anal. Calc. for C₂₅H₄₂N₂₀S₂Si₂: C, 59.23; H, 8.35; N, 5.53. Found: C, 59.43; H, 8.44; N, 5.55.

### Example 15

### 2,7-Bis-trimethylsilyl-benzo[2,1-b:3,4-b′]dithizole-4,5-dione (4c)

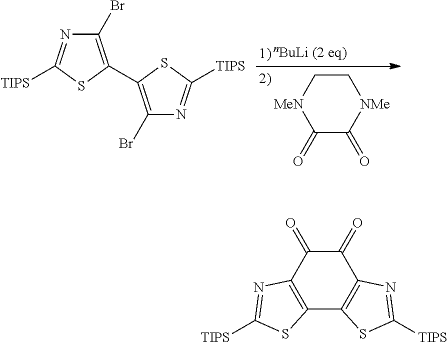

4,4′-Dibromo-2,2′-bis(triisopropylsilyl)-5,5′-bithiazole (4a) (1.5 mmol, 0.958 g) was dissolved in 75 ml of anhydrous THF under nitrogen atmosphere and the colorless solution was cooled in acetone/dry ice bath. n-Butyllithium (2.5 M in hexanes, 3.0 mmol) was added dropwise and the mixture became bright yellow. N,N-Dimethyl-piperazine-2,3-dione (1.5 mmol, 0.213 g) was added in one portion and the flask with suspension was placed into a water-ice bath. The mixture was stirred overnight, and orange-reddish solution was treated with NH₄Cl. The mixture became very dark in color and then orange-red. The organic phase was separated, the aqueous phase was extracted with hexanes and combined organic phases were dried over MgSO₄. The solvents were removed by rotary evaporation and the residue was purified by column chromatography (150 ml of silica gel, hexanes:CH₂Cl₂ (2:1, 1:1) as eluants). First two fractions with the product were kept separately and pure (by TLC) material was obtained (few mg). Fractions with slightly contaminated material were combined separately, the solvents were removed by rotary evaporation and the product was obtained as orange-red solid (0.21 g, 26.1% yield). HRMS (EI) calculated for C₂₆H₄₂N₂O₂S₂Si₂ 534.2226; found 534.2241. ¹H NMR (CDCl₃, 400 MHz): δ 1.51 (septet, J=7.5 Hz, 6H), 1.18 (d, J=7.5 Hz, 36H); ¹³C NMR (CDCl₃, 100 MHz): δ 174.0, 172.4, 149.8, 140.6, 18.4, 11.6. Anal. Calc. for C₂₆H₄₂N₂O₂S₂Si₂: C, 58.38; H, 7.91; N, 5.24. Found: C, 58.51; H, 7.98; N, 5.16.

### Example 15a

### 2,7-Bis-triisopropylsilyl-benzo[1,2-d:4,3-d]bis(thiazole)-4,5-dione

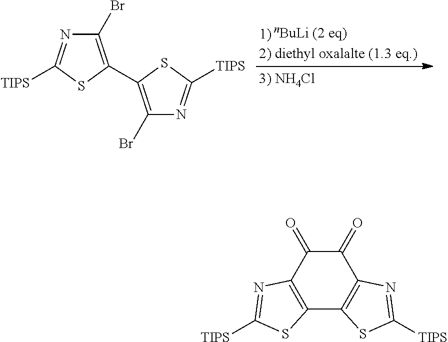

2,2′-Bis(triisopropylsilyl)-4,4′-dibromo-5,5′-dithiazole (20.0 mmol, 12.77 g) was dissolved in anhydrous THF (200 mL) under nitrogen atmosphere, and the resulting solution was cooled in pyridine/dry ace bath (˜−40 to −45° C. bath). n-Butyllithium (2.85 M in hexanes, 40.0 mmol, 14 mL) was added dropwise, stirred for 15 minutes, and then the suspension was transferred via cannula to a solution of diethyl oxalate (1.3 eq., 26.0 mmol, 3.80 g) in anhydrous THF (150 mL) (acetone/dry ice bath). The reaction mixture was stirred for ˜1 h, and then transferred via cannula to an aqueous solution of NH₄Cl. The resulting mixture with some insoluble white matter was vacuum filtered, orange-red organic phase was removed, and aqueous phase was extracted with hexanes:diethyl ether. Combined organic phases were dried over anhydrous magnesium sulfate, the drying agent was filtered off, the solvents were removed by rotary evaporation, and the crude product was purified by column chromatography (silica gel, dichloromethane to pack the column, dichloromethane:ethyl acetate (100:1) as eluant). First few fractions containing contaminated product were kept separately; later fractions with the pure product were combined, and the solvents was removed by rotary evaporation to give 2,7-bis-triisopropylsilyl-benzo[1,2-d:4,3-d′]bis(thiazole)-4,5-dione as red-orange solid (6.74 g, 63% yield). ¹H NMR analysis was in agreement with the literature data (Getmanenko, Y. A.; Risko, C.; Tongwa, P.; Kim, E. G.; Li, H.; Sandhu, B.; Timofeeva, T.; Bredas, J. L.; Marder, S. R. J Org Chem 2011, 76, 2660)

### Example 16

### 2,6-Di-iodo-cyclopenta[1,2-b:5,4-b′]dithiophen-4-one

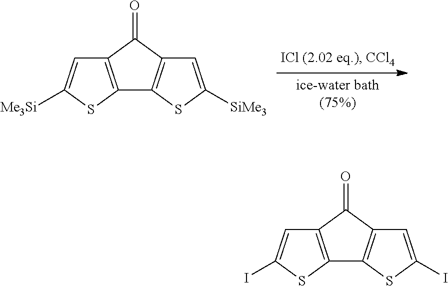 [SMILES: C[Si](C)(C)c1cc2c(s1)-c1sc([Si](C)(C)C)cc1C2=O ; O=C1c2cc(I)sc2-c2sc(I)cc21]

2,6-Bis-trimethylsilanyl-cyclopenta[1,2-b:5,4-b′]dithiophen-4-one (3.00 mmol, 1.01 g) was dissolved in 20 ml of CCl₄, a very dark red solution was cooled in ice-water bath and iodine monochloride (2.02 eq., 6.06 mmol, 0.98 g) in 10 ml of CH₂Cl₂ was added dropwise. The mixture changed color to dark purple. The cooling bath was removed, and the mixture was stirred for an hour and precipitation was observed. Water (50 ml) and several crystals of Na₂S₂O₃ were added, the bottom layer was separated, and the purple solution was dried over MgSO₄. The solvent was removed by rotary evaporation and the residue was dissolved in toluene-hexanes mixture under heating. The solution was cooled in ice-water bath and product was isolated as purple solid with some shine (0.65 g, 48.9% yield). The filter with MgSO₄ was thoroughly washed with CHCl₃, the purple solution was washed with aqueous Na₂S₂O₃, and the solvent was removed by rotary evaporation. The residue was heated with ˜30 ml of EtOAc, and the very dark solution was cooled to room temperature and then in ice-water bath. Additional amount of purple solid was obtained (0.35 g). The total amount of the product is 75.2% (1.00 g). HRMS calculated for C₉H₂I₂OS₂ 443.7636; found 443.7644. UV-vis (THF) λₘₐₓ: 207, 284, 518 (weak). ¹H NMR (THF-d8, 400 MHz): δ 7.20 (s, 2H); ¹³C{¹H}NMR (THF-d8, 100 MHz): δ 179.7, 154.5, 142.7, 131.2, 77.7. Anal. Calc. for C₉H₂I₂OS₂: C, 24.34; H, 0.45. Found: C, 24.74; H, 0.43.

### Example 17

### 2,7-Dibromo-benzo[1,2-b:6,5-b′]dithiophene-4,5-dione

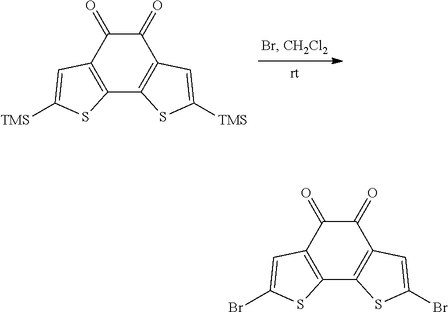 [SMILES: C[Si](C)(C)c1cc2c(s1)-c1sc([Si](C)(C)C)cc1C(=O)C2=O ; O=C1C(=O)c2cc(Br)sc2-c2sc(Br)cc21]

2,7-Bis-trimethylsilyl-benzo[1,2-b:6,5-b′]dithiophene-4,5-dione (4.0 mmol, 1.459 g) was dissolved in dichloromethane (40 ml) and bromine (2.2 eq., 8.8 mmol, 1.41 g) was added dropwise to a red-black solution. The reaction mixture became purple-black. The reaction mixture was analyzed by TLC (CH₂Cl₂ as eluant), and a new product and a minor impurity was detected. Additional amount of bromine (0.33 g) was added, the mixture was stirred for 0.5 h and treated with 10 ml of aqueous Na₂S₂O₃. The organic solvent was removed by rotary evaporation and the crude product was separated by vacuum filtration (1.95 g, 128% crude yield, slightly wet). This crude material was purified by column chromatography (300 ml of silica gel, CH₂Cl₂ as eluant). The solvent was removed from the combined fractions 3-12 and the black shiny microcrystalline material was obtained (0.90 g, 59.5% yield). The heavily stained column was eluted with chloroform, the solvent was removed from the combined fractions and additional amount of black microcrystalline solid was obtained (0.52 g, 34.4% yield). HRMS (EI) calculated for C₁₀H₂Br₂O₂S₂ 375.7863; found 375.7869. ¹H NMR (CDCl₃, 400 MHz): δ 7.47 (s, 2H); ¹³C{¹H} NMR (CDCl₃, 100 MHz): δ 172.5 (quaternary C), 143.6 (quaternary C), 135.4 (quaternary C), 130.1 (CH), 114.7 (quaternary C—Br) (assignment of the quaternary and CH signals was made based on the DEPT experiment). Anal. Calc. for C₁₀H₂Br₂O₂S₂: C, 31.77; H, 0.53. Found: C, 32.06; H, 0.40.

### Example 18

### 2,7-Dibromo-benzo[1,2-b:6,5-b′]dithiophene-4,5-dione

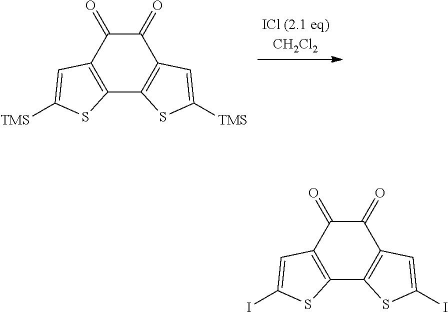 [SMILES: C[Si](C)(C)c1cc2c(s1)-c1sc([Si](C)(C)C)cc1C(=O)C2=O ; O=C1C(=O)c2cc(I)sc2-c2sc(I)cc21]

2,7-Bis-trimethylsilyl-benzo[1,2-b:6,5-b′]dithiophene-4,5-dione (2.58 mmol, 0.94 g) was dissolved in 25 ml of CH₂Cl₂ and iodine monochloride (2.1 eq., 5.41 mmol, 0.88 g) in 10 ml of CH₂Cl₂ was added dropwise to a dark red solution. The reaction mixture became purple in color and precipitate was observed. The mixture was stirred for ˜2 h at room temperature, treated with hexanes (˜30 ml) and brown-black solid was separated by vacuum filtration (1.21 g, 99.3% crude yield). This material was purified by column chromatography using hot CHCl₃ to apply the material and then CHCl₃:EtOAc (150:1) to elute the product. Fractions with pure compound were combined separately and black shiny solid was obtained after removal of the solvents (0.70 g). Fractions with slightly contaminated material were combined separately and black shiny solid was obtained after solvents removal (0.466 g). ¹H NMR (THF-d8, 400 MHz): δ 7.64 (s, 2H); ¹³C{¹H} NMR (THF-d8, 100 MHz): δ 172.6 (quaternary C), 147.0 (quaternary C), 138.4 (quaternary C), 137.4 (CH), 77.2 (quaternary C—I) (assignment of the quaternary and CH signals was made based on the DEPT experiment). HRMS (EI) calculated for C₁₀H₂I₂O₂S 471.7586; found 471.7608. Anal. Calc. for C₁₀H₂I₂O₂S₂: C, 25.44; H, 0.43. Found: C, 23.91; H, 0.54 (the TGA and NMR analysis confirmed the presence of CHCl₃, and this elemental analysis is in agreement with a material which has 1:1 ratio of diiodide and chloroform). Material was also recrystallized from toluene to potentially avoid co-crystallization with the solvent which observed for chloroform, but NMR and TGA analysis of the sample showed the presence of toluene in a sample (3.7% by TGA).

### Example 19

### 3,6-Di-n-hexyl-2,7-dibromo-benzo[1,2-b:6,5-b′]dithiophene-4,5-dione

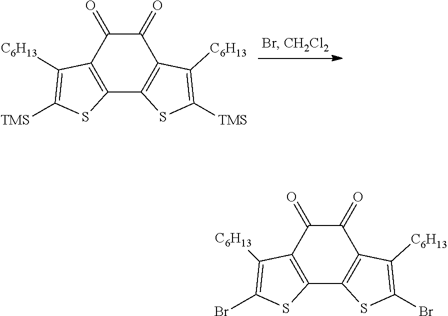

3,6-Di-n-hexyl-2,7-bis-trimethylsilyl-benzo[1,2-b:6,5-b′]dithiophene-4,5-dione (0.70 mmol, 0.37 g) was dissolved in dichloromethane (20 ml) and bromine (2.2 eq., 1.54 mmol, 0.25 g) was added dropwise to a red-purple solution. The dark purple mixture was stirred for 0.5 h and aqueous Na₂S₂O₃ was added. The organic phase was removed, dried over MgSO₄ and the solvent was partially removed by rotary evaporation. Purple solution was column chromatographed (250 ml of silica gel, hexanes:CH₂Cl₂ (1:1) to pack the column, hexanes to elute the byproduct, then hexanes:CH₂Cl₂ (1:1) to elute the product). Several fractions with slightly contaminated product was further purified by recrystallization from 2-PrOH and material was obtained as purple solid (0.163 g). Fractions with pure material were subjected to rotary evaporation and the residue was recrystallized from 2-PrOH to give purple solid (0.078 g). Total yield of the product is 63.2% (0.242 g). HRMS (EI) calculated for C₂₂H₂₆Br₂O₂S₂ 543.9741; found 543.9722. ¹H NMR (CDCl₃, 400 MHz): δ 2.88 (t, J=7.6 Hz, 4H), 1.51 (m, 4H), 1.38 (m, 4H), 1.32 (m, 8H), 0.91 (t, J=6.9 Hz, 6H); ¹³C{¹H} NMR (CDCl₃, 100 MHz): δ 173.5 (quaternary C), 145.5 (quaternary C), 144.1 (quaternary C), 131.8 (CH), 111.7 (quaternary C—Br), 31.5 (CH₂), 29.1 (CH₂), 28.7 (CH₂), 28.5 (CH₂), 22.6 (CH₂), 14.1 (CH₃) (assignment of the carbon signals was made based on the DEPT experiment). Anal. Calc. for C₂₂H₂₆Br₂O₂S₂: C, 48.36; H, 4.80. Found: C, 48.46; H, 4.81.

### Example 20

### 3,6-Di-n-hexyl-2,7-di-iodo-benzo[1,2-b:6,5-b′]dithiophene-4,5-dione

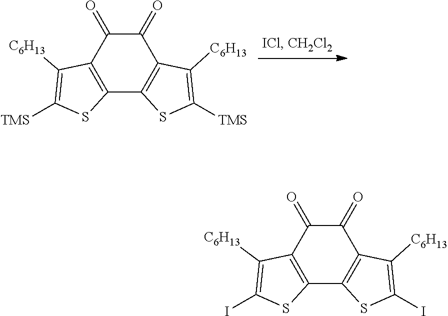

3,6-Di-n-hexyl-2,7-bis-trimethylsilyl-benzo[1,2-b:6,5-b′]dithiophene-4,5-dione (0.20 mmol, 0.107 g) was dissolved in dichloromethane (10 ml) and iodine monochloride (2.1 eq., 0.42 mmol, 0.068 g) was added dropwise to a dark red-purple solution. The purple mixture was stirred for 20 minutes and aqueous Na₂S₂O₃ was added. The purple organic phase was removed, dried over MgSO₄ and the solvent was removed by rotary evaporation. Crude product was purified by column chromatography (30 ml of silica gel, hexanes:CH₂Cl₂ (2:1) as eluant). The combined fractions were subjected to rotary evaporation and the residue was purified from 2-PrOH (˜10 ml). Material was obtained as purple solid in 55.9% yield (0.0716 mg). HRMS (EI) calculated for C₂₂H₂₆I₂O₂S₂ 639.9464; found 639.9468. ¹H NMR (CDCl₃, 400 MHz): δ 2.86 (t, J=7.4 Hz, 4H), 1.44 (m, 8H), 1.23 (m, 8H), 0.92 (t, J=7.0 Hz, 6H); ¹³C{¹H} NMR (CDCl₃, 100 MHz): δ 173.1 (quaternary C), 145.5 (quaternary C), 148.8 (quaternary C), 131.3 (CH), 78.0 (quaternary C—I), 31.5 (CH₂), 31.2 (CH₂), 29.2 (CH₂), 28.9 (CH₂), 22.6 (CH₂), 14.10 (CH₃) (assignment of the carbon signals was made based on the DEPT experiment). Anal. Calc. for C₂₂H₂₆I₂O₂S₂: C, 41.26; H, 4.09. Found: C, 41.44; H, 4.06.

### Example 21

### Preparation of 2,6-Dibromo-cyclopenta[1,2-b:5,4-b′]dithiophen-4-one

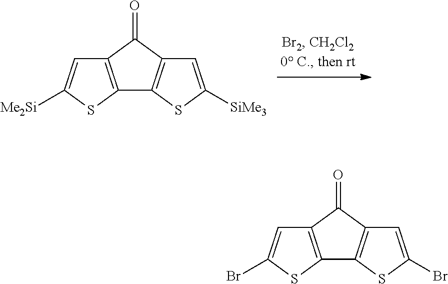

2,6-Bis-trimethylsilyl-cyclopenta[1,2-b:5,4-b′]dithiophen-4-one (3.0 mmol, 1.01 g) was dissolved in 20 mL of dichloromethane, cooled in ice-water bath and a solution of bromine (2.1 eq., 6.3 mmol, 1.01 g) in 10 mL of dichloromethane was added to a dark red solution. The reaction mixture became purple in color and after stirring for about 0.5 h it was allowed to warm to room temperature. Aqueous solution of Na₂S₂O₃ was added and organic solvent was removed by rotary evaporation. The dark purple solid was filtered off, washed with ethanol and dried. Crude product was obtained in 91.5% yield (0.96 g). This material was purified by column chromatography (150 mL of silica gel, CH₂Cl₂ as eluant; material was dissolved in boiling chloroform to apply to the column). Fractions with pure material were combined, the solvent was removed and product 2,6-dibromo-cyclopenta[1,2-b:5,4-b′]dithiophen-4-one was obtained as dark purple solid.

¹H NMR (CDCl₃, 400 MHz): δ 7.00 (s, 2H); ¹³C{¹H} NMR (CDCl₃, 100 MHz): δ 180.5 (quaternary C(O)), 148.7 (quaternary C), 139.5 (quaternary C), 124.4 (CH), 113.97 (quaternary C—Br) (assignment of the quaternary C and CH signals was made based on the DEPT experiment). Anal. Calc. for C₉H₂Br₂OS₂: C, 30.88; H, 0.58. Found: C, 30.87; H, 0.47.

Cyclic voltammograms of 2,6-dibromo-cyclopenta[1,2-b:5,4-b′]dithiophen-4-onein 0.1 M ⁿBu₄NPF₆ in THF, using Cp₂Fe internal standard at 0 V, 50 mV·s⁻¹ rate) gave a reversible reduction at E_{1/2}^{0/1-}=−1.52 V. In 0.1 M ⁿBu₄NPF₆ in CH₂Cl₂, using Cp₂Fe internal standard at 0 V, 50 mV·s⁻¹ rate) a semi-reversible oxidation was observed at E_{1/2}^{0/1}+=+1.05 V, and a reversible reduction E_{1/2}^{0/1-}=−1.48 V was also observed.

### Example 22

### Improved Procedure for the Preparation of 2,7-bis-trimethylsilyl-benzo[1,2-b:6,5-b′]dithiophene-4,5-dione

The yield and purification procedure for the preparation of 2,7-bis-trimethylsilyl-benzo[1,2-b:6,5-b′]dithiophene-4,5-dione were improved by using slight excess of diethyl oxalate (1.3 eq.). This modification allows simplifying the isolation of the product from the crude mixture by recrystallization and also improves the yields up to 76-80% yields.

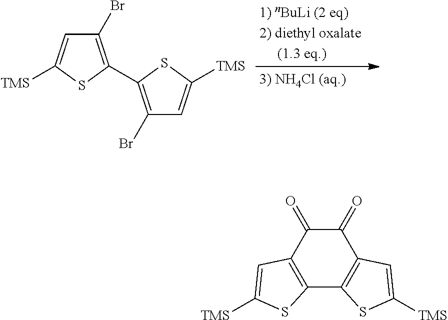 [SMILES: C[Si](C)(C)c1cc(Br)c(-c2sc([Si](C)(C)C)cc2Br)s1 ; C[Si](C)(C)c1cc2c(s1)-c1sc([Si](C)(C)C)cc1C(=O)C2=O]

3,3′-Dibromo-5,5′-bis-trimethylsilyl-2,2′-dithiophene (1a) (60.0 mmol, 28.11 g) was dissolved in anhydrous THF (240 mL), the solution was cooled in acetone/dry ice bath and n-butyllithium (2.87 M in hexanes, 2 eq., 120.0 mmol, 41.8 mL (caution! added in several portions with volume less than 20 mL) was added dropwise. The yellow-orange solution was stirred for 0.5 h and then transferred via cannula into a solution of diethyl oxalate (1.3 eq., 78.0 mmol, 11.40 g) in 200 mL of anhydrous THF (cooled in acetone/dry ice bath). After completion of the addition of the di-lithiated species to the diethyl oxalate, the orange-reddish mixture was stirred for 45 minutes and transferred via cannula into a solution of aqueous NH₄Cl. The dark red organic phase was separated, the aqueous phase was extracted with hexanes, and the combined organic phases were dried over MgSO₄. The solvents were removed by rotary evaporation and the crude product was heated to reflux with ˜500 ml of ethanol, cooled to room temperature, and dark-red needles were separated by the vacuum filtration (16.3 g, 76.7% yield). The mother liquor was subjected to rotary evaporation and the residue was recrystallized from ethanol to give additional amount of product (0.7 g, total yield 17.0 g, 79.9%).

¹H NMR (CDCl₃, 400 MHz): δ 7.60 (s, 2H), 0.36 (s, 18H, 6CH₃); ¹³C {H} NMR (CDCl₃, 100 MHz): δ 175.2 (quaternary C), 148.3 (quaternary C), 142.5 (quaternary C), 135.8 (quaternary C), 134.4 (CH), −0.44 (CH₃). HRMS (EI) calculated for C₁₆H₂₀O₂S₂Si₂ 364.0443; found 364.0469. Anal. Calc. for C₁₆H₂₀O₂S₂Si₂: C, 52.70; H, 5.53. Found: C, 52.70; H, 5.36.

### Example 23

### 2,7-Dichloro-benzo[1,2-b:6,5-b′]dithiophene-4,5-dione

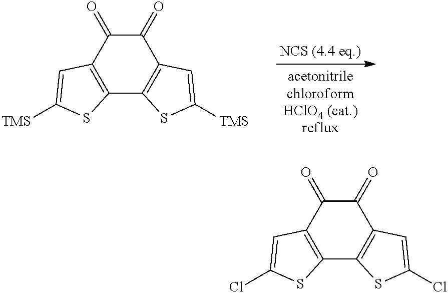 [SMILES: C[Si](C)(C)c1cc2c(s1)-c1sc([Si](C)(C)C)cc1C(=O)C2=O ; O=C1C(=O)c2cc(Cl)sc2-c2sc(Cl)cc21]

2,7-Bis-trimethylsilyl-benzo[1,2-b:6,5-b′]dithiophenebenzo[2,1-b:3,4-b′]dithiophene-4,5-dione (4.0 mmol, 1.42 g) was mixed with N-chlorosuccinimide (2.2 eq., 8.8 mmol, 1.18 g) and 50 mL of acetonitrile was added. Dark red mixture was heated to reflux overnight and analyzed by TLC. Only starting material was detected and HClO₄ (0.05 mL, 69-72%) was added followed by addition of N-chlorosuccinimide (2.2 eq., 8.8 mmol, 1.18 g) and 10 mL of CHCl₃. Two new more polar red spots were detected by TLC (possible products of protiodesilylation), and the resulting mixture was refluxed overnight. Reaction mixture was cooled to room temperature, treated with aqueous solution of Na₂S₂O₃ and organic solvents were removed by rotary evaporation. Organic matter was extracted with dichloromethane, purple organic phases were dried over MgSO₄, and the solvent was removed by rotary evaporation. Almost black microcrystalline compound was obtained, 1.24 g, 107% crude yield (possible crystallization with the solvent).

This crude product was purified by column chromatography (200 mL of silica gel, chloroform as eluant). Fractions containing pure product were combined, the solvent was removed by rotary evaporation and very dark crystalline compound was obtained (0.59 g, 45.6% yield). This material was dissolved in toluene (˜40 mL) under reflux (purple solution) and allowed to cool to room temperature. Long very dark purple needles were obtained by vacuum filtration (2,7-Dichloro-benzo[2,1-b:3,4-b′]dithiophene-4,5-dione, 0.39 g, 66.1% recovery). First two fractions containing the product with minor impurities were combined separately, the solvent was removed and the residue was dissolved in boiling 2-propanol with addition of dichloromethane and purple solution was allowed to cool to room temperature. Long needles/blades were separated by vacuum filtration (0.063 g). Filtrates from both recrystallizations were combined separately, the solvents were removed and the residue was dissolved in boiling toluene and left to cool down for crystal growth.

¹H NMR (CDCl₃, 400 MHz): δ 7.31 (s, 2H); ¹³C{¹H} NMR (CDCl₃, 100 MHz): δ 172.6 (quaternary C(O)), 141.0 (quaternary C), 134.5 (quaternary C), 132.2 (quaternary C), 126.2 (CH). HRMS (EI) calculated for C₁₀H₂Cl₂O₂S₂ 287.8873; found 287.8876. Anal. Calc. for C₁₀H₂Cl₂O₂S₂: C, 41.54; H, 0.70. Found: C, 41.54; H, 0.67.

A cyclic voltammogram (0.1 M ⁿBu₄NPF₆ in THF, Cp₂Fe internal standard at 0 V, 50 mV·s⁻¹ rate) of 2,7-dichloro-benzo[2,1-b:3,4-b′]dithiophene-4,5-dione was recorded: E_{1/2}^{0/1-}=−0.88 V (reversible), E_{1/2}^{1-/2-}=−1.68 V (reversible).

### Example 24

### 2,7-Di-bromo-benzo[2,1-b:3,4-b′]dithiophene-4,5-di-(1,3-dioxolane)

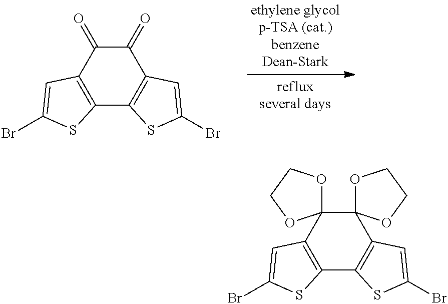 [SMILES: O=C1C(=O)c2cc(Br)sc2-c2sc(Br)cc21 ; Brc1cc2c(s1)-c1sc(Br)cc1C1(OCCO1)C21OCCO1]

2,7-Dibromo-benzo[2,1-b:3,4-b′]dithiophene-4,5-dione (18.0 mmol, 6.81 g), ethylene glycol (20 mL) and 100 mL of benzene were mixed together in a round bottom flask equipped with magnetic stir bar, Dean-Stark trap and a condenser. Catalytic amount (a few crystals) of p-TSA was added and the mixture was heated to reflux. Additional amount of ethylene glycol (40 mL) was added after a few hours and mixture was refluxed for 4 days until complete consumption of the starting material. Reaction mixture with greenish precipitate was cooled to room temperature, subjected to rotary evaporation (not a lot was removed), treated with water and greenish solid was separated by vacuum filtration (6.50 g, 77.5% crude yield). Organic matter in the filtrate was extracted with dichloromethane, combined with the greenish solid and purified by column chromatography (150 mL of silica gel, CH₂Cl₂:hexanes (2:1) as eluant). First fractions with slightly contaminated product were combined, the solvents were removed, the residue was heated with ˜250 mL of 2-propanol, cooled to room temperature and vacuum filtered (4.40 g, barely yellowish solid). Later fractions were kept separately, the solvents were removed by rotary evaporation and the residue was heated with ˜150 mL of 2-propanol to give off-white solid (2,7-Di-bromo-benzo[2,1-b:3,4-b′]dithiophene-4,5-di-(1,3-dioxolane), 1.21 g, combined yield 5.61 g, 85% recovery).

¹H NMR (CDCl₃, 400 MHz): δ 7.15 (s, 2H), 4.16 (m, 4H), 3.70 (m, 4H); ¹³C{¹H} NMR (400 MHz, CDCl₃): δ 135.9 (quaternary C), 133.5 (quaternary C), 128.1 (CH), 111.5 (quaternary C), 92.8 (quaternary C), 61.6 (CH₂). Anal. calc. for C₁₄H₁₀Br₂O₄S₂ C, 36.07; H, 2.16. Found: C, 36.35; H, 2.02.

### Example 25

### 2,7-Difluoro-benzo[2,1-b:3,4-b′]dithiophene-4,5-dione

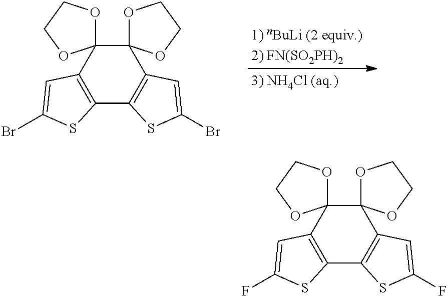 [SMILES: Brc1cc2c(s1)-c1sc(Br)cc1C1(OCCO1)C21OCCO1 ; Fc1cc2c(s1)-c1sc(F)cc1C1(OCCO1)C21OCCO1]

2,7-Di-bromo-benzo[2,1-b:3,4-b′]dithiophene-4,5-di-(1,3-dioxolane) (2.5 mmol, 1.165 g) was dissolved in 75 mL of anhydrous THF (nitrogen atmosphere) and the resulting yellowish solution was cooled in acetone/dry ice bath. n-Butyllithium (2.87 M in hexanes, 5.0 mmol, 1.75 mL) was added dropwise and yellowish solution became almost colorless suspension, which became light pink after stirring for a few minutes. The reaction mixture was stirred for 15 minutes and a solution of N-fluorobenzenesulfonimide (2.1 eq., 5.25 mmol, 1.66 g) in 25 mL of anhydrous THF was added dropwise. Reaction mixture became orange solution. After stirring for 10 minutes additional amount of N-fluorobenzenesulfonimide (0.16 g) was added, the reaction mixture was allowed to warm to room temperature and then treated with water. Organic phase was separated, the aqueous phase was extracted with dichloromethane and combined organic phases (yellow-brownish) were subjected to rotary evaporation. The residue was mixed with chloroform, heated to reflux and insoluble matter was separated by vacuum filtration. Filtrate was column chromatographed (˜250 mL of silica gel, dichloromethane as eluant). Fractions containing the product were combined, the solvent was removed by rotary evaporation and beige solid was obtained (microcrystalline compound, 0.46 g, 53.5% yield). The compound on the sides of the flask was mixed with 2-propanol, heated to reflux to dissolve the solid and cooled. Little colorless crystals formed on cooling indicating that 2-propanol could be a good solvent for recrystallization. Part of the solid (0.21 g) was recrystallized from 2-propanol, and purified product was obtained as yellowish large crystals (0.16 g, 76.2% recover).

¹H NMR (CDCl₃, 400 MHz): δ 6.61 (s, 2H), 4.13 (m, 4H), 3.71 (m, 4H); ¹³C{¹H} NMR (CDCl₃, 100 MHz): δ 165.2 (d, J=295 Hz, quaternary C—F), 131.7 (quaternary C), 120.8 (quaternary C), 105.8 (d, J=11 Hz, CH), 92.7 (quaternary C), 61.6 (CH₂). ¹⁹F NMR (CDCl₃, 376.3 MHz): δ −129.9 (1,1,2-trichlorotrifluoroethane was used as a reference with 6 at −71.75 ppm (t)). HRMS (EI) calculated C₁₄H₁₀F₂O₄S₂ 343.9989; found 343.9982. Anal. Calc. for C₁₄H₁₀F₂O₄S₂: C, 48.83; H, 2.93. Found: C, 48.73; H, 2.90.

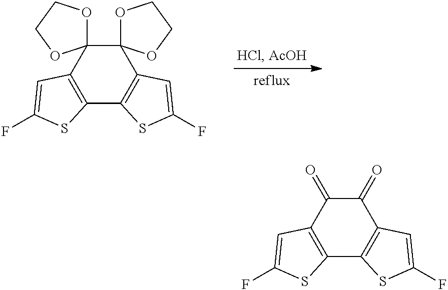 [SMILES: Fc1cc2c(s1)-c1sc(F)cc1C1(OCCO1)C21OCCO1 ; O=C1C(=O)c2cc(F)sc2-c2sc(F)cc21]

2,7-Difluoro-benzo[2,1-b:3,4-b′]dithiophene-4,5-di-(1,3-dioxolane) (0.5 mmol, 0.172 g) was mixed with acetic acid (10 mL) and the resulting mixture was heated to reflux. HCl (1 mL) was added dropwise, and yellowish mixture became purple within a few minutes. The mixture was refluxed for ˜10 minutes, analyzed by TLC (CHCl₃ as eluant) and complete consumption of the starting material was confirmed (a new purple spot of the product was detected as well). The reaction mixture was cooled to room temperature, treated with water and dark precipitated was separated by vacuum filtration, washed with water, then ethanol and dried (, 0.144 g, 113% crude yield, probably still contained some solvents). This material was recrystallized from toluene-hexanes and very dark purple needles were obtained (0.123 g, 96% yield). Some needles looked reasonable for single crystal X-ray analysis and were separated from the main batch.

2,7-Difluoro-benzo[2,1-b:3,4-b′]dithiophene-4,5-dione: ¹H NMR (CDCl₃, 400 MHz): δ 6.89 (s, 2H); ¹³C{¹H} NMR (CDCl₃, 100 MHz): δ 172.9 (quaternary C(O)), 165.4 (d, J=300 Hz, quaternary C—F), 133.0 (quaternary C), 132.2 (quaternary C), 107.3 (d, J=11 Hz, CH) (assignment of the CH and quaternary carbons was made based on DEPT-135 analysis). HRMS (EI) calculated for C₁₀H₂F₂O₂S₂ 255.9464; found 255.9476. Anal. Calc. for C₁₀H₂F₂O₂S₂: C, 46.87; H, 0.79. Found: C, 47.36; H, 0.83.

### Example 26

### 2,7-Bis-trimethylsilylethynyl-benzo[1,2-b:6,5-b′]dithiophene-4,5-dione

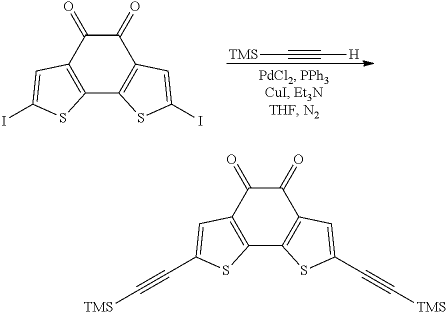 [SMILES: O=C1C(=O)c2cc(I)sc2-c2sc(I)cc21 ; C#C[Si](C)(C)C ; C[Si](C)(C)C#Cc1cc2c(s1)-c1sc(C#C[Si](C)(C)C)cc1C(=O)C2=O]

2,7-Diiodo-benzo[1,2-b:6,5-b′]dithiophene-4,5-dione (1.0 mmol, 0.472 g), PdCl₂ (0.04 eq., 0.04 mmol, 0.007 g), PPh₃ (0.1 eq., 0.1 mmol, 0.026 g) and Et₃N (2.2 eq., 2.2 mmol, 0.22 g) were mixed in an oven-dried Schlenk flask under nitrogen atmosphere. Anhydrous THF (30 mL) was added followed by addition of trimethylsilylacetylene (2.2 eq., 2.2 mmol, 0.22 g) and CuI (0.012 eq., 0.012 mmol, 2.3 mg). The mixture was heated (58° C. bath temperature initially, then 40-45° C.), but no reaction was observed by TLC analysis (CH₂Cl₂ as eluant) after ˜1.5 h of heating. Additional amount of Et₃N (0.3 mL) was added, followed by addition of trimethylsilylacetylene (2.4 mmol, 0.24 g). After stirring at heating (47-49° C. bath temperature) for 4 hours no reaction was observed based on TLC analysis and additional amount of CuI (6.5 mg) was added. After ˜20 minutes of stirring dark red-purple mixture became yellowish-greenish and the mixture was left to stir overnight (40° C., nitrogen atmosphere). The yellow-greenish mixture was cooled to room temperature and treated with water. Organic phase became dark purple-brown, brine was added and organic phase was separated. The aqueous phase was extracted with diethyl ether several times and combined organic phases were dried over MgSO₄. The drying agent was filtered off, the solvents were removed by rotary evaporation and the residue was purified by column chromatography (150 mL of silica gel, CH₂Cl₂ as eluant). Material came out contaminated, and the fractions with the product were combined, subjected to rotary evaporation and the residue was recrystallized from 2-propanol. Product was obtained as very dark needles (0.058 g, 14%). The column was eluted with CHCl₃:EtOAc and purple solution was collected, subjected to rotary evaporation and purified by column chromatography (150 mL of silica gel, CHCl₃ as eluant). Combined fractions were subjected to rotary evaporation, and the residue was recrystallized from ˜15 mL of EtOH. Very dark crystals were separated by vacuum filtration and additional amount of product was obtained (0.029 g, 7.0%).

¹H NMR (CDCl₃, 400 MHz): δ 7.53 (s, 2H), 0.27 (s, 18H); ¹³C{¹H} NMR (CDCl₃, 100 MHz): δ 173.6, 142.9, 135.0, 132.1 (CH), 124.5, 104.5, 95.0. HRMS (EI) calculated for C₂₀H₂₀O₂S₂Si₂ 412.0443; found 412.0449. Anal. Calc. for C₂₀H₂₀O₂S₂Si₂: C, 58.21; H, 4.88. Found: C, 57.36; H, 4.87 (ΔC −0.85)

Cyclic voltammograms of 2,7-bis-trimethylsilanylethynyl-benzo[1,2-b:6,5-b′]dithiophene-4,5-dione: were recorded (0.1 M ⁿBu₄NPF₆ in THF, Cp₂Fe internal standard at 0 V, 50 mV·s⁻¹ rate) and showed E_{1/2}^{0/1-}=−0.91 V (reversible), and E_{1/2}^{1-/2-}=−1.60 V (reversible).

### Example 27

### 2,7-Ethynyl-benzo[1,2-b:6,5-b′]dithiophene-4,5-dione

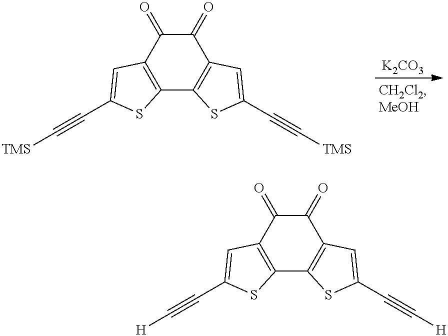

2,7-Bis-trimethylsilylethynyl-benzo[1,2-b:6,5-b′]dithiophene-4,5-dione (0.07 mmol, 0.029 g) was dissolved in a mixture of dichloromethane-methanol (10:10 mL) and K₂CO₃ (3.0 eq., 0.12 mmol, 0.029 g) was added to a dark blue-purple solution at room temperature. The reaction mixture was stirred for about 1 h and treated with water. Organic phase was removed, aqueous phase was extracted with dichloromethane and combined organic phases were dried over MgSO₄. The drying agent was filtered off, the solvent was removed and the crude product was purified by column chromatography (50 mL of silica gel, CH₂Cl₂ as eluant). Solvent was removed from combined fractions and product was obtained as dark microcrystalline solid (100% yield, 0.019 g).

¹H NMR (CDCl₃, 400 MHz): δ 7.61 (s, 2H), 3.56 (s, 2H); ¹³C{¹H} NMR (CDCl₃, 100 MHz): δ 173.50 (quaternary C(O)), 143.03 (quaternary C), 132.72 (CH), 123.41 (quaternary C), 85.69 (CH), 74.70 (quaternary C) (assignment of the quaternary and CH signals was made based on the DEPT experiment).

Cyclic voltammograms of 2,7-ethynyl-benzo[1,2-b:6,5-b′]dithiophene-4,5-dione (0.1 M ⁿBu₄NPF₆ in THF, Cp₂Fe internal standard at 0 V, 50 mV·s⁻¹ rate) showed two reversible reductions, E_{1/2}^{0/1-}=−0.91 V, E_{1/2}^{1-/2-=-1.60} V.

### Example 28

### 2,7-Bis-(4-n-hexyl-5-trimethylsilyl-thiophen-2-yl)-benzo[1,2-d:4,3-d]bis(thiazole)-4,5-dionebenzo[1,2-b:6,5-b′]dithiophene

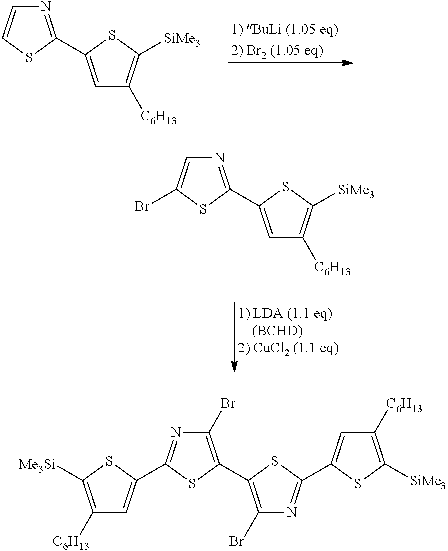

### Step 1-4,4′-Dibromo-2,2′-bis(4-hexyl-5-(trimethylsilyl)thiophen-2-yl)-5,5′-bithiazole

Lithium diisopropylamide (LDA) (2.2 eq., 0.37 M, 6 ml) was prepared from diisopropylamine (2.4 mmol, 0.24 g), n-butyllithium (2.5 M in hexanes, 2.2 mmol, 0.9 ml) and 5 ml of anhydrous THF. 2-(5-Trimethylsilyl-3-n-hexyl-thiophen-2-yl)-5-bromothiazole (1.0 mmol, 0.40 g, see Example 7) was dissolved in 20 ml of anhydrous THF and the yellowish solution was cooled in acetone/CO₂ bath (nitrogen atmosphere). Freshly prepared LDA (0.37 M in THF, 1.1 eq., 3 ml) was added dropwise to the bromothiazole derivative and the reaction mixture became light purple in color. The reaction mixture was stirred for 20 minutes and a small aliquot was treated with hexanes:MeOH, organic solvents were removed and the residue was analyzed by GC/MS analysis. The completion of the BCHD reaction was confirmed and CuCl₂ (1.1 eq., 0.148 g) was added in one portion to the purple reaction mixture. After stirring for 5 minutes the color changed to yellowish-green and the mixture was slowly warmed to room temperature without cooling bath removal.

Hexanes and water were added, the organic phase was removed and the aqueous phase was extracted with Et₂O (3×15-20 ml). The combined organic phases were dried over MgSO₄ and the solvents were removed by rotary evaporation to give crude product as dark yellow solid. This crude product was purified by column chromatography (50 ml of silica gel, hexanes:CH₂Cl₂ (3:2) and bright yellow-orange solid was obtained (0.27 g). Minor impurities were detected by the TLC analysis and material was further purified by the column chromatography (100 ml of silica gel, Hexanes:CH₂Cl₂ (35:15). The solvents were removed from combined fractions and product was obtained as yellow-orange oil which solidified on standing.

4,4′-Dibromo-2,2′-bis(4-hexyl-5-trimethylsilyl-thiophen-2-yl)-5,5′-bithiazole; ¹H NMR (CDCl₃, 400 MHz): δ 7.53 (s, 2H), 2.66 (t, J=8.0 Hz, 4H), 1.62 (m, 4H), 1.45-1.30 (m, 12H) 0.98 (t, J=6.9 Hz, 6H), 0.38 (s, 18H); ¹³C{¹H} NMR (CDCl₃, 100 MHz): δ 162.1 (quaternary C), 151.4 (quaternary C), 139.0 (quaternary C), 138.5 (quaternary C), 130.5 (CH), 127.6 (quaternary C), 121.0 (quaternary C), 31.7 (CH₂), 31.6 (CH₂), 31.3 (CH₂), 29.3 (CH₂), 22.6 (CH₂), 14.1 (CH₃), 0.14 (CH₃) (assignment of the quaternary, CH, CH₂ and CH₃ signals was made based on the DEPT experiment). HRMS (EI) calculated for C₃₂H₄₆Br₂N₂S₄Si₂ 800.0449; found 800.0420. Anal. Calc. for C₃₂H₄₆Br₂N₂S₄Si₂: C, 47.87; H, 5.77; N, 3.49. Found: 47.72; H, 5.77; N, 3.47.

### Step 2

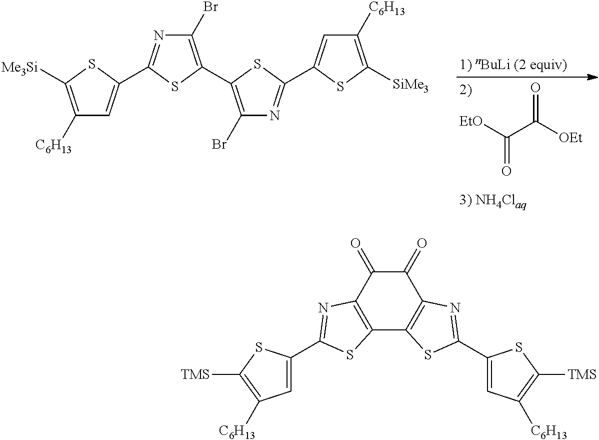

4,4′-Dibromo-2,2′-bis(4-n-hexyl-5-trimethylsilyl-thiophen-2-yl)-5,5′-bithiazole (0.5 mmol, 0.401 g) was dissolved in 30 mL of anhydrous THF under nitrogen atmosphere and the resulting bright yellow solution was cooled in acetone/dry ice bath. n-Butyllithium (2.85 M in hexanes, 1.0 mmol, 0.35 mL) was added dropwise, and reaction mixture became orange-red. After stirring for 0.5 h this solution was transferred via cannula into a solution of diethyl oxalate (1.2 eq., 0.6 mmol, 0.09 g) in 50 mL of anhydrous THF cooled in acetone/dry ice bath. Very dark red-orange solution became yellow-red-brownish. After stirring for 1 h only trace amount of the desired product was detected by TLC analysis and the mixture was allowed to warm to 0° C. After stirring for 3 hours additional amount of diethyl oxalate (0.2 mL) was added and the mixture was left to stir overnight. The reaction mixture was treated with aqueous NH₄Cl, dark brown organic phase was separated and the aqueous phase was extracted with dichloromethane. Combined organic phases were dried over MgSO₄, the organic solvents were removed by rotary evaporation and the residue was purified by column chromatography (100 mL of silica gel, CH₂Cl₂:EtOAc (30:1, 20:1, 10:1). All blue or green fractions were combined, the solvents were removed and the product (still impure) was obtained as green-blue film (˜50 mg). This material was further purified by column chromatography (˜50 mL of silica gel, CH₂Cl₂ as eluant). Fractions with material (blue in color) were combined, the solvent was removed by rotary evaporation and the product was obtained as blue-green film (˜30 mg, <10% yield).

¹H NMR (CDCl₃, 400 MHz): δ 7.59 (s, 2H), 2.65 (t, J=8.0 Hz, 4H), 1.61 (m, 4H), 1.42-1.30 (m, 12H), 0.93, (t, J=6.6 Hz, 6H), 0.38 (s, 18H); ¹³C{¹H} NMR (CDCl₃, 100 MHz): 172.5, 162.0, 151.6, 147.9, 140.9, 137.8, 136.8, 132.0 (CH), 31.7 (CH2), 31.6 (CH2), 31.3 (CH2), 29.3 (CH2), 22.6 (CH2), 14.1 (CH3), 0.1 (CH3). HRMS (EI) calculated for C₃₄H₄₆N₂O₂S₄Si₂ 698.1981. Found: 698.1970. (M+2 ion was also observed as a major ion: calculated for C₃₄H₄₈N₂O₂Si₂S₄ 700.2137; found 700.2090). Anal. Calc. for C₃₄H₄₆N₂O₂S₄Si₂: C, 58.41; H, 6.63; N, 4.01. Found: 58.50; H, 6.64; N, 4.11.

### Example 29

### Synthesis of 2,7-bis(perfluorobenzoyl)benzo[1,2-b:3,4-b′]dithiophene-4,5-dione

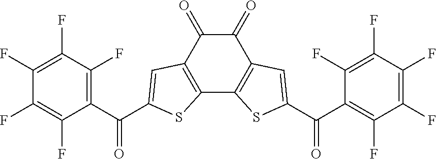 [SMILES: O=C1C(=O)c2cc(C(=O)c3c(F)c(F)c(F)c(F)c3F)sc2-c2sc(C(=O)c3c(F)c(F)c(F)c(F)c3F)cc21]

Step 1:

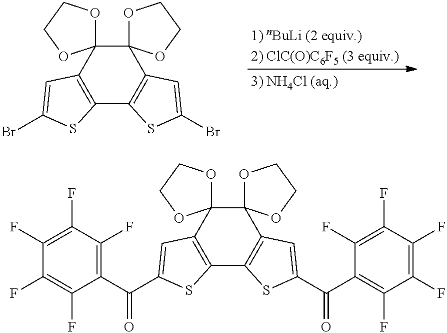

2,7-Dibromo-benzo[2,1-b:3,4-b′]dithiophene-4,5-di-(1,3-dioxolane) (3.0 mmol, 1.40 g) was dissolved in 75 mL of anhydrous THF, and solution was cooled in acetone/dry ice bath. n-Butyllithium (2.85 M in hexanes, 6.0 mmol, 2.11 mL) was added dropwise and purple suspension formed. The reaction mixture was stirred for ˜40 minutes and transferred via cannula into a solution of pentafluorobenzoyl chloride (9.0 mmol, 2.07 g) in 75 mL of anhydrous THF cooled in acetone/dry ice bath. Yellow-brown solution formed. After stirring for ˜2 h the cooling bath was removed, the mixture was treated with aqueous solution of NH₄Cl, and organic phase was removed. Aqueous phase was extracted with CH₂Cl₂ and combined organic phases were dried over MgSO₄. The drying agent was filtered off, and the solvents were removed by rotary evaporation. The crude product was purified by column chromatography (250 mL of silica gel, hexanes:CH₂Cl₂ as eluant. Fractions with pure product were combined, and the solvents were removed from yellow solution, and yellow solid was obtained. This material contained some solvent, and 100 mg was recrystallized from 2-propanol (˜75 mL). Yellow solid (83 mg) was obtained. Anal. Calc. for C₂₈H₁₀F₁₀O₆S₂: C, 48.28; H, 1.45. Found: C, 48.14; H, 1.54.

¹H NMR (CDCl₃, 400 MHz): δ 7.57 (s, 2H), 4.17 (m, 4H), 3.70 (m, 4H); ¹³C{¹H} NMR (CDCl₃, 100 MHz): δ 176.0, 142.9, 141.7, 140.1, 133.6 (CH), 61.5 (CH₂) (multiplets for C—F carbons were observed as weak signals at 145.1, 142.6, 139.0, 136.5). ¹⁹F NMR (CDCl₃, 376.3 MHz): δ −139.4 (m, 4F), −148.9 (appears as poorly resolved tt, 2F), −159.0 (appears as not well resolved qt, 4F) (1,1,2-trichlorotrifluoroethane was used as a reference with 6 at −71.75 ppm (t)). HRMS (EI) calculated for C₂₈H₁₀F₁₀O₆S₂ 695.9759; found 695.9733.

Step 2:

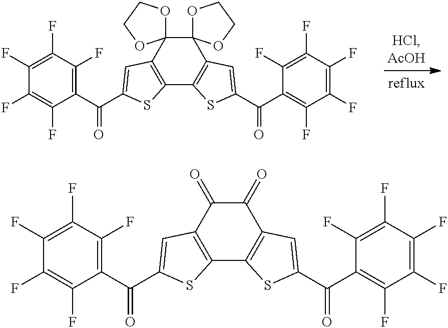 [SMILES: O=C(c1cc2c(s1)-c1sc(C(=O)c3c(F)c(F)c(F)c(F)c3F)cc1C1(OCCO1)C21OCCO1)c1c(F)c(F)c(F)c(F)c1F ; O=C1C(=O)c2cc(C(=O)c3c(F)c(F)c(F)c(F)c3F)sc2-c2sc(C(=O)c3c(F)c(F)c(F)c(F)c3F)cc21]

2,7-Bis-pentafluorobenzoyl-benzo[2,1-b:3,4-b′]dithiazole-4,5-di-(1,3-dioxolane) (0.4 mmol, 0.279 g) was mixed with 50 mL of acetic acid and the mixture was heated to reflux. HCl (˜5 mL) was added to a yellow solution and the reaction mixture became orange and then red-orange. After reflux for 1 h the mixture was cooled to room temperature and only small amount of precipitate formed. The mixture was heated to reflux and water was added until precipitation was observed. The reaction mixture was cooled, and orange solid was separated, washed with water, ethanol and dried, (0.190 g, 78.2%). This material was purified for mobility measurement by column chromatography (100 mL of silica gel, CH₂Cl₂ as eluant). Middle fractions with the product were combined, the solvent was removed and orange-red powder was obtained (0.109 g, 77.9% recovery).

Bis(perfluorobenzoyl)benzo[1,2-b:3,4-b′]dithiophene-4,5-dione. ¹H NMR (CDCl₃, 400 MHz): δ 7.88 (s, 2H); ¹³C{¹H} NMR (CDCl₃, 100 MHz): δ 176.5 (quaternary C(O)), 173.1 (quaternary C(O)), 148.7, 144.3, 137.3, 134.4 (weak C—F carbons were detected as multiplets at 145.2, 142.7, 139.2, 136.6). ¹⁹F NMR (CDCl₃, 376.3 MHz): δ −139.1 (m, 4F), −147.1 (tt, J=20.7 Hz, 3.4 Hz, 2F), −158.2 (m, 4F) (1,1,2-trichlorotrifluoroethane was used as a reference with δ at −71.75 ppm (t)). HRMS (EI) calculated for C₂₄H₂F₁₀O₄S₂ 607.9235; found 607.9216 (M+2H at 609.9 was observed with ˜80% intensity with respect to molecular ion). Anal. Calc. for C₂₄H₂F₁₀O₄S₂: C, 47.38; H, 0.33. Found: C, 47.13; H, 0.34.

### PREVIOUSLY CLAIMED EMBODIMENTS

In addition, the 54 claims of the prior PCT/EP2011/051913 application are provided hereinbelow as 54 embodiments:

### Embodiment 1

A method for synthesizing a bishalo-bisheteroaryl compound comprising the structure

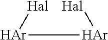

wherein HAr is an optionally substituted five or six membered heteroaryl ring comprising at least one ring carbon atom and at least one ring heteroatom, and Hal is a halogen: and wherein the steps of the method comprise:
providing an optionally substituted precursor compound comprising a halo-heteroaryl ring having an Hal substituent at a first position on the HAr ring;
treating the precursor compound with a strongly basic compound to induce the isomerization of the precursor compound to produce an intermediate compound wherein the Hal atom is bound to a different position on the HAr ring;
treating the intermediate compound with an oxidizing agent so as to form a carbon-carbon bond between two intermediate compounds and thereby form the bishalo-bisheteroaryl compound.

### Embodiment 2

The method of embodiment 1, wherein Hal is Br or I.

### Embodiment 3

The method of embodiment 1 wherein HAr is an optionally substituted five membered heteroaryl ring.

### Embodiment 4

The method of embodiment 1 wherein HAr and Hal of the precursor compound comprise the structure

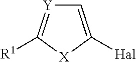

wherein
a) R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;
X is O, S, Se, or NR³ wherein R³ is a C₁-C₁₈ alkyl, perfluoroalkyl, aryl, or heteroaryl; and
Y is CH, CR⁴, or N, wherein R⁴ is a C₁-C₁₈ alkyl, aryl, or heteroaryl.

### Embodiment 5

The method of embodiment 1 wherein HAr and Hal of the precursor compound comprise the structure

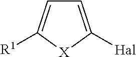

wherein
R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each
R² is an independently selected alkyl or aryl, and each R²¹ is an independently selected alkyl or aryl, or the R²¹ groups together form an optionally substituted alkylene group bridging the oxygen atoms;
X is S, Se, or NR³ wherein R³ is a C₁-C₁₈ alkyl, perfluoroalkyl, aryl, or heteroaryl.

### Embodiment 6

The method of embodiment 1 wherein HAr and Hal of the precursor compound comprise the structure

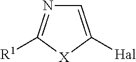

wherein
R¹ is a C₁-C₃₀ organic radical selected from optionally substituted alkyl, alkynyl, aryl, or heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms; and
X is S or NR³ wherein R³ is a C₁-C₁₈ alkyl, perfluoroalkyl, aryl, or heteroaryl.

### Embodiment 7

The method of embodiment 1 wherein HAr and Hal of the precursor compound comprise the structure

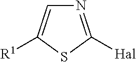

wherein
R¹ is a halide, or a C₁-C₃₀ organic radical selected from alkyl, alkynyl, aryl, heteroaryl, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

### Embodiment 8

The method of any one of embodiments 4-7 wherein R¹ is a C₁-C₃₀ aryl or heteroaryl optionally substituted by one to four ring substituents independently selected from halides, alkyl, alkynyl, perfluoroalkyl, alkoxide, perfluoroalkoxide, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

### Embodiment 9

The method of any one of embodiments 4-7 wherein R¹ is

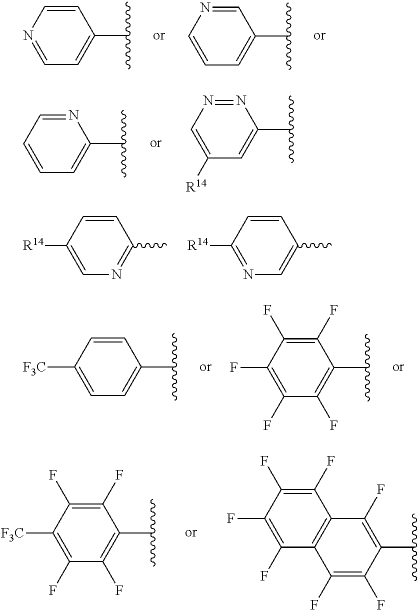

wherein R¹⁴ is hydrogen or a C₁-C₁₈ alkyl, perfluoroalkyl, or alkoxy group.

### Embodiment 10

The method of any one of embodiments 4-7 wherein R¹ is

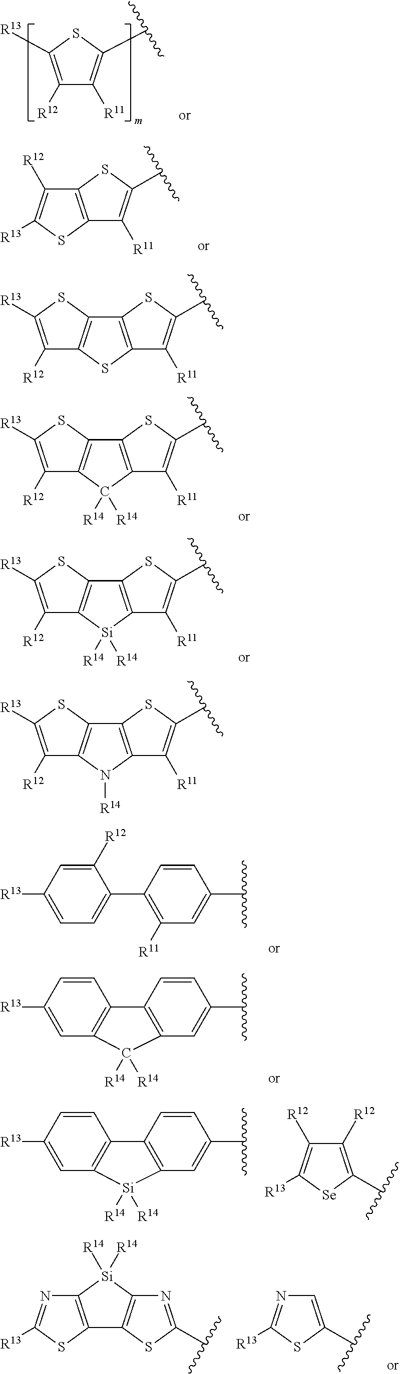

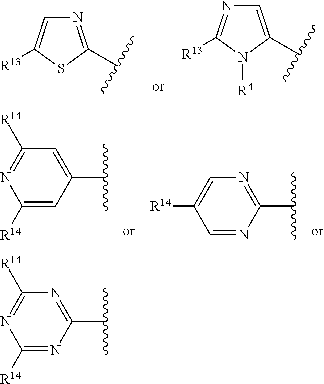

wherein m is 1, 2, 3, or 4, and R¹¹, R¹², R¹⁴ are a C₁-C₈ alkyl, perfluoroalkyl, alkoxy, or perfluoroalkoxy group, and R¹³ is hydrogen, —B(—OR²¹)₂, Si(R²)₃, Si(OR²)₃ or Sn(R²)₃, wherein each R² is an independently selected alkyl or aryl, and each R²¹ is an independently selected alkyl or aryl, or the R²¹ groups together form an optionally substituted alkylene group to form a ring bridging the oxygen atoms.

### Embodiment 11

The method of any one of embodiments 1-10 wherein the strongly basic compound is an alkyl lithium compound.

### Embodiment 12

The method of any one of embodiments 1-10 wherein the strongly basic compound is a lithium dialkylamide compound.

### Embodiment 13

The method of any one of embodiments 1-10 wherein the oxidizing agent is a Cu(II) salt.

### Embodiment 14

The method of any one of embodiments 1-10 wherein the bishalo-bisheteroaryl compound is a 2,2′-bishalo-1,1′-bisheteroaryl compound.

### Embodiment 15

The method of embodiment 4 wherein the bishalo-bisheteroaryl compound has the structure

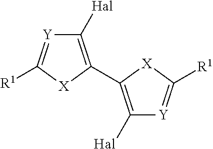

wherein
R¹ is a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each
R² is an independently selected alkyl or aryl, and each R²¹ is an independently selected alkyl or aryl, or the R²¹ groups together form an optionally substituted alkylene group bridging the oxygen atoms;
X is O, S, Se, or NR³ wherein R³ is a C₁-C₁₈ alkyl, perfluoroalkyl, aryl, or heteroaryl; and
Y is CH, CR⁴, or N, wherein R⁴ is a C₁-C₁₈ alkyl, aryl, or heteroaryl.

### Embodiment 16

The method of embodiments 1-3 wherein the bishalo-bisheteroaryl compound has one of the structures

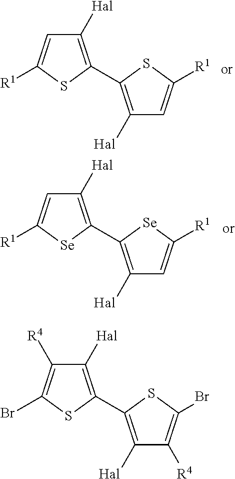

wherein
R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;
R⁴ is a C₁-C₁₈ alkyl, aryl, or heteroaryl.

### Embodiment 17

The method of any one of embodiments 1-2 wherein the bishalo-bisheteroaryl compound has one of the structures

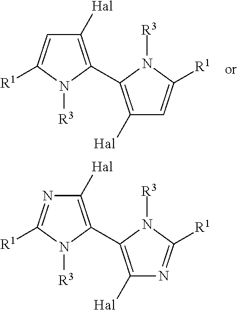

wherein
R¹ is hydrogen or a halide, or a C₁-C₃₀ organic radical selected from optionally substituted alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;
R³ is a C₁-C₁₈ alkyl, perfluoroalkyl, aryl, or heteroaryl.

### Embodiment 18

The method of any one of embodiments 1-3 wherein the bishalo-bisheteroaryl compound has one of the structures

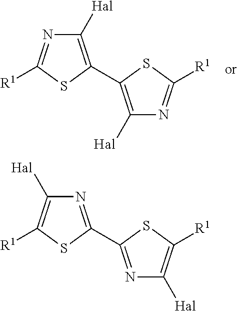

wherein R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

### Embodiment 19

The method of any one of embodiments 1-2 wherein the bishalo-bisheteroaryl compound has one of the structures

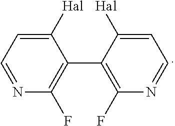

### Embodiment 20

A method for synthesizing a fused tricyclic compound comprising the structure

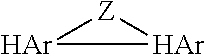

wherein
HAr is as defined in any one of embodiments 1-9,
Z is S, Se, NR⁵, C(O), C(O)C(O), Si(R⁵)₂, SO, SO₂, PR⁵, P(O)R⁵, BR⁵, or C(R⁵)₂ wherein
R⁵ is a C₁-C₅₀ organic radical selected from optionally substituted alkyl, perfluoroalkyl, aryl, and heteroaryl,

and wherein the method comprises the steps of any one of embodiments 1-17, and then further comprises the steps of
optionally treating the bishalo-bisheteroaryl compound with an organometallic compound to exchange a metal for the Hal substituents, and form a bismetallo-bisheteroaryl compound, and
reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

### Embodiment 21

The method of embodiment 20 wherein the organometallic compound is an alkyl lithium compound or lithium diorganoamide.

### Embodiment 22

The method of embodiment 20 wherein the organometallic compound is a transition metal compound.

### Embodiment 23

The method of embodiment 20 wherein the electrophile is a compound V—R⁶—V′, where R⁶ is selected from S, Se, NR⁵, C(O), C(O)C(O), Si (R⁵)₂, SO, SO₂, PR⁵, P(O)R⁵, BR⁵, or C(R⁵)₂, V and V′ are leaving groups or V and V′ together form a leaving group suitable for a condensation reaction with the bismetallo-bisheteroaryl compound to form the fused tricyclic compound.

### Embodiment 24

The method of embodiment 20 wherein the fused tricyclic compound has the structure

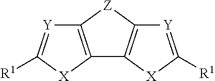

wherein
R¹ is hydrogen, a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;
X is O, S, Se, or NR³ wherein R³ is a C₁-C₁₈ alkyl, perfluoroalkyl, aryl, or heteroaryl; and
Y is CH, CR⁴, or N, wherein R⁴ is a C₁-C₁₈ alkyl, aryl, or heteroaryl; and
Z is S, Se, NR⁵, C(O), C(O)C(O), Si(R⁵)₂, SO, SO₂, PR⁵, P(O)R⁵, BR⁵, or C(R⁵)₂, wherein
R⁵ is a C₁-C₅₀ organic radical selected from optionally substituted alkyl, perfluoroalkyl, aryl, and heteroaryl.

### Embodiment 25

The method of embodiment 20 wherein the fused tricyclic compound has the structure

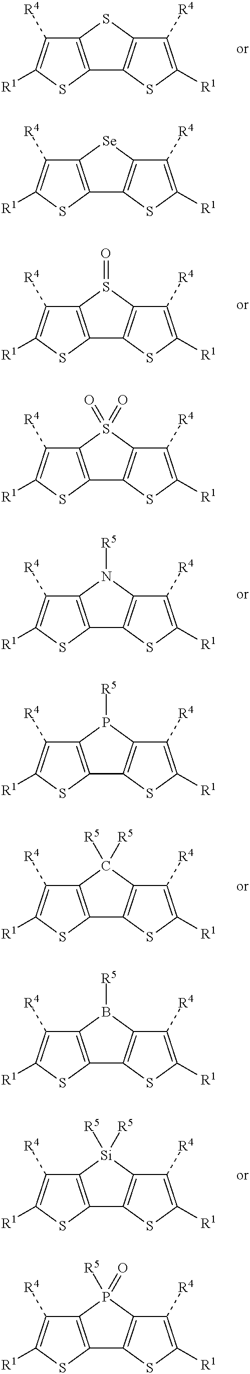

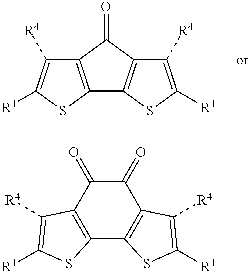

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms, R⁴ is hydrogen or optionally a C₁-C₁₈ alkyl group, and R⁵ is a C₁-C₅₀ organic radical selected from alkyl, aryl, heteroaryl.

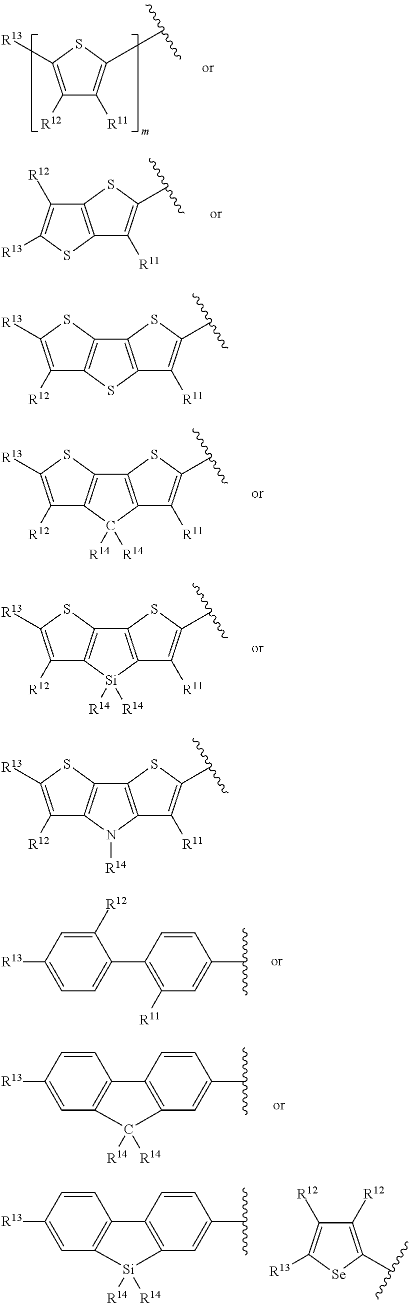

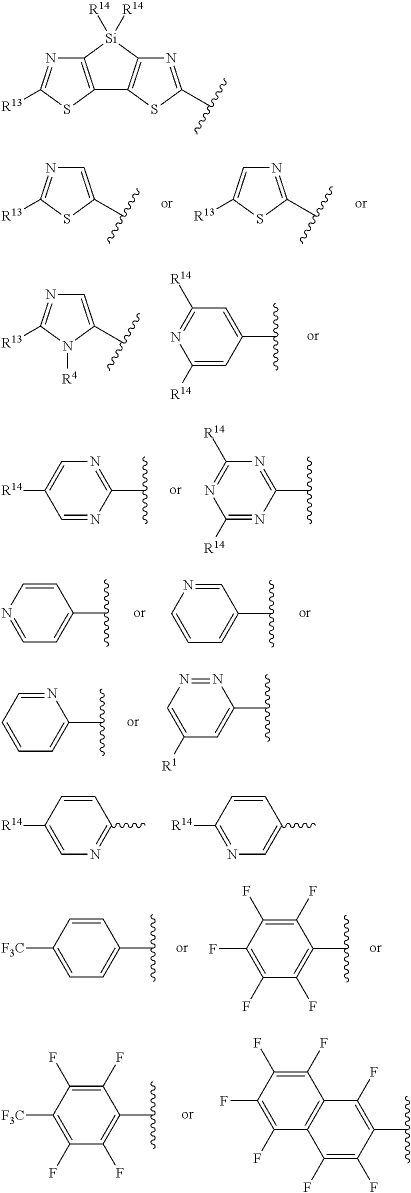

wherein m is 1, 2, 3, or 4, and R¹¹, R¹², R¹⁴ are a C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

### Embodiment 27

The method of embodiment 20 wherein the fused tricyclic compound has the structure

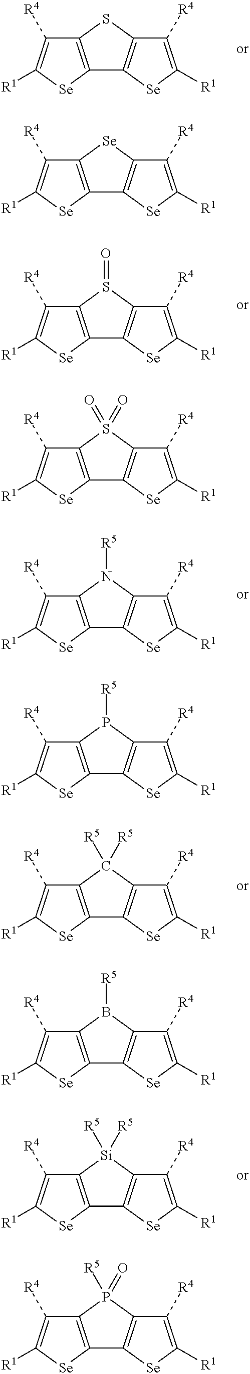

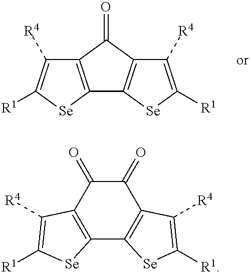

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms, R⁴ is hydrogen or optionally a C₁-C₁₈ alkyl group, and R⁵ is a C₁-C₅₀ organic radical selected from alkyl, aryl, heteroaryl.

### Embodiment 28

The method of embodiment 20 wherein the fused tricyclic compound has the structure

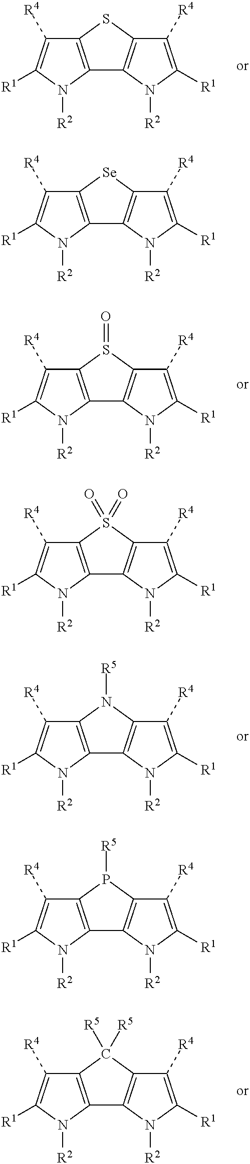

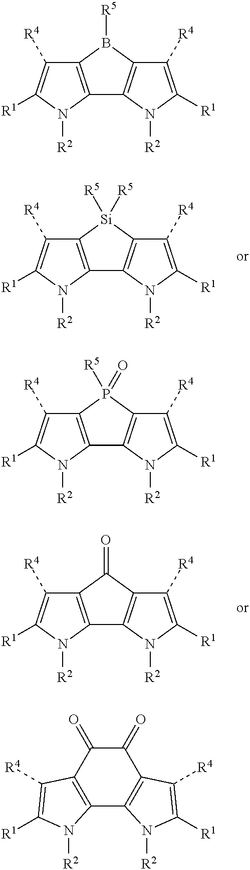

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₁₈ alkyl group, and R⁵ is a C₁-C₅₀ organic radical selected from alkyl, aryl, heteroaryl.

### Embodiment 29

The method of embodiment 20 wherein the fused tricyclic compound has the structure

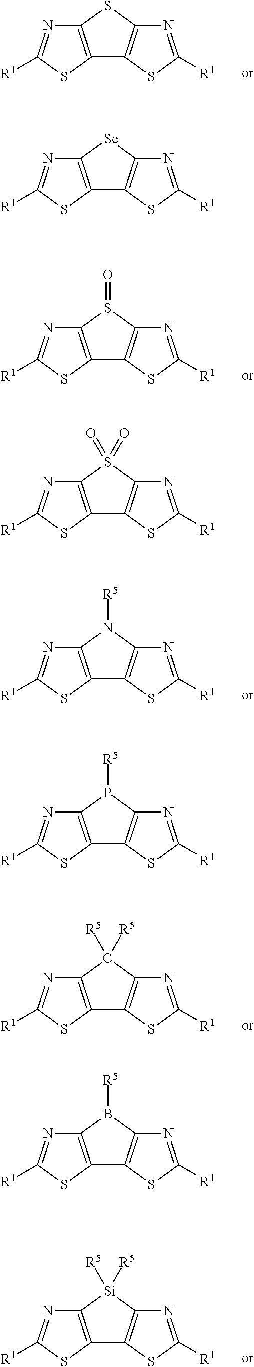

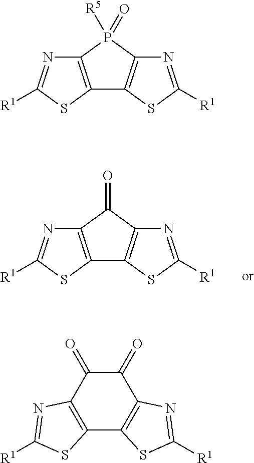

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₈ alkyl group, and R⁵ is a C₁-C₅₀ organic radical selected from alkyl, aryl, heteroaryl.

### Embodiment 30

The method of embodiment 29 wherein R¹ is

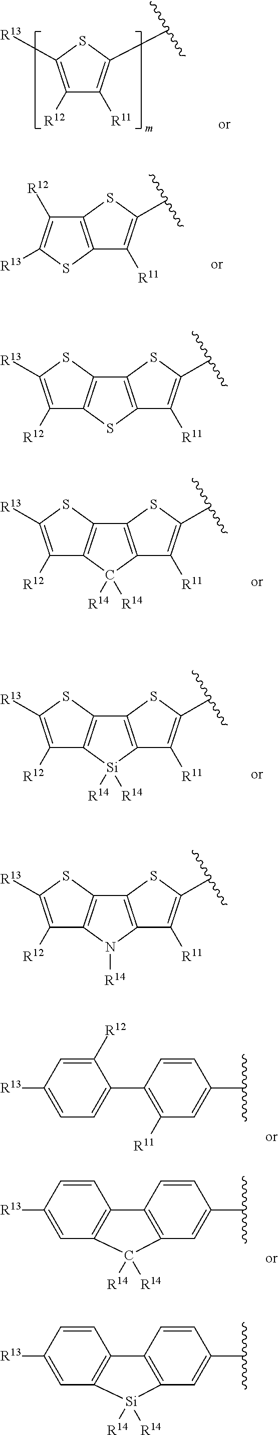

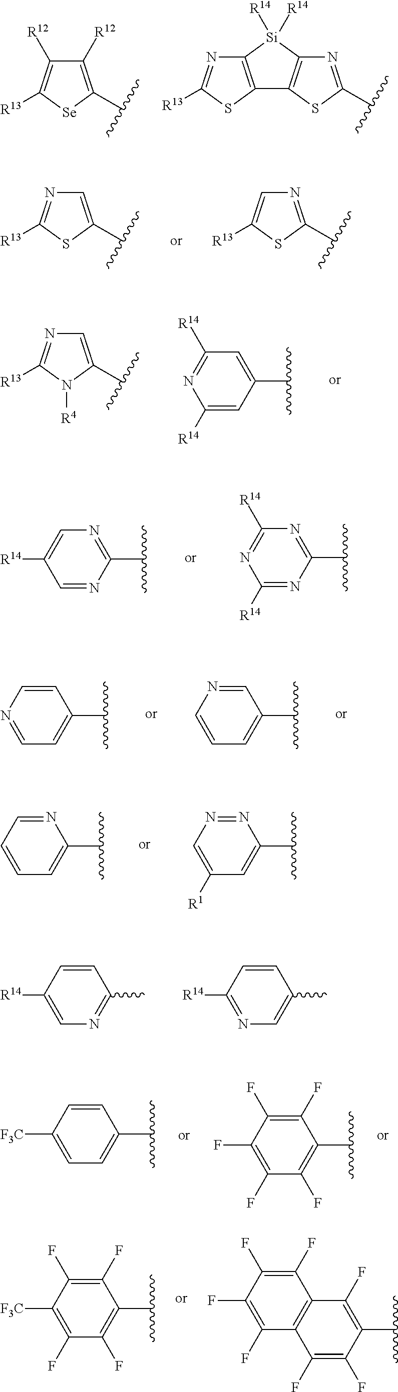

wherein m is 1, 2, 3, or 4, and R¹¹, R¹², R¹⁴ are a C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

### Embodiment 31

A compound produced by any one of the processes of embodiments 1-30.

### Embodiment 32

A composition comprising one or more of the compounds of embodiment 31.

### Embodiment 33

An electronic device comprising one or more of the compounds of embodiment 32.

### Embodiment 34

A compound having the structure:

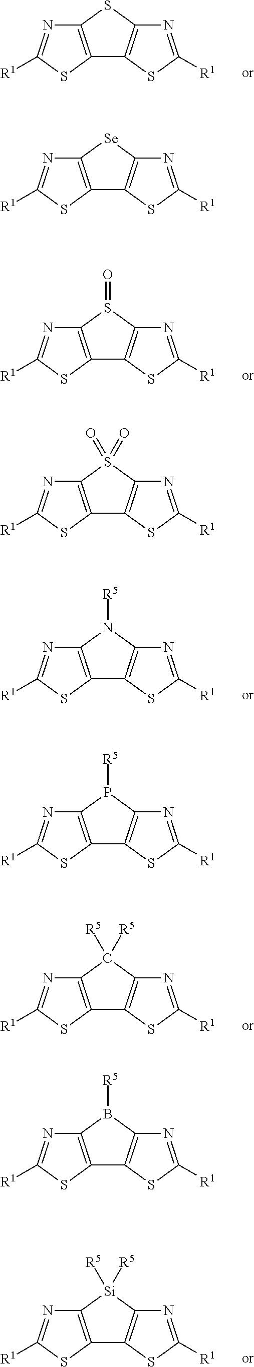

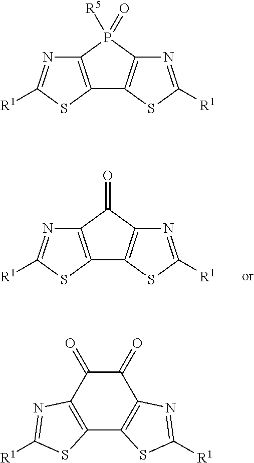

wherein R¹ is hydrogen or a halide, or a C₁-C₃₀ organic radical selected from optionally substitute alkyl, alkynyl, aryl, and heteroaryl, or —Sn(R²)₃, —Si(R²)₃, Si(OR²)₃ or —B(—OR²¹)₂ wherein each R² is an independently selected alkyl or aryl and each R²¹ is an independently selected alkyl or aryl, or the R²¹ groups together form an optionally substituted alkylene group bridging the oxygen atoms, and R⁵ is a C₁-C₅₀ organic radical selected from alkyl, aryl, heteroaryl.

### Embodiment 35

The compound of embodiment 34 wherein R¹ is

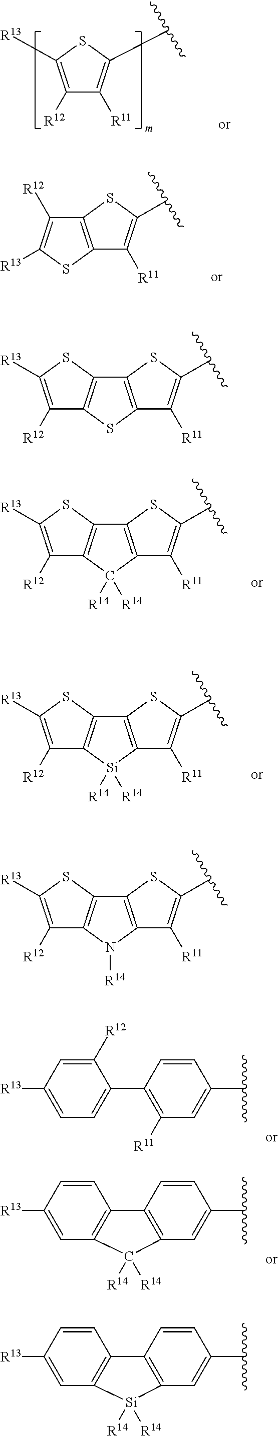

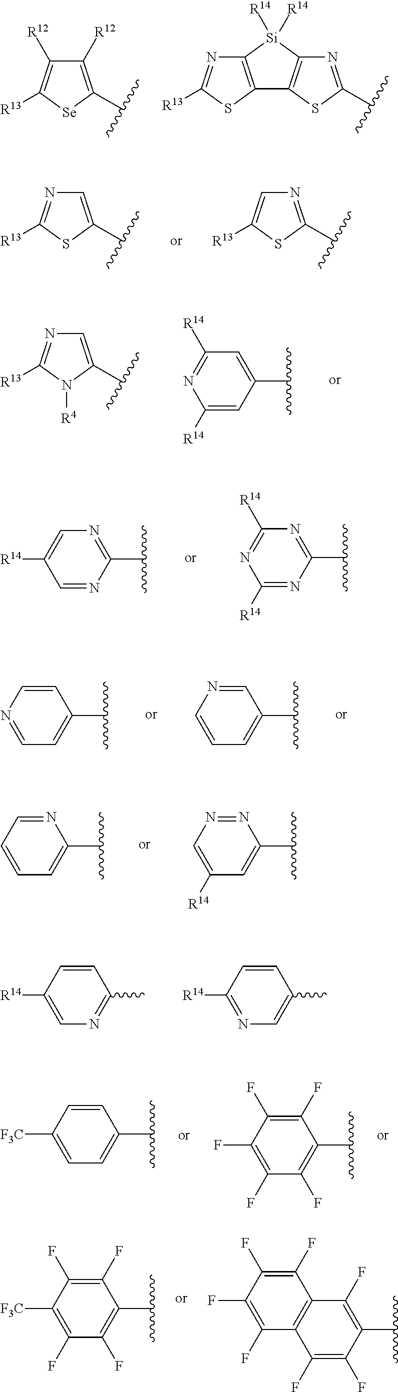

wherein m is 1, 2, 3, or 4, and R⁴, R¹¹, R¹², R¹⁴ are an independently selected C₁-C₁₈ alkyl, perfluoroalkyl, alkoxy, or perfluoroalkoxy group, and R¹³ is hydrogen, —B(—OR²¹)₂, Si(R²)₃, Si(OR²)₃ or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

### Embodiment 36

A fused tricyclic compound comprising the structure

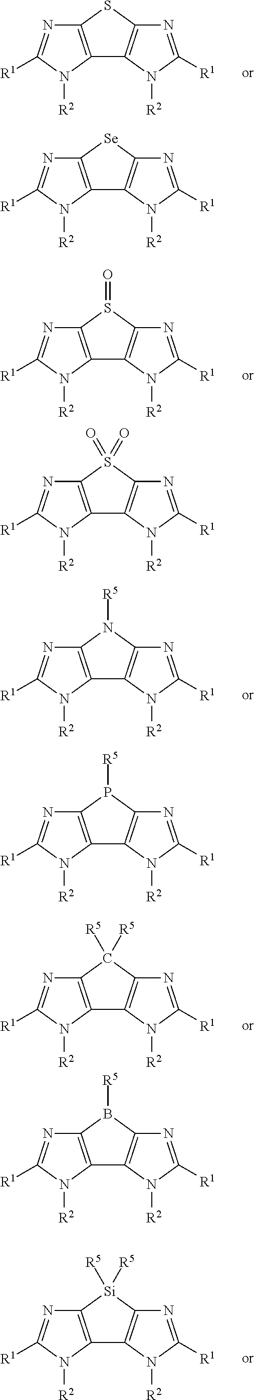

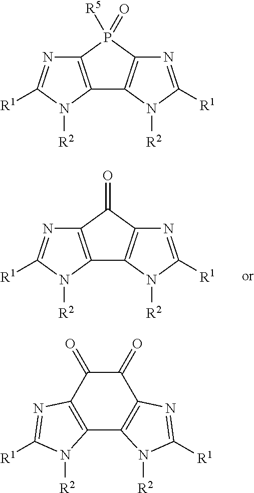

wherein R¹ is hydrogen or a halide, or a C₁-C₃₀ organic radical selected from alkyl, alkynyl, aryl, heteroaryl, or —Sn(R²)₃, —Si(R²)₃, or —B(—OR²¹)₂ wherein each R² is an independently selected alkyl or aryl and each R²¹ is an independently selected alkyl or aryl, or the R²¹ groups together form an optionally substituted alkylene group to form a ring bridging the oxygen atoms, and R⁵ is a C₁-C₅₀ organic radical selected from alkyl, aryl, heteroaryl.

### Embodiment 37

The compound of embodiment 36 wherein R¹ is

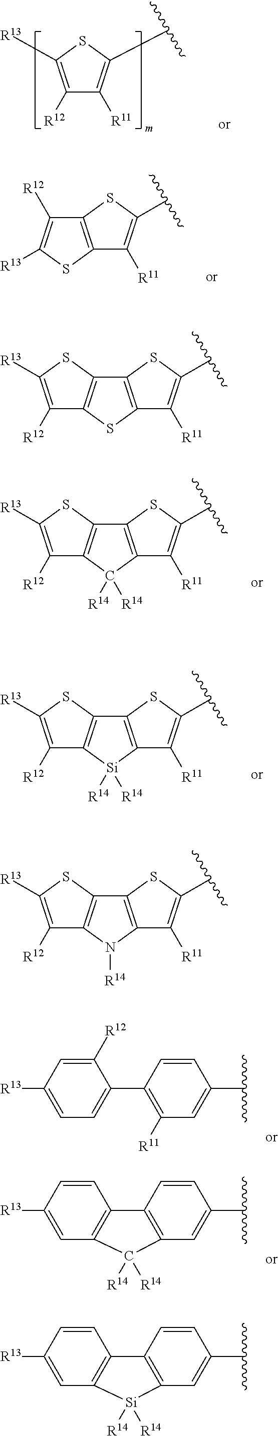

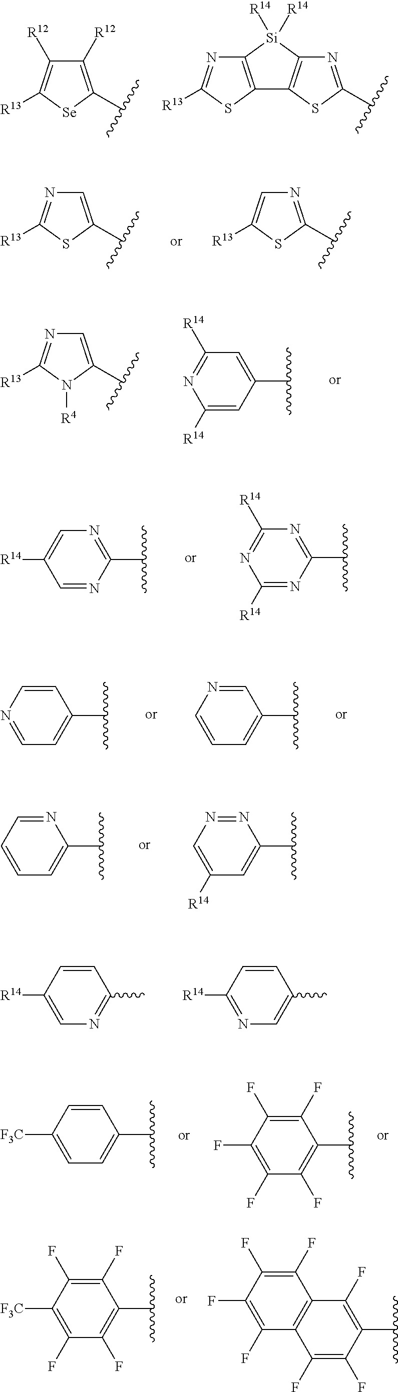

wherein m is 1, 2, 3, or 4, and R¹¹, R¹², R¹⁴ are a C₁-C₁₈ alkyl or alkoxy group, and R¹³ is hydrogen, halide, Si(R²)₃, or Sn(R²)₃.

### Embodiment 38

A compound having the structure

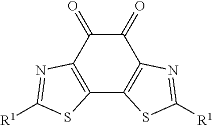

wherein R¹ is hydrogen, a halide, an optionally substituted C₁-C₃₀ alkynyl, aryl or heteroaryl, Si(R²)₃, Sn(R²)₃, or B(OR²)₂ wherein each R² is an independently selected C₁-C₁₈ alkyl or aryl, or the R² groups together form a cyclic alkylene.

### Embodiment 39

The compound of embodiment 38 wherein R¹ is

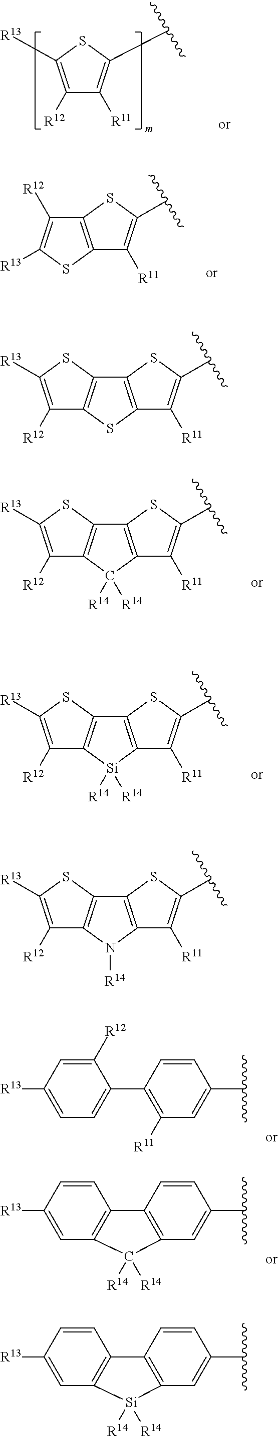

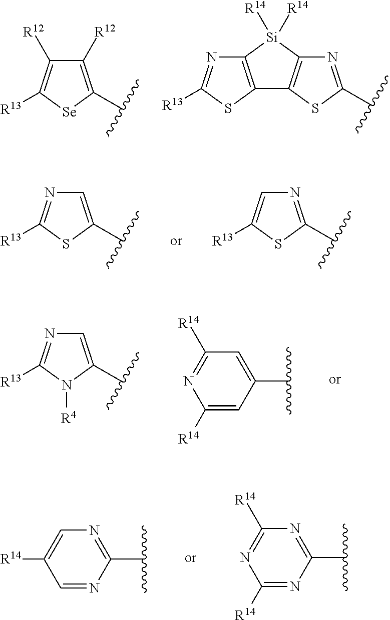

wherein m is 1, 2, 3, or 4, and R⁴, R¹¹, R¹², R¹⁴ are a C₁-C₁₈ alkyl, perfluoroalkyl, or alkoxy group, and R¹³ is hydrogen, halide, Si(R²)₃, or Sn(R²)₃.

### Embodiment 40

The compound of embodiment 39 wherein R¹ is

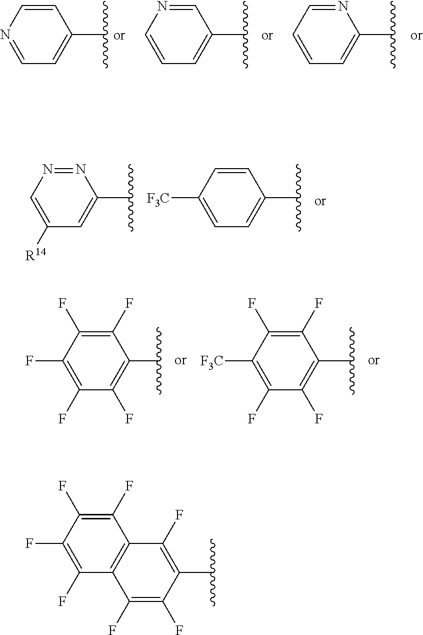

wherein R¹⁴ is hydrogen or a C₁-C₁₈ alkyl, perfluoroalkyl, or alkoxy group.

### Embodiment 41

A compound having the structure:

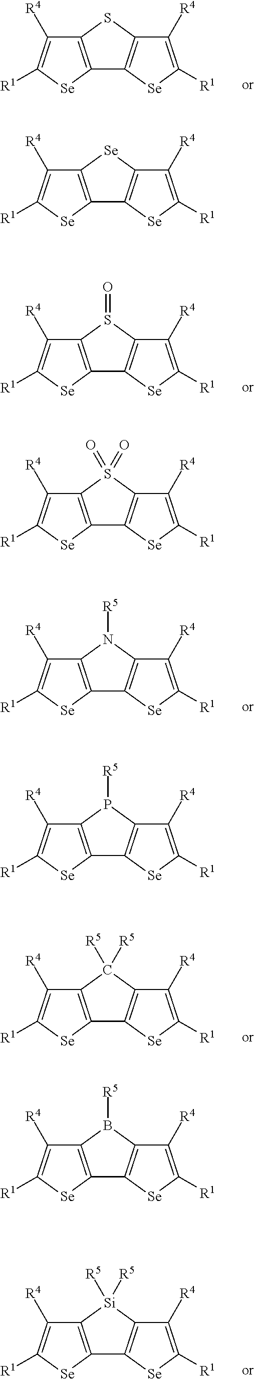

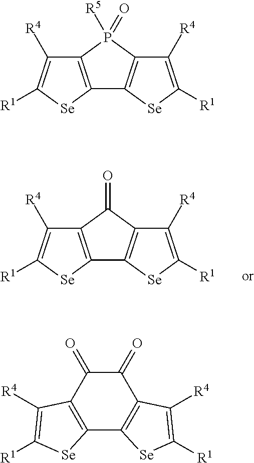

wherein R¹ is hydrogen or a halide, or a C₁-C₃₀ organic radical selected from optionally substitute alkyl, alkynyl, aryl, and heteroaryl, or —Sn(R²)₃, —Si(R²)₃, Si(OR²)₃ or —B(—OR²¹)₂ wherein each R² is an independently selected alkyl or aryl and each R²¹ is an independently selected alkyl or aryl, or the R²¹ groups together form an optionally substituted alkylene group bridging the oxygen atoms, and R⁵ is a C₁-C₅₀ organic radical selected from alkyl, aryl, heteroaryl.

### Embodiment 42

The compound of embodiment 41 wherein R¹ is

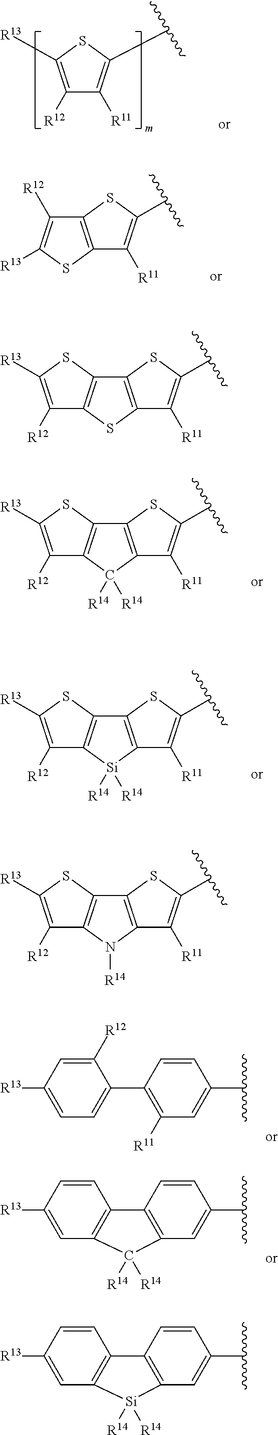

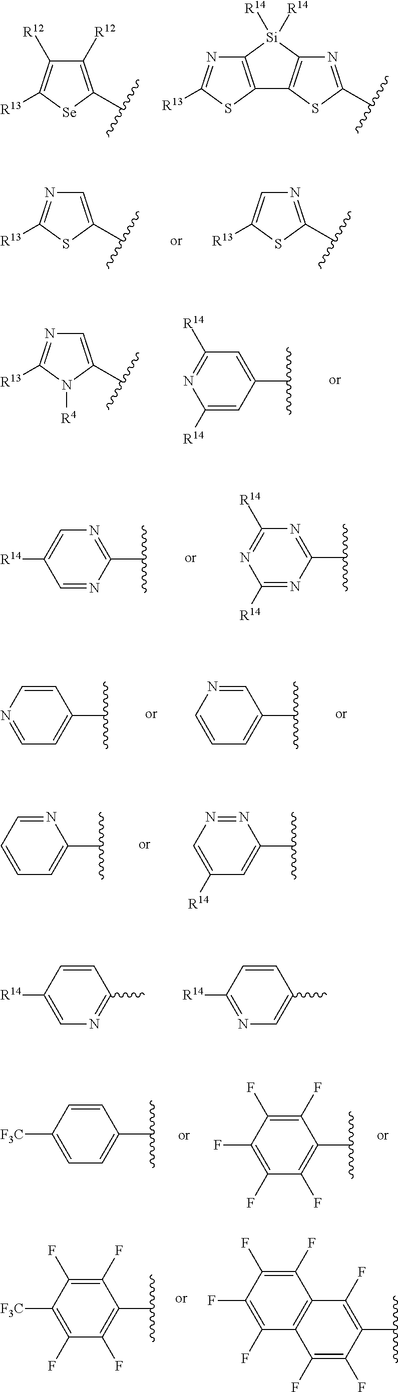

wherein m is 1, 2, 3, or 4, and R⁴, R¹¹, R¹², R¹⁴ are an independently selected C₁-C₁₈ alkyl, perfluoroalkyl, alkoxy, or perfluoroalkoxy group, and R¹³ is hydrogen, —B(—OR²¹)₂, Si(R²)₃, Si(OR²)₃ or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

### Embodiment 43

A compound having the structure

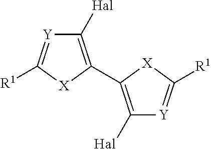

wherein
R¹ comprises an optionally substituted C₁-C₃₀ aryl or heteroaryl,
X is O, Se, or NR³ wherein R³ is a C₁-C₁₈ alkyl, fluoroalkyl, aryl, or heteroaryl, and
Y is CH, CR⁴, or N, wherein R⁴ is an optionally substituted C₁-C₁₈ alkyl, aryl, or heteroaryl.

### Embodiment 44

A fused tricyclic compound having the structure

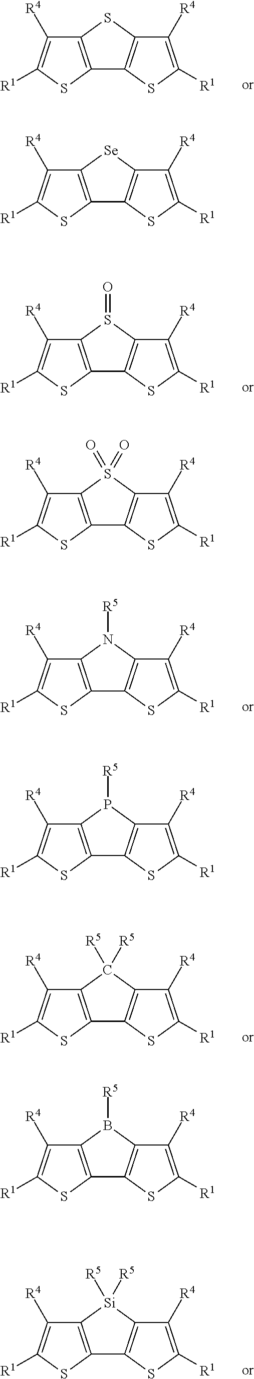

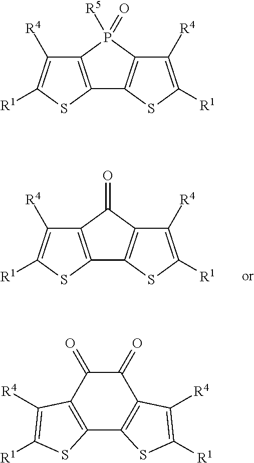

wherein R¹ is hydrogen or a halide, or a C₁-C₃₀ organic radical, R⁴ is hydrogen or optionally a C₁-C₁₈ alkyl group, and R⁵ is a C₁-C₅₀ organic radical selected from alkyl, aryl, heteroaryl.

### Embodiment 45

The compounds of embodiment 44 wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

### Embodiment 46

The compound of embodiment 44 wherein R¹ is an organic acyl compound having the formula

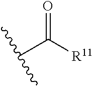

wherein R¹¹ is an aryl or heteroaryl optionally substituted with 1-10 independently selected halide, cyano, alkyl, perfluoroalkyl, acyl, alkoxy, or perfluoroalkoxy groups.

### Embodiment 47

The compound of embodiment 44 wherein R¹ is

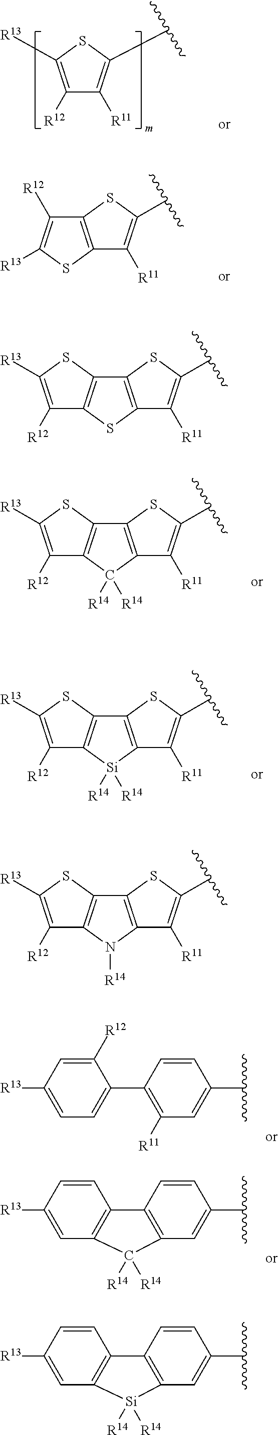

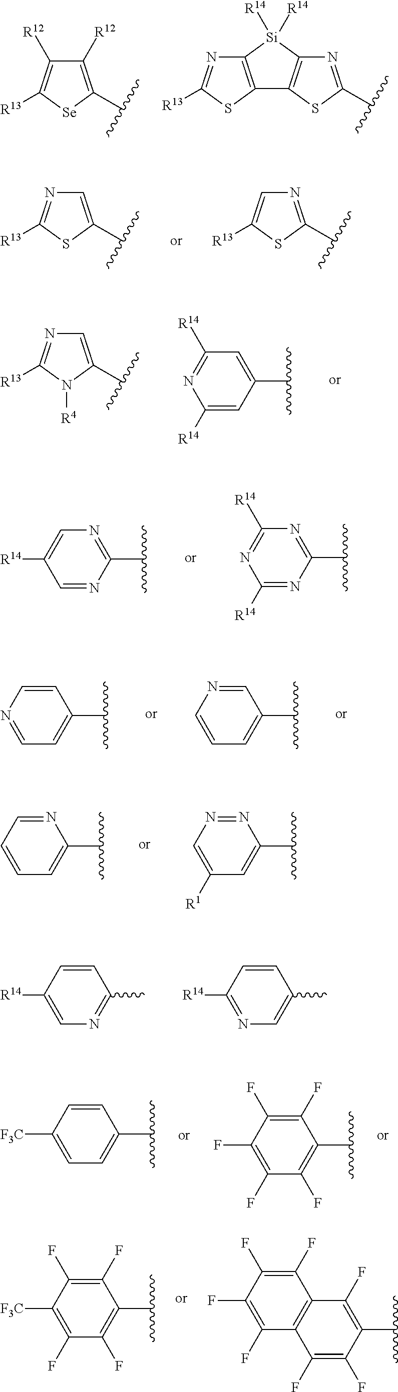

wherein m is 1, 2, 3, or 4, and R¹¹, R¹², R¹⁴ are a C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

### Embodiment 48

The compound of embodiment 44 wherein R¹ is

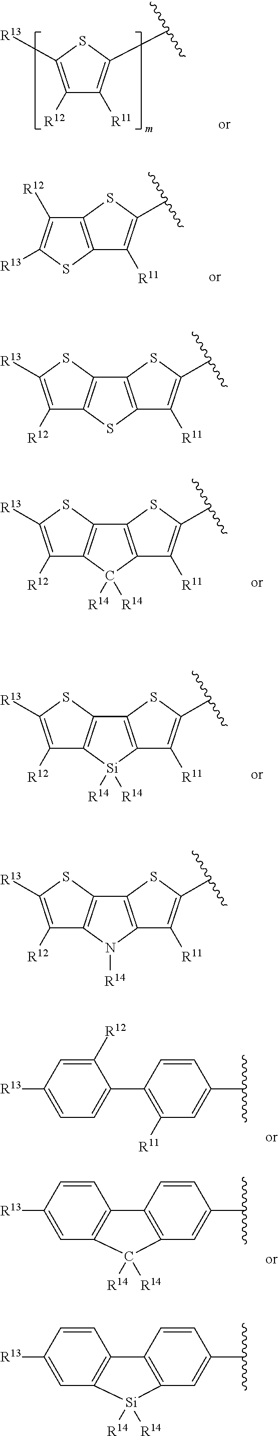

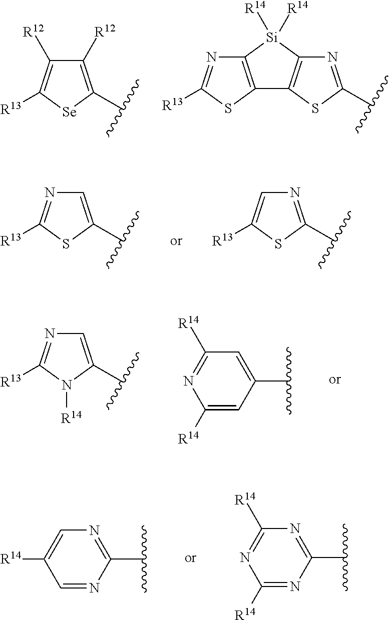

wherein m is 1, 2, 3, or 4, and R¹¹, R¹, R¹⁴ are a C₁-C₁₈ alkyl or alkoxy group, and R¹³ is hydrogen, —B(—OR²¹)₂, Si(R²)₃, or Sn(R²)₃.

### Embodiment 49

The compound of embodiment 44 wherein R¹ is

### Embodiment 50

A compound having the structure

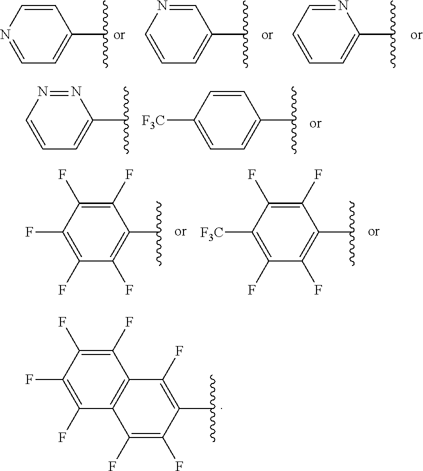

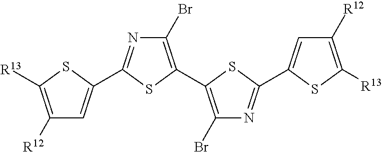

wherein R¹² is a C₁-C₁₈ alkyl or alkoxy group and R¹³ is hydrogen, halide, Si(R²)₃, wherein each R² is an independently selected alkyl or aryl.

### Embodiment 51

A polymer or copolymer comprising a repeat unit having the structure

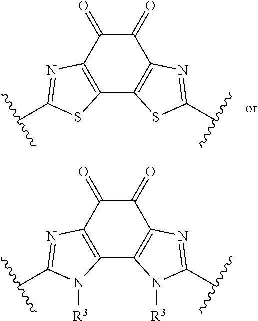

wherein R³ is a C₁-C₁₈ alkyl, perfluoroalkyl, aryl, or heteroaryl.

### Embodiment 52

A polymer or copolymer comprising a repeat unit having the structure

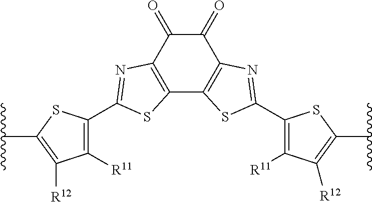

wherein R¹¹ and R¹² are hydrogen or a C₁-C₁₈ alkyl.

### Embodiment 53

A mono or bis ketal compound having the formula

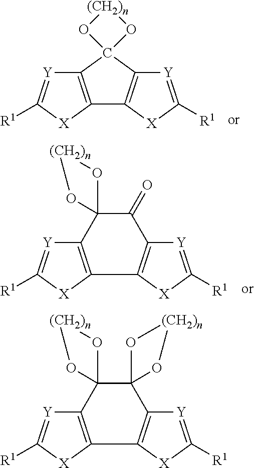

wherein
wherein R¹ is hydrogen or a halide, or a C₁-C₃₀ organic radical;
X is O, S, Se, or NR³ wherein R³ is a C₁-C₁₈ alkyl, perfluoroalkyl, aryl, or heteroaryl; and
Y is CH, CR⁴, or N, wherein R⁴ is a C₁-C₁₈ alkyl, aryl, or heteroaryl.

### Embodiment 54

The compound of embodiment 53, wherein the C₁-C₃₀ organic radical is selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

### TECHNICAL LITERATURE

The article Getmanenko et al., Organic Letters, 2010, 12, 9, 2136-2139 is hereby incorporated by reference in its entirety for all purposes.
The article Getmanenko et al., J. Org. Chem., 2011, 76, 2660-2671 is hereby incorporated by reference in its entirety for all purposes.
The article Barlow et al., J. Phys. Chem. B, 2010, 114, 14397-14407 is hereby incorporated by reference in its entirety for all purposes.
Patent application PCT/EP2011/051913 filed Feb. 10, 2011 is hereby incorporated by reference in its entirety for all purposes.
U.S. Provisional Application 61/303,163 filed Feb. 10, 2010 is hereby incorporated by reference in its entirety for all purposes.

### Additional Embodiments

### General

Additional embodiments, in some cases expanding on the embodiments described above, are described hereinbelow.

For example, one embodiment provides for compounds represented by fused ring system comprising at least one tricyclic ring systems A-B-C, where A and C are optionally substituted five- or six-membered heteroaryl outer rings which are covalently linked by carbon-carbon bonding and are further fused by a bridging group to form central ring B. The heteroaryl outer rings can be fused to other rings as described above for heteroaryl groups. The central ring can be, for example, a five- or six-membered ring. Moreover the outer rings can be further functionalized including functionalized with fused rings, spacer groups, terminal groups, reactive groups, polymerizable moieties, and the like. For example, they can be functionalized with acyl groups, fluorinated groups such as fluoroalkyl or fluoroaryl groups, or with heteroarylene groups. Also, the tricyclic ring system can be part of a larger ring system. For example, it can be coupled to form larger ring systems, e.g., (A-B-C)_{c}. The outer rings can be also fused to other rings to create, for example, compounds comprising four, five, or six, or more fused rings. Moreover, the bridging group can provide an electron-withdrawing effect. The bridging group can also comprise masking or precursor groups to mask a reactive group during synthesis (e.g., mask a carbonyl).

To illustrate, a particularly important example of a tricyclic core compound A-B-C can be represented as (X):

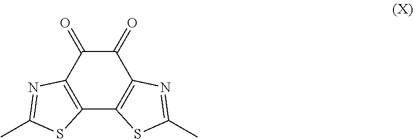

which comprises two outer rings which are thiazole rings and an inner ring which is a six-membered carbon ring comprising two adjacent carbonyls. The three rings are fused.

The two outer rings can be the same rings, and the A-B-C compound can be a symmetrical molecule with a plane of symmetry passing through the central ring (see X, for example). Alternatively, the A-B-C compound can be an asymmetrical molecule with no plane of symmetry passing through the central ring.

Four embodiments for the tricyclic compound include compounds represented by Formulas (XI), (XII), (XIII), and/or (XIV):

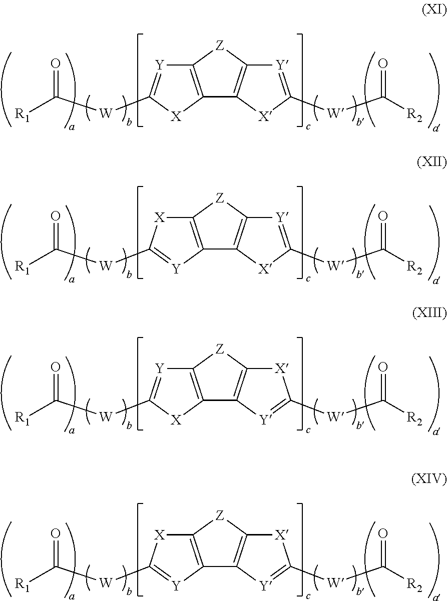

In one embodiment for XI, XII, XIII, and/or XIV, Y and Y′ are the same. In another embodiment, X and X′ are the same. In another embodiment, Y and Y′ are the same and X and X′ are the same.

In these embodiments, X and/or X′ can be, for example, O, S, Se, NR³, PR³, or Si(R³)₂. R³ can be, for example, a group that facilitates improved solubility for the compound. For example, it can be alkyl, heteroalkyl, or alkylaryl including, for example, a C₆-C₃₀ group. Examples of X and X′ are also provided above with respect to structures (Ia) and (IIa).

In other embodiments, Y and/or Y′ can be, for example, N, P, CH, CR⁴, or SiR⁴. The group R⁴ can be, for example, a group that is an electron withdrawing group. It can be, for example, H, alkyl, fluorinated alkyl, aryl, fluorinated aryl, or heteroaryl. Examples of Y and Y′ are also provided above with respect to structures (Ia) and (IIa).

Z can be a bridging moiety. In one embodiment, Z can be a moiety as described above for compound (IIa). For example, Z can be S, Se, NR⁵, C(O), C(O)C(O), Si(R⁵)₂, SO, SO₂, PR⁵, P(O)R⁵, BR⁵, or C(R⁵)₂ wherein, for example, R⁵ is a C₁-C₅₀ organic radical selected from optionally substituted alkyl, perfluoroalkyl, aryl, and heteroaryl. In addition, Z can comprise cyano substituent groups. For example, cyano substituent groups can be substituted onto a one carbon or two carbon bridge. For example, Z can be, for example, >C═C(CN)₂ or —C═C(CN₂)—C═C(CN₂)—. Other examples of Z can be found in the Barlow reference cited above. Z can provide an electron withdrawing function and can comprise electron withdrawing groups. Z can also comprise substituents which function to mask functional groups or function as a precursor to another group.
The article Zhou et al., Macromolecules, 41, 8302-8305, 2008 describes dithieno[3,2-b:2′,3′-d]pyrrole systems, e.g., where Z is NR⁵. See also, for example, Zhang et al., J. Am. Chem. Soc., 2008, 130, 13167-13176.
The article Zhan et al., J. Materials Chem., 2009, 19, 5794-5803 describes systems wherein Z is S or NR⁵.
Suzuki et al., Organic Letters, 2008, 10, 16, 3393-3396 describes a system wherein Z is S(O)₂.
Rieger et al., Materials, 2010, 3, 1904-1912 and Meyer et al., Beilstein J. Org. Chem., 2010, 6, 1180-1187 describe a system for Z is C(O)C(O).
Berlin et al., Chem. Mater., 2004, 16, 3667-3676 describes an example where Z is C(O) or C═C(CN)₂ for a dithiophene system. See also, for example, Chonan et al., Bull. Chem. Soc. Jpn., 77, 1487-1497 (2004) for a C(O) example for Z and Kozaki et al., Synthetic Metals, 135-136 (2003) 107-108 for an example of Z is C(O) or C═C(CN)₂. See also, for example, Kozaki et al., Organic Letters, 2002, 4, 25, 4535-4538.
The article Ohshita et al, J. Organometallic Chemistry, 553 (1998) 487-491 describes dithienosiloles, wherein Z is Si(R⁵)₂. See also, for example, Ohshita et al., Organometallics, 1999, 18, 1453-1459 and Son et al., Organometallics, 2008, 27, 2464-2473.

For embodiments wherein Z is BR⁵, the R⁵ group can be a relatively bulky group to enhance stability and prevent intramolecular reactions (e.g., a C4, C6, or C8 or higher R group).
Xiao et al., Macromolecules, 2008, 41, 5688-5696 describe bithiophenes wherein Z is C(R⁵)₂.
Ie et al., Organic Letters, 2007, 9, 11, 2115-2118, describes the Z bridging group as CF₂ for a bithiophene, and oligomers thereof.

In addition, optional groups W and W′ are shown. These groups W and W′ can be the same or different. The compound can comprise just W, or just W′, or both W and W′. If the acyl group is present, group W can be a spacer. If the acyl group is not present, group W can be a terminal group. Examples of W can be found above in the R¹ groups described for structure (Ia) and (IIa), wherein the W is adapted, as desired, to bond to an acyl group. For example, the W group can be an electron rich or an electron poor group as described above. The W group also can provide for conjugation which extends from the tricyclic core to the W group. The optional W group can be a heteroarylene group, for example. Examples can be represented by:

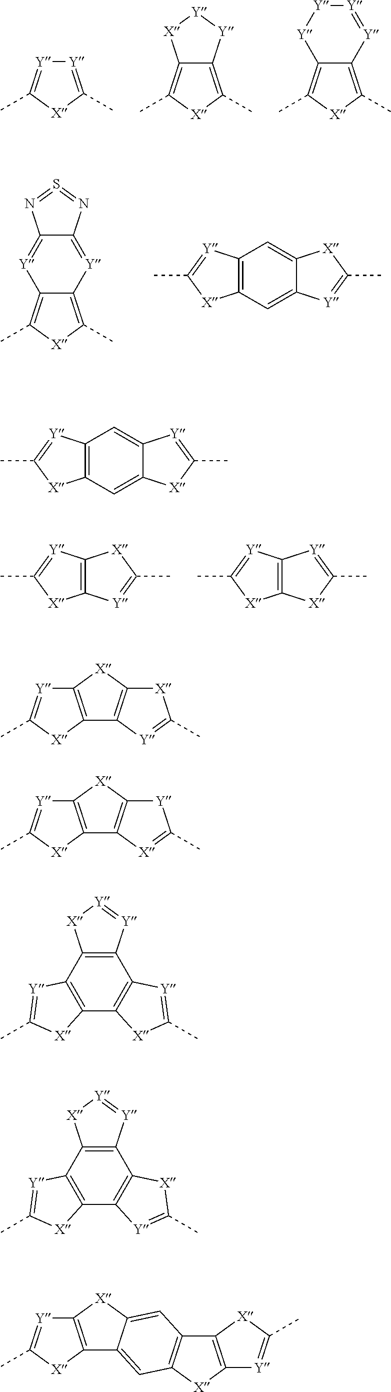

wherein independently X″ and Y″ can be moieties described herein for X and Y, or X′ and Y′.

In addition, optional acyl groups represented by —C(O)—R¹ and —C(O)—R² are shown. These groups acyl groups can be the same or different. The compound can comprise just —C(O)—R¹, or just —C(O)—R², or both —C(O)—R¹ and —C(O)—R². Groups R¹ and R² independently can be, for example, alkyl, fluorinated alkyl, aryl, fluorinated aryl, heteroaryl, arylalkyl, or heteroarylalkyl.

In formulas XI, XII, XIII, and XIV, a core tricyclic group is shown which can be a single tricyclic unit (i.e., c is 1) or which can be repeated when the tricyclic group is coupled (e.g., c is 2, 3, 4, 5, 6, and higher). The value for c can be, for example, 1-4.

The values for b and b′ independently can be, for example, 0, 1, 2, 3, or 4.

The values for a and a′ independently can be, for example, 0 or 1.

Methods of making, methods of using, compositions, and articles are described with respect to compounds represented by formulas such as Formulas (XI), (XII), (XIII), and (XIV).

In one embodiment, W and W′ are not thiophene or thiophene-containing moieties. In one embodiment, the tricyclic core does not comprise thiophene (e.g., X and X′ are not S, and Y and Y′ are not C). In one embodiment, the entire compound is free of thiophene rings.

In many cases, X will equal X′ and Y will equal Y′. This can arise when the same starting heteroaryl ring compound is coupled to itself. However, they can be different. For example, the following scheme illustrates how two different ring compounds can be coupled together:

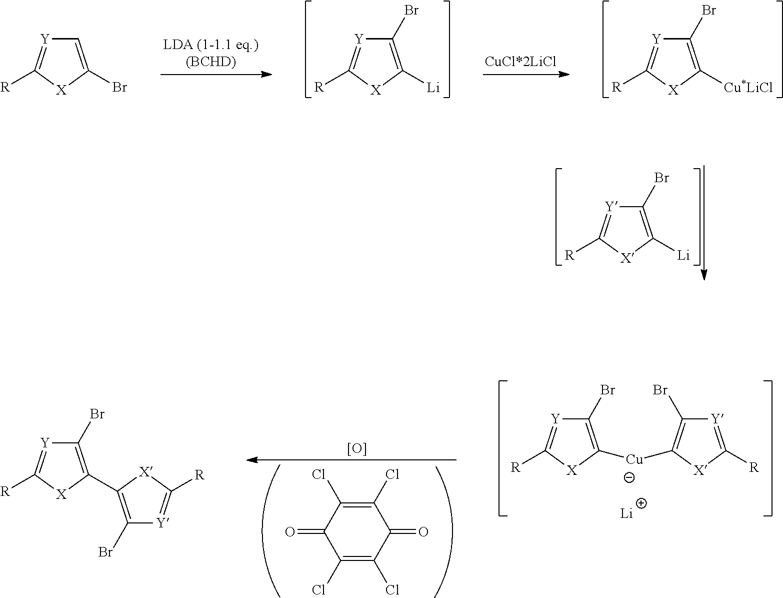

The compounds for Formula XIV can be prepared according to the following scheme:

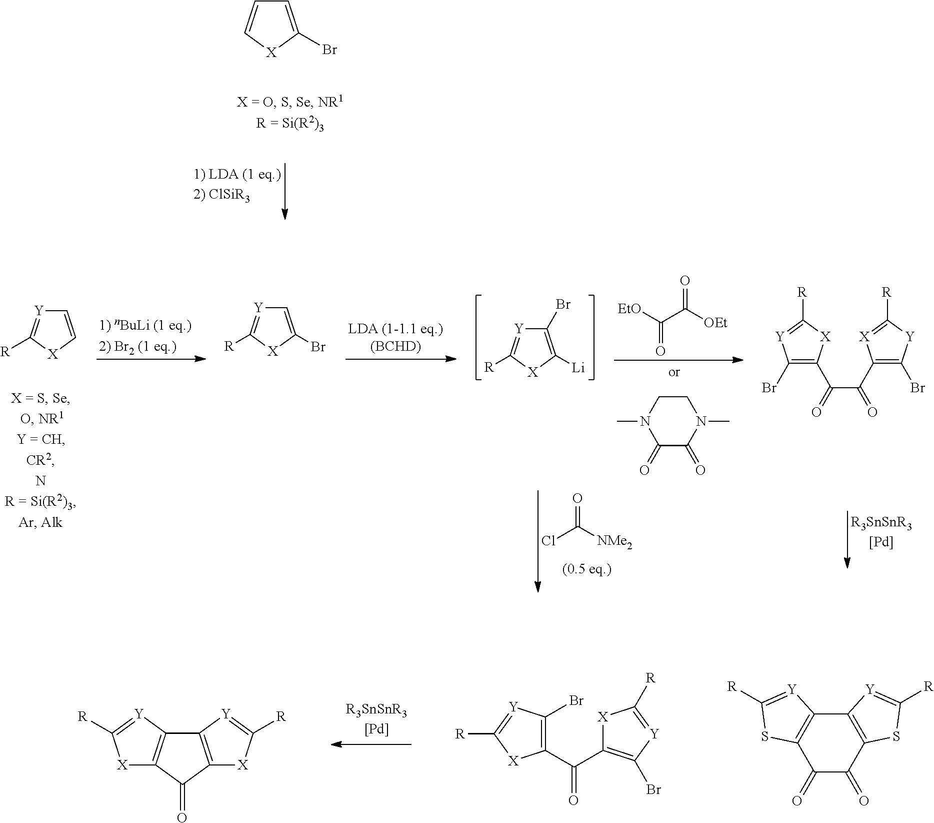

See also, for example, the following scheme:

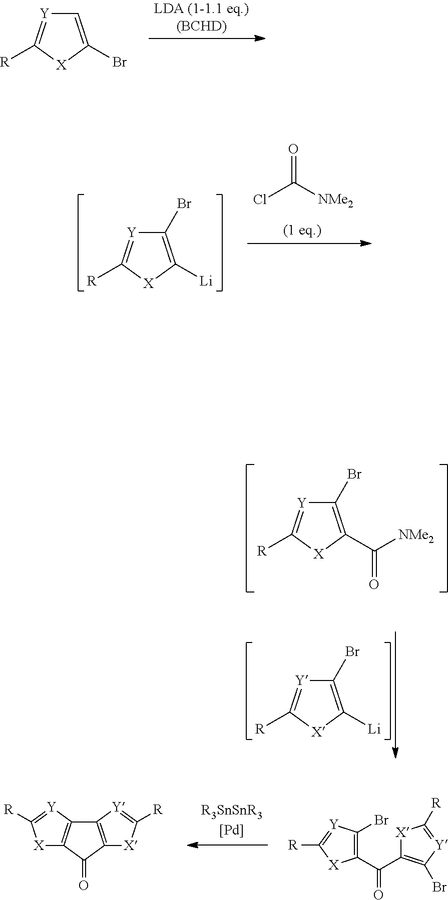

In some embodiments, particular features, compounds, methods, devices, and the like are excluded from the embodiments described herein. For example, in some embodiments, the use of a thiophene ring in the compound can be excluded. In another embodiment, for example, a fused tricyclic compound comprising three fused thiophene rings can be excluded. One or more embodiments described in technical literature can be excluded. For example, one or more embodiments from the PCT '913 application can be excluded from a described or claimed invention as described or claimed herein.

At least four additional categories of embodiments are described further below (A, B, C, and D).

### I. Additional Embodiments

### Acyl (A)

The acyl group (e.g., carbonyl, —C(O)—) can provide compounds, including compounds of interest in organic electronics, with attractive synthetic versatility and electronic properties. See, for example, Marks et al., J. Am. Chem. Soc., 2005, 127, 1348-1349; Marks et al., J. Am. Chem. Soc., 2005, 127, 13476; Marks et al., Chem. Commun. 2009, 1846; Marks et al., Chem. Euro. J. 2010, 16, 1911; and Marks et al. US Patent Publication 2009/0267061.

Acyl groups can extend conjugation. Furthermore, the acyl addition may provide further stability to the core, while also providing a facile manner in which to polymerize the monomers to form polymers with advantageous electronic properties.

Numerous synthetic pathways to the formation or transformation of acyl compounds exist, many of which are described in texts such as, for example, Smith and March “March's Advanced Organic Chemistry,” 6^{th} Edition, Wiley, New York, N.Y., 2007, and references cited therein, which is hereby incorporated by reference.

For example, nucleophilic addition to form a carbon-carbon bond between an acyl moiety and a nucleophile is known in the art. In one embodiment, an acyl moiety is formed by reacting a nucleophilic carbon with a compound comprising a carbonyl moiety. Nucleophilic additions to other functional groups that are then converted to the carbonyl functionality of the acyl moiety are contemplated by this description. Such additional functional groups include for example, imines, which may be hydrolyzed to the corresponding carbonyl compound.

One embodiment is:

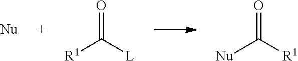

In the above scheme, Nu is a nucleophilic compound, such as the heteroarylene, coupled heteroarylene or tricyclic heteroarylene compound described herein, wherein the heteroarylene compound has been treated with a base to form the nucleophilic carbon, which then forms a bond with the carbon atom of the carbonyl compound. L may be any leaving group, and one skilled in the art would recognize that this includes but is not limited to, for example, halides, triflates and amides.

Additional embodiments include protected carbonyl groups on the acyl moiety. The protected carbonyl may be in the form of a protected carbonyl, such as for example a ketal or acetal, or it may be in the form of a heteroatom moiety that is able to be converted into the carbonyl functional group. This may include, for example, a protected alcohol or amine, which can be later deprotected and oxidized to the corresponding carbonyl functionality.

In some of these embodiments, the R group that will ultimately contain the acyl functionality may be present at a stage of the synthesis prior to the BCHD method. This functionality may be in the form of a protected carbonyl, such as for example a ketal, acetal, orthoester, or imine. Alternatively, the functional position may be in the form of an alcohol or protected alcohol, which can be later oxidized or deprotected and oxidized, respectively, to the corresponding acyl.

For example, the heterarylene compound shown in the synthetic scheme below may contain an R¹ group of possible structures

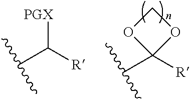

wherein PG is a protecting group, X is a hetero atom, n is an integer from 0 to 7 and R′ is any group appended to the carbonyl of an aryl functional group that is defined herein.

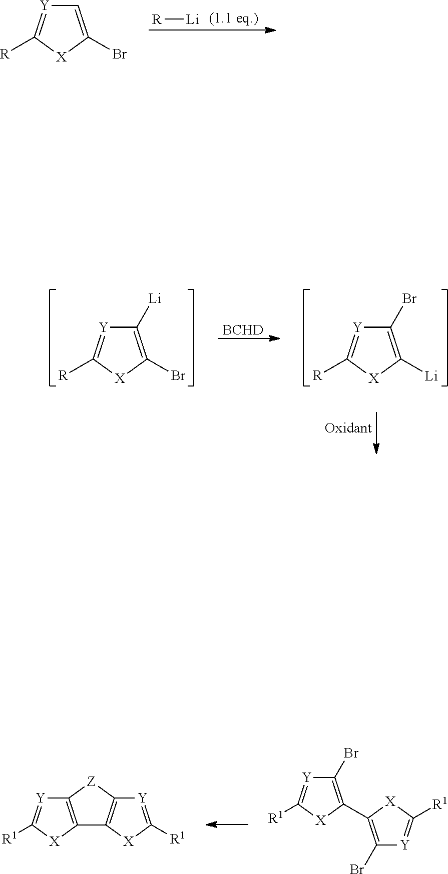

Upon cyclization, the carbonyl may be deprotected by methods known in the art, and those described herein, for example, by treatment with acid at elevated temperature. Alternatively, PG-X may be subject to deprotecting conditions and the resulting compound may be oxidized or otherwise converted to the carbonyl by methods known in the art.

Additionally, the protected carbonyl functionality described above may be bonded to a heteroarylene moiety that is coupled to another heteroarylene or tricyclic core compound through methods described here in. Similar deprotection strategies as mentioned above, may be utilized to obtain the acyl moiety.

Other acylation embodiments are provided below:

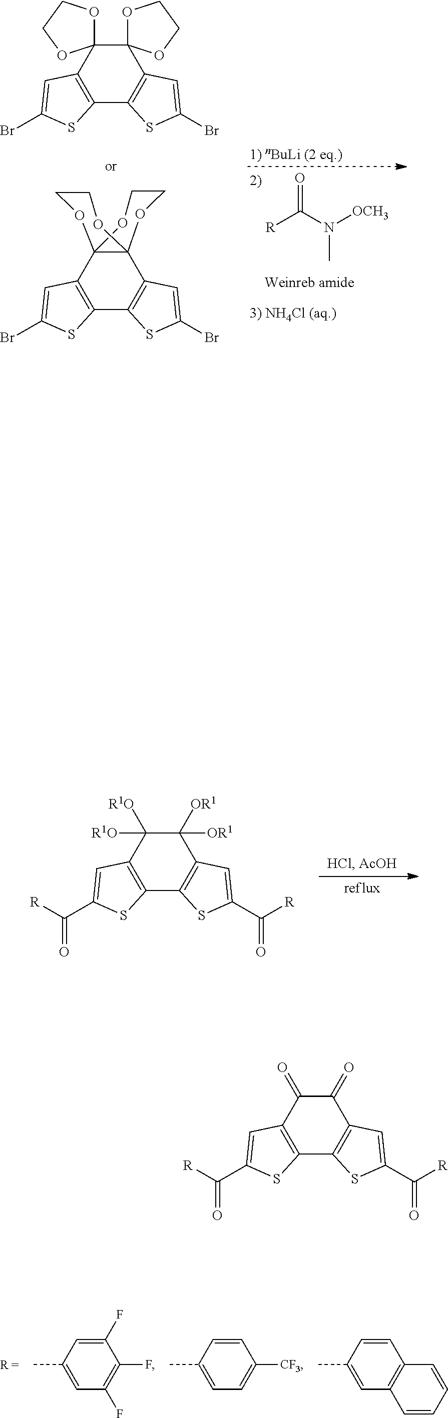

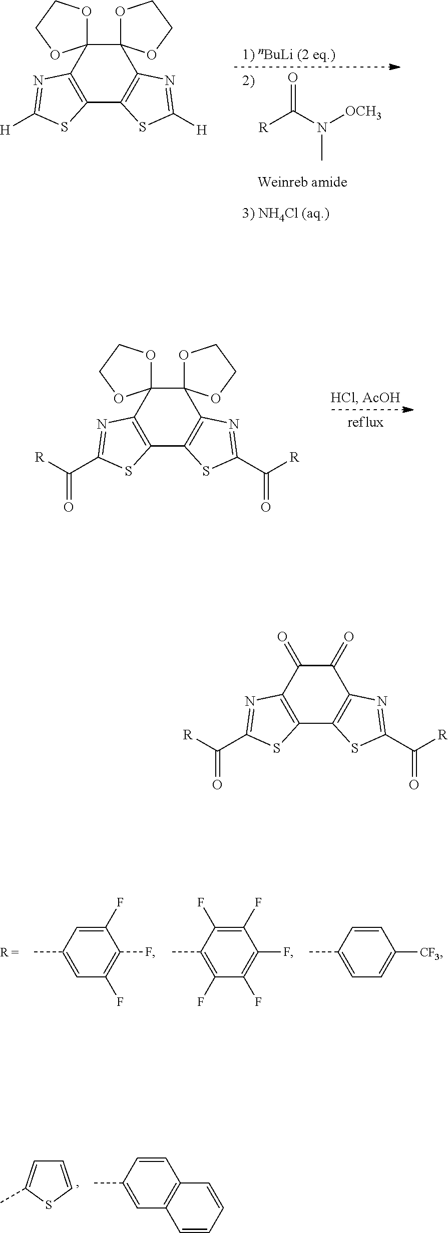

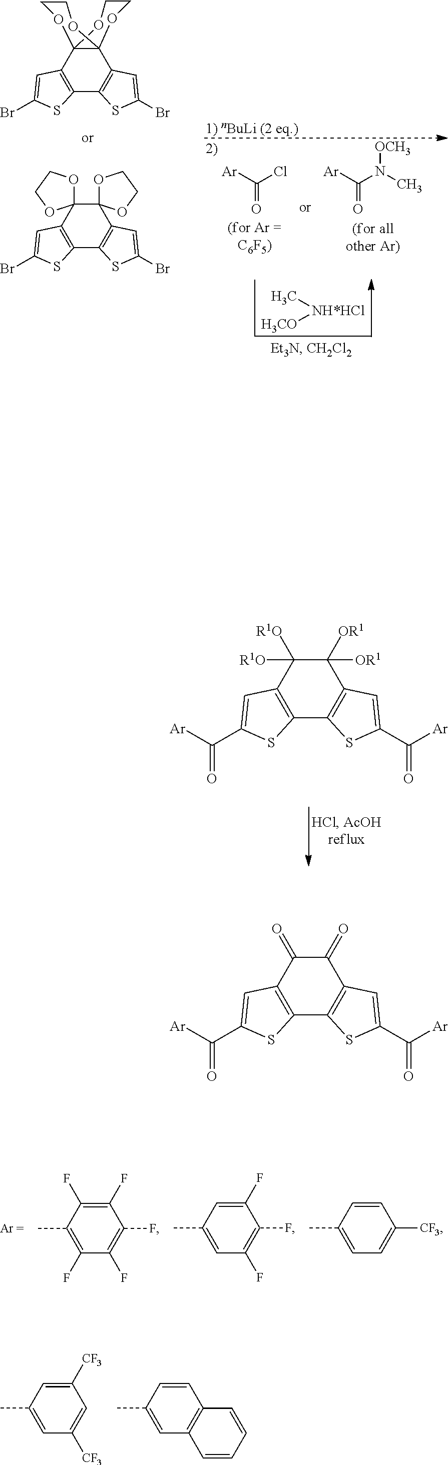

Hence, one aspect provides embodiments wherein the compound such as represented by XI, XII, XIII, or XIV comprises at least one acyl group or, for example, two or more acyl groups. For example, in the compounds represented by XI, XII, XIII, and XIV, a can be 1, a′ can be 1, or both a and a′ can be 1.

In an additional embodiment, a proviso can be provided that methods, compounds, and compositions described herein, exclude acyl compounds and related methods of making and using which are described in PCT/EP2011/051913. For example, acyl compounds and groups are shown on pages 32-33 of this '913 application (and also shown above), at working example 30 of this '913 application, and also at claim 46 of the '913 application. For example, this '913 application teaches with respect to structure (IIa)

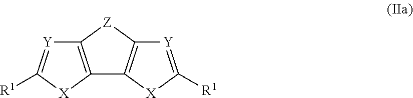

and its description of R¹ groups: “such R¹ organic radicals can be selected from an organic acyl compound having the formula

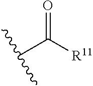

wherein R¹¹ is an aryl or heteroaryl optionally substituted with 1-10 independently selected halide, cyano, alkyl, perfluoroalkyl, acyl, alkoxy, or perfluoroalkoxy groups.”

In these embodiments, X is O, S, Se, or NR³ wherein R³ is a C₁-C₁₈ alkyl, perfluoroalkyl, aryl, or heteroaryl; and Y is CH, CR⁴, or N, wherein R⁴ is a C₁-C₁₈ alkyl, aryl, or heteroaryl.

This '913 application also describes in Example 30 the synthesis of the following acyl compound, and its precursor compound, both of which can be excluded:

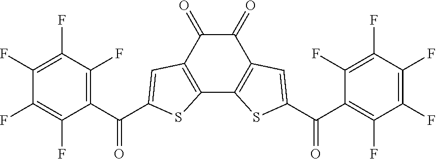 [SMILES: O=C1C(=O)c2cc(C(=O)c3c(F)c(F)c(F)c(F)c3F)sc2-c2sc(C(=O)c3c(F)c(F)c(F)c(F)c3F)cc21]

All of these embodiments can be excluded from the claimed inventions.

In one embodiment, the compounds comprise at least one acyl group but are also free of any thiophene groups.

Hence, one aspect provides, for example, a method comprising: (a) providing at least one first compound comprising at least one heteroaryl ring comprising at least one halogen substituent on the ring, (b) reacting the first compound in a ring coupling reaction sequence to form a second compound which is different from the first compound and which is a bishalo-bisheteroaryl compound comprising a first ring and a second ring covalently linked by a carbon-carbon bond, wherein the halogen moves to a new position on the ring during the coupling reaction sequence, (c) reacting the second compound in a ring formation reaction sequence to form a third compound comprising a tricyclic core, wherein the third compound is different from the first and second compounds, wherein the tricyclic core comprises three fused rings including a first outer ring, a second outer ring, and a third central ring which is formed in the ring formation reaction and fuses to the first and second rings, (d) reacting the third compound in a reaction sequence to provide a fourth compound comprising at least one acyl group.

For example, one embodiment provides a method comprising:

providing an optionally substituted precursor compound comprising a five- or six-membered heteroaryl ring having a halogen substituent at a first position on the heteroaryl ring;

treating the precursor compound with a strongly basic compound to induce the isomerization of the precursor compound to produce an intermediate compound wherein the halogen atom is bound to a different position on the heteroaryl ring;

treating the intermediate compound with an oxidizing agent so as to form a carbon-carbon bond between two intermediate compounds and thereby form a bishalo-bisheteroaryl compound represented by:

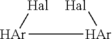

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce a Z group, or a precursor thereof suitable for forming a fused tricyclic compound represented by:

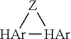

wherein:

Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl; and

wherein either:

(a) the moiety:

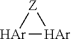

is an acyl compound which comprises at least one heteroaryl ring which is substituted with at least one substituent comprising at least one acyl or protected acyl group; or

(b) the moiety

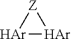

is subjected to one or more further reaction steps to form an acyl compound wherein one or both of the HAr moieties are substituted with at least one substituent comprising at least one acyl or protected acyl group;
with the proviso that the following compounds are excluded from being the acyl compound:

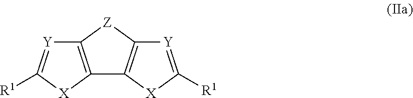

wherein the R¹ organic radicals can be selected from an organic acyl compound having the formula

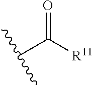

wherein R¹¹ is an aryl or heteroaryl optionally substituted with 1-10 independently selected halide, cyano, alkyl, perfluoroalkyl, acyl, alkoxy, or perfluoroalkoxy groups; and wherein X is O, S, Se, or NR³ wherein R³ is a C₁-C₁₈ alkyl, perfluoroalkyl, aryl, or heteroaryl; and Y is CH, CR⁴, or N, wherein R⁴ is a C₁-C₁₈ alkyl, aryl, or heteroaryl; and Z of formula (IIa) is S, Se, NR⁵, C(O), C(O)C(O), Si(R⁵)₂, SO, SO₂, PR⁵, P(O)R⁵, BR⁵, C(R⁵)₂, wherein R⁵ is a C₁-C₅₀ organic radical selected from optionally substituted alkyl, perfluoroalkyl, aryl, and heteroaryl.

In another embodiment, the moiety:

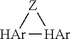

is subjected to one or more further reaction steps to form an acyl compound wherein one or both of the HAr moieties are substituted with at least one substituent comprising at least one acyl or protected acyl group.

In another embodiment, the moiety:

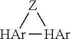

is subjected to one or more further reaction steps to form an acyl compound wherein one or both of the HAr moieties are substituted with at least one substituent comprising at least one acyl group.

In another embodiment, the moiety:

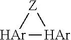

is an acyl compound which comprises at least one heteroaryl ring which is substituted with at least one substituent comprising at least one acyl or protected acyl group.

In another embodiment, the moiety:

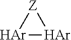

is an acyl compound which comprises at least one heteroaryl ring which is substituted with at least one substituent comprising at least one acyl group.

In another embodiment, the acyl compound comprises at least two acyl or protected acyl groups.

In another embodiment, the acyl group is covalently bonded to at least one heteroarylene group different from the two HAr moieties.

In another embodiment, the acyl group is covalently bonded to at least one heteroarylene group different from the two HAr moieties and represented by W, which is a single unit W or part of an oligomeric structure (W)_{b}, wherein b is 2-4.

In another embodiment, the acyl group is bonded to at least one thiophene ring.

In another embodiment, the acyl group is bonded to a fluorinated aryl group.

In another embodiment, the heteroaryl rings HAr are each an optionally substituted five membered heteroaryl ring.

In another embodiment, the heteroaryl rings HAr are thiazole or thiophene. In another embodiment, the heteroaryl rings HAr are thiazole. In another embodiment, the heteroaryl rings HAr are thiophene.

In another embodiment, the heteroaryl ring and halogen of the precursor compound comprise the structure

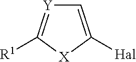

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, the heteroaryl ring and the halogen of the precursor compound comprise the structure:

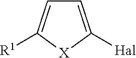

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is S, Se, or NR³ wherein R³ is a C₁-C₁₈ alkyl, perfluoroalkyl, aryl, or heteroaryl.

In another embodiment, the heteroarylene ring and halogen of the precursor compound comprise the structure:

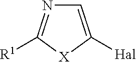

wherein

R¹ is a C₁-C₃₀ organic radical selected from optionally substituted alkyl, alkynyl, aryl, or heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms; and

X is S or NR³ wherein R³ is a C₁-C₁₈ alkyl, perfluoroalkyl, aryl, or heteroaryl.

In another embodiment, the heteroarylene ring and halogen of the precursor compound comprise the structure:

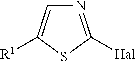

wherein

R¹ is a halide, or a C₁-C₃₀ organic radical selected from alkyl, alkynyl, aryl, heteroaryl, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In another embodiment, R¹ is a C₁-C₃₀ aryl or heteroaryl optionally substituted by one to four ring substituents independently selected from halides, alkyl, alkynyl, perfluoroalkyl, alkoxide, perfluoroalkoxide, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In another embodiment, the halogen is bromine or iodine.

In another embodiment, the bishalo-bisheteroaryl compound has one of the structures

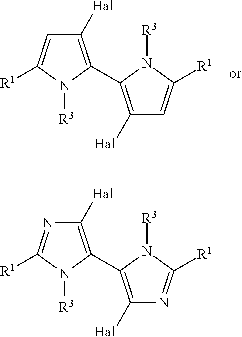

wherein

R¹ is hydrogen or a halide, or a C₁-C₃₀ organic radical selected from optionally substituted alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R³ is a C₁-C₁₈ alkyl, perfluoroalkyl, aryl, or heteroaryl.

In another embodiment, the bishalo-bisheteroaryl compound has one of the structures

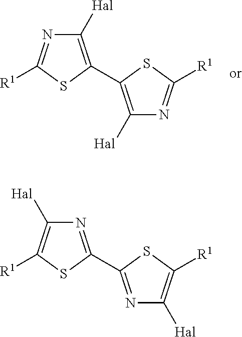

wherein R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

In another embodiment, the bishalo-bisheteroaryl compound has one of the structures

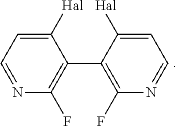

In another embodiment, the fused tricyclic compound has the structure

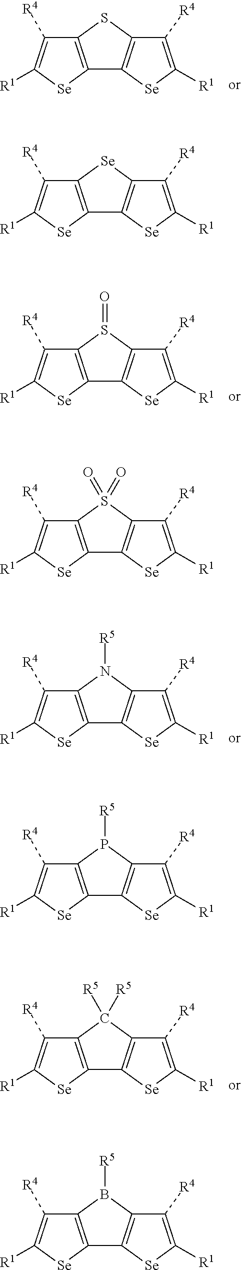

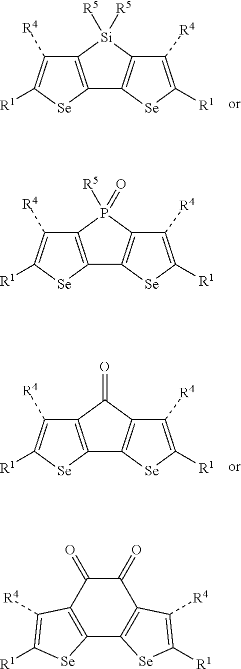

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms, R⁴ is hydrogen or optionally a C₁-C₁₈ alkyl group, and R⁵ is a C₁-C₅₀ organic radical selected from alkyl, aryl, heteroaryl.

In another embodiment, the fused tricyclic compound has the structure

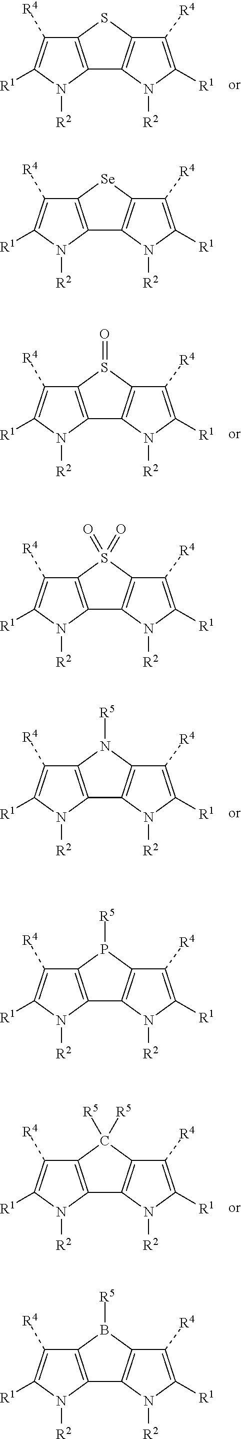

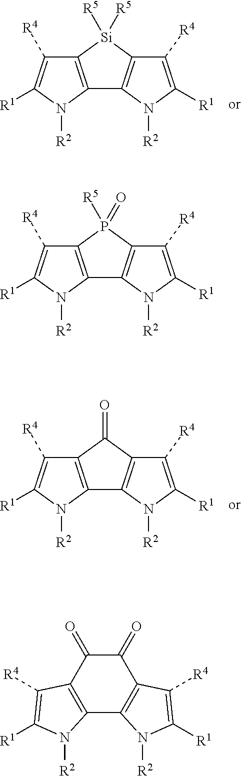

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₁₈ alkyl group, and R⁵ is a C₁-C₅₀ organic radical selected from alkyl, aryl, heteroaryl.

In another embodiment, the fused tricyclic compound has the structure:

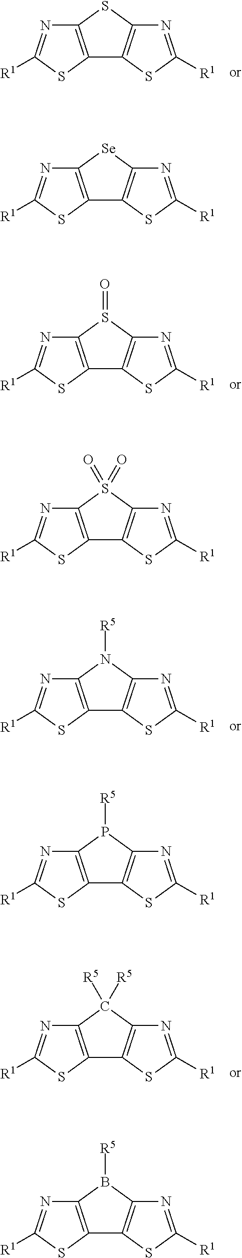

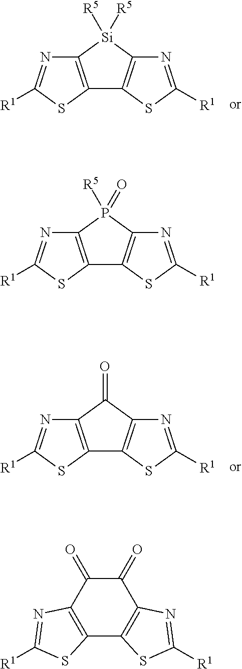

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₈ alkyl group, and R⁵ is a C₁-C₅₀ organic radical selected from alkyl, aryl, heteroaryl.

In another embodiment, the acyl compound is represented by:

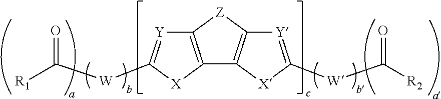

wherein a is 1 and a′ is 0, or a is 0 and a′ is 1, or both a and a′ are 1;

wherein R₁ and R₂ independently are alkyl, fluoroalkyl, or aryl and each R₂₁ is, heteroaryl, arylalkyl, or heteroarylalkyl;

wherein W and W′ independently comprise at least one heteroarylene group;

wherein b and b′ independently are 0, 1, 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴, wherein R⁴ is H, alkyl, fluorinated alkyl, aryl, fluorinated aryl, or heteroaryl.

In another embodiment, a compound is produced by any one of the process methods described herein.

In another embodiment, a composition is provided comprising one or more of the compounds described herein.

In another embodiment, a device is provided comprising one or more of the compounds described herein.

In another aspect, a method is provided for synthesizing a fused tricyclic acyl compound with use of a bishalo-bisheteroaryl compound having the structure

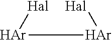

wherein HAr is an optionally substituted five or six membered heteroaryl ring comprising at least one ring carbon atom and at least one ring heteroatom, and Hal is a halogen: and wherein the steps of the method comprise:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate compound with an oxidizing agent so as to form a carbon-carbon bond between two intermediate compounds and thereby form the bishalo-bisheteroaryl compound;

subjecting the bishalo-bisheteroaryl compound to one or more further reaction steps to form a fused tricyclic acyl compound;

with the proviso that the following compounds are excluded from being the fused tricyclic acyl compound:

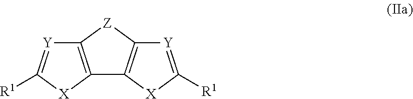

wherein the R¹ organic radicals can be selected from an organic acyl compound having the formula

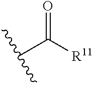

wherein R¹¹ is an aryl or heteroaryl optionally substituted with 1-10 independently selected halide, cyano, alkyl, perfluoroalkyl, acyl, alkoxy, or perfluoroalkoxy groups; and wherein X is O, S, Se, or NR³ wherein R³ is a C₁-C₁₈ alkyl, perfluoroalkyl, aryl, or heteroaryl; and Y is CH, CR⁴, or N, wherein R⁴ is a C₁-C₁₈ alkyl, aryl, or heteroaryl; and Z of formula (IIa) is S, Se, NR⁵, C(O), C(O)C(O), Si(R⁵)₂, SO, SO₂, PR⁵, P(O)R⁵, BR⁵, C(R⁵)₂, wherein R⁵ is a C₁-C₅₀ organic radical selected from optionally substituted alkyl, perfluoroalkyl, aryl, and heteroaryl.

In another embodiment, the acyl compound comprises at least two acyl groups.

In another embodiment, the acyl compound comprises an acyl group which is covalently bonded to at least heteroarylene group.

In another embodiment, the acyl compound comprises an acyl group which is covalently bonded to at least heteroarylene group represented by W, which is part of an oligomeric structure (W)_{b}, wherein b is 2-4.

In another embodiment, the acyl group is bonded to a fluorinated aryl group.

In another embodiment, the heteroaryl ring is an optionally substituted five membered heteroaryl ring.

In another embodiment, the heteroaryl ring is thiazole or thiophene. In another embodiment, the heteroaryl ring is thiazole. In another embodiment, the heteroaryl ring is thiophene.

In another embodiment, the heteroaryl ring and halogen of the precursor compound comprise the structure

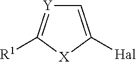

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, a compound is provided having the structure:

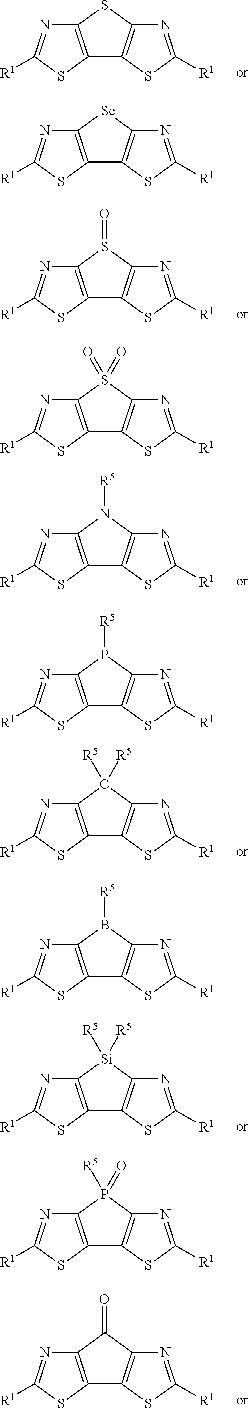

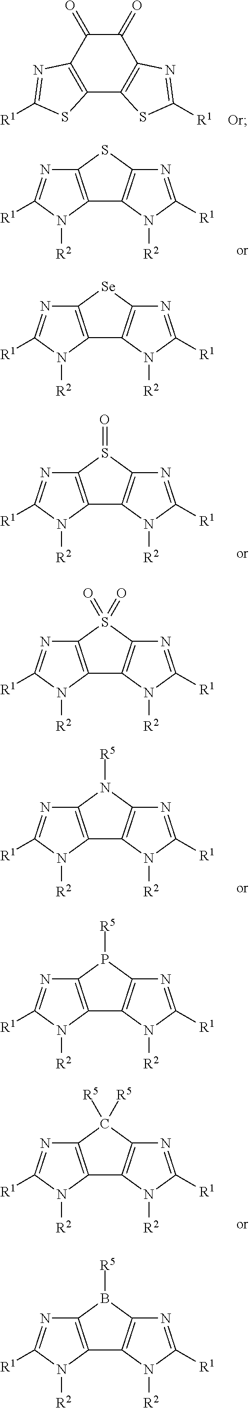

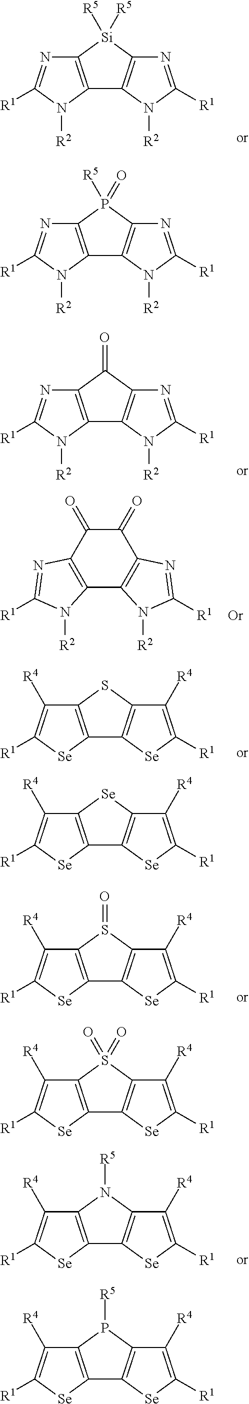

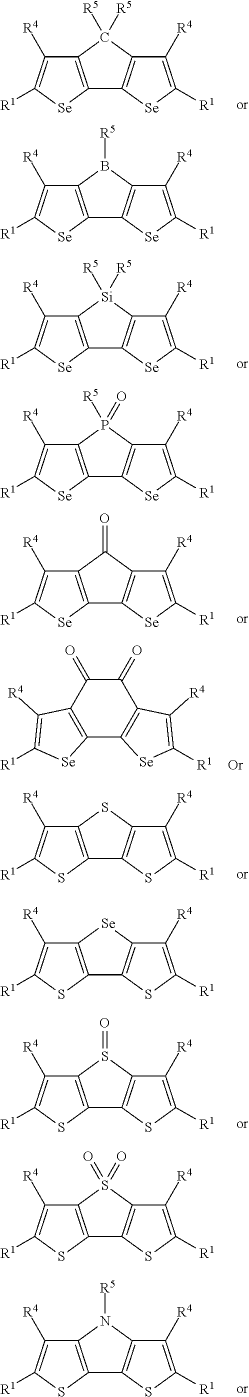

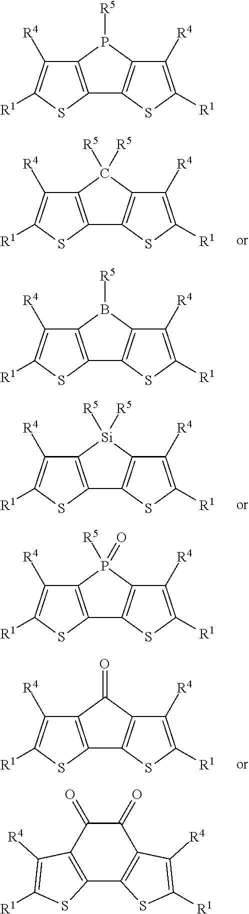

wherein R¹ is an organic radical comprising at least one acyl group; and R⁴ is hydrogen or optionally a C₁-C₁₈ alkyl group; and R⁵ is a C₁-C₅₀ organic radical selected from alkyl, aryl, heteroaryl;

with the proviso that R¹ is not

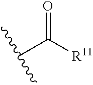

wherein R¹¹ is an aryl or heteroaryl optionally substituted with 1-10 independently selected halide, cyano, alkyl, perfluoroalkyl, acyl, alkoxy, or perfluoroalkoxy groups.

In another embodiment, the compound is represented by:

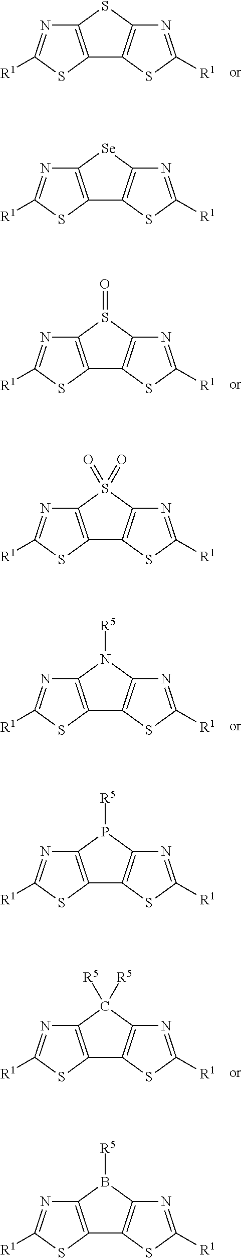

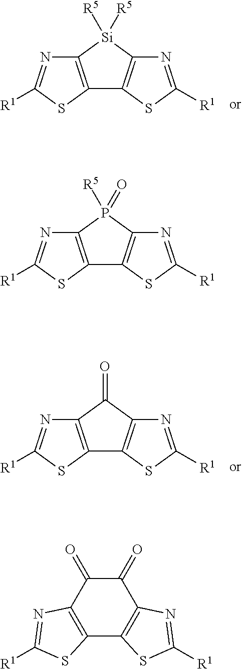

In another embodiment, the compound is represented by:

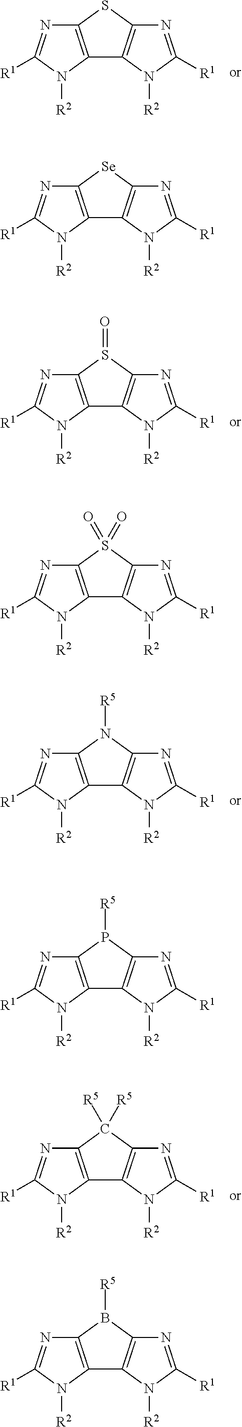

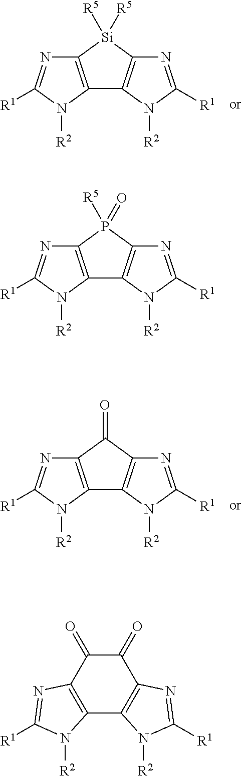

In another embodiment, the compound is represented by:

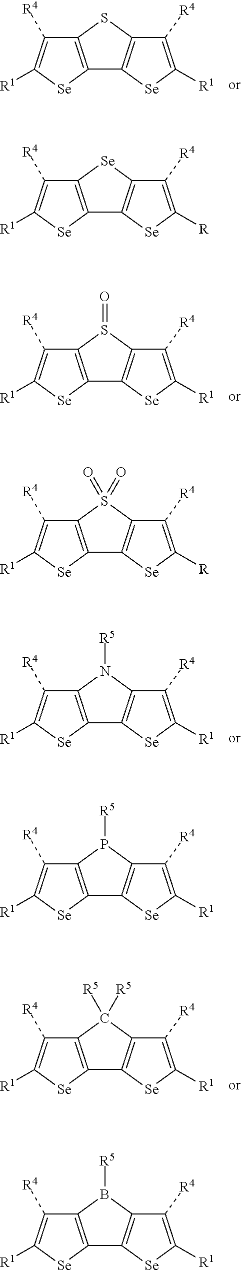

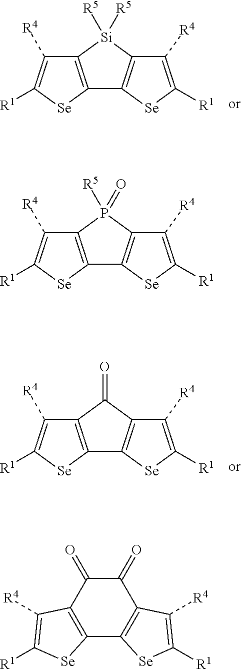

In another embodiment, the compound is represented by:

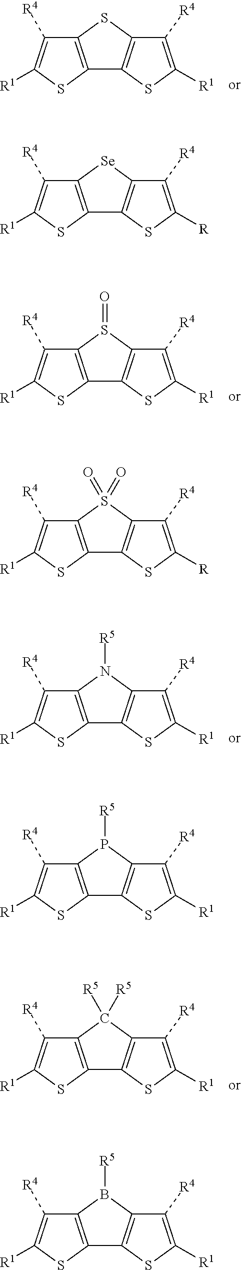

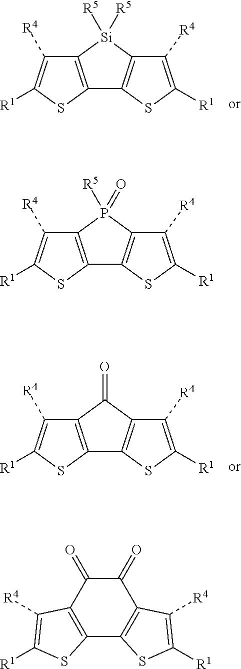

In another embodiment, the compound is represented by:

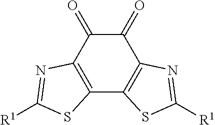

In another embodiment, wherein R¹ comprises at least one of:

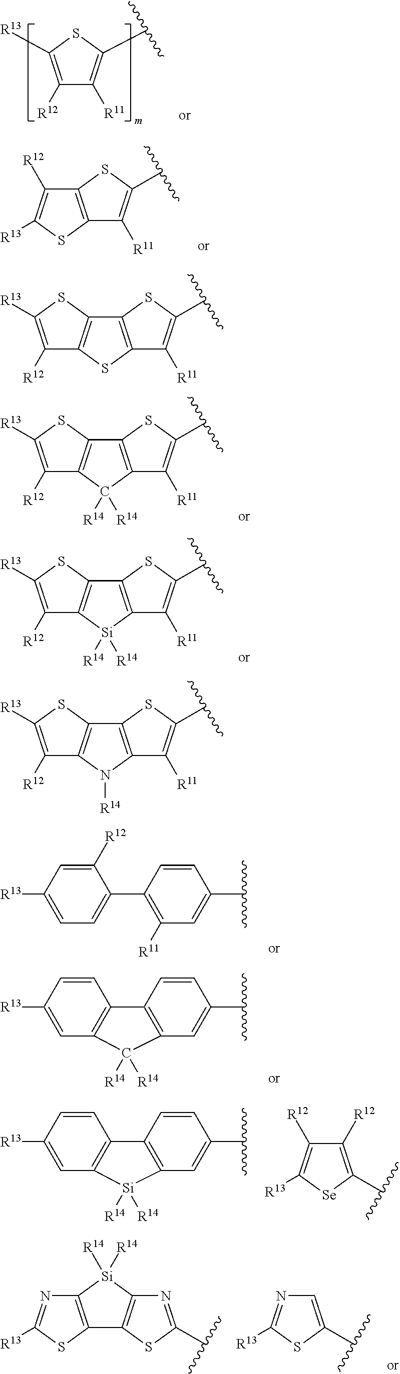

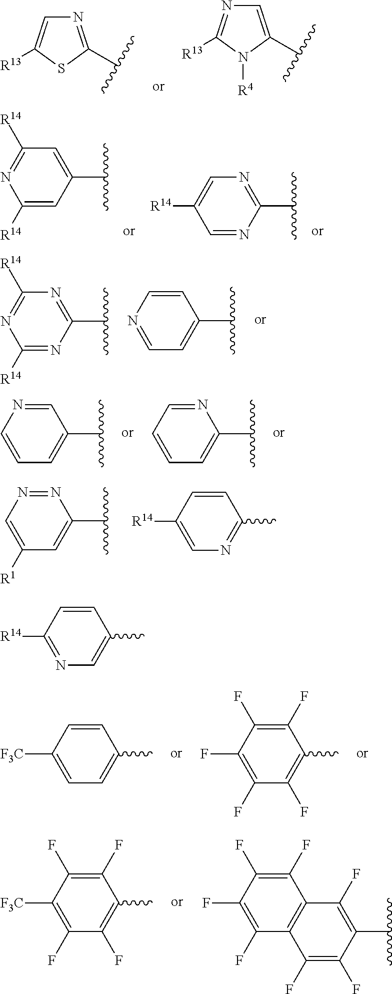

wherein m is 1, 2, 3, or 4, and R⁴, R¹¹, R¹², R¹⁴ are an independently selected hydrogen, C₁-C₈ alkyl, perfluoroalkyl, alkoxy, or perfluoroalkoxy group, and R¹³ is hydrogen, —B(—OR²¹)₂, Si(R²)₃, Si(OR²)₃ or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

In another embodiment, the acyl compound comprises at least two acyl groups.

In another embodiment, the acyl group is covalently bonded to at least one heteroarylene group.

In another embodiment, the acyl group is bonded to a fluorinated aryl group.

Another aspect provides a composition represented by at least one of:

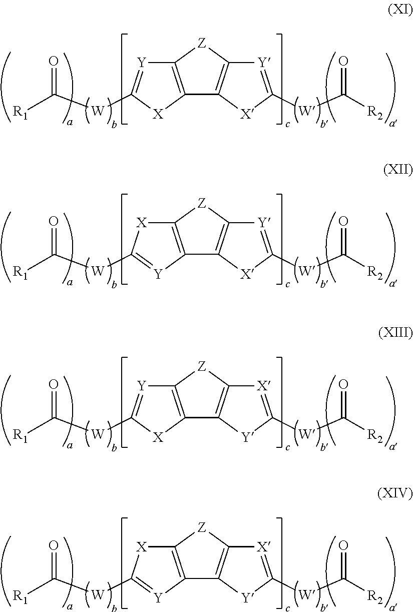

wherein a is 1 and a′ is 0, or a is 0 and a′ is 1, or both a and a′ are 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 0, 1, 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴, wherein R⁴ is H, alkyl, fluorinated alkyl, aryl, fluorinated aryl, or heteroaryl;

wherein Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl;

with the proviso that the following compounds are excluded from being the acyl compound for formula (XI):

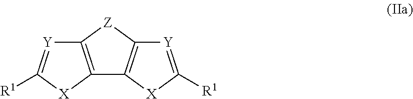

wherein the R¹ organic radicals can be selected from an organic acyl compound having the formula

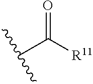

wherein R¹¹ is an aryl or heteroaryl optionally substituted with 1-10 independently selected halide, cyano, alkyl, perfluoroalkyl, acyl, alkoxy, or perfluoroalkoxy groups; and wherein X is O, S, Se, or NR³ wherein R³ is a C₁-C₁₈ alkyl, perfluoroalkyl, aryl, or heteroaryl; and Y is CH, CR⁴, or N, wherein R⁴ is a C₁-C₁₈ alkyl, aryl, or heteroaryl; and Z of formula (IIa) is S, Se, NR⁵, C(O), C(O)C(O), Si(R⁵)₂, SO, SO₂, PR⁵, P(O)R⁵, BR⁵, C(R⁵)₂, wherein R⁵ is a C₁-C₅₀ organic radical selected from optionally substituted alkyl, perfluoroalkyl, aryl, and heteroaryl.

In another embodiment, the composition is selected from formula (XI).

In another embodiment, the composition does not comprise any thiophene moiety.

In another embodiment, c is 2.

In another embodiment, a mono or bis ketal compound is provided having the formula:

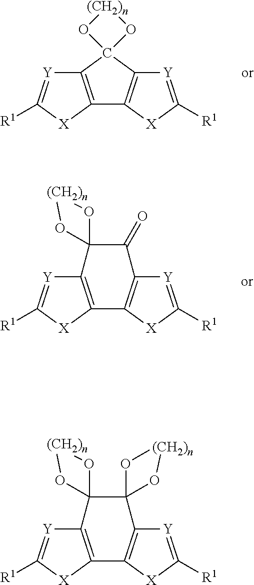

wherein

wherein R¹ is an organic radical comprising at least one acyl group;

n is 2 or 3;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, the organic radical is selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

### Additional Embodiments

### Heteroarylene Spacer (B)

Another aspect provides for use of one or more, and in particular two or more, heteroarylene moieties as substituents for and in conjugation with the fused tricyclic core.

In this aspect, one embodiment provides for exclusion of embodiments described in the '931 PCT application shown as, for example, at the top of page 8, wherein R¹ is not:

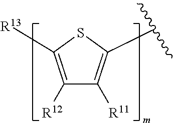

wherein m is 2, 3, or 4, and R¹¹, R¹², are hydrogen, C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

For example, another aspect provides a method comprising:

providing an optionally substituted precursor compound comprising a five- or six-membered heteroaryl ring having a halogen substituent at a first position on the heteroaryl ring;

treating the precursor compound with a strongly basic compound to induce the isomerization of the precursor compound to produce an intermediate compound wherein the halogen atom is bound to a different position on the heteroaryl ring;

treating the intermediate compound with an oxidizing agent so as to form a carbon-carbon bond between two intermediate compounds and thereby form a bishalo-bisheteroaryl compound represented by:

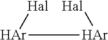

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce a Z group, or a precursor thereof suitable for forming a fused tricyclic compound represented by:

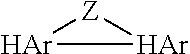

wherein:

Z is S, Se, NR⁵, C(O), C(O)C(O), Si(R⁵)₂, SO, SO₂, PR⁵, P(O)R⁵, BR⁵, C(R⁵)₂, >C═C(CN)₂, or —[C═C(CN₂)]₂—, wherein R⁵ is a C₁-C₅₀ organic radical selected from optionally substituted alkyl, perfluoroalkyl, aryl, and heteroaryl; and

wherein either the moiety:

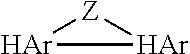

comprises at least one R¹ substituent covalently bonded to one or both of the HAr moieties which comprises 2, 3, or 4 heteroarylene moieties in conjugation with the HAr moiety;

or the moiety

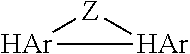

is subjected to one or more further reaction steps to form at least one R¹ substituent covalently bonded to one or both of the HAr moieties which comprises 2, 3, or 4 heteroarylene moieties in conjugation with the HAr moiety; with the proviso that R¹ is not:

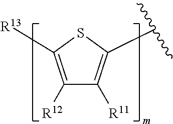

wherein m is 2, 3, or 4, and R¹¹, R¹², are hydrogen, C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

In another embodiment, the moiety:

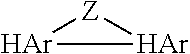

comprises at least one R¹ substituent covalently bonded to one or both of the HAr moieties which comprises 2, 3, or 4 heteroarylene moieties in conjugation with the HAr moiety.

In another embodiment, the moiety

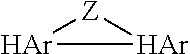

is subjected to one or more further reaction steps to form at least one R¹ substituent covalently bonded to one or both of the HAr moieties which comprises 2, 3, or 4 heteroarylene moieties in conjugation with the HAr moiety.

In another embodiment, the heteroarylene moiety of R¹ is a thiophene or thiazole moiety.

In another embodiment, two heteroarylene moieties on R¹ are present.

In another embodiment, three heteroarylene moieties on R¹ are present.

In another embodiment, four heteroarylene moieties on R¹ are present.

In another embodiment, both of the HAr moieties in:

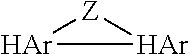

comprise the R¹ substituent comprising 2-4 heteroarylene moieties.

In another embodiment, the R¹ substituent further comprises at least one acyl moiety.

In another embodiment, HAr and Hal of the precursor compound comprise the structure

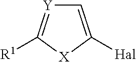

wherein R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, HAr and Hal of the precursor compound comprise the structure

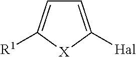

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is S, Se, or NR³ wherein R³ is a C₁-C₁₈ alkyl, perfluoroalkyl, aryl, or heteroaryl.

In another embodiment, HAr and Hal of the precursor compound comprise the structure

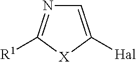

wherein

R¹ is a C₁-C₃₀ organic radical selected from optionally substituted alkyl, alkynyl, aryl, or heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms; and

X is S or NR³ wherein R³ is a C₁-C₁₈ alkyl, perfluoroalkyl, aryl, or heteroaryl.

In another embodiment, HAr and Hal of the precursor compound comprise the structure

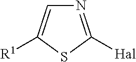

wherein

R¹ is a halide, or a C₁-C₃₀ organic radical selected from alkyl, alkynyl, aryl, heteroaryl, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In another embodiment, R¹ is a C₁-C₃₀ aryl or heteroaryl optionally substituted by one to four ring substituents independently selected from halides, alkyl, alkynyl, perfluoroalkyl, alkoxide, perfluoroalkoxide, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In another embodiment, the strongly basic compound is an alkyl lithium compound.

In another embodiment, the strongly basic compound is a lithium dialkylamide compound.

In another embodiment, the oxidizing agent is a Cu(II) salt.

In another embodiment, the bishalo-bisheteroaryl compound is a 2,2′-bishalo-1,1′-bisheteroaryl compound.

In another embodiment, the bishalo-bisheteroaryl compound has the structure

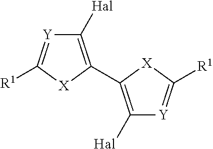

wherein

R¹ is a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, the bishalo-bisheteroaryl compound has one of the structures

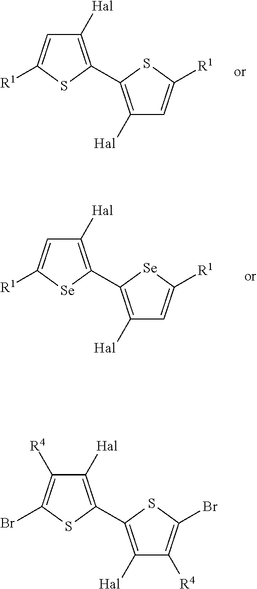

wherein

R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R⁴ is a C₁-C₁₈ alkyl, aryl, or heteroaryl.

In another embodiment, the bishalo-bisheteroaryl compound has one of the structures

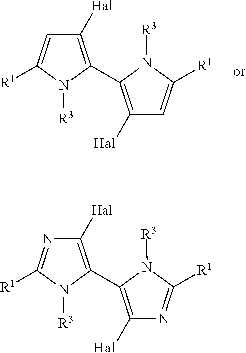

wherein

R¹ is hydrogen or a halide, or a C₁-C₃₀ organic radical selected from optionally substituted alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R³ is a C₁-C₁₈ alkyl, perfluoroalkyl, aryl, or heteroaryl.

In another embodiment, the bishalo-bisheteroaryl compound has one of the structures

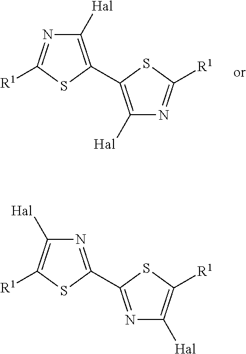

wherein R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

In another embodiment, the organometallic compound is an alkyl lithium compound or lithium diorganoamide.

In another embodiment, the organometallic compound is a transition metal compound.

In another embodiment, the electrophile is a compound V—R⁶—V′, where R⁶ is selected from S, Se, NR⁵, C(O), C(O)C(O), Si (R⁵)₂, SO, SO₂, PR⁵, P(O)R⁵, BR⁵, or C(R⁵)₂, V and V′ are leaving groups or V and V′ together form a leaving group suitable for a condensation reaction with the bismetallo-bisheteroaryl compound to form the fused tricyclic compound.

In another embodiment, the fused tricyclic compound has the structure

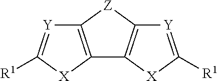

wherein X is O, S, Se, or NR³ wherein R³ is a C₁-C₁₈ alkyl, perfluoroalkyl, aryl, or heteroaryl; and Y is CH, CR⁴, or N, wherein R⁴ is a C₁-C₁₈ alkyl, aryl, or heteroaryl; and wherein Z is S, Se, NR⁵, C(O), C(O)C(O), Si(R⁵)₂, SO, SO₂, PR⁵, P(O)R⁵, BR⁵, or C(R⁵)₂, wherein R⁵ is a C₁-C₅₀ organic radical selected from optionally substituted alkyl, perfluoroalkyl, aryl, and heteroaryl.

In another embodiment, the fused tricyclic compound has the structure

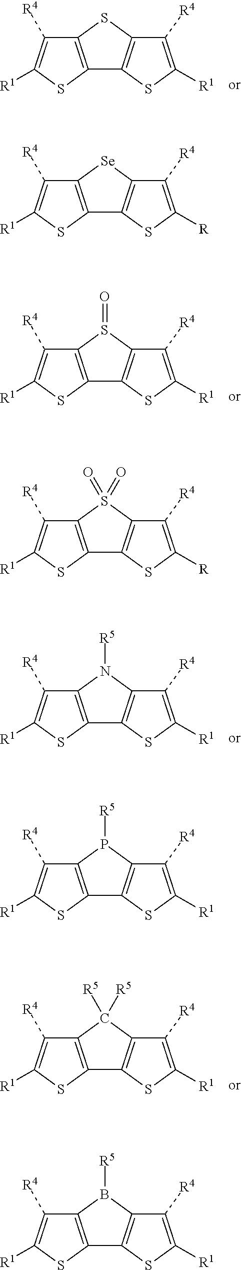

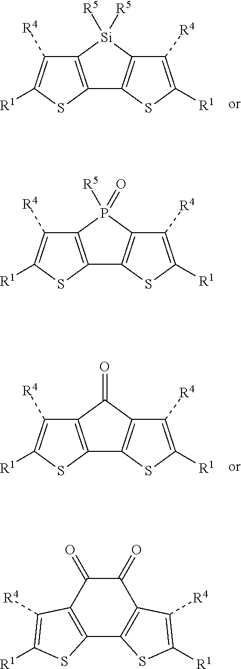

wherein R⁴ is hydrogen or optionally a C₁-C₁₈ alkyl group.

In another embodiment, the fused tricyclic compound has the structure

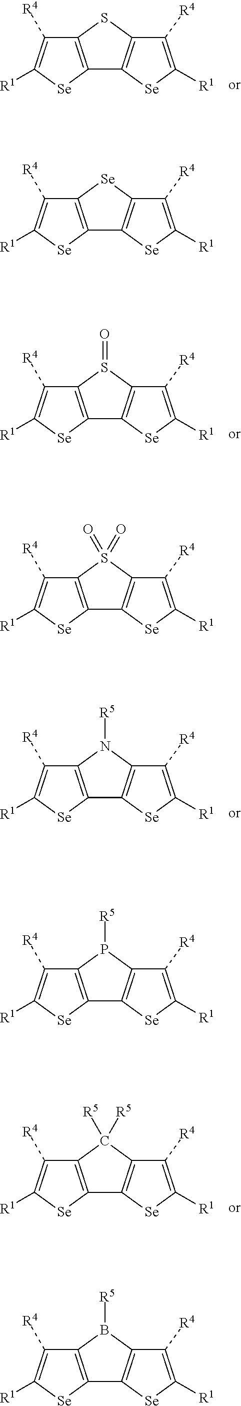

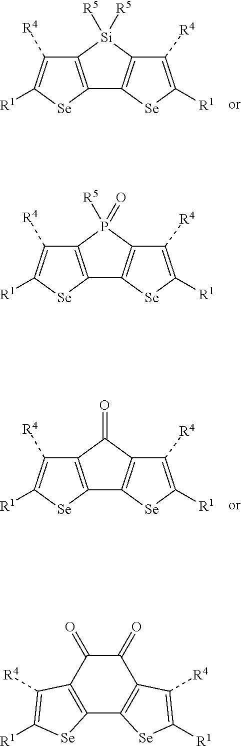

wherein R⁴ is hydrogen or optionally a C₁-C₁₈ alkyl group.

In another embodiment, the fused tricyclic compound has the structure

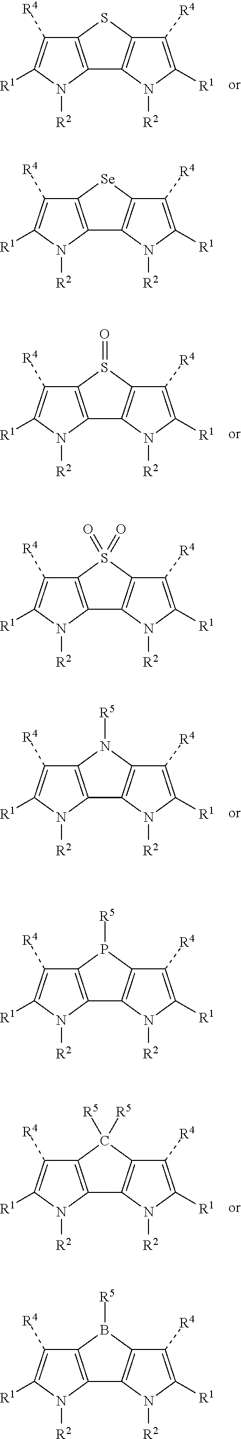

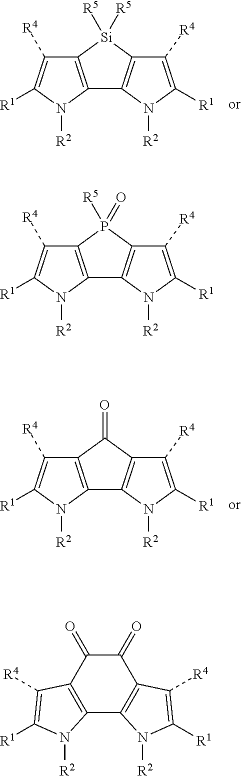

wherein R² is an independently selected alkyl, perfluoroalkyl, or aryl, and R⁴ is hydrogen or optionally a C₁-C₈ alkyl group.

In another embodiment, the fused tricyclic compound has the structure

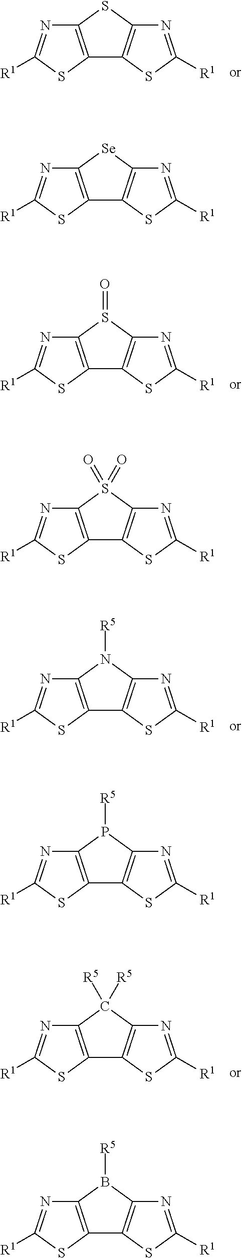

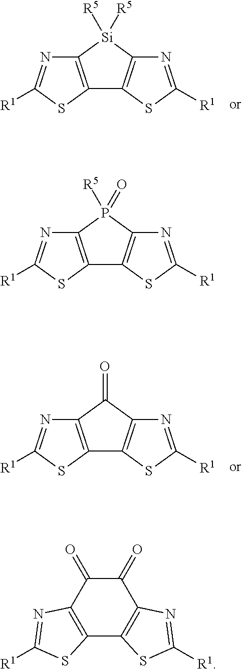

In another embodiment, the fused tricyclic aromatic compound is represented by:

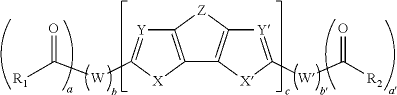

wherein a and a′ independently are 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴, wherein R⁴ is H, alkyl, fluorinated alkyl, aryl, fluorinated aryl, or heteroaryl.

In another embodiment, a method is provided for synthesizing a fused tricyclic acyl compound with use of a bishalo-bisheteroaryl compound having the structure

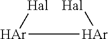

wherein HAr is an optionally substituted five or six membered heteroaryl ring comprising at least one ring carbon atom and at least one ring heteroatom, and Hal is a halogen: and wherein the steps of the method comprise:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate compound with an oxidizing agent so as to form a carbon-carbon bond between two intermediate compounds and thereby form the bishalo-bisheteroaryl compound;

subjecting the bishalo-bisheteroaryl compound to one or more further reaction steps to form a fused tricyclic compound; wherein either:

(a)

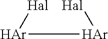

comprises at least one R¹ substituent covalently bonded to one or both of the HAr moieties which comprises 2, 3, or 4 heteroarylene moieties in conjugation with HAr; or

subjecting the bishalo-bisheteroaryl compound to one or more further reaction steps to form at least one R¹ substituent covalently bonded to one or both of the HAr moieties which comprises 2, 3, or 4 heteroarylene moieties in conjugation with HAr;

with the proviso that R¹ is not:

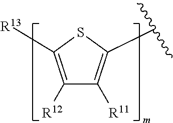

wherein m is 2, 3, or 4, and R¹¹, R¹², are hydrogen, C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

In another embodiment,

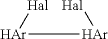

comprises at least one R¹ substituent covalently bonded to one or both of the HAr moieties which comprises 2, 3, or 4 heteroarylene moieties in conjugation with HAr.

In another embodiment, the steps comprise further subjecting the bishalo-bisheteroaryl compound to one or more further reaction steps to form at least one R¹ substituent covalently bonded to one or both of the HAr moieties which comprises 2, 3, or 4 heteroarylene moieties in conjugation with HAr

In another embodiment, the heteroarylene moiety of R¹ is a five-membered ring.

In another embodiment, the heteroarylene moiety of R¹ is a thiophene or thiazole moiety.

In another embodiment, two heteroarylene moieties on R¹ are present.

In another embodiment, three heteroarylene moieties on R^{I} are present.

In another embodiment, four heteroarylene moieties on R^{I} are present.

In another embodiment, both of the HAr moieties in:

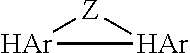

comprise the R¹ substituent comprising 2-4 heteroarylene moieties.

In another embodiment, the R¹ substituent further comprises at least one acyl moiety.

In another embodiment, a compound is provided having one of the following groups of fused tricyclic core structures:

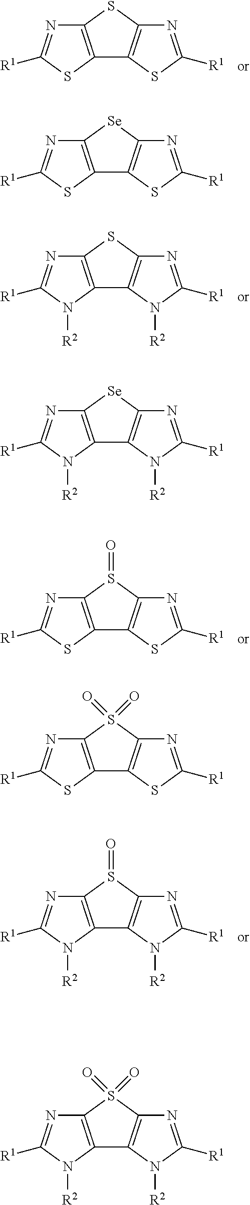

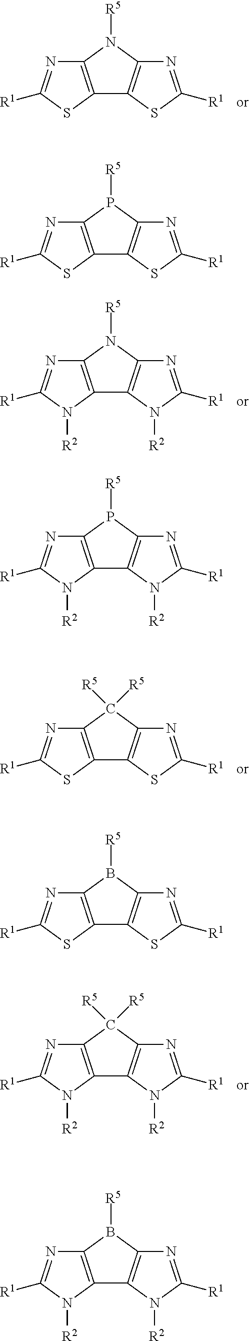

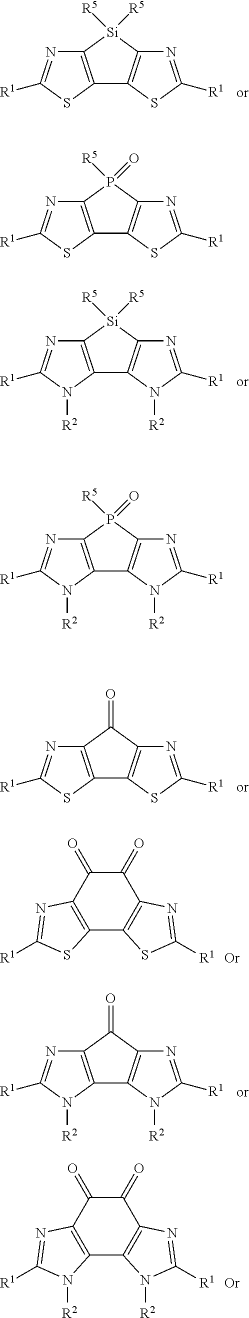

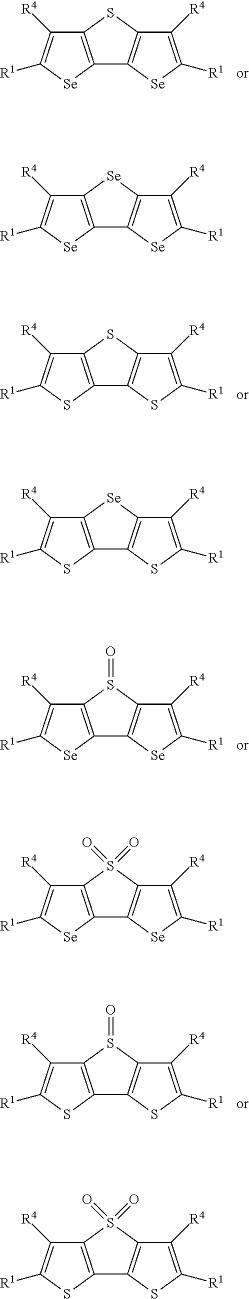

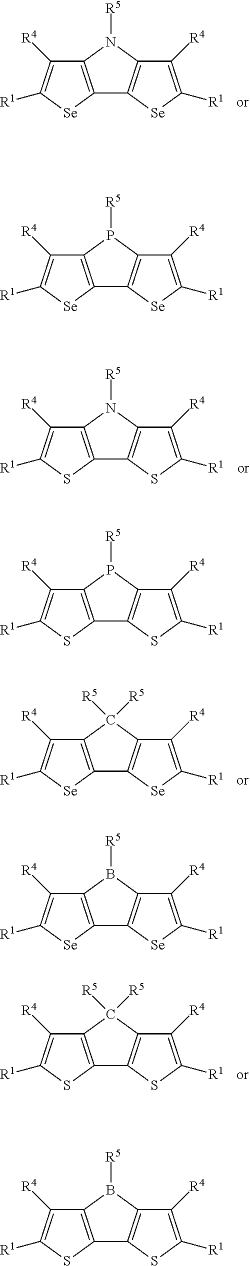

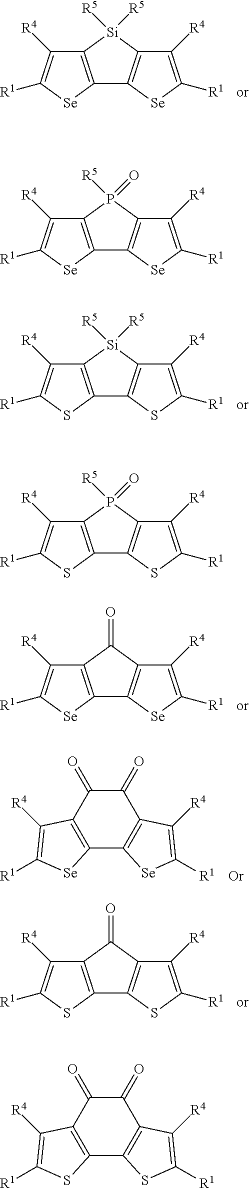

wherein R⁴ is hydrogen or optionally a C₁-C₁₈ alkyl group; R⁵ is a C₁-C₅₀ organic radical selected from alkyl, aryl, heteroaryl, and wherein at least one of the R¹ substituents comprises 2, 3, or 4 heteroarylene moieties in conjugation with the fused tricyclic core;

with the proviso that R¹ is not:

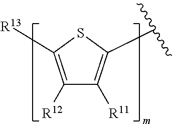

wherein m is 2, 3, or 4, and R¹¹, R¹², are hydrogen, C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

In another embodiment, the compound is selected from:

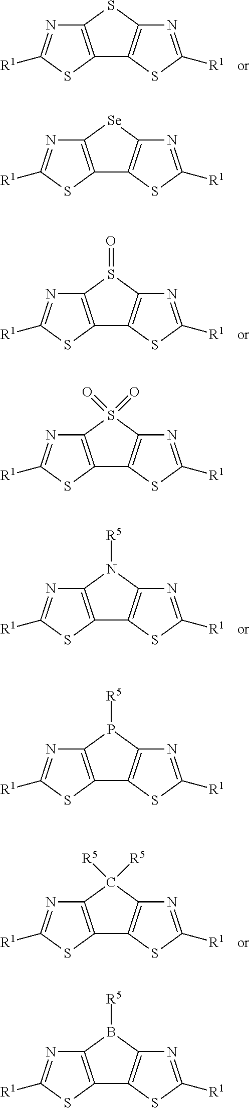

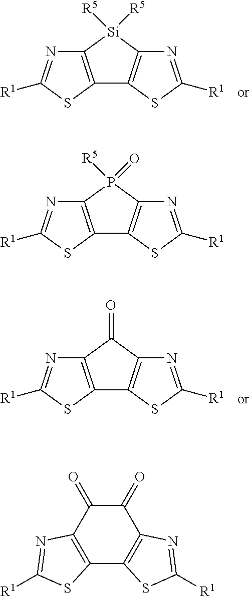

In another embodiment, the compound is selected from:

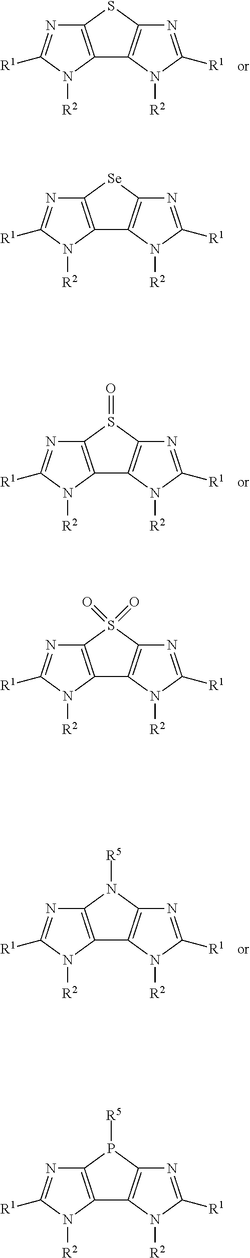

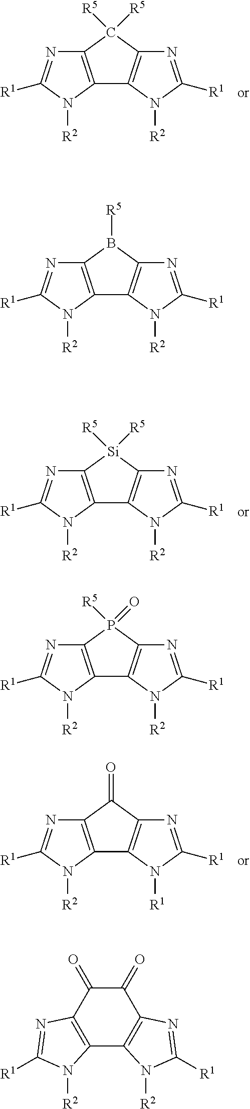

In another embodiment, the compound is selected from:

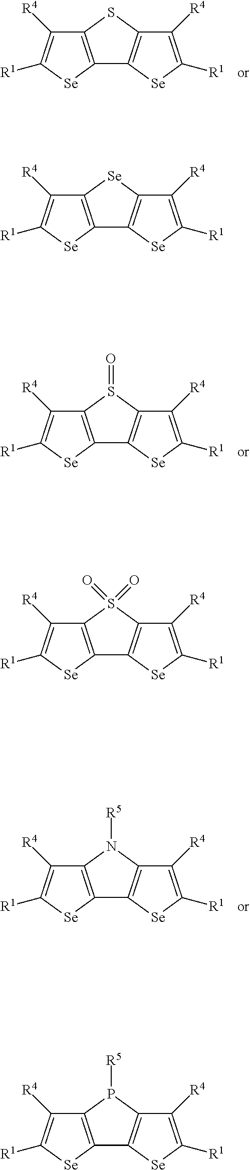

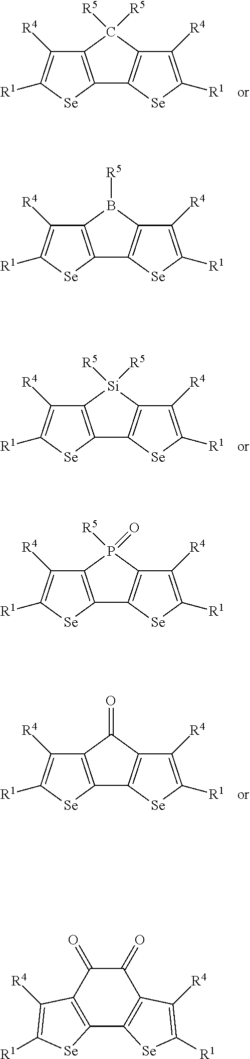

In another embodiment, the compound is selected from:

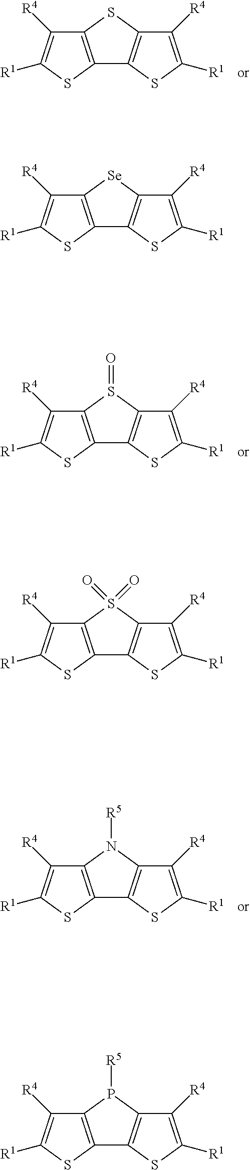

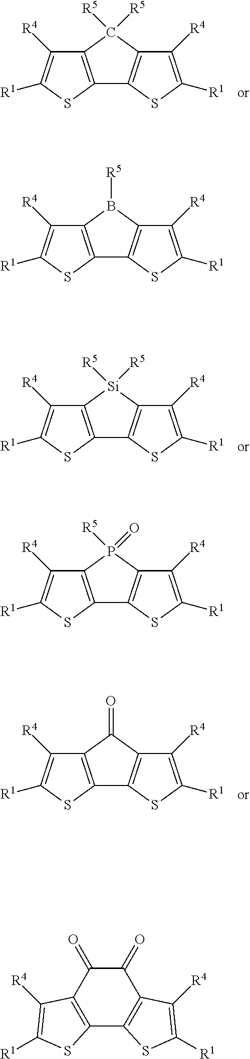

In another embodiment, the compound has the structure

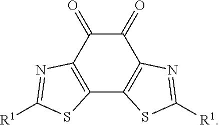

In another embodiment, R¹ comprises an acyl group.

In another embodiment, R¹ comprises two heteroarylene moieties.

In another embodiment, R¹ comprises three heteroarylene moieties.

In another embodiment, R¹ comprises four heteroarylene moieties.

Another embodiment provides a composition represented by at least one of:

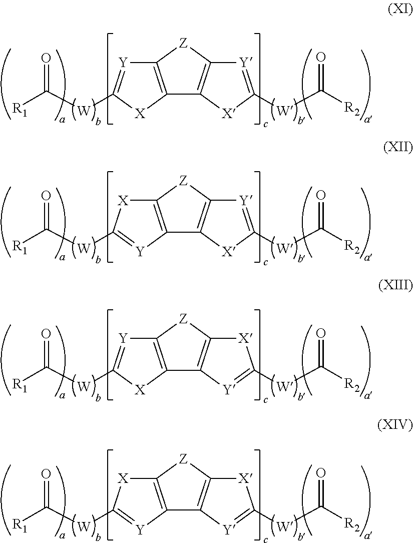

wherein independently a is 0 or 1, and a′ is 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴, wherein R⁴ is H, alkyl, fluorinated alkyl, aryl, fluorinated aryl, or heteroaryl;

wherein Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl;

with the proviso that for formula (XI) if c is 1, and a and a′ are each zero, then (W)_{b} and (W′)_{b′} are not represented by:

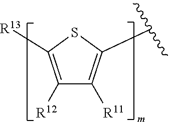

wherein m is 2, 3, or 4, and R¹¹, R¹², are hydrogen, C₁-C₁₈ alkyl, perfluoroalkyl, alkoxy, or perfluoroalkoxy group, and R¹³ is hydrogen, —B(—OR²¹)₂, Si(R²)₃, Si(OR²)₃, or Sn(R²)₃, wherein each R² is an independently selected alkyl or aryl, and each R²¹ is an independently selected alkyl or aryl, or the R²¹ groups together form an optionally substituted alkylene group bridging the oxygen atoms.

In one embodiment, the compound is selected from formula (XI).

In another embodiment, W and W′ are represented by one of:

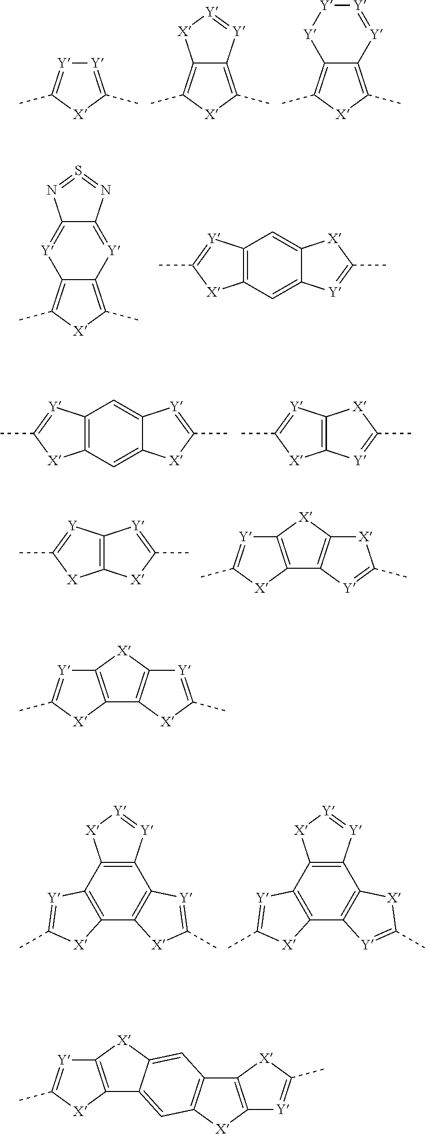

wherein each instance of X′ and Y′ is independently S, Se, NR³, PR³, Si(R³)₂, N, P, CR⁴, or SiR⁴.

In another embodiment, a compound is provided produced by any one of the processes described herein.

In another embodiment, a composition is provided comprising one or more of the compounds described herein.

Another embodiment provides a device comprising one or more of the compounds described herein.

Other embodiments for synthesizing heteroarylene group(s) bonded to the core are shown below:

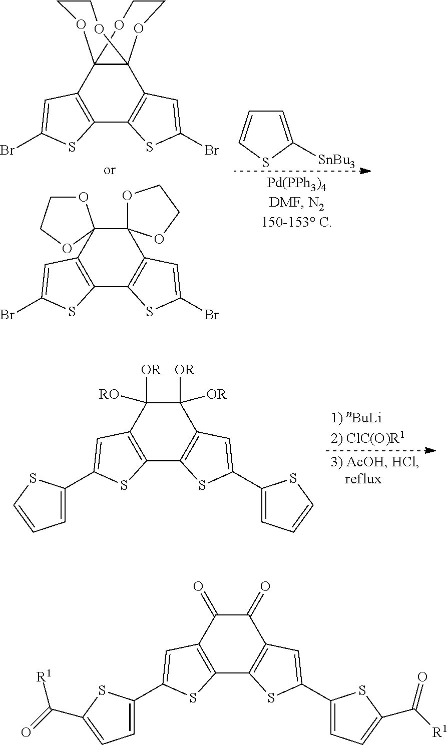

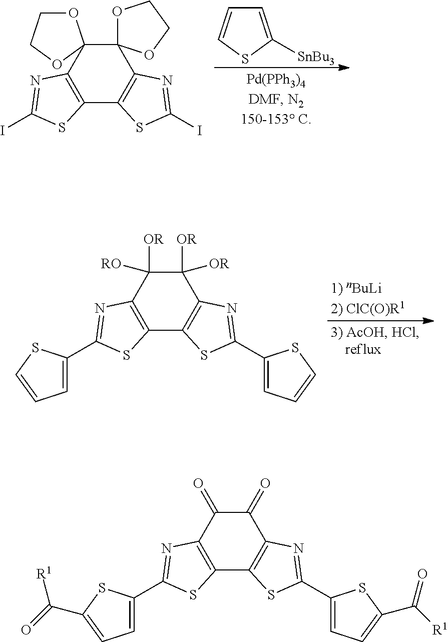

### Scheme. Synthetic Route Towards Acyl Derivatives of Benzo[2,1-b:3,4-b′]dithiophenes (top) and Benzo-dithiazole-4,5-diones (bottom) with Thiophene Spacer

In addition, it is possible to break the symmetry of the dibromide and prepare materials with the following structure:

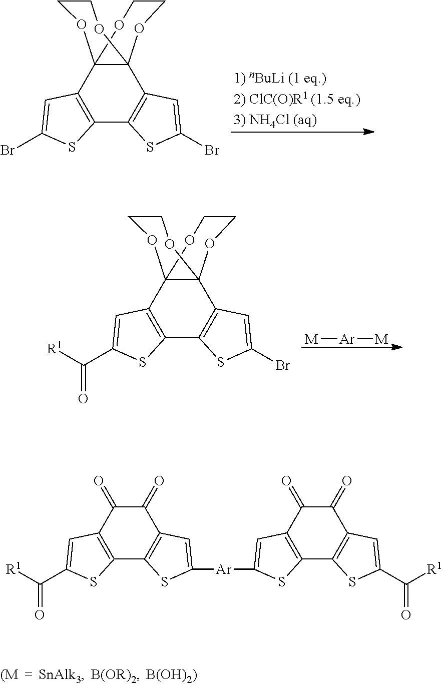

### Additional Embodiments

### Core Coupling (C)

In other aspects, the tricyclic core can be coupled to generate larger structures including oligomers including, for example, dimers, trimers, or tetramers. For example, one side of the tricyclic core can be treated with a blocking agent, leaving the other side reactive for coupling. Other methods of coupling, including ring closure after coupling, are illustrated below:

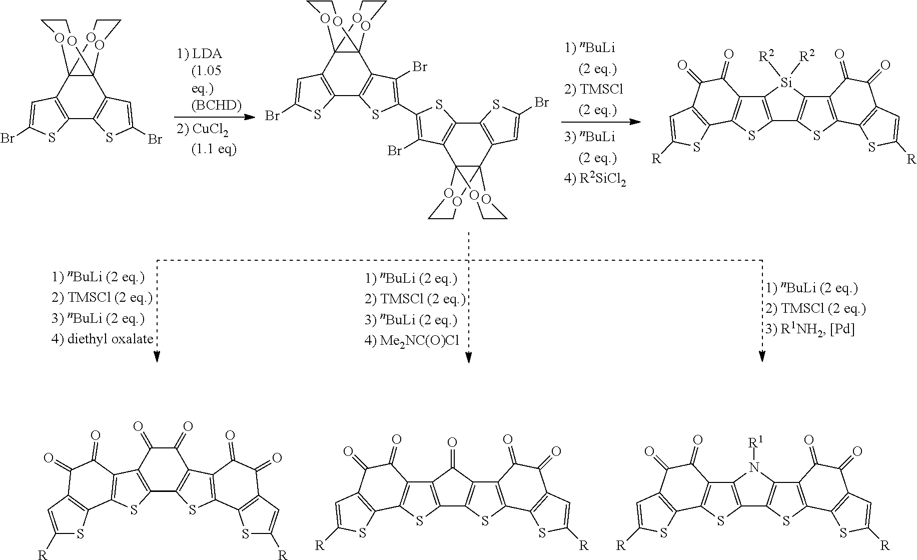

Another aspect provides for a method comprising:

providing an optionally substituted precursor compound comprising a five- or six-membered heteroaryl ring having a halogen substituent at a first position on the heteroaryl ring;

treating the precursor compound with a strongly basic compound to induce the isomerization of the precursor compound to produce an intermediate compound wherein the halogen atom is bound to a different position on the heteroaryl ring;

treating the intermediate compound with an oxidizing agent so as to form a carbon-carbon bond between two intermediate compounds and thereby form a bishalo-bisheteroaryl compound represented by:

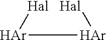

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce a Z group, or a precursor thereof suitable for forming a fused tricyclic compound represented by (II):

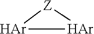

wherein:

Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl; and

reacting the compound of formula (II) to covalently bond to itself to form an oligomer comprising two, three, or four coupled units.

In one embodiment, the oligomer comprises two coupled units.

In one embodiment, the oligomer comprises three coupled units.

In one embodiment, the oligomer comprises four coupled units.

In one embodiment, the oligomer comprises at least one acyl group.

In one embodiment, the oligomer comprises at least two acyl groups.

In one embodiment, the reaction of the compound of formula (II) comprises reaction with a blocking agent to provide a partially blocked compound comprising one reactive site for coupling on the heteroaryl ring and one blocked site on the other heteroaryl ring, and coupling the partially blocked compound at the reactive site.

In one embodiment, the reaction of the compound of formula (II) comprises reaction with an acyl blocking agent to provide a partially blocked compound comprising one halogenated reactive site for coupling on the heteroaryl ring and one blocked site on the other heteroaryl ring, and coupling the partially blocked compound at the halogenated reactive site.

In one embodiment, the reaction of the compound of formula (II) comprises reaction with a fluorinated blocking agent to provide a partially blocked compound comprising one reactive site for coupling on the heteroaryl ring and one blocked site on the other heteroaryl ring, and coupling the partially blocked compound at the reactive site.

In one embodiment, substituents of the compound of formula (II) are adapted to provide the oligomer with a solubility of at least 0.1 mg/mL in chlorobenzene.

In one embodiment, the heteroaryl rings are thiophene or thiazole.

In one embodiment, the heteroaryl rings are thiophene.

In one embodiment, the heteroaryl rings are thiazole.

In one embodiment, Hal is Br or I.

In one embodiment, HAr is an optionally substituted five membered heteroaryl ring.

In one embodiment, HAr and Hal of the precursor compound comprise the structure

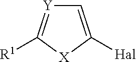

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In one embodiment, HAr and Hal of the precursor compound comprise the structure

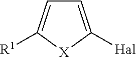

wherein

R¹ is a halide, or a C₁-C₃₀ organic radical selected from optionally substituted alkyl, alkynyl, aryl, and heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is S, Se, or NR³ wherein R³ is a C₁-C₁₈ alkyl, perfluoroalkyl, aryl, or heteroaryl.

In one embodiment, HAr and Hal of the precursor compound comprise the structure

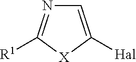

wherein

R¹ is a C₁-C₃₀ organic radical selected from optionally substituted alkyl, alkynyl, aryl, or heteroaryl, or —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms; and

X is S or NR³ wherein R³ is a C₁-C₁₈ alkyl, perfluoroalkyl, aryl, or heteroaryl.

In one embodiment, HAr and Hal of the precursor compound comprise the structure

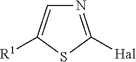

wherein

R¹ is a halide, or a C₁-C₃₀ organic radical selected from alkyl, alkynyl, aryl, heteroaryl, —Sn(R²)₃, —Si(R²)₃, —Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group to form a ring bridging the oxygen atoms.

In one embodiment, the strongly basic compound is an alkyl lithium compound.

In one embodiment, the bishalo-bisheteroaryl compound has the structure

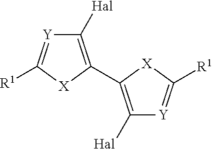

wherein

R¹ is a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In one embodiment, the bishalo-bisheteroaryl compound has one of the structures

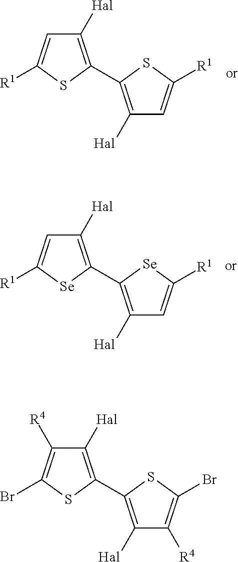

wherein

R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R⁴ is a C₁-C₁₈ alkyl, aryl, or heteroaryl.

In one embodiment, the bishalo-bisheteroaryl compound has one of the structures:

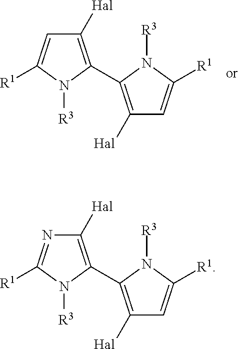

wherein

R¹ is hydrogen or a halide, or a C₁-C₃₀ organic radical selected from optionally substituted alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

R³ is a C₁-C₁₈ alkyl, perfluoroalkyl, aryl, or heteroaryl.

In one embodiment, the bishalo-bisheteroaryl compound has one of the structures

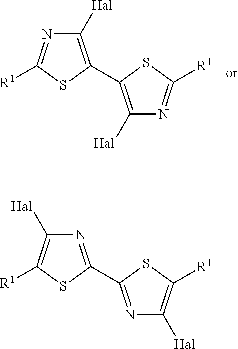

wherein R¹ is hydrogen or a halide, or a C₁-C₃₀ organic radical selected from alkyl, alkynyl, aryl, heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms.

In one embodiment, the electrophile is a compound V—R⁶—V′, where R⁶ is selected from S, Se, NR⁵, C(O), C(O)C(O), Si (R⁵)₂, SO, SO₂, PR⁵, P(O)R⁵, BR⁵, or C(R⁵)₂, V and V′ are leaving groups or V and V′ together form a leaving group suitable for a condensation reaction with the bismetallo-bisheteroaryl compound to form the fused tricyclic compound.

In one embodiment, the fused tricyclic compound has the structure

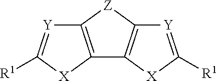

wherein

R¹ is hydrogen, a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl; and

Z is S, Se, NR⁵, C(O), C(O)C(O), Si(R⁵)₂, SO, SO₂, PR⁵, P(O)R⁵, BR⁵, or C(R⁵)₂, wherein R⁵ is a C₁-C₅₀ organic radical selected from optionally substituted alkyl, perfluoroalkyl, aryl, and heteroaryl.

In one embodiment, the fused tricyclic compound has the structure

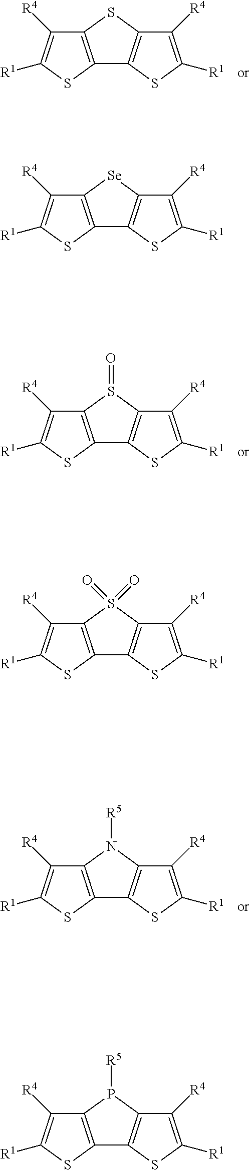

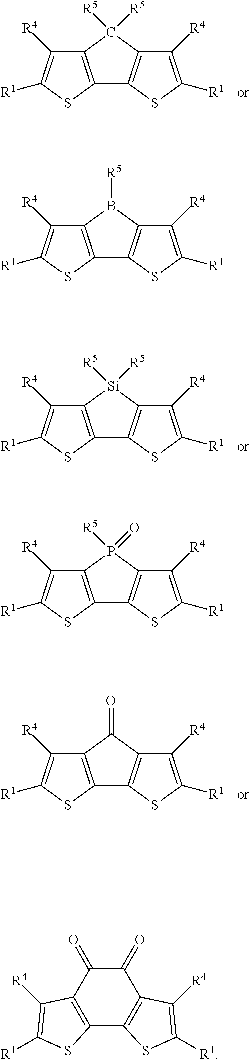

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms, R⁴ is hydrogen or optionally a C₁-C₁₈ alkyl group, and R⁵ is a C₁-C₅₀ organic radical selected from alkyl, aryl, heteroaryl.

In one embodiment, the fused tricyclic compound has the structure

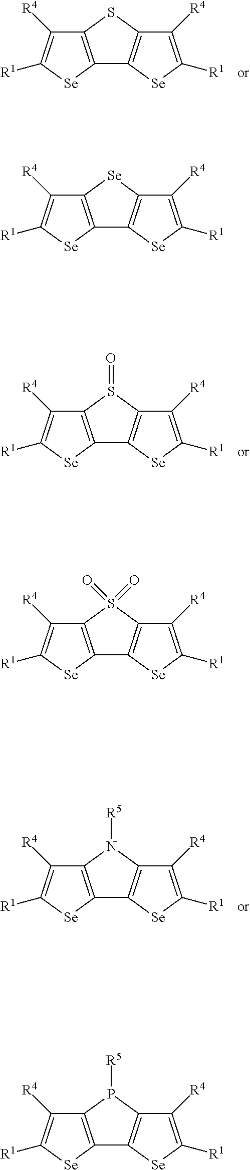

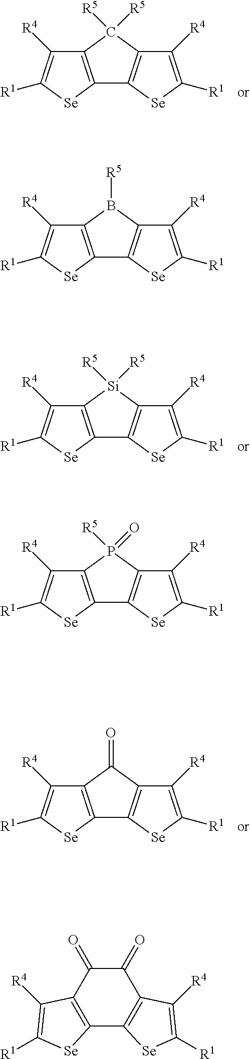

wherein R¹ is hydrogen or a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms, R⁴ is hydrogen or optionally a C₁-C₁₈ alkyl group, and R⁵ is a C₁-C₅₀ organic radical selected from alkyl, aryl, heteroaryl.

In one embodiment, the fused tricyclic compound has the structure

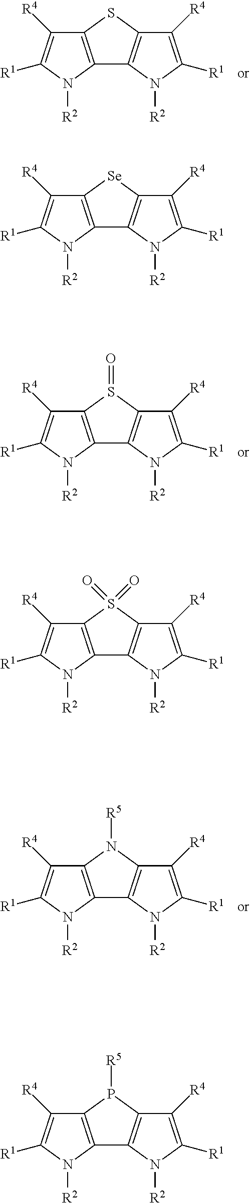

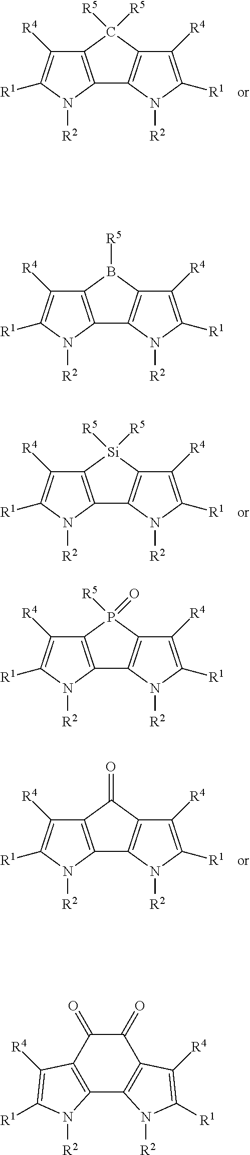

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₁₈ alkyl group, and R⁵ is a C₁-C₅₀ organic radical selected from alkyl, aryl, heteroaryl.

In one embodiment, the fused tricyclic compound has the structure

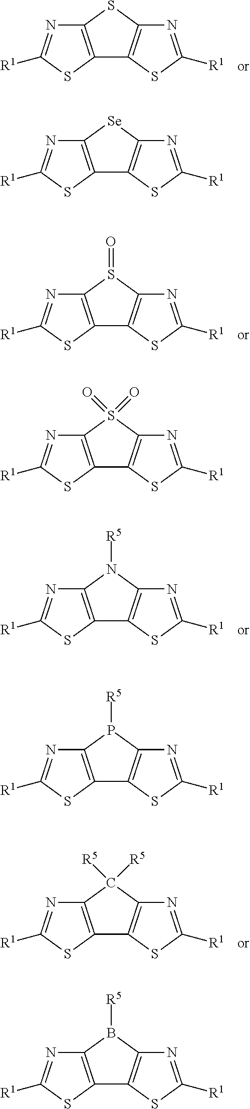

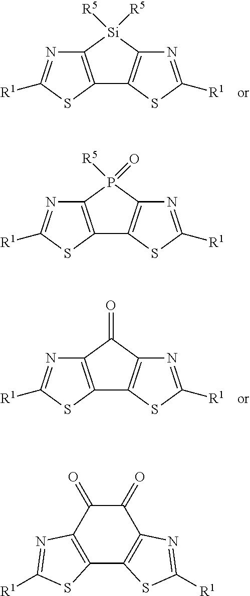

wherein R¹ is hydrogen or a halide, or a C₁-C₃₀ organic radical selected from alkyl, aryl, or heteroaryl, or —Sn(R²)₃, —Si(R²)₃, Si(OR²)₃ or —B(—OR²¹)₂ wherein each R² is an independently selected alkyl, perfluoroalkyl, or aryl and each R²¹ is an independently selected alkyl or aryl, or the R²¹ groups together form an optionally substituted alkylene group to form a ring bridging the oxygen atoms, R⁴ is hydrogen or optionally a C₁-C₁₈ alkyl group, and R⁵ is a C₁-C₅₀ organic radical selected from alkyl, aryl, heteroaryl.

Another embodiment provides that the oligomer is represented by:

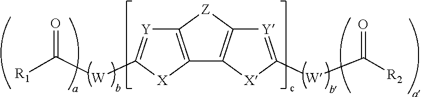

wherein a and a′ independently are 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 0, 1, 2, 3, or 4;

wherein c is 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴, wherein R⁴ is H, alkyl, fluorinated alkyl, aryl, fluorinated aryl, or heteroaryl.

In one embodiment, a method is provided for synthesizing a fused tricyclic acyl compound, and derivatives thereof, with use of a bishalo-bisheteroaryl compound having the structure

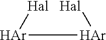

wherein HAr is an optionally substituted five or six membered heteroaryl ring comprising at least one ring carbon atom and at least one ring heteroatom, and Hal is a halogen: and wherein the steps of the method comprise:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate compound with an oxidizing agent so as to form a carbon-carbon bond between two intermediate compounds and thereby form the bishalo-bisheteroaryl compound;

subjecting the bishalo-bisheteroaryl compound to one or more further reaction steps to form at least one used fused tricyclic compound and subsequently covalently bond to itself to form an oligomer comprising two, three, or four coupled units.

In one embodiment, the oligomer comprises two coupled units.

In one embodiment, the oligomer comprises three coupled units.

In one embodiment, the oligomer comprises four coupled units.

In one embodiment, the oligomer comprises at least one acyl group.

In one embodiment, the reaction to form the oligomer comprises reaction of the fused tricyclic compound with a blocking agent to provide a partially blocked compound comprising one reactive site for coupling on the heteroaryl ring and one blocked site on the other heteroaryl ring, and coupling the partially blocked compound at the reactive site to form the oligomer.

In one embodiment, the reaction to form the oligomer comprises reaction of the fused tricyclic compound with a blocking agent to provide a partially blocked compound comprising one halogenated reactive site for coupling on the heteroaryl ring and one blocked site on the other heteroaryl ring, and coupling the partially blocked compound at the halogenated reactive site.

In one embodiment, the reaction to form the oligomer comprises reaction of the fused tricyclic compound with a fluorinated blocking agent to provide a partially blocked compound comprising one reactive site for coupling on the heteroaryl ring and one blocked site on the other heteroaryl ring, and coupling the partially blocked compound at the reactive site.

In one embodiment, substituents of the oligomer are adapted to provide the oligomer with a solubility of at least 0.1 mg/mL in chlorobenzene.

In one embodiment, the heteroaryl rings are thiophene or thiazole.

In one embodiment, a composition is provided comprising at least one oligomer compound comprising 2, 3, or 4 coupled units represented by:

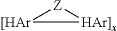

wherein x is 2, 3, or 4:

Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl; and wherein the HAr units are thiophene, thiazole, selenophene, or pyrrole.

In one embodiment, the HAr repeat units are thiophene.

In one embodiment, the HAr repeat units are thiazole.

In one embodiment, the HAr repeat units are selenophene.

In one embodiment, the HAr repeat units are pyrrole.

In one embodiment, the moiety

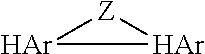

has one of the following structures:

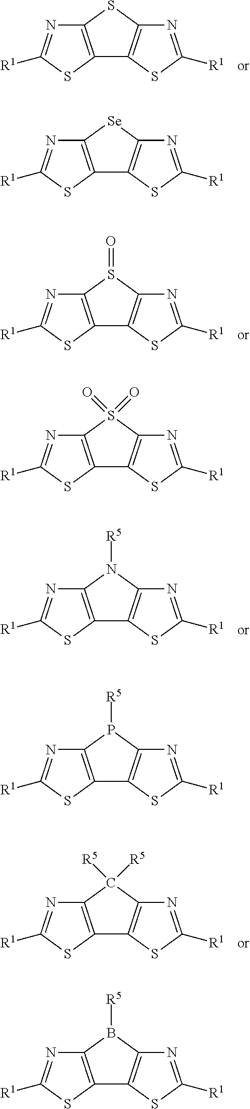

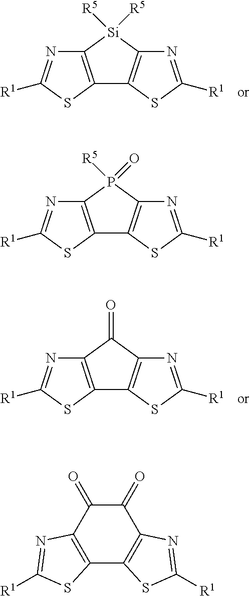

wherein R¹ is a terminal group for the oligomer or a covalent bond to another coupled unit in the oligomer.

In one embodiment, the moiety

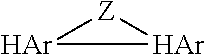

has one of the following structures:

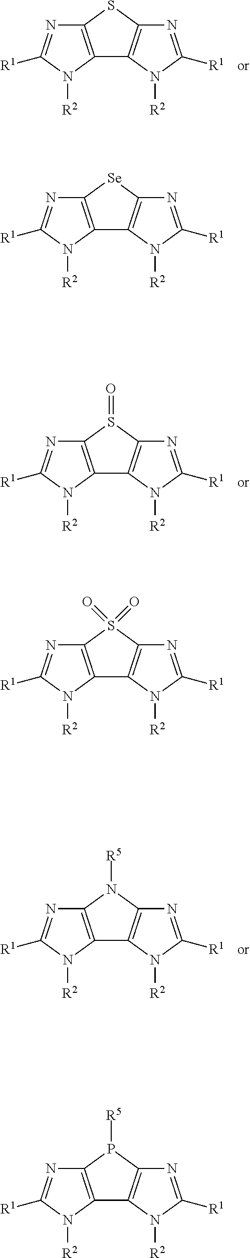

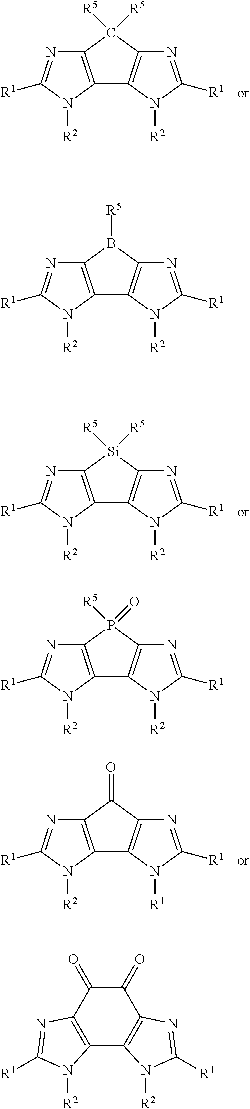

wherein R¹ is a terminal group for the oligomer or a covalent bond to another coupled unit in the oligomer.

In one embodiment, the moiety

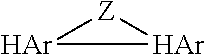

has one of the following structures:

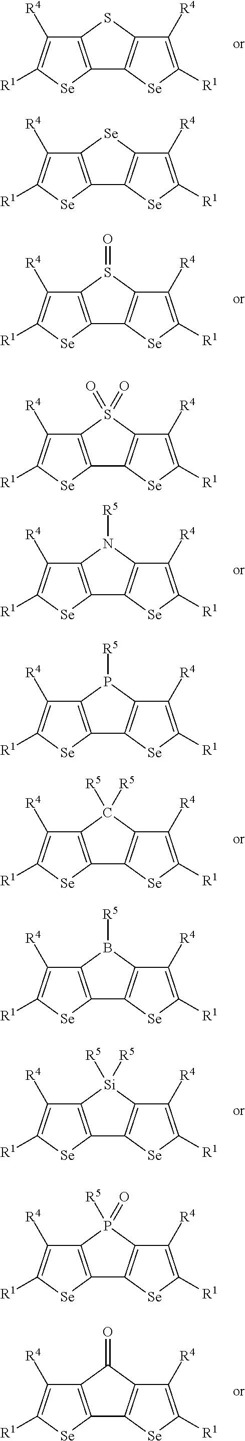

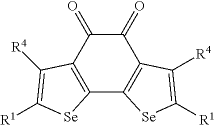

wherein R¹ is a terminal group for the oligomer or a covalent bond to another coupled unit in the oligomer.

In one embodiment, the moiety

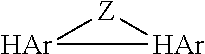

has one of the following structures:

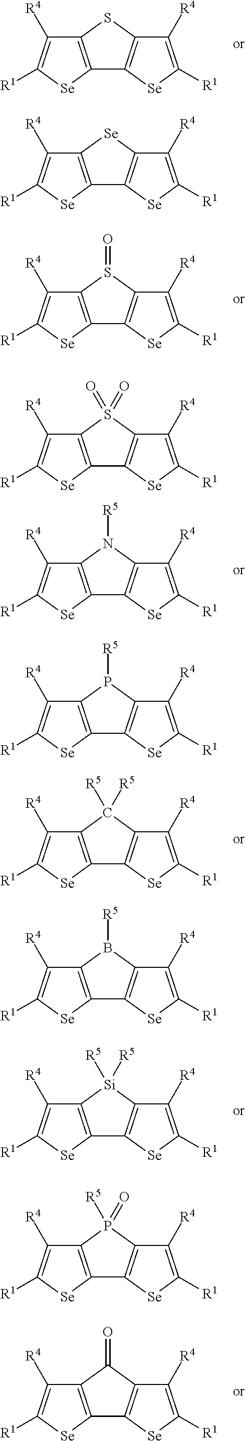

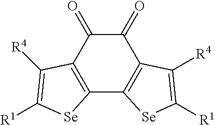

wherein R¹ is a terminal group for the oligomer or a covalent bond to another coupled unit in the oligomer.

In one embodiment, the oligomer compound comprises at least one acyl group.

In one embodiment, a composition is represented by at least one of:

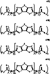

wherein independently a is 0 or 1, and a′ is 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 0, 1, 2, 3, or 4;

wherein c is 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴. wherein R⁴ is H, alkyl, fluorinated alkyl, aryl, fluorinated aryl, or heteroaryl;

wherein Z is S, Se, NR⁵, C(O), C(O)C(O), Si(R⁵)₂, SO, SO₂, PR⁵, P(O)R⁵, BR⁵, C(R⁵)₂, C═C(CN)₂, or [C═C(CN₂)]₂, wherein R⁵ is a C₁-C₅₀ organic radical selected from optionally substituted alkyl, perfluoroalkyl, aryl, and heteroaryl.

In one embodiment, the composition is selected from formula (XI).

In one embodiment, a composition is provided produced by any one of the processes described herein.

In one embodiment, a composition is provided comprising one or more of the compounds described herein.

In one embodiment, a device is provided comprising one or more of the compounds described herein.

### Additional Embodiments

### Electron Withdrawing Groups (D)

Electron-withdrawing groups can be also included as Z including groups comprising one or more nitrile groups, including for example, two, three, or four nitrile groups. Electron-withdrawing groups such as nitrile also can be used in substituent groups for the heterarylene rings (HAr).

Another aspect provides a method for synthesizing a fused tricyclic compound comprising the structure

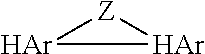

wherein

HAr a five or six membered heteroaryl group,

Z is C═C(CN)₂, or [C═C(CN₂)]₂

comprising:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate compound with an oxidizing agent so as to form a carbon-carbon bond between two intermediate compounds and thereby form the bishalo-bisheteroaryl compound.

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

In one embodiment, the organometallic compound is an alkyl lithium compound or lithium diorganoamide.

In another embodiment, the organometallic compound is a transition metal compound.

In another embodiment, the fused tricyclic compound has the structure

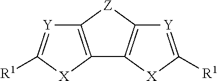

wherein

R¹ is hydrogen, a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

In another embodiment, a composition is provided represented by at least one of:

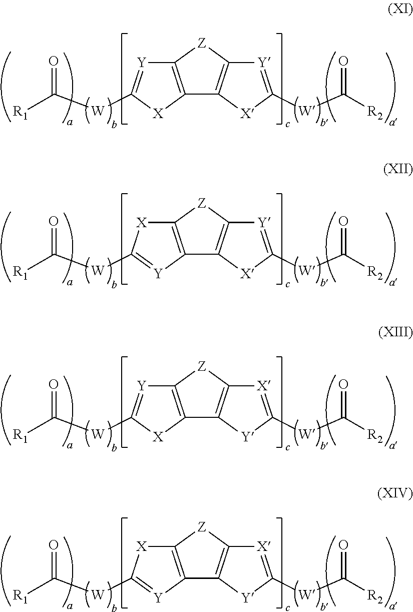

wherein independently a is 0 or 1, and a′ is 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 0, 1, 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴. wherein R⁴ is H, alkyl, fluorinated alkyl, aryl, fluorinated aryl, or heteroaryl;

wherein Z is C═C(CN)₂, or [C═C(CN₂)]₂.

In another embodiment, the compound is selected from formula XI.

In another embodiment, Z is C═C(CN)₂.

In another embodiment, Z is [C═C(CN₂)]₂.

Another embodiment provides a composition comprising at least one tricyclic fused aromatic compound represented by:

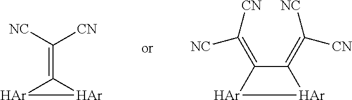

wherein HAr represent a five- or six-membered heteroarylene ring.

In one embodiment, the compound is represented by:

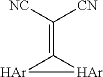

In another embodiment, the compound is represented by:

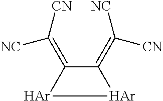

Other embodiments comprise compositions made from the processes described herein.

Other embodiments comprise compositions and devices comprising the compositions described herein.

The reference Mills et al., Synthetic Metals, 102 (1999) 1000-1001 describes an example of a carbon-bridged dithiophene where Z is C═C(CN)₂.

### Additional Embodiments

### Bridging Units (E)

In other methods embodied herein, the rearranged and often highly reactive intermediate compound described below is used to form bishalo-bisheteroaryl compound that comprises a —Z— bridging group. In some embodiments this bridged bishalo-bisheteroaryl compound can be further oxidatively coupled to form tricyclic compounds of the general formula II(b).

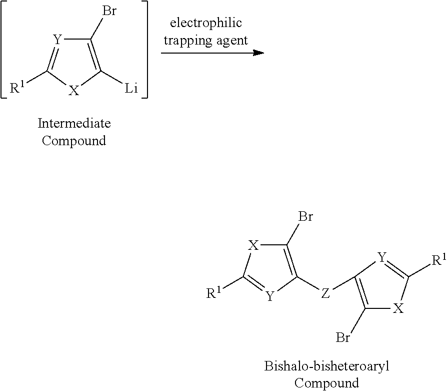

The tricyclic compounds embodied by Formula (IIb) can be novel. Additionally, the synthesis through a BCHD rearrangement is a novel route to tricyclic compounds of the Formula (IIb). Other tricyclic compounds of similar structure are known in the art, although they are accessed through alternate reactions. See Meyer, A, Synthesis and Properties of Thienyl-Substituted Dithienophiles.

Treatment of the reactive intermediate with an electron accepting reagent, such as diethyl oxalate provides the bishalo-bisheteroaryl compound. Electrophilic compounds disclosed herein especially under the proceeding section titled “Methods for Synthesizing Fused Tricyclic Compounds” may be used to link two heteroaryl units in an analogous manner to the following demonstrative scheme. Although formation of the diketone bridge is shown, it is understood that this is merely an embodiment and is a non-limiting example.

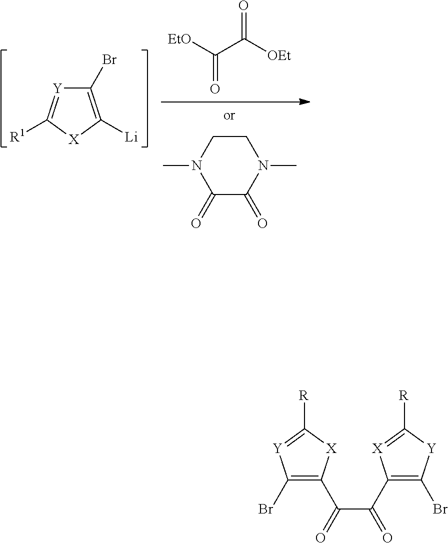

Applications

The compounds described herein can be used in, for example, organic electronics and printed electronics applications including, for example, transistors, TFTs, field-effect transistory, photodetectors and photovoltaics, solar cells, light emitting diodes, organic light emitting diodes, sensors, displays, flat panel displays, RFID, electronic paper, artificial skin, and the like.

The compounds can be also, if desired, subjected to oligomerization or polymerization processes for further use in applications.

Patterning methods can be carried out including, for example, ink jet printing and soft lithography. Film formation methods can be carried out including, for example, spin coating, dip coating, and the like.

Flexible substrates such as polymeric materials and rigid substrates such as glasses can be used.

Field-effect transistors are described in, for example, Bao, Locklin, Organic Field-Effect Transistors, CRC Press, 2007. Organic photovoltaics and solar cells are described in, for example, Sun, Sariciftci, Organic Photovoltaics, Taylor, 2005. OLEDs are described in, for example, Li, Meng, Organic Light-Emitting Materials and Devices, CRC, 2007.

The field-effect transistor can be fabricated with a top gate or bottom gate configuration. Substrates, source and drain electrodes, dielectric layers, and gate electrodes can be fabricated as known in the art. The active organic semiconducting layer can be solution processed or vacuum processed. Solution processing can be carried out with use of organic solvents such as chlorobenzene or dichlorobenzene. Solid concentration can be, for example, 0.1 mg/mL, or at least 1 mg/mL, or at least 10 mg/mL. The working examples below provide embodiments and methods of making which allow for demonstration of the field effect. One can provide the compounds with, for example, electron-withdrawing substituents or with larger naphthalene imide substituents (see, for example, working example 41).

In one embodiment, for example, a device is provided comprising one or more of the compositions or compounds described herein, wherein the device is, for example, a field effect transistor in which the active semiconducting layer comprises one or more of the compositions or compounds described herein and has a mobility of at least 1×10⁻⁵ cm²/Vs, or at least 1×10⁻⁴ cm²/Vs, or at least 1×10⁻³ cm²/Vs.

The I_{on/off} ratio can be, for example, at least 10, or at least 50, or at least 100.

Synthesis, device fabrication and FET measurements are illustrated in the following additional, non-limiting working examples.

### Working Examples Part 2

### Example 30

### Synthesis of 2,7-Bis-(5-n-nonyl-thiophen-2-yl)-benzo[1,2-b:6,5-b′]dithiophene-4,5-dione of the formula

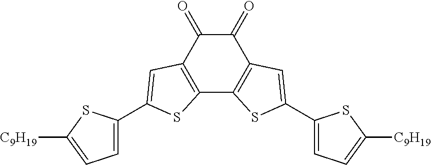

Step 1.

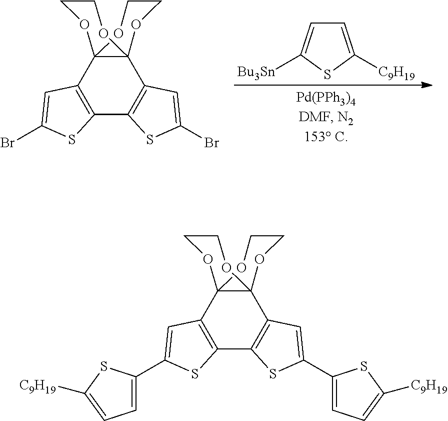

2,7-Dibromo-benzo[1,2-b:6,5-b′]dithiophene-4,5-bis(ethyleneoxolane) ((1.5 mmol, 0.70 g), 2-tri-n-butylstannylthiophene (2.1 eq., 3.15 mmol, 1.57 g) and Pd(PPh₃)₄ (5 mol %, 0.075 mmol, 0.087 g) were mixed under nitrogen in an oven-dried flask. Anhydrous DMF (20 mL) was added and the resulting yellowish suspension was heated to reflux and the mixture became yellow, then orange-red and then dark brown within a few minutes. Reaction mixture was cooled to room temperature, treated with water and hexanes. Organic phase was removed, the aqueous phase was extracted with hexanes and combined organic phases were dried over MgSO₄. The drying agent was filtered off, the solvents were removed by rotary evaporation and the residue was purified by column chromatography (200 mL of silica gel, hexanes:CH₂Cl₂ (1:1), then CH₂Cl₂ as eluants). Combined fractions were subjected to rotary evaporation and orange shiny solid was heated to reflux with ˜40 mL of EtOH (not all dissolve). The mixture was cooled (some needles formed on cooling) and the product was separated by vacuum filtration (YAG-V-275-a, 0.93 g, shiny orange solid, 85.3% yield). Part of this material (0.42 g) was recrystallized from 2-propanol and bright orange needles were separated by filtration (0.37 g, 88.1% recovery).

¹H NMR (CDCl₃, 400 MHz): δ 7.18 (s, 2H), 6.99 (d, J=3.5 Hz, 2H) 6.69 (d, J=3.6 Hz, 2H), 4.19 (m, 4H), 3.77 (m, 4H), 2.80 (t, J=7.6 Hz, 4H), 1.67 (m, 4H), 1.50-1.20 (m, 24H), 0.91 (t, J=6.8 Hz, 6H); ¹³C{¹H} NMR (CDCl₃, 100 MHz): 6146.1 (quaternary C), 136.8 (quaternary C), 136.2 (quaternary C), 134.2 (quaternary C), 131.0 (quaternary C), 124.9 (CH), 123.7 (CH), 120.8 (CH), 93.4, 61.7 (CH₂), 31.9 (CH₂), 31.6 (CH₂), 30.2 (CH₂), 29.5 (CH₂), 29.4 (CH₂), 29.3 (CH₂), 29.1 (CH₂), 22.7 (CH₂), 14.1 (CH₃). HRMS (EI) analysis calculated for C₄₀H₅₂O₄S₄ 724.2748; found 724.2734. Anal. Calc. for C₄₀H₅₂O₄S₄: C, 66.26; H, 7.23. Found: C, 66.37; H, 7.23.

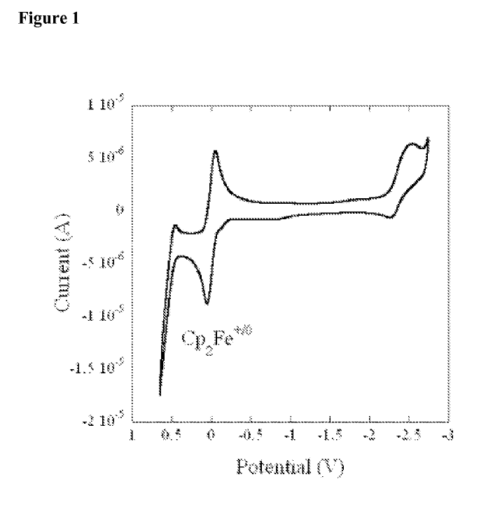

Cyclic voltammetry was conducted on the resulting product, the results of which are disclosed in FIG. 1. The CV data showed (0.1 M ⁿBu₄NPF₆ in THF, Cp₂Fe internal standard at 0 V, 50 mV·s⁻¹ rate) an E_{1/2}^{0/1-}=−2.42 V (partially reversible)

Step 2.

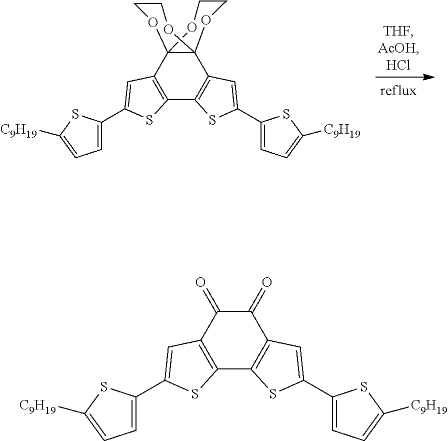

2,7-Bis-(5-n-nonyl-thiophen-2-yl)-benzo[1,2-b:6,5-b′]dithiophene-4,5-bis(ethyleneoxolane) (0.7 mmol, 0.508 g) was mixed with THF (50 mL) and acetic acid (50 mL) and mixture was heated to reflux. HCl (˜10 mL) was added to orange solution, and it brown-yellow, then dark-green-brown, then dark blue-green, and then dark blue. After ˜10 minutes of reflux the mixture was cooled to room temperature, THF was removed by rotary evaporation and the residue was treated with water (˜50-70 mL). The green precipitate was separated by vacuum filtration (0.39 g, 87.4% crude yield). This crude product was purified by column chromatography (˜150 mL of silica gel, dichloromethane as eluant). Combined fractions were subjected to rotary evaporation, the residue was dissolved in several mL of dichloromethane, and the solution was left for slow concentration in attempt to grow single crystals. Several very dark blue crystals were separated for the single crystal X-ray analysis, and the rest of the material was purified by column chromatography (˜150 mL of silica gel, dichloromethane as eluant). Fractions with the desired compound were combined, distilled 2-propanol was added and dichloromethane was removed by rotary evaporation. Additional amount of 2-propanol was added, the mixture was heated to reflux, cooled to room temperature and dark green solid was separated by vacuum filtration (0.36 g, 80.7% purified yield).

¹H NMR (CDCl₃, 400 MHz): δ7.34 (s, 2H), 7.00 (d, J=3.5 Hz, 2H), 6.69 (d, J=3.5 Hz, 2H), 2.79 (t, J=7.5 Hz, 4H), 1.66 (m, 4H), 1.50-1.20 (m, 24H), 0.89 (t, J=6.6 Hz, 6H); ¹³C{¹H} NMR (CDCl₃, 100 MHz): δ 174.2 (quaternary C(O)), 147.9 (quaternary C), 141.1 (quaternary C), 138.4 (quaternary C), 135.5 (quaternary C), 132.2 (quaternary C), 125.2 (CH), 125.1 (CH), 121.8 (CH), 31.9 (CH₂), 31.5 (CH₂), 30.2 (CH₂), 29.5 (CH₂), 29.3 (CH₂), 29.2 (9) (CH₂), 29.1 (CH₂), 22.7 (CH₂), 14.1 (CH₃). HRMS (EI) calculated for C₃₆H₄₄O₂S₄ 636.2224; found 636.2225 (M+2 (638.1) was observed as a major ion). Anal. Calcd. for C₃₆H₄₄O₂S₄: C, 67.88; H, 6.96. Found: C, 67.93; H, 6.87.

### Example 31

### Synthesis of 2,7-bis-(2-pentafluorobenzoyl-thiophen-2-yl)-benzo[1,2-d:4,3-d′]bis(thiazole)-4,5-dione

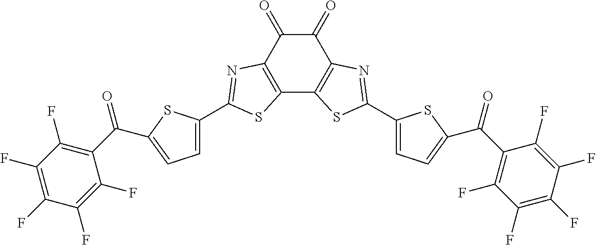 [SMILES: O=C1C(=O)c2nc(-c3ccc(C(=O)c4c(F)c(F)c(F)c(F)c4F)s3)sc2-c2sc(-c3ccc(C(=O)c4c(F)c(F)c(F)c(F)c4F)s3)nc21]

Step 1. (literature procedures (Getmanenko, Y. A.; Risko, C.; Tongwa, P.; Kim, E. G.; Li, H.; Sandhu, B.; Timofeeva, T.; Bredas, J. L.; Marder, S. R. J Org Chem 2011, 76, 2660) were used to prepare 2,7-bis-triisopropylsilyl-benzo[2,1-b:3,4-b′]dithiazole-4,5-dione).

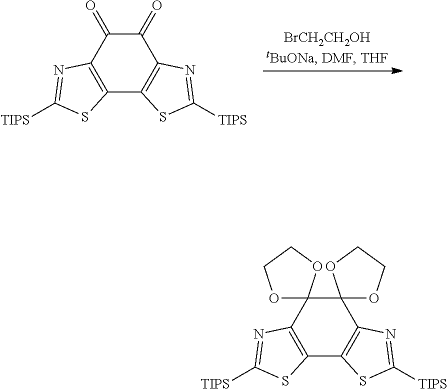

Literature conditions (Barbasiewicz, M.; Makosza, M. Organic Letters 2006, 8, 3745) for the protection of the carbonyl group were used for bithiazole derivative.

2,7-Bis-triisopropylsilyl-benzo[2,1-b:3,4-b′]dithiazole-4,5-dione (4.0 mmol, 2.14 g) was dissolved in a mixture of anhydrous THF (15 mL) and anhydrous DMF (30 mL) under nitrogen atmosphere and the orange-red solution was cooled in acetone/dry ice bath. 2-Bromoethanol (3 eq., 12.0 mmol, 1.50 g) was added followed by dropwise addition of solution ^{t}BuONa (14.05 mmol, 1.35 g) in anhydrous DMF (30 mL) and the mixture became brownish-yellow and then green. After addition of 15 mL of ^{t}BuONa solution the mixture stopped stirring and heavy precipitate was observed. Additional amount of anhydrous THF (70 mL) was added, the cooling bath was removed for ˜5 minutes and after stirring was resumed the mixture was cooled in acetone/dry ice bath. Precipitate formed again, the cooling bath was removed and the rest of the ^{t}BuONa solution was added dropwise. The mixture was allowed to warm to room temperature and treated with aqueous NH₄Cl. The color ganged from green to orangish-yellow. Diethyl ether was added and the yellow-orange organic phase was removed. The aqueous phase was extracted with diethyl ether and combined organic phases were dried over MgSO₄. The solvents were removed by rotary evaporation and then under vacuum (residual DMF), and the residue was purified by column chromatography (150 mL of silica gel, CHCl₃, then CHCl₃:EtOAc (50:1) as eluants). Combined fractions were subjected to rotary evaporation and the product was obtained as yellowish-reddish oil, which solidified after removal of residual amount of solvent and scratching (2.10 g, light carrot-like color; recrystallization from 2-PrOH afforded white solid). First fractions with slightly impure product (by TLC) were kept separately (0.51 g).

¹H NMR (CDCl₃, 400 MHz): δ 4.32-4.39 (m, 4H), 4.25-4.32 (m, 4H), 1.38 (sept, J=7.4 Hz, 6H), 1.13 (d, J=7.4 Hz, 36H); ¹³C{¹H} NMR (CDCl₃, 100 MHz): δ 169.1, 154.0, 126.9, 106.4, 66.8, 18.4 (CH), 11.6 (CH₃). HRMS (EI) calculated for C₃₀H₅₀N₂O₄S₂Si₂ 622.2751; found 622.2754. Anal. Calc. for C₃₀H₅₀N₂O₄S₂Si₂: C, 57.83; H, 8.09; N, 4.50. Found: C, 57.89; H, 8.02; N, 4.52.

Step 2.

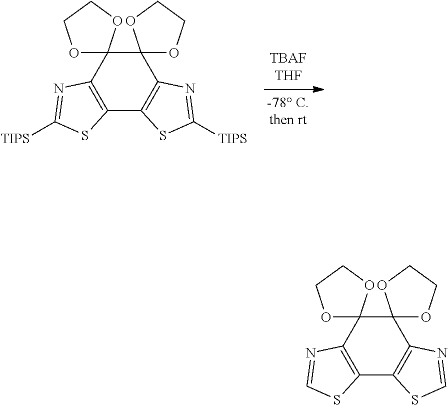

Di-protected 2,7-bis-triisopropylsilyl-benzo[2,1-b:3,4-b′]dithiazole-4,5-dione (3.08 mmol, 1.92 g) was dissolved in 50 mL of THF and the resulting yellowish solution was cooled in acetone/dry ice bath (nitrogen atmosphere). TBAF (1.0 M in THF, 2.2 eq., 6.8 mL) was added dropwise and the green reaction mixture was warmed to room temperature. The solvent was removed by rotary evaporation and the crude product was purified by column chromatography (150 mL of silica gel, CHCl₃:EtOAc (3:1)). Combined fractions were subjected to rotary evaporation and the yellowish solid was recrystallized from −50 mL of 2-PrOH. Product was obtained as colorless plates (0.42 g, 44.2% yield).

(for batch EG-I-110-b): ¹H NMR (CDCl₃, 400 MHz): δ 8.67 (s, 2H), 4.30-4.35 (m, 8H); ¹³C{¹H} NMR (CDCl₃, 100 MHz): δ 152.7, 151.2 (CH), 124.4, 106.9, 67.1 (CH₂O). HRMS (EI) calculated for C₁₂H₁₀N₂O₄S 310.0082; found 310.0082. Anal. Calcd. for C₁₂H₁₀N₂O₄S₂: C, 46.44; H, 3.25; N, 9.03. Found: C, 46.57; H, 3.25; N, 9.06.

Step 3.

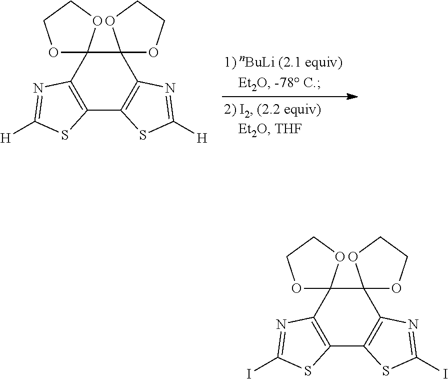 [SMILES: c1nc2c(s1)-c1scnc1C1(OCCO1)C21OCCO1 ; Ic1nc2c(s1)-c1sc(I)nc1C1(OCCO1)C21OCCO1]

Bithiazole derivative (2.0 mmol, 0.62 g) was dissolved in 100 mL of anhydrous THF and 50 mL of anhydrous diethyl ether under nitrogen atmosphere and the solution was cooled in acetone/dry ice bath. n-Butyllithium (2.85 M in hexanes, 2.1 eq., 4.2 mmol, 1.5 mL) was added dropwise to a colorless solution and it became yellow-orange with precipitate. The mixture was stirred for 20 minutes and a solution of iodine (2.2 eq., 4.4 mmol, 1.12 g) in 20 mL of anhydrous THF was added dropwise. The reaction mixture (suspension) became red, then orange and then orange-red solution. After stirring for 10 minutes the reaction mixture was allowed to warm to room temperature and treated with aqueous Na₂S₂O₃. The mixture was transferred to a round bottom flask and the organic solvents were removed by rotary evaporation. The off-white solid with some dark matter of the sides of the flask was vacuum filtered and the filtrate was extracted with dichloromethane. This organic phase was combined with the solid and brown solution was column chromatographed (100 mL of silica gel, CH₂Cl₂:EtOAc (10:1) as eluant). Combined fractions were subjected to rotary evaporation and the product was obtained as white solid (0.35 g, 31.1% yield). The material became yellowish after a few hours of exposure to ambient conditions. The residue on the sides of the flask was dissolved in boiling 2-PrOH and yellow tiny crystals formed on cooling (˜50 mg).

¹H NMR (CDCl₃, 400 MHz): δ 4.30 (m, 8H); ¹³C{¹H} NMR (CDCl₃, 100 MHz): δ 153.8, 129.4, 106.21, 98.8, 67.2. HRMS (EI) calculated for C₁₂H₈I₂N₂O₄S₂ 561.8015; found 561.8019. Elemental analysis calculated for C₁₂H₈I₂N₂O₄S₂: C, 25.64; H, 1.43; N, 4.98. Found: C, 25.80; H, 1.34; N, 4.94.

Step 4.

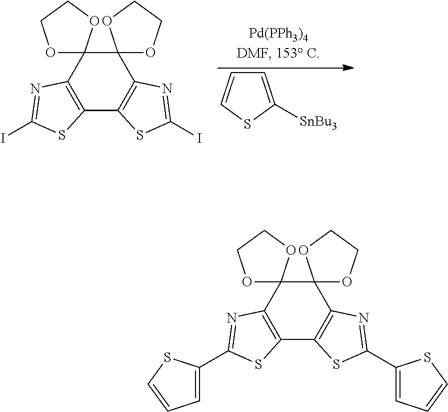

2,7-Iodo-benzo[2,1-b:3,4-b′]dithiazole-4,5-di-(1,3-dioxolane) (0.35 mmol, 0.196 g) was mixed with 2-tri-n-butylstannyl-thiophene (2.1 eq., 0.73 mmol, 0.27 g) and Pd(PPh₃)₄ (5 mol %, 0.0175 mmol, 0.02 g) were mixed in the oven-dried flask under nitrogen atmosphere. Anhydrous DMF (20 mL) was added and the yellow suspension was heated up to 153° C. The reaction mixture became orange, and then brown-yellow within a few minutes. The reaction mixture was cooled to room temperature, treated with water and precipitate was separated by vacuum filtration, washed with ethanol and dried (0.155 g, 93.9% crude yield). This material was purified by column chromatography (˜50 mL of silica gel, CH₂Cl₂, then CH₂Cl₂:EtOAc (20:1) as eluants). The solvents were removed from combined fractions and the product was obtained as bright yellow microcrystalline compound (0.132 g, 80% purified yield).

(This material was fully characterized on a previous batch: ¹H NMR (CDCl₃, 400 MHz): δ 7.51 (dd, J=3.7 Hz, 1.0 Hz, 2H), 7.41 (dd, J=5.0 Hz, 1.0 Hz, 2H), 7.07 (dd, J=5.0 Hz, 3.8 Hz, 2H), 4.45-4.30 (m, 8H); ¹³C{¹H} NMR (CDCl₃, 100 MHz): δ 160.1, 152.6, 136.8, 128.3, 127.9, 126.9, 123.6, 106.7, 67.2. HRMS (EI) calc. for C₂₀H₁₄N₂O₄S₄: 473.9836; found 473.9832. Anal. Calcd. for: C, 50.61; H, 2.97; N, 5.90. Found: C, 50.41; H, 2.83; N, 5.88.)

Step 5.

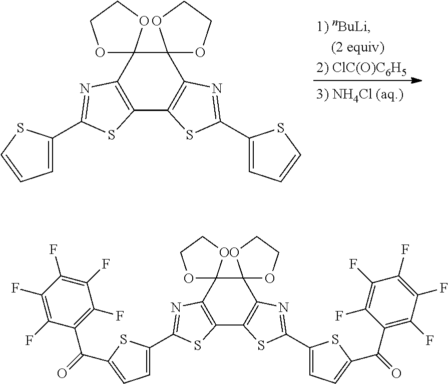 [SMILES: c1csc(-c2nc3c(s2)-c2sc(-c4cccs4)nc2C2(OCCO2)C32OCCO2)c1 ; O=C(c1ccc(-c2nc3c(s2)-c2sc(-c4ccc(C(=O)c5c(F)c(F)c(F)c(F)c5F)s4)nc2C2(OCCO2)C32OCCO2)s1)c1c(F)c(F)c(F)c(F)c1F]

2,7-Bis-(thiophene-2-yl)-benzo[2,1-b:3,4-b′]dithiazole-4,5-di-(1,3-dioxolane) (0.27 mmol, 0.128 g) was dissolved in 80 mL of anhydrous THF under nitrogen atmosphere and bright yellow solution was cooled in acetone/dry ice bath. n-Butyllithium (2.85 M in hexanes, 2 eq., 0.54 mmol, 019 mL) was added dropwise and the mixture became green-yellow. After stirring for 0.5 h pentafluorobenzoyl chloride (4.8 eq., 1.3 mmol, 0.3 g) was added quickly and the reaction mixture became brown-yellow. After stirring for 0.5 h the reaction mixture was allowed to warm to room temperature and treated with aqueous NH₄Cl. Organic phase was separated, aqueous phase was extracted with CH₂Cl₂ and combined orange-red organic phases were dried over MgSO₄. Drying agent was filtered off and the solvents were removed by rotary evaporation, and the crude product was purified by column chromatography (100 mL of silica gel, CH₂Cl₂ as a solvent to pack the column, CH₂Cl₂:EtOAc (100:1, 50:1) as eluant). Product came out contaminated with the mono-substituted byproduct, all fractions were combined, the solvents were removed and the residue was further purified by column chromatography (150 mL of silica gel, CH₂Cl₂:EtOAc (50:1) as eluant). Fractions with a minor impurity were combined, and the solvents were removed by rotary evaporation (15 mg). Fractions with pure material were combined separately, the solvents were removed by rotary evaporation and product was obtained as bright orange solid (86 mg).

¹H NMR (CDCl₃, 400 MHz): δ 7.54 (d, J=4.1 Hz, 2H), 7.50 (d, J=4.1 Hz, 2H), 4.38 (m, 8H); ¹³C{¹H} NMR (CDCl₃, 100 MHz): δ 158.4, 154.7, 146.7, 143.6, 136.1(CH), 127.3 (CH), 125.8, 106.3, 67.6 (CH₂) (quaternary C(O) and C—F signals were not detected due to not sufficient concentration and number of scans; ¹³C NMR should be re-recorded at higher concentration). HRMS (EI) calculated for C₃₄H₁₂N₂O₆S₄F₁₀ 861.9419; found 861.9404. Anal. Calcd. for C₃₄H₁₂N₂O₆S₄F₁₀: C, 47.33; H, 1.40; N, 3.25. Found: C, 47.30; H, 1.46; N, 3.22.

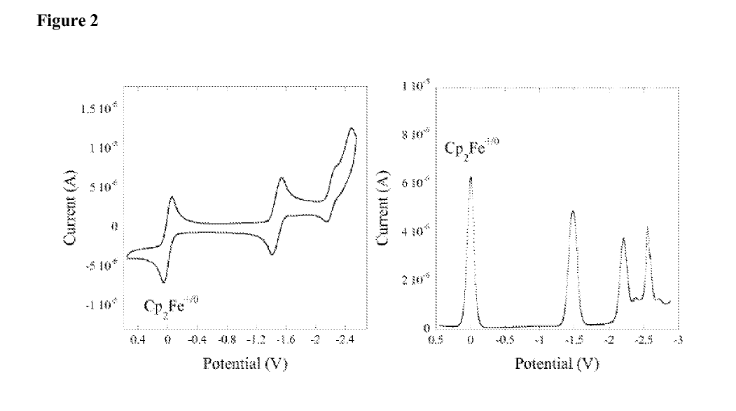

Cyclic voltammetry and Differential pulse voltammetry (DPV) were conducted on the resulting product, the results of which are disclosed in FIG. 2. The CV data showed (0.1 M ⁿBu₄NPF₆ in THF, Cp₂Fe internal standard at 0 V, 50 mV·s⁻¹ rate)E_{1/2}^{0/-1}=−1.48 V, E_{1/2}^{-1/-2}=−2.21 V. The DPV data showed (0.1 M ⁿBu₄NPF₆ in THF, Cp₂Fe internal standard at 0 V): E^{0/-1}=−1.48 V, E^{-1/-2}=−2.21 V, E^{-2/-3}=−2.56 V.

Step 6.

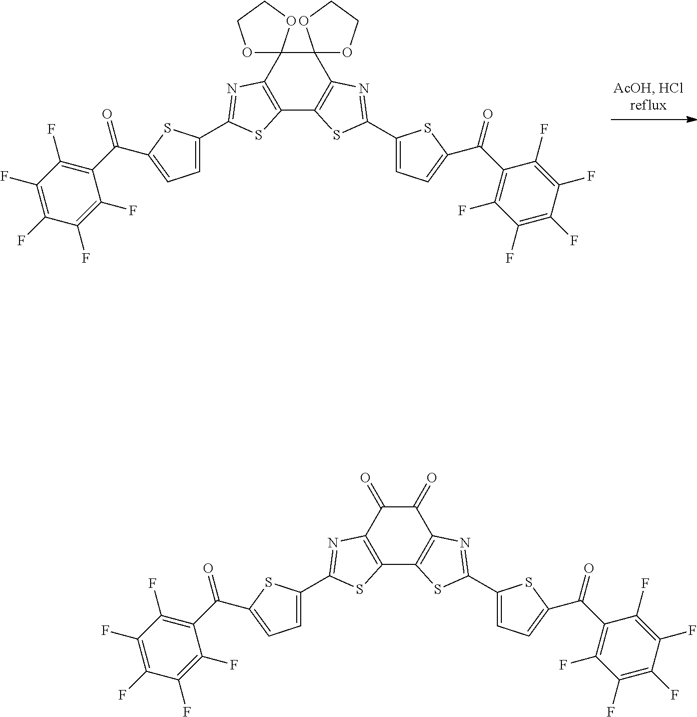 [SMILES: O=C(c1ccc(-c2nc3c(s2)-c2sc(-c4ccc(C(=O)c5c(F)c(F)c(F)c(F)c5F)s4)nc2C2(OCCO2)C32OCCO2)s1)c1c(F)c(F)c(F)c(F)c1F ; O=C1C(=O)c2nc(-c3ccc(C(=O)c4c(F)c(F)c(F)c(F)c4F)s3)sc2-c2sc(-c3ccc(C(=O)c4c(F)c(F)c(F)c(F)c4F)s3)nc21]

2,7-Bis-(5-pentafluorobenzoyl-thiophene-2-yl)-benzo[2,1-b:3,4-b′]dithiazole-4,5-di-(1,3-dioxolane) (0.087 mmol, 0.075 g) was mixed with acetic acid (20 mL) and the resulting mixture was heated to reflux. HCl (3 mL) was added dropwise to a bright orange solution and the mixture became dark brown and then within a few minutes precipitate formed. Additional amount of HCl (2 mL) was added and the mixture was refluxed for ˜1 h, cooled to room temperature and treated with water. Green-grey shiny solid was separated by vacuum filtration, washed with water and ethanol and dried (0.068 g, ˜100% crude yield). This material was purified by column chromatography (30 mL of silica gel, CHCl₃ and CHCl₃:EtOAc (50:1) as eluants, hot chloroform to dissolve material and load to the column). Middle fractions with pure material were combined, subjected to rotary evaporation and the residue (green solid) was heated to reflux with 2-propanol, cooled and green-grey solid was separated by vacuum filtration (17.4 mg). First few and last fractions with the product were combined with mother liquor of said green-grey solid, the volatile solvents were removed by rotary evaporation, THF was added until clear solution formed and then concentrated until precipitation took place. Green solid was separated by filtration (5 mg). Filter papers of both green-grey and green solid were washed with THF, the solvent was removed and additional amount of product was obtained (13 mg, brown film on the sides).

Mixture of green and gray-green solids: ¹H NMR (THF-d8, 400 MHz): δ 7.91 (d, J=4.3 Hz, 2H), 7.78 (d, J=4.1 Hz, 2H) (CHCl₃ peak at d 7.90 ppm was detected, which means that either the tube was not dried or that the sample traps chloroform). DEPT-135 (CDCl₃, 100 MHz): δ 137.8 (CH), 130.3 (CH). HRMS (EI) analysis calculated for C₃₀H₄F₁₀N₂O₄S₄ 773.8894; found 773.8885 (M+2 (776.1) was observed as a major ion). Anal. Calcd. for C₃₀H₄F₁₀N₂O₄S₄: C, 46.52; H, 0.52; N, 3.62. Found: C, 46.34; H, 0.57; N, 3.91.

Green solids: ¹³C{¹H} NMR (THF-d8, 100 MHz): δ 177.0, 171.2, 160.3, 151.1, 146.1, 145.7, 143.6 (m), 140.1 (m), 137.9 (CH), 137.6-136.9 (m), 130.4 (CH), 114.4 (m). ¹⁹F NMR (CDCl₃, 376.3 MHz): δ −141.0 (4F), −151.7 (2F), −160.9 (m, 4F) (1,1,2-trichlorotrifluoroethane was used as a reference with d at −71.75 ppm (t)).

### Example 32

### Synthesis of Protected and Thiophene Compounds

Step 1.

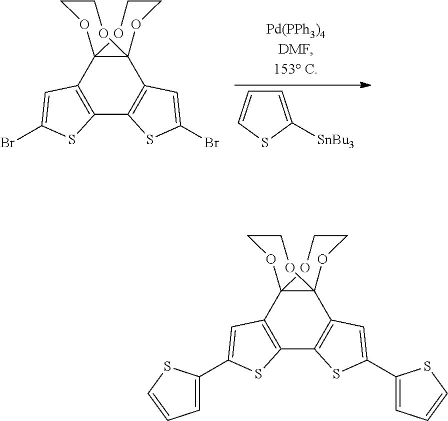

2,7-Dibromo-benzo[1,2-b:6,5-b′]dithiophene-4,5-bis(ethyleneoxolane) (3.0 mmol, 1.40 g), 2-tri-n-butylstannyl-thiophene (2.1 eq., 6.3 mmol, 2.35 g) and Pd(PPh₃)₄ (2.5 mol %, 0.075 mmol, 0.087 g) were mixed in an oven-dried flask under nitrogen atmosphere. Anhydrous DMF (30 mL) was added and the suspension was heated to 153° C. Yellow solution formed during heating, and the color changed to orange, then orange-red and within a few minutes very dark yellowish-brown. The reaction mixture was cooled to room temperature, treated with water and organic matter was extracted with CH₂Cl₂ several times. Combined organic phases were dried over MgSO₄, the drying agent was filtered off, and the organic solvents were removed by rotary evaporation. Crude product obtained as orange solid with some oil was purified by column chromatography twice (˜200 mL of silica gel, CH₂Cl₂ as eluant). Fractions with pure product (by TLC) were combined, the solvent was removed and orange solid was obtained (Pdt—252-b, 1.34 g, faint smell of tin byproduct was detectable). Last fractions with product were combined separately, the solvent was removed and the residue was dissolved in 2-propanol-dichloromethane under heating. No solid precipitated on cooling, and dichloromethane was removed by rotary evaporation. Shiny little orange crystals were filtered off (Pdt—252-d, 0.111 g).

Material Pdt—252-b was recrystallized from toluene with addition of hexanes and yellow-orange crystals were obtained (Pdt—252-e, 1.08 g, 80.6% recovery). Mother liquors of materials Pdt—252-d and Pdt—252-e were combined, the sides of the flasks were rinsed with dichloromethane and volatile solvent was removed by rotary evaporation. Orange crystals were removed by vacuum filtration (Pdt—252-f, 0.118 g).

¹H NMR (CDCl₃, 400 MHz): δ7.28 (s, 2H), 7.25 (dd, J=5.1 Hz, 1.1 Hz, 2H), 7.20 (dd, J=3.6 Hz, 1.1 Hz, 2H), 7.04 (dd, J=5.1 Hz, 3.6 Hz, 2H), 4.21 (m, 4H), 3.80 (m, 4H); ¹³C{¹H} NMR (CDCl₃, 100 MHz): δ 136.7 (quaternary C), 136.5 (quaternary C), 136.3 (quaternary C), 131.5 (quaternary C), 127.9 (CH), 124.9 (CH), 124.0 (CH), 121.7 (CH), 93.3 (CH₂), 61.7 (quaternary C). HRMS (EI) calculated for C₂₂H₁₆O₄S₄ 471.9931; found 471.9934. Anal. Calc. for C₂₂H₁₆O₄S₄: C, 55.91; H, 3.41. Found: C, 56.38; H, 3.48.

Step 2.

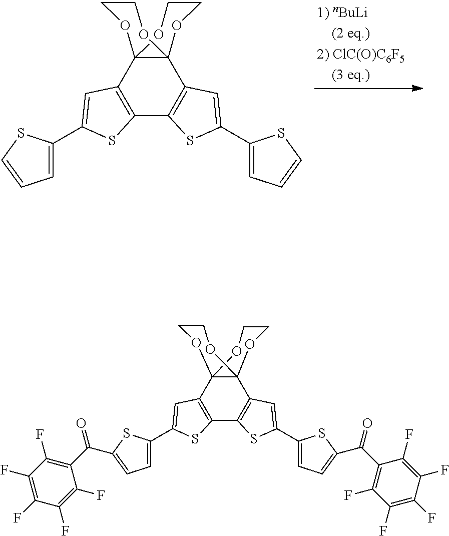 [SMILES: c1csc(-c2cc3c(s2)-c2sc(-c4cccs4)cc2C24OCCOC32OCCO4)c1 ; O=C(c1ccc(-c2cc3c(s2)-c2sc(-c4ccc(C(=O)c5c(F)c(F)c(F)c(F)c5F)s4)cc2C24OCCOC32OCCO4)s1)c1c(F)c(F)c(F)c(F)c1F]

2,7-Bis-(thiophene-2-yl)-benzo[2,1-b:3,4-b′]dithiazole-4,5-bis(ethyleneoxolane) (1.5 mmol, 0.709 g) was dissolved in anhydrous THF under nitrogen atmosphere and yellow solution was cooled in acetone/dry ice bath. n-Butyllithium (2.85 M in hexanes, 3.0 mmol, 1.05 mL) was added dropwise and yellow solution became lighter in color and then precipitate formed. The reaction mixture was stirred for 1 h and pentafluorobenzoyl chloride (3 eq., 4.5 mmol, 1.04 g) was added quickly to the suspension. Yellow mixture became orange-reddish, and after stirring for 40 minutes bright orange-red solution was allowed to warm to room temperature. After 10 minutes of stirring precipitate was observed. Mixture was treated with aqueous NH₄Cl and dichloromethane was added. Organic phase was removed and dried over MgSO₄. The drying agent was filtered off and the organic solvents were removed by rotary evaporation. Crude product was purified by column chromatography (150 mL of silica gel, dichloromethane as eluant). First fractions with a product slightly contaminated by mono-substituted material were combined separately, the solvent was removed by rotary evaporation and red solid was obtained (Pdt—259-a, 0.45 g, ˜35% yield). Fractions with pure product were combined separately, the solvent was removed by rotary evaporation and dark red solid was obtained (Pdt—259-b, 0.67 g, 51.9% yield).

¹H NMR (CDCl₃, 400 MHz): δ7.50 (s, 2H), 7.42 (d, J=4.1 Hz, 2H), 7.24 (d, J=4.1 Hz, 2H), 4.23 (m, 4H), 3.76 (m, 4H); DEPT-135 (CDCl₃, 100 MHz): δ 136.94 (CH), 124.9(3) (CH), 124.8(6) (CH), 61.7 (CH₂). HRMS (EI) calculated for C₃₆H₁₄F₁₀O₆S₄ 859.9514; found 859.9509. Anal. Calc. for C₃₆H₁₄F₁₀O₆S₄: C, 50.23; H, 1.64. Found: C, 50.14; H, 1.46.

Step 3.

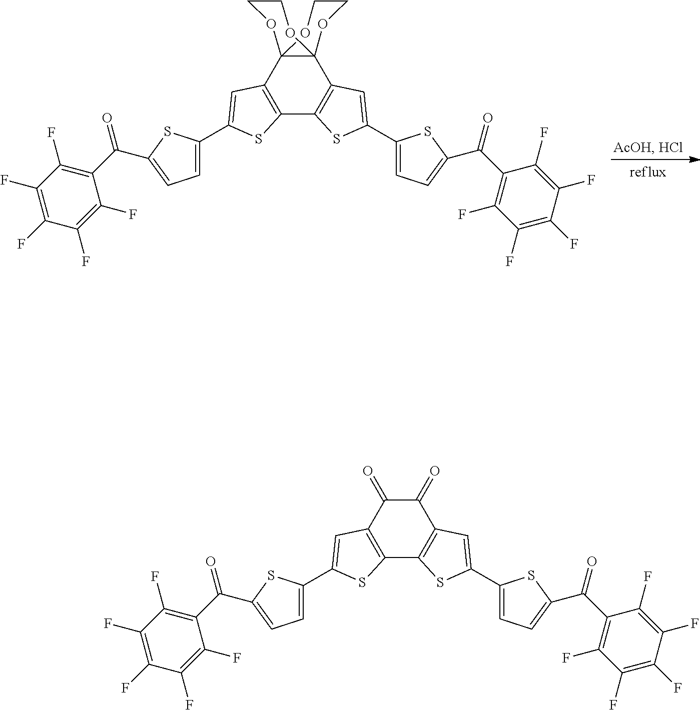 [SMILES: O=C(c1ccc(-c2cc3c(s2)-c2sc(-c4ccc(C(=O)c5c(F)c(F)c(F)c(F)c5F)s4)cc2C24OCCOC32OCCO4)s1)c1c(F)c(F)c(F)c(F)c1F ; O=C1C(=O)c2cc(-c3ccc(C(=O)c4c(F)c(F)c(F)c(F)c4F)s3)sc2-c2sc(-c3ccc(C(=O)c4c(F)c(F)c(F)c(F)c4F)s3)cc21]

2,7-Bis-(5-pentafluorobenzoyl-thiophene-2-yl)-benzo[1,2-b:6,5-b′]dithiophene-4,5-bis(ethyleneoxolane) (0.5 mmol, 0.43 g) was mixed with 75 mL of acetic acid and the resulting mixture was heated to reflux. HCl (5 mL) was added to the orange-red solution and the reaction mixture became dark immediately and then precipitate formed. Reaction mixture was refluxed for 2 hours, cooled to room temperature and precipitate was separated by vacuum filtration, washed with water, ethanol and dried (Pdt—261-a, 0.412 g (107% crude yield), green-grey solid). This material was refluxed in ˜120 mL of boiling 1,1,2,2-tetrachloroethane, filtered while hot (some material did not dissolve) and cooled. Dark solid was separated by vacuum filtration (Pdt—309-a, 0.133 g). Material on the filter was combined with mother liquor, heated to reflux (˜75 mL of 1,1,2,2-tetrachloroethane was added), gravity filtered while hot and cooled to room temperature. Dark solid was separated by vacuum filtration (Pdt—309-b, 0.215 g). This material has low solubility in common solvents and ¹³C NMR were not recorded. ¹H NMR (CDCl₃, 400 MHz, 380 K): δ7.78 (s, 2H), 7.55 (d, J=3.9 Hz, 2H), 7.38 (d, J=4.0 Hz, 2H). HRMS (EI) calculated for C₃₂H₆F₁₀O₄S₄ 771.8989; found 771.8978. Anal. Calc. for C₃₂H₆F₁₀O₄S₄: C, 49.74; H, 0.78. Found: C, 49.47; H, 0.77.

### Example 33

### Synthesis of Non-Symmetric Acyl Compounds and Coupling Thereof (Also: Multiple Tricyclic Ring Moieties in Single Compound)

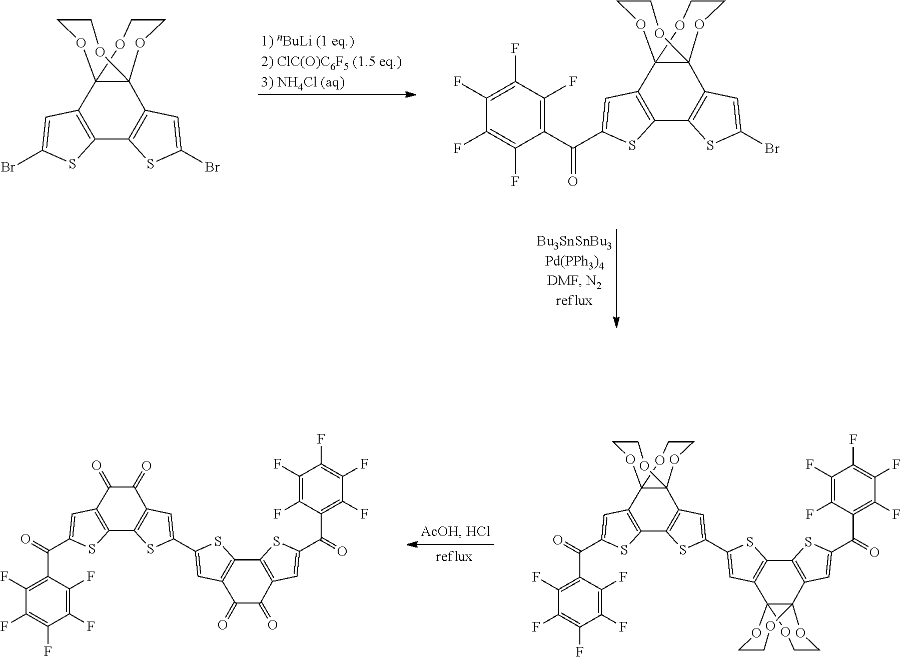 [SMILES: Brc1cc2c(s1)-c1sc(Br)cc1C13OCCOC21OCCO3 ; O=C(c1cc2c(s1)-c1sc(Br)cc1C13OCCOC21OCCO3)c1c(F)c(F)c(F)c(F)c1F ; O=C1C(=O)c2cc(-c3cc4c(s3)-c3sc(C(=O)c5c(F)c(F)c(F)c(F)c5F)cc3C(=O)C4=O)sc2-c2sc(C(=O)c3c(F)c(F)c(F)c(F)c3F)cc21 ; O=C(c1cc2c(s1)-c1sc(-c3cc4c(s3)-c3sc(C(=O)c5c(F)c(F)c(F)c(F)c5F)cc3C35OCCOC43OCCO5)cc1C13OCCOC21OCCO3)c1c(F)c(F)c(F)c(F)c1F]

Step 1.

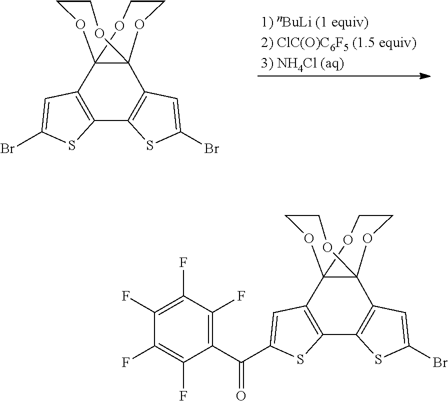 [SMILES: Brc1cc2c(s1)-c1sc(Br)cc1C13OCCOC21OCCO3 ; O=C(c1cc2c(s1)-c1sc(Br)cc1C13OCCOC21OCCO3)c1c(F)c(F)c(F)c(F)c1F]

2,7-Dibromo-benzo[1,2-b:6,5-b′]dithiophene-4,5-bis(ethyleneoxolane) (3.0 mmol, 1.40 g) was dissolved in anhydrous THF (75 mL) and yellowish solution was cooled in acetone/dry ice bath under nitrogen atmosphere. n-Butyllithium (2.85 M in hexanes, 1.0 eq., 3.0 mmol, 1.05 mL) was added dropwise and the mixture became purple. After stirring for 15 minutes pentafluorobenzoyl chloride (1.5 eq., 4.5 mmol, 1.04 g) was added quickly to the purple suspension. The reaction mixture was allowed to warm to room temperature and treated with aqueous NH₄Cl. Organic matter was extracted with dichloromethane several times and combined organic phases were dried over MgSO₄. The drying agent was filtered off and the residue was purified by column chromatography (150 mL of silica gel, CH₂Cl₂:hexanes (2:1) as eluant). Combined fractions were subjected to rotary evaporation and yellow solid was obtained (1.53 g).

¹H NMR (CDCl₃, 400 MHz): d 7.50 (s, 1H), 7.23 (s, 1H), 4.16 (m, 4H), 3.67 (m, 4H) (this material contained starting 2,7-dibromo-benzo[1,2-b:6,5-b′]dithiophene-4,5-bis(ethyleneoxolane) (d 7.14 (s, 0.30H)) and 2,7-bis-pentafluorobenzoyl-benzo[1,2-b:6,5-b′]dithiophene-4,5-bis(ethyleneoxolane) (d 7.57 (s, 0.40H)). DEPT-135 (CDCl₃, 100 MHz): d 134.0 (CH), 128.8 (CH), 61.7 (CH₂), 61.5 (CH₂). HRMS (EI) calculated for C₂₁H₁₀BrF₅O₅S₂ 579.9073; found 579.9074.

Said yellow solid was further purified by column chromatography (200 mL of silica gel, CH₂Cl₂:hexanes (35:15, then 2:1). Combined fractions were subjected to rotary evaporation and the residue was recrystallized from 2-propanol. A yellow crystalline material (tiny needles and spheres)was separated by vacuum filtration (0.93 g). Last fractions with material were combined separately, the solvents were removed by rotary evaporation and the residue was recrystallized from 2-propanol to give yellow solid (0.24 g).

¹H NMR showed the presence of the same impurities as in a very similar ratio: 2,7-dibromo-benzo[1,2-b:6,5-b′]dithiophene-4,5-bis(ethyleneoxolane) (d 7.14 (s, 0.24H)) and 2,7-bis-pentafluorobenzoyl-benzo[1,2-b:6,5-b′]dithiophene-4,5-bis(ethyleneoxolane) (d 7.57 (s, 0.31H)), which indicates that purity of the product did not improve significantly after another column chromatography and recrystallization.

¹³C {¹H} NMR (CDCl₃, 100 MHz): δ 175.7 (quaternary C(O), 143.3 (quaternary C), 140.3 (quaternary C), 139.8 (quaternary C), 136.9 (quaternary C), 134.0 (CH), 132.9, 128.8 (CH), 115.8 (quaternary C—Br), 92.5, 92.4, 61.6 (CH₂), 61.4 (CH₂) (C—F signals were observed as weak multiplets and not certain).

Step 2.

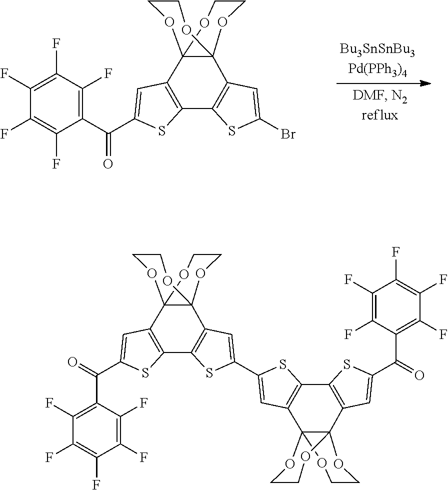 [SMILES: O=C(c1cc2c(s1)-c1sc(Br)cc1C13OCCOC21OCCO3)c1c(F)c(F)c(F)c(F)c1F ; O=C(c1cc2c(s1)-c1sc(-c3cc4c(s3)-c3sc(C(=O)c5c(F)c(F)c(F)c(F)c5F)cc3C35OCCOC43OCCO5)cc1C13OCCOC21OCCO3)c1c(F)c(F)c(F)c(F)c1F]

2-Bromo-7-pentafluorobenzoyl-benzo[1,2-b:6,5-b′]dithiophene-4,5-bis(ethyleneoxolane) (0.5 mmol, 0.291 g; ˜70-80% purity), hexa-n-butylditin (0.55 mmol, 0.16 g) and Pd(PPh₃)₄ (2 mol %, 0.01 mmol, 0.012 g) were mixed under nitrogen atmosphere and anhydrous DMF (15 mL) was added. The yellow reaction mixture was heated to reflux, and it became orange and then red-orange. After 40 minutes the reaction mixture was cooled to room temperature, treated with water, and organic matter was extracted with dichloromethane. Combined organic phases were dried over MgSO₄, the drying agent was filtered off and solvents were removed to give crude product as dark red matter. This crude material was purified by column chromatography (200 mL of silica gel, CH₂Cl₂, then CH₂Cl₂:EtOAc (50:1, 30:1) as eluants). Fractions containing product were combined, the solvents were removed and bright orange solid was obtained (0.10 g, faint smell of tin byproduct). Last fractions with product were combined separately, the solvents were removed and the residue was heated to reflux with 2-propanol (not soluble). Orange-red solid was removed by vacuum filtration (23 mg).

¹H NMR (CDCl₃, 400 MHz): δ 7.52 (s, 2H), 7.40 (s, 2H), 4.20 (m, 8H), 3.72 (m, 8H); ¹³C{¹H} NMR (CDCl₃, 100 MHz): δ 175.7 (quaternary C(O)), 143.6 (quaternary C), 140.9 (quaternary C), 140.5 (quaternary C), 138.5 (quaternary C), 137.5 (quaternary C), 134.0 (CH), 131.4, 123.3 (CH), 92.7, 92.5, 61.7 (CH₂), 61.5 (CH₂) (C—F signals were detected as very weak multiplets at d 145.0, 142.5, 136.4, 113.4 and are not certain). HRMS (EI) analysis calculated for C₄₂H₂₀F₁₀O₁₀S₄ 1001.9780; found 1001.9772.

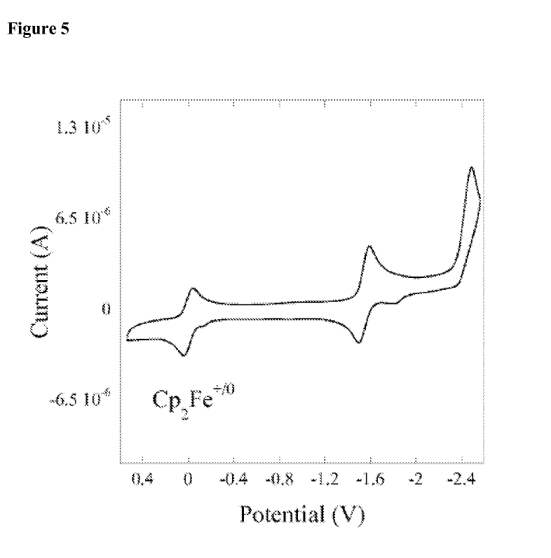

Cyclic voltammetry was performed on the resulting compound and the results are shown in FIG. 5. The cyclic voltammogram (0.1 M ⁿBu₄NPF₆ in THF, Cp₂Fe internal standard at 0 V, 50 mV·s¹ rate) showed: E_{1/2}^{0/1-}=−1.54 V (reversible), E_{1/2}^{0/1-}=−2.42 V (not reversible, large error).

Step 3.

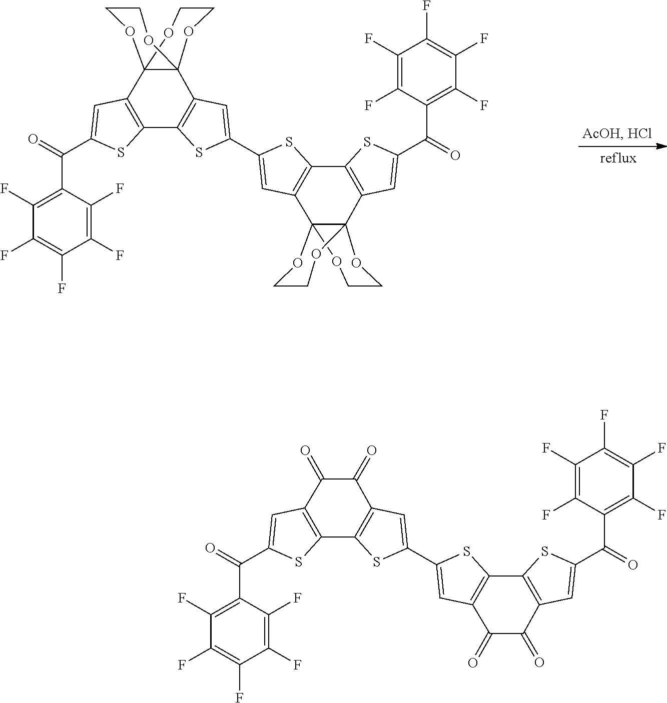 [SMILES: O=C(c1cc2c(s1)-c1sc(-c3cc4c(s3)-c3sc(C(=O)c5c(F)c(F)c(F)c(F)c5F)cc3C35OCCOC43OCCO5)cc1C13OCCOC21OCCO3)c1c(F)c(F)c(F)c(F)c1F ; O=C1C(=O)c2cc(-c3cc4c(s3)-c3sc(C(=O)c5c(F)c(F)c(F)c(F)c5F)cc3C(=O)C4=O)sc2-c2sc(C(=O)c3c(F)c(F)c(F)c(F)c3F)cc21]

7,7′-Bis-pentafluorobenzoyl-2,2′-bis-benzo[1,2-b:6,5-b′]dithiophene-4,5-bis(ethyleneoxolane) (0.083 mmol, 0.083 mg) was mixed with acetic acid (˜40 mL) and the mixture was heated to reflux. HCl (˜3 mL) was added to an orange-red solution and the mixture became dark brown within a few minutes. The reaction mixture was refluxed for ˜1 h, cooled to room temperature and a very dark solid was separated by vacuum filtration, washed with water, ethanol and dried (0.043 g, 63.2% crude yield). Not soluble in CHCl₃, CH₂Cl₂, acetonitrile; 1,4-dioxane and THF become purple-pink; material can be recrystallized from 1,1,2,2-tetrachloroethane. Recording of ¹H NMR (THF-d8, 400 MHz) was attempted, but the sample is not sufficiently soluble even under heating. HRMS (EI) C₃₄H₄F₁₀O₆S₄ 825.8731; found 825.8736 (M+2 (828) was observed as a minor ion). Anal. Calc. for C₃₄H₄F₁₀O₆S₄: C, 49.74; H, 0.78. Found: C, 49.47; H, 0.77.

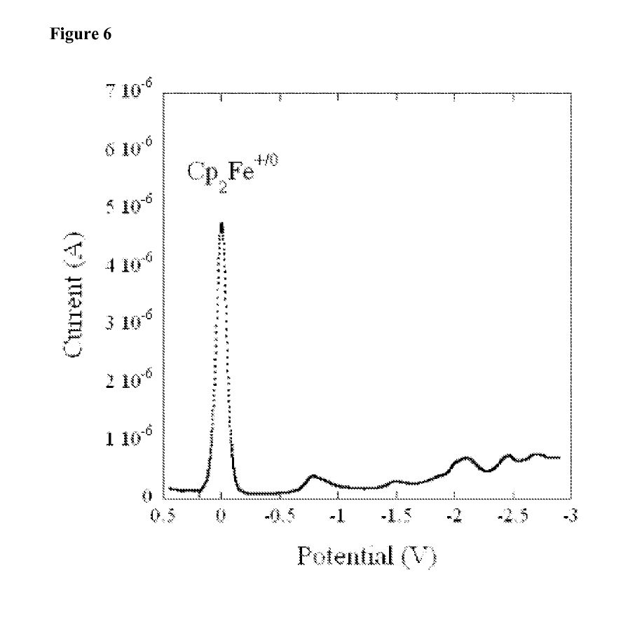

Differential pulse voltammetry was performed on the resulting compounds and the results are shown in FIG. 6. The differential pulse voltammetry (DPV) (0.1 M ⁿBu₄NPF₆ in THF, Cp₂Fe internal standard at 0 V) showed: E^{0/-2}=−0.79 V (2 e⁻), E^{-2/-3}=−1.50 V (1.3 e⁻), E^{-3/-5(?)}=−2.10 V (4.8 e⁻), E^{-5/-7(?)}=−2.47 V (2.6 e⁻).

### Example 34

### Preparation of asymmetrical 2-(5-pentafluorobenzoyl-thiophene-2-yl)-7-(thiophene-2-yl)-benzo[1,2-b:6,5-b′]dithiophene-4,5-dione

Step 1.

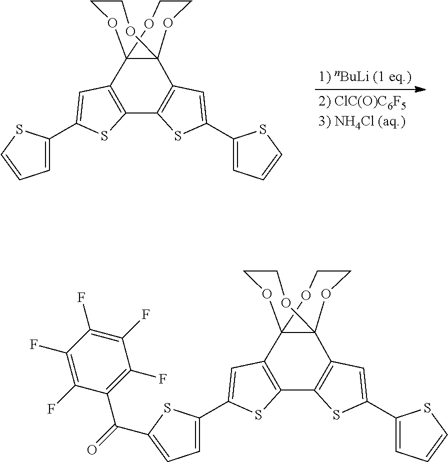 [SMILES: c1csc(-c2cc3c(s2)-c2sc(-c4cccs4)cc2C24OCCOC32OCCO4)c1 ; O=C(c1ccc(-c2cc3c(s2)-c2sc(-c4cccs4)cc2C24OCCOC32OCCO4)s1)c1c(F)c(F)c(F)c(F)c1F]

2,7-Bis-(thiophen-2-yl)-benzo[1,2-b:6,5-b′]dithiophene-4,5-bis(ethyleneoxolane) (1.0 mmol, 0.473 g) was dissolved in 50 mL of anhydrous THF under nitrogen atmosphere and yellow solution was cooled in acetone/dry ice bath. n-Butyllithium (2.85 M in hexanes, 1.0 eq., 1.0 mmol, 0.35 mL) was added dropwise and reaction mixture became dark orange. After stirring for 25 minutes pentafluorobenzoyl chloride (1.5 eq., 1.5 mmol, 0.35 g) was added, the mixture was stirred for about 1 h and allowed to warm to room temperature. Dark orange cloudy mixture was treated with aqueous NH₄Cl and bright orange-red organic phase was separated. Aqueous phase was extracted with dichloromethane and combined organic phases were dried over MgSO₄. The drying agent was filtered off, the solvents were removed by rotary evaporation and the residue (dark red-orange solid) was purified by column chromatography (150 mL of silica gel, CH₂Cl₂:hexanes (3:1) to elute unreacted starting material, CH₂Cl₂ to elute the product and di-substituted byproduct). Unreacted starting material, 2,7-bis-(thiophen-2-yl)-benzo[1,2-b:6,5-b′]dithiophene-4,5-bis(ethyleneoxolane), was recovered (0.062 g, 13.1% recovery). Desired product, 2-(5-pentafluorobenzoyl-thiophen-2-yl)-7-(thiophen-2-yl)-benzo[1,2-b:6,5-b′]dithiophene-4,5-bis(ethyleneoxolane), was obtained as red solid (0.237 g, 35.5%). Di-substituted material, 2,7-bis-(5-pentafluorobenzoyl-thiophen-2-yl)-benzo[1,2-b:6,5-b′]dithiophene-4,5-bis(ethyleneoxolane) was also isolated (0.195 g, 25.2% yield).

¹H NMR (CDCl₃, 400 MHz): δ 7.49 (s, 1H), 7.41 (d, J=3.6 Hz, 1H), 7.32-7.25 (m, 2H; overlaps with residual CHCl₃), 7.21 (m, 2H), 7.05 (m, 1H), 4.22 (m, 4H), 3.78 (m, 4H) (this material contained dichloromethane (d 5.31, 0.81H) and it should be recrystallized to obtain a sample for elemental analysis). DEPT-135 (CDCl₃, 100 MHz): δ 137.0 (CH), 128.1 (CH), 125.4 (CH), 124.8 (CH), 124.5 (CH), 124.4 (CH), 121.8 (CH), 61.8 (CH₂), 61.7 (CH₂). HRMS (EI) calculated for C₂₉H₁₅F₅O₅S₄ 665.9722; found 665.9727.

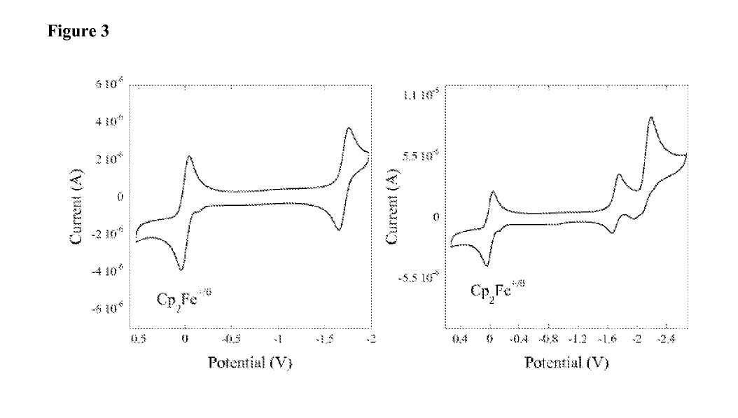

The Compound was measured by cyclic voltammetry as shown in FIG. 3. The Cyclic voltammogram (0.1 M ⁿBu₄NPF₆ in THF, Cp₂Fe internal standard at 0 V, 50 mV·s⁻¹ rate) of 2-(5-pentafluorobenzoyl-thiophen-2-yl)-7-(thiophen-2-yl)-benzo[2,1-b:3,4-b′]dithiophene-4,5-bis(ethyleneoxolane) showed: E_{1/2}^{0/1-}=−1.71 V, E_{1/2}^{1-/2-}=−2.14 V (partially reversible).

Step 2.

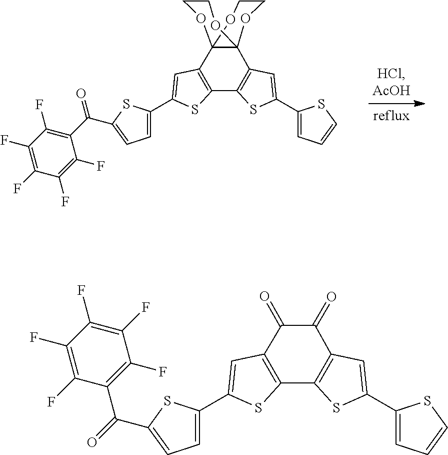 [SMILES: O=C(c1ccc(-c2cc3c(s2)-c2sc(-c4cccs4)cc2C24OCCOC32OCCO4)s1)c1c(F)c(F)c(F)c(F)c1F ; O=C1C(=O)c2cc(-c3ccc(C(=O)c4c(F)c(F)c(F)c(F)c4F)s3)sc2-c2sc(-c3cccs3)cc21]

2-(5-Pentafluorobenzoyl-thiophen-2-yl)-7-(thiophen-2-yl)-benzo[1,2-b:6,5-b′]dithiophene-4,5-bis(ethyleneoxolane) (0.15 mmol, 0.100 g) was mixed with acetic acid (40 mL) and the resulting mixture was heated to reflux. HCl (3 mL) was added and the red solution became dark in color. The reaction mixture was refluxed for ˜1 h, cooled to room temperature and treated with water. Dark solid was separated by vacuum filtration, washed with water and ethanol and dried (0.126 g). This crude material was purified by column chromatography (150 mL of silica gel, CH₂Cl₂, then CH₂Cl₂:EtOAc (50:1) as eluants). Fractions with product were combined, the solvents were removed by rotary evaporation and the residue was heated to reflux with 2-propanol, cooled to room temperature and solid was separated by vacuum filtration (81 mg, 93% yield).

¹H NMR (CDCl₃, 400 MHz): δ 7.44 (s, 1H), 7.57 (s, 1H), 7.47 (m, 1H), 7.38 (m, 1H), 7.33-7.25 (m, 2H; overlaps with residual CHCl₃), 7.10 (m, 1H); ¹³C{¹H} NMR (CDCl₃, 100 MHz) was not recorded due to poor solubility of the material in CDCl₃. HRMS (EI) calculated for C₂₅H₇F₅O₃S₄ 577.9198; found 577.9217 (M+2 ion was also observed in almost 1:1 intensity ratio with respect to molecular ion). Anal. Calc. for C₂₅H₇F₅O₃S₄: C, 51.90; H, 1.22. Found: C, 51.96; H, 1.14.

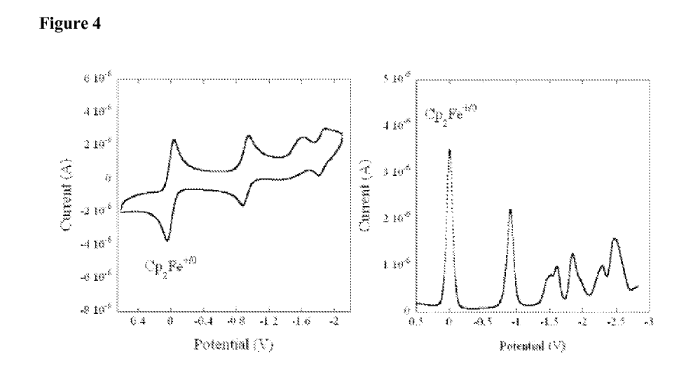

The resulting compound was measured with cyclic voltammetry and DPV as shown in FIG. 4. The Cyclic voltammogram (0.1 M ⁿBu₄NPF₆ in THF, Cp₂Fe internal standard at 0 V, 50 mV·s⁻¹ rate) showed: E_{1/2}^{0/-1}=−0.92 V (rev.); E_{1/2}^{-1/-2}=−1.63 V (partially rev.); E_{1/2}^{-2/-3(?)}=−1.86 V (rev.); E_{1/2}^{-3/-4 (?)}=−2.15 V (partially rev). The differential pulse voltammetry (DPV) (0.1 M ⁿBu₄NPF₆ in THF, Cp₂Fe internal standard at 0 V) showed: E^{0/-1}=−0.92 V (1e⁻); E^{-1/-2}=−1.62 V (0.8 e⁻); E^{-2/-3(?)}=−1.85 V (0.8 e⁻); E^{-3/-4(?)}=−2.30 V (0.6 e⁻); E^{-4/-5(?)}=−2.48 V (1.2 e⁻).

Additionally, TGA analysis was conducted on the resulting compound resulting in an onset at 367.7° C., (99% at 321.9° C. and 90% at 407.3° C.); TGA analysis (5° C./min heating rate) of 2-(5-pentafluorobenzoyl-thiophen-2-yl)-7-(thiophene-2-yl)-benzo[2,1-b:3,4-b′]dithiophene-4,5-dione: T_{d}=379° C. (5% mass loss). Finally, DSC analysis was conducted on the resulting compound (10° C./min heating-cooling rate) of 2-(5-pentafluorobenzoyl-thiophen-2-yl)-7-(thiophene-2-yl)-benzo[2,1-b:3,4-b′]dithiophene-4,5-dione: m.p. 286.4° C.

### Example 35

### Synthesis of Non-Aryl Compound with Heterarylene Spacer Groups

Step 1.

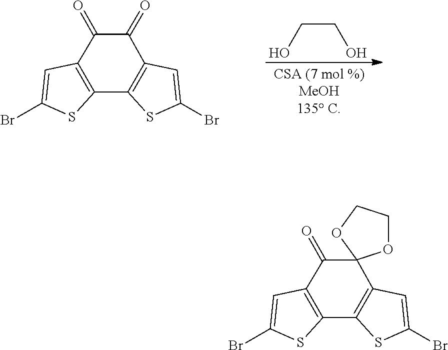

2,7-Dibromo-benzo[1,2-b:6,5-b′]dithiophene-4,5-dione (0.50 mmol, 0.19 g) was mixed with ethylene glycol (20 ml), MeOH (5 ml) and 10-camphorsulfonic acid (0.07 mol %, 0.035 mmol, 8.0 mg). The reaction mixture was heated to a vigorous reflux (145-155° C. bath temperature) for 7.5 h, cooled to room temperature and treated with MeOH. Hexanes was added and the mixture was vigorously stirred for ˜20 minutes. The organic phase contained some insoluble dark solid and was diluted with dichloromethane. The organic phase was separated, the aqueous phase was extracted with hexanes, and combined organic phases were dried over MgSO₄. The solvents were removed by rotary evaporation and the residue (reddish-brownish solid) was purified by column chromatography (100 ml of silica gel, hexanes:CH₂Cl₂ (3:2). The solvents were removed from combined fractions and yellow solid was recrystallized from 2-PrOH to give bright yellow fluffy needles (0.090 g, 42.6% yield).

HRMS (EI) calculated for C₁₂H₆Br₂O₃S₂ 419.8125; found 419.8134. ¹H NMR (CDCl₃, 400 MHz): δ7.35 (s, 1H), 7.13 (s, 1H), 4.47 (m, 2H), 4.31 (m, 2H); ¹³C{¹H} NMR (CDCl₃, 100 MHz): δ 189.03 (quaternary C(O)), 144.91 (quaternary C), 139.47 (quaternary C), 132.44 (quaternary C), 131.71 (quaternary C), 130.31 (CH), 128.21 (CH), 114.28 (quaternary C—Br), 111.61 (quaternary C—Br), 98.68 (quaternary C), 66.17 (CH₂) (assignment of the quaternary, CH, CH₂ and CH₃ signals was made based on the DEPT experiment). Anal. Calcd. for C₁₂H₆Br₂O₃S₂: C, C, 34.14; H, 1.43. Found: C, 34.38; H, 1.32

Step 2.

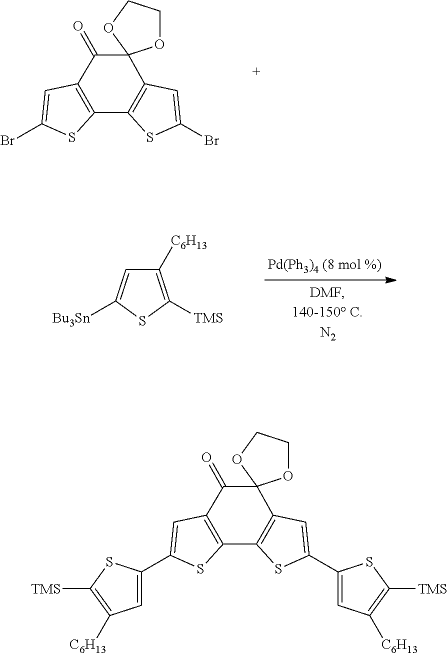

Aryl dibromide (0.10 mmol, 0.042 g) was mixed with 2-trimethylsilyl-3-n-hexyl-5-tri-n-butylstannylthiophene (2.1 eq., 0.21 mmol, 0.11 g) were mixed in the oven-dried two-neck flask equipped with magnetic stirbar, nitrogen inlet and septum. Catalyst Pd(PPh₃)₄ (0.08 mol %, 0.008 mmol, 1.8 mg) and anhydrous DMF (10 ml) were added and the bright yellow solution was heated up to 140-150° C. (bath temperature). At 125° C. the reaction mixture became orange, and then at 140° C. the color changed to orange-red. The mixture was stirred for 30 minutes and TLC analysis (CH₂Cl₂) as eluant showed complete consumption of the starting dibromide and a presence of less polar red product. The reaction mixture was cooled to room temperature, treated with water and organic matter was extracted with Et₂O (30 ml, then 3×˜20 ml). Bright red-orange fluorescent organic phases were dried over MgSO₄ and the solvent was removed by rotary evaporation to give the crude product as thick red oil. This material was purified by column chromatography (30 ml of silica gel, Hexanes:CH₂Cl₂ (2:1) as eluant. Fractions 2-6 were combined, the solvents were removed by rotary evaporation and dark bright red oil was obtained (0.029 g). Fractions 7-12 were combined separately and additional amount of product was obtained 0.041 g, red oil which solidified on standing).

HRMS (EI) calculated for C₃₈H₅₂O₃S₄Si₂ 740.2338; found 740.2336. ¹H NMR (CDCl₃, 400 MHz): δ 7.40 (s, 1H), 7.21 (s, 1H), 7.16 (s, 1H), 7.14 (s, 1H), 4.52 (m, 2H), 4.36 (m, 2H), 2.63 (t, J=7.94 Hz, 4H), 1.45-1.25 (m, 12H), 0.95-0.80 (m, 6H), 0.36 (s, 18H); ¹³C {¹H} NMR (CDCl₃, 100 MHz): δ 190.67 (quaternary C(O)), 151.42 (quaternary C), 151.39 (quaternary C), 143.39 (quaternary C), 140.05 (quaternary C), 139.56 (quaternary C), 139.13 (quaternary C), 138.43 (quaternary C), 135.70 (quaternary C), 134.20 (quaternary C), 132.09 (quaternary C), 130.06 (quaternary C), 127.95 (CH), 127.86 (CH), 123.43 (CH), 120.99 (CH), 99.37 (quaternary C), 66.14 (CH₂), 31.72 (CH₂), 31.65 (CH₂), 31.41 (CH₂), 29.37 (CH₂), 22.60 (CH₂), 14.08 (CH₃), 0.28 (CH₃) (one quaternary C is missing presumable due to overlap; assignment of the quaternary, CH, CH₂ and CH₃ signals was made based on the DEPT experiment). HRMS (EI) calculated for C₃₈H₅₂O₃S₄Si₂ 740.2338, found 740.2336. Anal. Calcd. for C₃₈H₅₂O₃S₄Si₂: C, 61.57; H, 7.07. Found: C, 61.41; H, 7.20.

Step 3

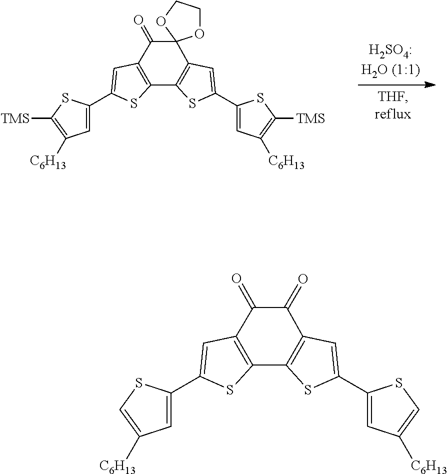

Protected ketone derivative (1.09 mmol, 0.807 g) was dissolved in 30 ml of THF and H₂SO₄ (2 ml, 1:1 volume ratio) was added. The orange fluorescent reaction mixture was heated to reflux and it became dark orange-brown. After reflux for 1.5 h the starting material was still detectable by TLC and additional amount of H₂SO₄:H₂O (1 ml: 1 ml) was added. The mixture was refluxed for additional 7 hours, and dark blue solution was cooled to room temperature. TLC analysis (hexanes:CHCl₃ (1:1) as eluant) showed complete consumption of the starting material. The mixture was treated with water (product precipitated out) and organic matter was extracted with diethyl ether several times. Combined organic phases were dried over MgSO₄, filtered and subjected to rotary evaporation. The crude product obtained as dark blue solid (0.5 g and a bit on the sides of the flask) was purified by column chromatography (100 ml of silica gel, hexanes:CH₂Cl₂ (1:1) as eluant). Trace amount of unreacted starting material (less polar) was removed, and blue fractions with desired product were subjected to rotary evaporation and the residue was recrystallized from −150 ml of 2-PrOH. Purified material was obtained ad black-blue solid (0.44 g, 73.1% yield).

¹H NMR (CDCl₃, 400 MHz): δ7.44 (s, 2H), 7.05 (s, 2H), 6.91 (s, 2H), 2.59 (t, J=7.67 Hz, 4H), 1.61 (m, 4H), 1.40-1.23 (m, 12H), 0.91 (t, J=6.53 Hz, 6H); ¹³C{¹H} NMR (CDCl₃, 100 MHz): 6174.2 (quaternary C(O)), 144.7 (quaternary C), 141.4 (quaternary C), 138.4 (quaternary C), 135.7 (quaternary C), 134.5 (quaternary C), 126.7 (CH), 122.4 (CH), 121.2 (CH), 31.7 (CH₂), 30.4 (CH₂), 30.33 (CH₂), 29.0 (CH₂), 22.62 (CH₂), 14.12 (CH₃) (assignment of the carbon signals was made based on the DEPT experiment). HRMS (EI) calculated for C₃₀H₃₂O₂S₄ 552.1285; found 552.1263. Anal. calc. for C₃₀H₃₂O₂S₄: C, 65.18; H, 5.83. Found: C, 65.38; H, 5.80.

### Example 36

### Preparation of asymmetric 2-pentafluorobenzoyl-7-(2-n-nonylthiophen-2-yl)-benzo[1,2-b:6,5-b′]dithiophene-4,5-dione

Step 1

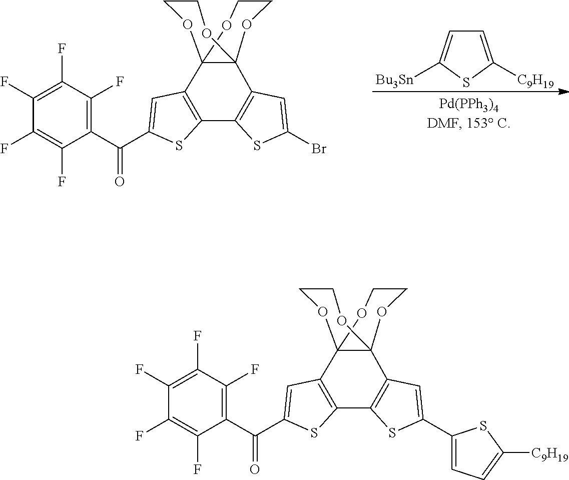

2-Bromo-7-pentafluorobenzoyl-bis-benzo[2,1-b:3,4-b′]dithiophene-4,5-bis(ethyleneoxolane) (1.0 mmol, 0.58 g; ˜80% purity, contains 2,7-dibromo-benzo[2,1-b:3,4-b′]dithiophene-4,5-bis(ethyleneoxolane) and 2,7-bis-pentafluorobenzoyl-benzo[2,1-b:3,4-b]dithiophene-4,5-bis(ethyleneoxolane)) and 2-tri-n-butylstannyl-5-n-nonylthiophene (1.05 eq., 1.05 mmol, 0.52 g) were mixed in the oven-dried flask under nitrogen atmosphere. Catalyst Pd(PPh₃)₄ (0.05 mol %, 0.05 mmol, 0.06 g) was added followed by addition of anhydrous DMF (10 mL) and the reaction mixture was heated for a few minutes at reflux. Yellow mixture became orange, then orange-red and then dark brown within. Dark reaction mixture was allowed to cool to room temperature, treated with water and organic matter was extracted with CH₂Cl₂. Combined organic phases were dried over MgSO₄ and volatile organic solvent were removed by rotary evaporation. The residue was purified by column chromatography (150 mL of silica gel, hexanes:dichloromethane (1:1) to pack the column, then hexanes:dichloromethane mixture (2:1, 1:1, 1:2) for elution). Yellow fractions (fluorescent) containing the product were combined, the solvents were removed and orange solid was obtained (0.51 g, 71.8%).

¹H NMR (CDCl₃, 400 MHz): δ7.50 (s, 1H), 7.23 (s, 1H), 7.10 (d, J=3.6 Hz, 1H), 6.73 (d, J=3.6 Hz, 1H), 4.18 (m, 4H), 3.72 (m, 4H), 2.82 (t, J=7.6 Hz, 2H), 1.80-1.50 (overlapping multiplets, 4H), 1.45-1.20 (m, 10H), 0.93 (t, J=7.3 Hz, 3H) (this material contains up to 20% impurity). HRMS calculated for C₃₄H₃₁F₅O₅S₃ 710.1254; found 710.1243. (This material should be further purified and submitted for elemental analysis).

Step 2.

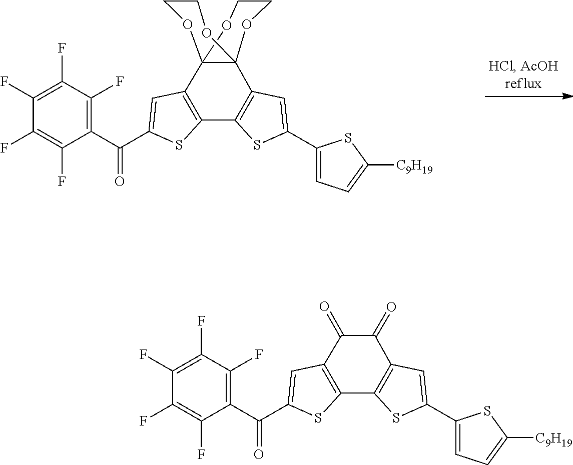

2-Pentafluorobenzoyl-7-(5-n-nonyl-thiophene-2-yl)-benzo[1,2-b:6,5-b′]dithiophene-4,5-bis-(ethyloxolane) (35) (˜0.6 mmol, 0.42 g, ˜80% purity) was heated to reflux with acetic acid (40 mL). HCl was added dropwise, and the reaction mixture became dark brown. After reflux for ˜0.5 h the reaction mixture was cooled to room temperature, treated with water, and dark solid was separated by vacuum filtration, washed with water and ethanol (some precipitate started to form in the filtrate). Crude product was obtained as dark solid (0.22 g, 60% yield). Solid that formed in the filtrate was separated by vacuum filtration, combined with the crude product, and purified by column chromatography (silica gel, dichloromethane as eluant). Fractions with material (almost pure, trace amount of impurity was detected by TLC) were combined, the solvent was removed by rotary evaporation, and the residue was further purified by column chromatography (silica gel, chloroform as eluant). Less polar yellow impurity and more polar orange impurity were separated, and fractions with the product (blue-green, pure by TLC analysis) were combined, the solvents were removed, and the residue was purified by another column chromatography (silica gel, chloroform as eluant). Green-blue fractions were combined, the solvent was removed, and the residue was heated with ˜100 mL of distilled 2-propanol (partially dissolved), cooled and blue-dark solid was separated by vacuum filtration (0.197 g, 53.5%). ¹H NMR analysis showed the presence of impurity (not detected by TLC), even after purification by successive chromatographic columns, and material was further purified by two successive silica gel columns (chloroform as eluant for the first column and dichloromethane as eluant for the second column). ¹H NMR (CDCl₃, 400 MHz): δ 7.77 (s, 1H), 7.52 (s, 1H), 7.16 (d, J=3.6 Hz, 1H), 6.77 (d, J=3.6 Hz, 1H), 2.84 (t, J=7.6 Hz, 2H), 1.70 (m, 2H), 1.50-1.20 (m, 12H), 0.90 (t, J=6.9 Hz, 3H); ¹³C{¹H} NMR (CDCl₃, 100 MHz): δ 176.3, 173.9, 173.6, 151.8, 149.6, 142.6, 141.2, 138.3, 138.2, 134.9 (CH), 134.7, 131.6, 126.4 (CH), 125.6 (CH), 122.3 (CH), 31.9 (CH₂), 31.5 (CH₂), 30.3 (CH₂), 29.5 (CH₂), 29.3 (CH₂), 29.27 (CH₂), 29.02 (CH₂), 22.7 (CH₂), 14.1 (CH₃). HRMS (EI) calculated for C₃₀H₂₃F₅O₃S₃ 622.0729, found 622.0742. Anal. Calcd. for C₃₀H₂₃F₅O₃S₃: C, 57.87; H, 3.72. Found: C, 58.13; H, 3.67.

### Example 37

### Prophetic

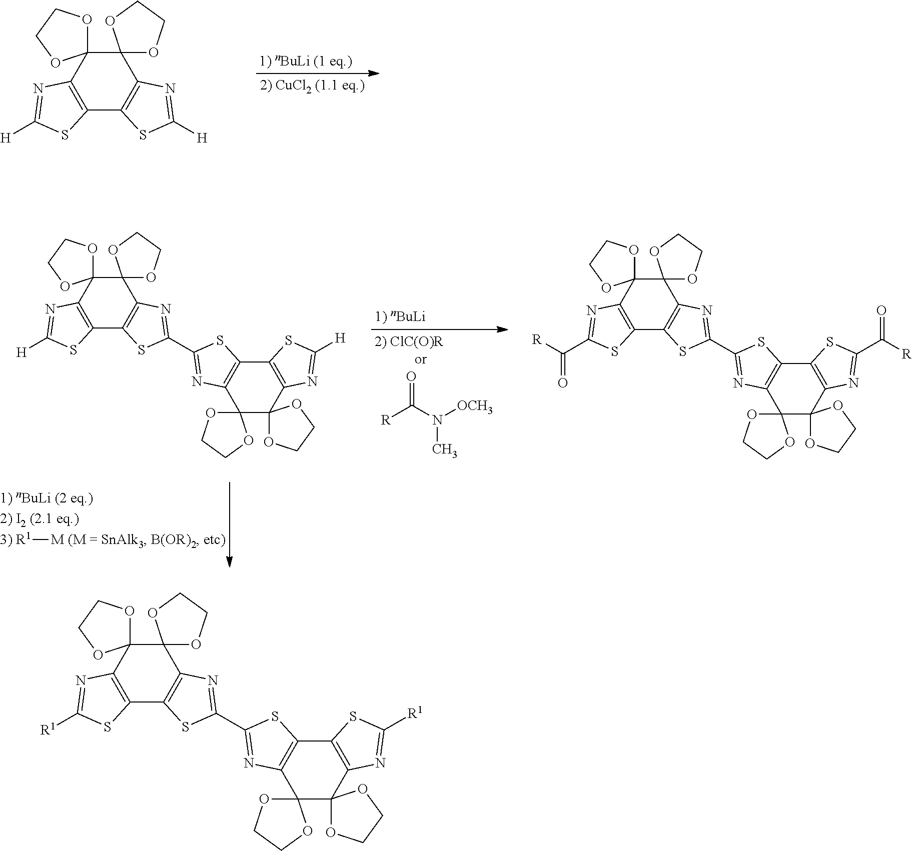

Scheme 4. Synthetic approach towards materials with bis(benzodithiazole-4,5-dione) core.

### Example 38

### Secondary Synthetic Route to Heteroarylene Compounds

Step 1.

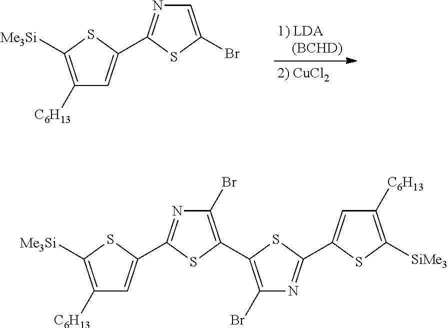

Lithium diisopropylamide (LDA) (2.2 eq., 0.37 M, 6 ml) was prepared from diisopropylamine (2.4 mmol, 0.24 g), n-BuLi (2.5 M in hexanes, 2.2 mmol, 0.9 ml) and 5 ml of anhydrous THF.

2-(5-Trimethylsilyl-3-n-hexyl-thiophen-2-yl)-5-bromothiazole (1.0 mmol, 0.40 g) was dissolved in 20 ml of anhydrous THF and the yellowish solution was cooled in acetone/CO₂ bath (nitrogen atmosphere). Freshly prepared LDA (0.37 M in THF, 1.1 eq., 3 ml) was added dropwise to the bromothiazole derivative and the reaction mixture became light purple in color. The reaction mixture was stirred for 20 minutes and a small aliquot was treated with hexanes:MeOH, organic solvents were removed and the residue was analyzed by GC/MS analysis (file YG4-078b.D) and ¹H NMR. Resulting ¹H NMR spectra confirmed halogen dance.

The completion of the BCHD reaction was confirmed and CuCl₂ (1.1 eq., 0.148 g) was added in one portion to the purple reaction mixture. After stirring for 5 minutes the color changed to yellowish-green and the mixture was slowly warmed to room temperature without cooling bath removal. Hexanes and water were added, the organic phase was removed and the aqueous phase was extracted with Et₂O (3×15-20 ml). The combined organic phases were dried over MgSO₄ and the solvents were removed by rotary evaporation to give crude product as dark yellow solid. This crude product was purified by column chromatography (50 ml of silica gel, hexanes:CH₂Cl₂ (3:2) and bright yellow-orange solid was obtained (0.27 g). Minor impurities were detected by the TLC analysis and material was further purified by the column chromatography (100 ml of silica gel, Hexanes:CH₂Cl₂ (35:15). The solvents were removed from combined fractions and product was obtained as yellow-orange oil which solidified on standing. ¹H NMR (CDCl₃, 400 MHz): δ 7.53 (s, 2H), 2.66 (t, J=8.0 Hz, 4H), 1.62 (m, 4H), 1.45-1.30 (m, 12H) 0.98 (t, J=6.9 Hz, 6H), 0.38 (s, 18H); ¹³C{¹H} NMR (CDCl₃, 100 MHz): δ 162.1 (quaternary C), 151.4 (quaternary C), 139.0 (quaternary C), 138.5 (quaternary C), 130.5 (CH), 127.6 (quaternary C), 121.0 (quaternary C), 31.7 (CH₂), 31.6 (CH₂), 31.3 (CH₂), 29.3 (CH₂), 22.6 (CH₂), 14.1 (CH₃), 0.14 (CH₃) (assignment of the quaternary, CH, CH₂ and CH₃ signals was made based on the DEPT experiment). HRMS (EI) calculated for C₃₂H₄₆Br₂N₂S₄Si₂ 800.0449; found 800.0420. Anal. Calc. for C₃₂H₄₆Br₂N₂S₄Si₂: C, 47.87; H, 5.77; N, 3.49. Found: 47.72; H, 5.77; N, 3.47.

Step 2.

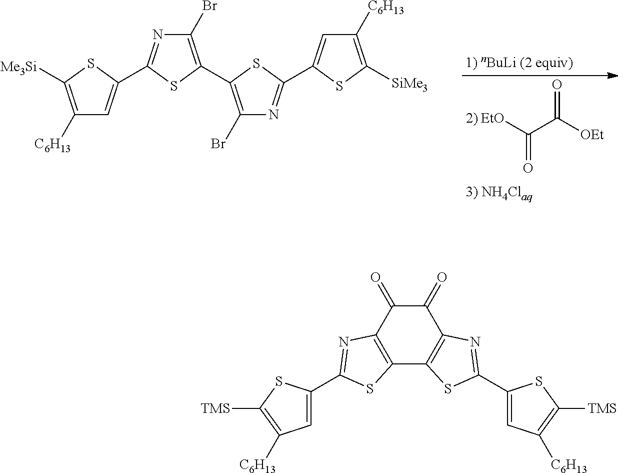

4,4′-Dibromo-2,2′-bis(4-hexyl-5-trimethylsilyl-thiophen-2-yl)-5,5′-bithiazole (0.5 mmol, 0.401 g) was dissolved in 30 mL of anhydrous THF under nitrogen atmosphere and the resulting bright yellow solution was cooled in acetone/dry ice bath. n-Butyllithium (2.85 M in hexanes, 1.0 mmol, 0.35 mL) was added dropwise, and reaction mixture became orange-red. After stirring for 0.5 h this solution was transferred via cannula into a solution of diethyl oxalate (1.2 eq., 0.6 mmol, 0.09 g) in 50 mL of anhydrous THF cooled in acetone/dry ice bath. Very dark red-orange solution became yellow-red-brownish. After stirring for 1 h only trace amount of the desired product was detected by TLC analysis and the mixture was allowed to warm to 0° C. After stirring for 3 hours additional amount of diethyl oxalate (0.2 mL) was added and the mixture was left to stir overnight. The reaction mixture was treated with aqueous NH₄Cl, dark brown organic phase was separated and the aqueous phase was extracted with dichloromethane. Combined organic phases were dried over MgSO₄, the organic solvents were removed by rotary evaporation and the residue was purified by column chromatography (100 mL of silica gel, CH₂Cl₂:EtOAc (30:1, 20:1, 10:1). All blue or green fractions were combined, the solvents were removed and the product (still impure) was obtained as green-blue film (˜50 mg). This material was further purified by column chromatography (˜50 mL of silica gel, CH₂Cl₂ as eluant). Fractions with material (blue in color) were combined, the solvent was removed by rotary evaporation and the product was obtained as blue-green film (˜30 mg, <10% yield).

¹H NMR (CDCl₃, 400 MHz): δ7.59 (s, 2H), 2.65 (t, J=8.0 Hz, 4H), 1.61 (m, 4H), 1.42-1.30 (m, 12H), 0.93, (t, J=6.6 Hz, 6H), 0.38 (s, 18H); ¹³C{¹H} NMR (CDCl3, 100 MHz): δ 172.5, 162.0, 151.6, 147.9, 140.9, 137.8, 136.8, 132.0 (CH), 31.7 (CH2), 31.6 (CH2), 31.3 (CH2), 29.3 (CH2), 22.6 (CH2), 14.1 (CH3), 0.1 (CH3). HRMS (EI) calculated for C₃₄H₄₆N₂O₂S₄Si₂ 698.1981. Found: 698.1970. (M+2 ion was also observed as a major ion: calculated for C₃₄H₄₈N₂O₂Si₂S₄ 700.2137; found 700.2090). Anal. Calc. for C₃₄H₄₆N₂O₂S₄Si₂: C, 58.41; H, 6.63; N, 4.01. Found: 58.50; H, 6.64; N, 4.11.

### Example 39

In addition, electrochemical analysis was carried out and the results provided below:

TABLE 2-1
Summary of electrochemical analyses of 2,7-bis-aroyl-benzo[1,2-b:6,5-B′]dithiophene-4,5-diones.

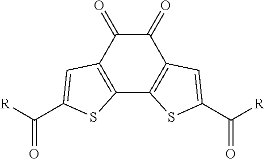

| | | | | E_{1/2}^{0/1-}, V vs | T_{d}, ° C. (5% | |
|---|---|---|---|---|---|---|
| R | E_{1/2}^{0/1-}, V¹ | E_{1/2}^{1-/2-}, V | E_{1/2}^{2-/3-}, V | SCE | weight loss) | m.p., ° C. |
| 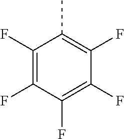 | −0.72 | −1.31 | −1.77 | −0.16 | 324 | 275.2 |
| 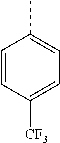 | −0.79 | −1.43 | −1.88 | −0.23 | 344 | 295.2 |
| 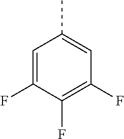 | −0.76 | −1.37 | −1.87 | −0.20 | TBD | 311.8 |
| 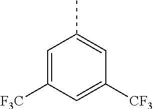 | −0.76 | −1.38 | −2.01 | −0.20 | ~320 | 203.9 |

¹Reduction potentials were determined by cyclic voltammetry in 0.1 M ⁿBu₄NPF₆ in THF using Cp₂Fe^{0/1+} internal standard at 0 V with 50 mV · s⁻¹ scan rate.

TABLE 2-2
Summary of electrochemical analyses of 2,7-bis(aroyl)-benzo-dithiazole-4,5-(1,3-
dioxolane)s and 2,7-bis(aroyl)-benzo-dithiophene-4,5-diones protected at α-dicabonyl
bridge.

| | R bonded covalently | | |
|---|---|---|---|
| | to acyl (through | | |
| Core | dashed lines) | E_{1/2}^{0/1-}, V¹ | E_{1/2}^{1-/2-}, V |
| 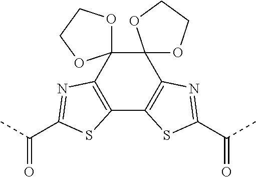 | 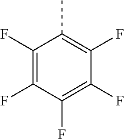 | −1.09 | −1.43 |
| 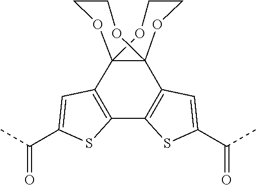 | | −1.33 | −1.65 |
| 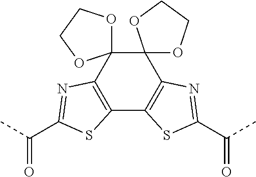 | 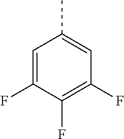 | −1.19 | −1.31 |
| 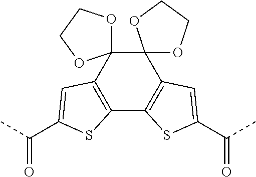 | | −1.50 | −1.72 |
| 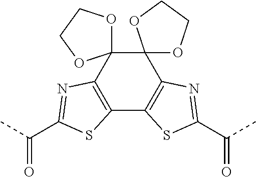 | 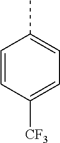 | −1.26 | −1.50 |
| 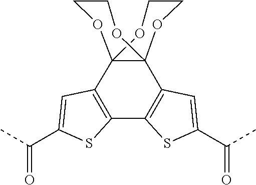 | | −1.52 | −1.76 |
| 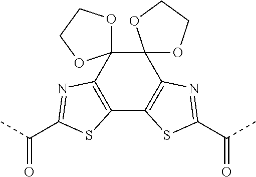 | 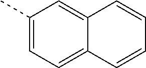 | −1.36 | −1.60 |
| 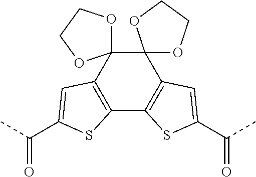 | | −1.64 | −1.85 |

### Example 40

### Device Fabrication and Characterization of OFETs

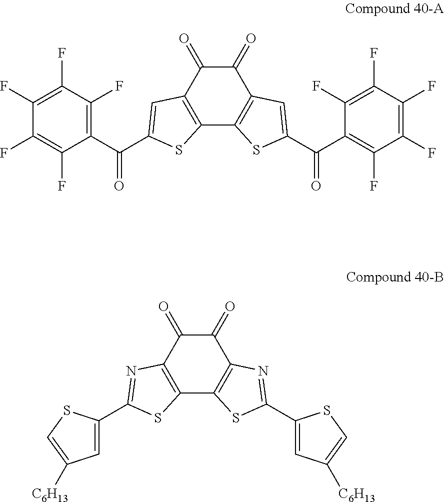

OFETs were fabricated on heavily n-doped silicon substrates (n⁺-Si, as the gate electrode) with 200-nm-thick thermally grown SiO₂ as the gate dielectric. Prior to surface modification, the substrates were treated by O₂ plasma for 3 minutes, to change the surface property of SiO₂ towards hydrophilic. SiO₂ dielectric surface was then coated with a thin buffer layer of BCB (Cyclotene™, Dow Chemicals), to provide a high-quality hydroxyl-free interface. The BCB was diluted in trimethylbenzene (TMB) with the ratio 1:20, and spin coated at 3000 rpm for 60 seconds to provide a very thin uniform layer (thickness was not measured, final capacitance density was measured). The samples were cross-linked at 250° C. on a hot plate for 1 h in a N₂-filled glovebox. The total capacitance density (Cᵢ) measured from parallel-plate capacitors was 15.0 nF/cm². Organic semiconductor layers were formed on the substrates by thermal evaporation for acyl compound 40-A and spin coating for dithiazole compound 40-B with a solution prepared in chlorobenzene (14 mg/mL) at 500 rpm for 10 sec and at 2,000 rpm for 20 sec. Finally, Ca/Au source/drain electrodes were deposited by thermal evaporation through a shadow mask. The transistor channel width W was 1200 μm and the channel length L was 100 μm. Devices were never exposed to normal ambient during fabrication and testing.

All current-voltage (I-V) and capacitance-voltage (C-V) characteristics were measured in a N₂-filled glove box (O₂, H₂O<0.1 ppm) in the dark with an Agilent E5272A source/monitor unit and an Agilent 4284A LCR meter.

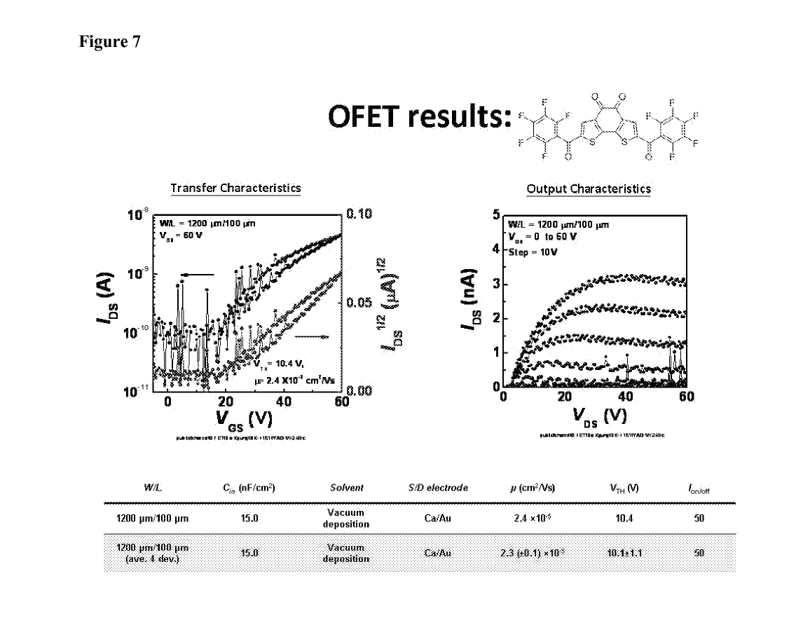

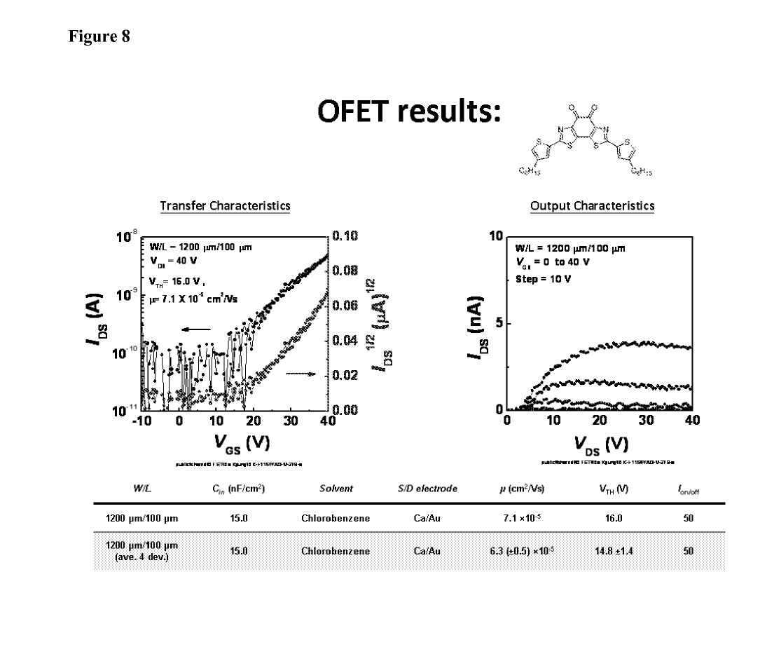

The resulting measurements for the compound 40-A are shown in FIG. 7. The results for the compound 40-B are shown in FIG. 8.

### Example 41

### Additional FET Testing

Additional FET testing was carried out with the following procedure using a modified device structure:

OFETs with bottom contact and top gate structure were fabricated on glass substrates (Eagle 2000 Corning). Au (50 nm) bottom contact source/drain electrodes were deposited by thermal evaporation through a shadow mask. Organic semiconductor layers were formed on the substrates by spin coating with a solution prepared from chlorobenzene (30 mg/mL of selenium compound 41-A and 15 mg/mL of compound 41-B) and dichlorobenzene (20 mg/mL of dithiazole compound 41-D) at 500 rpm for 10 sec and at 2,000 rpm for 20 sec. Compound 41-C film was deposition by vacuum deposition. Bi-layers of CYTOP (45 nm) and Al₂O₃(50 nm) were used as top gate dielectrics. CYTOP solution (CTL-809M) was purchased from Asahi Glass with a concentration of 9 wt. %. To deposit the 45-nm-thick fluoropolymer layers, the original solution was diluted with their solvents (CT-solv. 180) to have solution:solvent ratios of 1:3.5. CYTOP layers were deposited by spin coating at 3000 rpm for 60 sec. Al₂O₃ (50 nm) films were deposited on fluoropolymer layers by atomic layer deposition (ALD) at 110° C. using alternating exposures of trimethyl aluminum [Al(CH₃)₃] and H₂O vapor at a deposition rate of approximately 0.1 nm per cycle. The total capacitance density (Cᵢ) measured from parallel-plate capacitors was 35.2 nF/cm². All spin coating and annealing processes were carried out in a N₂-filled dry box. Finally, Al (150 nm) gate electrodes were deposited by thermal evaporation through a shadow mask. The transistor channel width W was 2550 μm and the channel length L was 180 μm.

All current-voltage (I-V) and capacitance-voltage (C-V) characteristics were measured in a N₂-filled glove box (O₂, H₂O<0.1 ppm) in the dark with an Agilent E5272A source/monitor unit and an Agilent 4284A LCR meter.

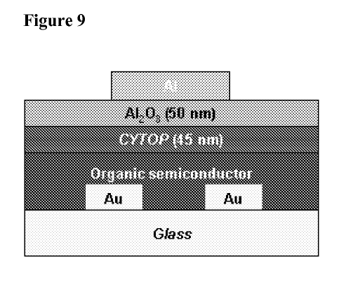

The device illustration for this example is shown in FIG. 9.

Formulas for the compounds are below including the Figures with their FET performance (Compound 41-B did not show field effect behavior in this example):

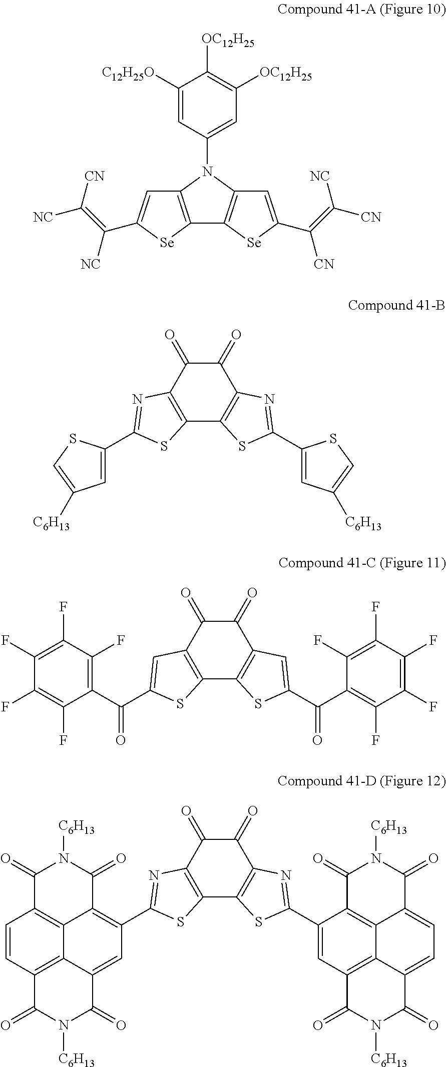

### Example 42

### Selective BCHD followed by CuCl₂ oxidation for 2,7-dibromo-benzo[1,2-b:6,5-b′]dithiophene-4,5-bis(ethyleneoxolane)

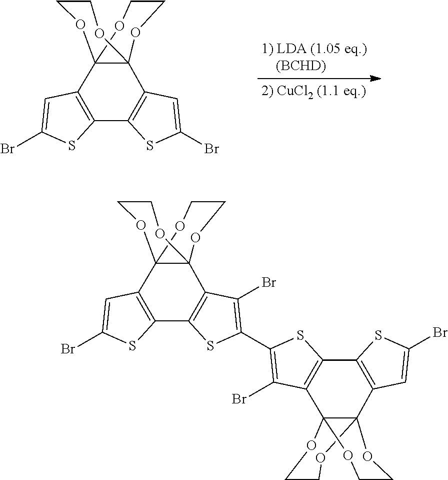 [SMILES: Brc1cc2c(s1)-c1sc(Br)cc1C13OCCOC21OCCO3 ; Brc1cc2c(s1)-c1sc(-c3sc4c(c3Br)C35OCCOC3(OCCO5)c3cc(Br)sc3-4)c(Br)c1C13OCCOC21OCCO3]

2,7-Di-bromo-benzo[1,2-b:6,5-b′]dithiophenebenzo[1,2-b:6,5-b′]dithiophene-4,5-bis(ethyleneoxolane) (2.5 mmol, 1.165 g) was dissolved in 75 mL of anhydrous THF under nitrogen atmosphere and the resulting solution was cooled in acetone/dry ice bath. Lithium diisopropyl amide (freshly prepared from diisopropylamine (2.89 mmol, 0.292 g, n-butyllithium (2.87 M in hexanes, 2.625 mmol, 0.91 mL) and 25 mL of THF) was added dropwise and the reaction mixture became colorless, then light pink, pink-purple and then light purple. The reaction mixture was stirred for 0.5 h and CuCl₂ (1.1 eq., 2.75 mmol, 0.37 g) was added in one portion. After stirring for 50 minutes the cooling bath was removed, the reaction mixture was allowed to warm to room temperature and treated with hexanes. The resulting mixture was filtered through silica gel plug, the solvents were removed by rotary evaporation and the residue was purified by column chromatography (˜200 mL of silica gel, chloroform, then chloroform:ethyl acetate (˜20:1). Fraction with yellow product were combined, the solvents were removed and the residue was heated with 2-propanol with addition of dichloromethane (material only partially dissolved). After cooling yellow little crystals formed. The product was separated by vacuum filtration and yellow solid was obtained (0.76 g, 65.3% yield). ¹H NMR (CDCl₃, 400 MHz): δ 7.19 (s, 2H), 4.21 (m, 8H), 3.73 (m, 8H); ¹³C{¹H} NMR (CDCl₃, 100 MHz): δ 137.0, 135.6, 133.3, 131.1, 128.3 (CH), 126.5, 113.4, 113.0, 94.4, 92.6, 61.5 (CH₂), 61.3 (CH₂). HRMS (EI) calculated for C₂₈H₁₈Br₄O₈S₄ 925.6618; found: 925.6621. Anal. Calc. for C₂₈H₁₈Br₄O₈S₄: C, 36.15; H, 1.95. Found: C, 36.35; H, 2.13.

The BCHD of this step was observed by proton NMR.

### Example 43

### Modeling

Modeling showed close contacts and partial overlap of π-systems of 2,7-Bis-Pentafluorobenzoyl-benzo[1,2-b:6,5-b′]dithiophene-4,5-dione

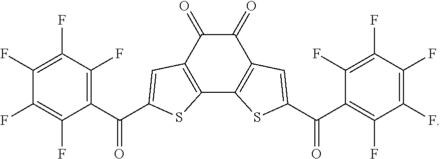 [SMILES: O=C1C(=O)c2cc(C(=O)c3c(F)c(F)c(F)c(F)c3F)sc2-c2sc(C(=O)c3c(F)c(F)c(F)c(F)c3F)cc21]

Additionally, modeling showed packing of 2,7-Bis-(4-Trifluoromethyl)-benzo[1,2-b:6,5-b′]dithiophene-4,5-dione and partial overlap of π-π systems of 2,7-Bis-(4-Trifluoromethyl)-benzo[1,2-b:6,5-b′]dithiophene-4,5-dione

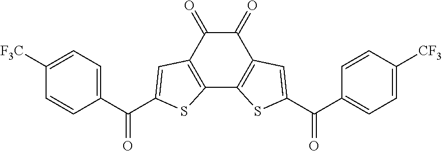 [SMILES: O=C(c1ccc(C(F)(F)F)cc1)c1cc2c(s1)-c1sc(C(=O)c3ccc(C(F)(F)F)cc3)cc1C(=O)C2=O]

### Example 44

### 2,7-Dibromo-benzo[1,2-b:6,5-b′]dithiophene-4-one-5-(1,3-dioxolane) (5b)

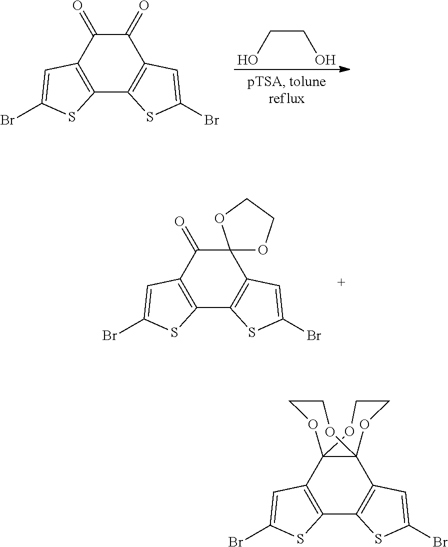

2,7-Dibromo-benzo[1,2-b:6,5-b′]dithiophene-4,5-dione (1.0 mmol, 0.376 g) was mixed with toluene (50 mL), ethylene glycole (10 eq., 10.0 mmol, 0.62 g) and catalytic amount of p-toluenesulfonic acid (polymer bound). The red-purple solution was heated to reflux and after 2 hours additional amount of ethylene glycol was added (0.3 mL). After reflux overnight additional amount of p-toluenesulfonic acid (polymer bound) and ethylene glycol (2 mL) was added and the mixture was refluxed for additional 8 h. The orange-reddish mixture was cooled to room temperature and applied to the column (150 mL of silica gel, dichloromethane as eluant). First bright yellow fractions were combined, the solvent was removed and the residue was recrystallized from 2-propanol. Mono-protected product was obtained as bright yellow needles (0.16 g, 37.9%). Later yellowish fractions with more polar product, 2,7-dibromo-benzo[1,2-b:6,5-b′]dithiophene-4,5-bis-(ethyleneoxolane), were comibned separately, the solvents were removed and the residue was recrystallized from 2-propanol. Pale yellowish needles of 5a were isolated after vacuum filtration (0.078 g, 16.7%).

2,7-Dibromo-benzo[1,2-b:6,5-b′]dithiophene-4-one-5-(1,3-dioxolane): ¹H NMR (CDCl₃, 400 MHz): δ7.35 (s, 1H), 7.13 (s, 1H), 4.47 (m, 2H), 4.31 (m, 2H); ¹³C{¹H} NMR (CDCl₃, 100 MHz): δ 189.03 (quaternary C(O)), 144.91 (quaternary C), 139.47 (quaternary C), 132.44 (quaternary C), 131.7 (quaternary C), 130.3 (CH), 128.21 (CH), 114.3 (quaternary C—Br), 111.61 (quaternary C—Br), 98.7 (quaternary C), 66.2 (CH₂) (assignment of the quaternary, CH, CH₂ and CH₃ signals was made based on the DEPT-135 experiment). HRMS (EI) calculated for C₁₂H₆Br₂O₃S₂ 419.8125; found 419.8134. Anal. Calcd. for C₁₂H₆Br₂O₃S₂: C, 34.14, H, 1.43. Found: C, 34.38; H, 1.32.

Different isomer with carbonyl groups protected as ketal groups was obtained. 2,7-Dibromo-benzo[1,2-b:6,5-b′]dithiophene-4,5-bis-(1,3-dioxolane) (7)

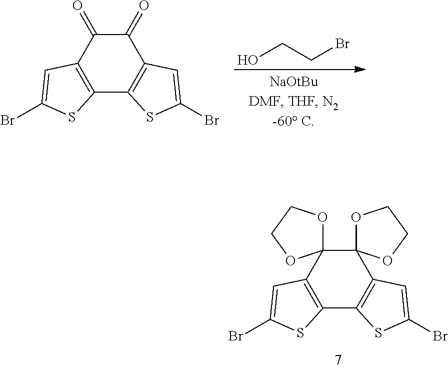

Modified literature conditions were used for the protection reaction. See Barbasiewicz, M.; Makosza, M. Organic Letters 2006, 8, 3745

2,7-Bis-trimethylsilyl-benzo[1,2-b:6,5-b′]dithiophene-4,5-dione (1.0 mmol, 0.378 g) was dissolved in anhydrous THF (30 mL) under nitrogen atmosphere, anhydrous DMF (30 mL) and 2-bromoethanol (3.0 eq., 0.37 g) were added, and dark red reaction mixture was cooled in chloroform/dry ice bath. A solution of ^{t}BuONa (3.0 eq., 3.0 mmol, 0.29 g) in anhydrous DMF (10 mL) was added dropwise. After addition of 4 mL of the base solution a thick suspension formed (dirty yellow-red-brown color). After addition of 6 mL of base (out of 10 mL), the reaction mixture became very difficult to stir, and anhydrous THF (10 mL) was added to a green suspension. After completion of addition of the base additional amount of THF (10 mL) was added, the mixture was stirred for 20 minutes, warmed to room temperature, and then treated with water. Organic phase was removed, the aqueous phase was extracted with hexanes, and combined organic phases were dried over anhydrous magnesium sulfate. The drying agent was filtered off, organic solvents were removed by rotary evaporation and the residue was purified by column chromatography (silica gel, dichloromethane:hexanes (2:1) as eluant). Fractions with mono-protected byproduct, 2,7-dibromo-benzo[1,2-b:6,5-b′]dithiophene-4-one-5-(1,3-dioxolane), were combined, the solvent was removed, and a few mg of material was obtained. Fractions with the desired product, Dibromo-benzo[1,2-b:6,5-b′]dithiophene-4,5-bis-(1,3-dioxolane), were combined, the solvent was removed, and the residue (0.23 g, 49.3% yield) was recrystallized from 2-propanol. Crystals suitable for the single crystal X-ray analysis were obtained after vacuum filtration. ¹H NMR (CDCl₃, 400 MHz): δ 7.04 (s, 2H), 4.22 (m, 4H), 4.15 (m, 4H); ¹³C{¹H} NMR (CDCl₃, 100 MHz): δ 138.2, 132.6, 128.1 (CH), 111.0, 107.3, 66.6 (CH₂) (assignment of CH and CH₂ carbons was made based on DEPT-135 experiment; all other carbons are quaternary). HRMS (EI) calculated for C₁₄H₁₀Br₂O₄S₂ 463.8387; found 463.8387. Anal. Calcd. for C₁₄H₁₀Br₂O₄S₂: C, 36.07; H, 2.16. Found: C, 35.97; H, 2.09.

### Example 45

### 2,7-Bis-(3,4,5-trifluorobenzoyl)-benzo[1,2-b:6,5-b′]dithiophene-4,5-dione

### Step 1. 2,7-Bis-(3,4,5-trifluorobenzoyl)-benzo[1,2-b:6,5-b′]dithiophene-4,5-bis-(1,3-dioxolane)

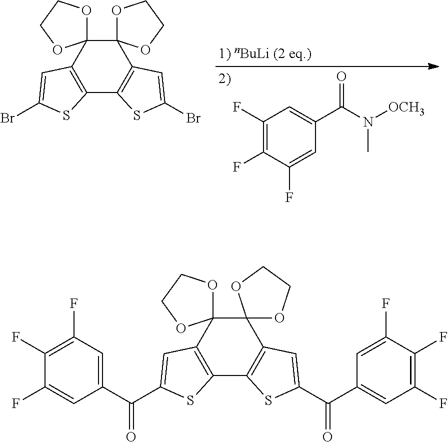 [SMILES: Brc1cc2c(s1)-c1sc(Br)cc1C1(OCCO1)C21OCCO1 ; CON(C)C(=O)c1cc(F)c(F)c(F)c1 ; O=C(c1cc(F)c(F)c(F)c1)c1cc2c(s1)-c1sc(C(=O)c3cc(F)c(F)c(F)c3)cc1C1(OCCO1)C21OCCO1]

2,7-Dibromo-benzo[1,2-b:6,5-b′]dithiophene-4,5-bis-(1,3-dioxolane) (7) (2.0 mmol, 0.93 g) was dissolved in anhydrous THF (100 mL) under nitrogen atmosphere, and the colorless solution was cooled in acetone/dry ice bath. n-Butyllithium (2.85 M in hexanes, 4.0 mmol, 1.4 mL) was added dropwise, and greenish suspension formed. The reaction mixture was stirred for 15 minutes, and N-methoxy-N-methyl-3,4,5-trifluorobenzamide (11b) (4.4 mmol, 0.96 g) was added. After 10 minutes of stirring yellow mixture (solution) was warmed to room temperature, and aqueous NH₄Cl was added (purple-yellow mixture formed). Aqueous phase was removed, organic matter was extracted with dichloromethane-hexanes mixture, and combined organic phases were dried over anhydrous magnesium sulfate. The drying agent was flittered off, the solvents were removed by rotary evaporation, and the residue was purified by column chromatography (silica gel, dichlormethane as eluant; chloroform to dissolve the material to apply to the column). Combined fractions were subjected to rotary evaporation, yellow solid was dissolved in 2-propanol-chloroform, and yellow solution was concentrated by reflux until saturation point was reached. Yellow-greenish tiny crystals were separated by vacuum filtration (0.52 g). Mother liquor with some precipitate was subjected to rotary evaporation, and additional amount of yellow solid was obtained (0.40 g; 0.92 g total yield, 73.6% yield). ¹H NMR (CDCl₃, 400 MHz): δ7.58 (m, 6H), 4.29 (m, 4H), 4.20 (m, 4H); ¹³C{¹H} NMR (CDCl₃, 100 MHz): 3183.6, 151.2 (dd, J=252 Hz, 8.5 Hz), 147.7, 140.0, 132.1 (CH), 113.7 (dd, J=16.1 Hz, 6.6 Hz, CH), 92.5, 66.8 (CH₂) (two quaternary CF signals are not certain; two weak multiplets at 143 and 133 ppm were observed). ¹⁹F NMR (CDCl₃, 376.3 MHz): δ −131.5 (dd, J=20.0 Hz, 7.3 Hz, 4F), −152.8 (m, 2F) (1,1,2-trichlorotrifluoroethane was used as internal reference with δ at −71.75 ppm (t)). HRMS (EI) calculated for C₂₈H₁₄F₆O₆S₂ 624.0136; found 624.0139. Anal. Calcd. for C₂₈H₁₄F₆O₆S₂: C, 53.85; H, 2.26. Found: C, 53.59; H, 2.44.

### Step 2

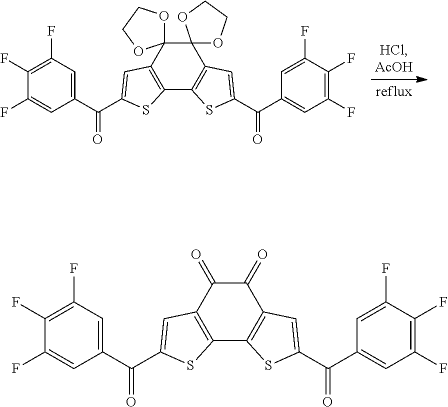 [SMILES: O=C(c1cc(F)c(F)c(F)c1)c1cc2c(s1)-c1sc(C(=O)c3cc(F)c(F)c(F)c3)cc1C1(OCCO1)C21OCCO1 ; O=C(c1cc(F)c(F)c(F)c1)c1cc2c(s1)-c1sc(C(=O)c3cc(F)c(F)c(F)c3)cc1C(=O)C2=O]

2,7-Bis-(3,4,5-trifluorobenzoyl)-benzo[1,2-b:6,5-b′]dithiophene-4,5-(1,3-dioxolane) (0.7 mmol, 0.437 g) was heated to reflux with acetic acid (50 mL), and HCl (˜5 mL) was added to a bright yellow solution. The reaction mixture became orange, then red-orange with precipitate. After reflux for ˜1 h the mixture was cooled to room temperature, the precipitate was separated by vacuum filtration, washed with water and ethanol, and dried. Crude product was obtained as orange-red solid (0.33 g, 87.8% crude yield). This materials was recrystallized from 1,4-dioxane (˜75 mL to dissolve it under reflux and then concentrated down to ˜30 mL when the solution became cloudy). Product was obtained as red solid (0.25 g, 75.8% recovery). ¹H NMR (1,2-dichloroethane-d4, 400 MHz, 370 K): δ 8.02 (s, 2H), 7.64 (t, J=6.8 Hz, 4H); ¹³C{¹H} NMR (CDCl₃, 100 MHz) was not recorded due to low solubility of this material at room or elevated temperature in CDCl₃ or 1,2-dichloroethane-d4). ¹⁹F NMR (CDCl₃, 376.3 MHz): δ −130.4 (m, 4F), −150.8 (m, 2F) (1,1,2-trichlorotrifluoroethane was used as internal reference with 3 at −71.75 ppm (t)). HRMS (EI) calculated for C₂₄H₆F₆O₄S₂ 535.9612; found 535.9616. Anal. Calcd. for C₂₄H₆F₆O₄S₂ C, 53.74; H, 1.13. Found: 53.57, H, 1.05.

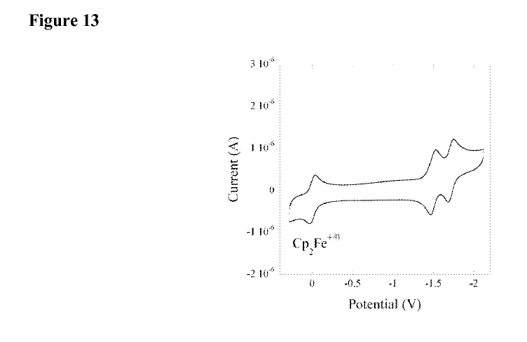

See FIG. 13. The cyclic voltammogram of 2,7-bis-(3,4,5-trifluorobenzoyl)-benzo[1,2-b:6,5-b′]dithiophene-4,5-bis-(1,3-dioxolane) (0.1 M ⁿBu₄NPF₆ in THF, Cp₂Fe internal standard at 0 V, 50 mV·s⁻¹ rate) showed: E_{1/2}^{0/1-}=−1.50 V, E_{1/2}^{1-/2-}=−1.72 V.

### Example 46

### 2,7-Bis-(4-trifluoromethylbenzoyl)-benzo[1,2-b:6,5-b′]dithiophene-4,5-dione

### Step 1. 2,7-Bis-(4-trifluoromethylbenzoyl)-benzo[1,2-b:6,5-b′]dithiophene-4,5-bis-(ethyleneoxolane) (9c′)

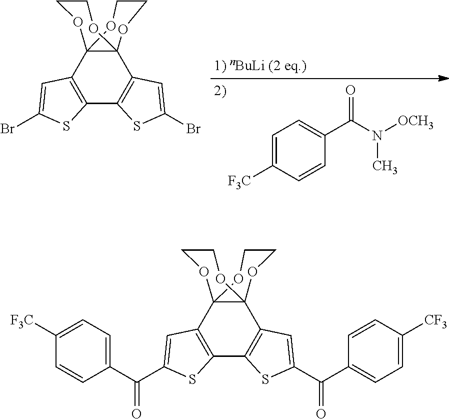 [SMILES: Brc1cc2c(s1)-c1sc(Br)cc1C13OCCOC21OCCO3 ; CON(C)C(=O)c1ccc(C(F)(F)F)cc1 ; O=C(c1ccc(C(F)(F)F)cc1)c1cc2c(s1)-c1sc(C(=O)c3ccc(C(F)(F)F)cc3)cc1C13OCCOC21OCCO3]

2,7-Dibromo-benzo[1,2-b:6,5-b′]dithiophene-4,5-bis-(ethyleneoxolane) (5a) (0.3 mmol, 0.14 g) was dissolved in anhydrous THF (50 mL) under nitrogen atmosphere, and the resulting solution was cooled in acetone/dry ice bath. n-Butyllithium (1.6 M in hexanes, 0.6 mmol, 0.4 mL) was added dropwise, the reaction mixture was stirred for 10-15 minutes and N-methoxy-N-methyl-4-(trifluoromethyl)benzamide (2.2 eq., 0.66 mmol, 0.154 g) was added. The reaction mixture was stirred for ˜0.5 h, warmed to room temperature, and then treated with aqueous NH₄Cl. Yellow organic phase was separated, aqueous phase was extracted with hexanes, and combined organic phases were dried over anhydrous magnesium sulfate. The drying agent was filtered off, the solvent were removed by rotary evaporation and the residue (yellow solid) was purified by column chromatography (silica gel, dichloromethane as eluant). Combined fractions were subjected to rotary evaporation, and product was obtained as yellow solid (0.111 g, 56.6% yield). ¹H NMR (CDCl₃, 400 MHz): δ 7.98 (d, J=8.1 Hz, 4H), 7.81 (d, J=8.2 Hz, 4H), 7.70 (s, 2H), 4.19 (m, 4H), 3.70 (m, 4H); ¹³C{¹H}NMR (CDCl₃, 100 MHz): δ 186.3, 143.1, 140.4, 140.37, 139.2, 134.0 (q, J=32 Hz), 132.9 (CH), 129.3 (CH), 125.7 (q, J=4 Hz, CH), 124.9, 122.2, 92.5, 61.5 (CH₂) (assignment of CH and CH₃ carbons was made based on DEPT-135 experiment; all other carbons are quaternary). HRMS (EI) calculated for C₃₀H₁₈F₆O₆S₂ 652.0449; found 652.0453. Anal. Calcd. for C₃₀H₁₈F₆O₆S₂: C, 55.21; H, 2.78. Found: C, 54.92; H, 3.30.

Step 1.

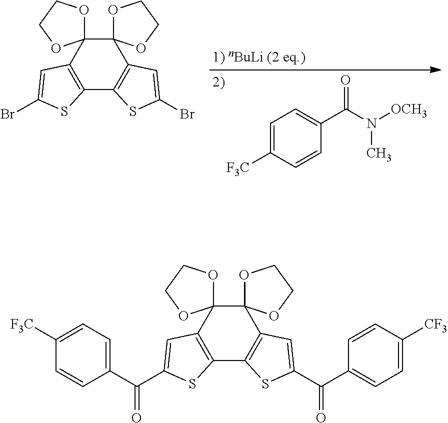 [SMILES: Brc1cc2c(s1)-c1sc(Br)cc1C1(OCCO1)C21OCCO1 ; CON(C)C(=O)c1ccc(C(F)(F)F)cc1 ; O=C(c1ccc(C(F)(F)F)cc1)c1cc2c(s1)-c1sc(C(=O)c3ccc(C(F)(F)F)cc3)cc1C1(OCCO1)C21OCCO1]

2,7-Dibromo-benzo[1,2-b:6,5-b′]dithiophene-4,5-bis-(1,3-dioxolane) (5.0 mmol, 2.33 g) was dissolved in anhydrous THF (200 mL) under nitrogen atmosphere, and the resulting solution was cooled in acetone/dry ice bath. n-Butyllithium (2.85 M in hexanes, 10.0 mmol, 0.4 mL) was added dropwise, the reaction mixture was stirred for 40 minutes, and N-methoxy-N-methyl-4-(trifluoromethyl)benzamide (11c) (2.1 eq., 10.5 mmol, 2.45 g) was added. The reaction mixture was stirred for ˜0.5 h, cooling bath was removed, and the mixture was allowed to warm to room temperature. Aqueous ammonium chloride was added, organic phase was removed, and aqueous phase was extracted with hexanes:dichloromethane. Combined organic phases were dried over anhydrous magnesium sulfate, the drying agent was filtered off, and the solvents were removed by rotary evaporation to give crude product, which was purified by column chromatography (silica gel, chloroform as eluant). Fractions with almost pure compound were combined, the solvent was removed, and yellow solid was obtained (0.8 g). Fractions with contaminated product were combined separately, and the solvent was removed to give additional amount of product (2.02 g), which was further purified by column chromatography (silica gel, dichloromethane as eluant) (1.13 g, yellow solid; 59% combined yield). ¹H NMR (CDCl₃, 400 MHz): δ 7.98 (d, J=8.1 Hz, 4H), 7.81 (d, J=8.2 Hz, 4H), 7.57 (s, 2H), 4.26 (m, 4H), 4.17 (m, 4H); ¹³C{¹H} NMR (CDCl₃, 100 MHz): δ 183.30, 142.53, 141.54, 140.57, 139.97, 133.9 (q, J=48.8 Hz), 129.48, 129.21, 125.70 (m), 124.92, 119.50, 107.06, 66.79. ¹⁹F NMR (CDCl₃, 376.3 MHz): 3-63.0 (s, 6F) (1,1,2-trichlorotrifluoroethane was used as a reference with 3 at −71.75 ppm (t)). HRMS (EI) calculated for C₃₀H₁₈F₆O₆S₂ 652.0449; found 652.0449. Anal. Calcd. for C₃₀H₁₈F₆O₆S₂: C, 55.21; H, 2.78. Found: C, 54.95; H, 2.66.

Step 2.

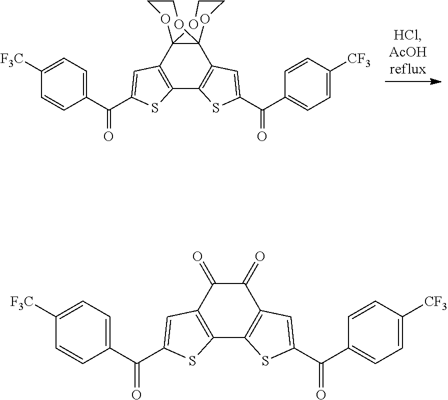 [SMILES: O=C(c1ccc(C(F)(F)F)cc1)c1cc2c(s1)-c1sc(C(=O)c3ccc(C(F)(F)F)cc3)cc1C13OCCOC21OCCO3 ; O=C(c1ccc(C(F)(F)F)cc1)c1cc2c(s1)-c1sc(C(=O)c3ccc(C(F)(F)F)cc3)cc1C(=O)C2=O]

2,7-Bis-(4-trifluoromethylbenzoyl)-benzo[1,2-b:6,5-b′]dithiophene-4,5-bis-(ethyleneoxolane) (9c′) (0.8 mmol, 0.522 g) was mixed with acetic acid (40 mL), and the resulting mixture was heated to reflux. HCl (˜5 mL) was added to a bright yellow solution, and it became orange and then red. After reflux for ˜1.5 h the reaction mixture was cooled to room temperature, water was added and precipitate was separated by vacuum filtration (0.42 g, 93.3% crude yield, red-orange solid). This material was purified by column chromatography (˜100 mL of silica gel, chloroform as eluant; hot chloroform to dissolve the material and apply to the column). Fraction with slightly contaminated product was kept separately; fraction with pure product (by TLC) was subjected to rotary evaporation, and product was obtained as red shiny solid (0.196 g, 43.6% purified yield).

¹H NMR (CDCl₃, 400 MHz): δ 8.00 (m, 6H), 7.86 (m, 4H); ¹³C{¹H} NMR (CDCl₃, 100 MHz): δ (material is not sufficiently soluble in CDCl₃ or 1,2-dichloroethane at room temperature or elevated temperature). HRMS (EI) calculated for C₂₆H₁₀F₆O₄S₂ 563.9925; found 563.9921.

Step 2.

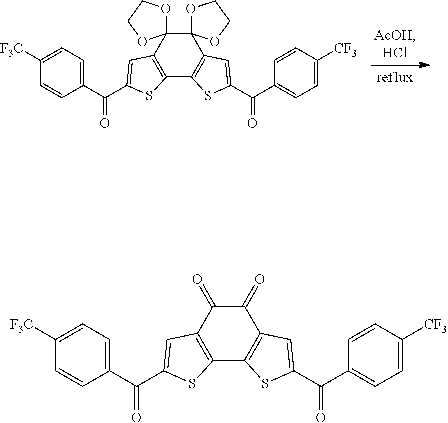 [SMILES: O=C(c1ccc(C(F)(F)F)cc1)c1cc2c(s1)-c1sc(C(=O)c3ccc(C(F)(F)F)cc3)cc1C1(OCCO1)C21OCCO1 ; O=C(c1ccc(C(F)(F)F)cc1)c1cc2c(s1)-c1sc(C(=O)c3ccc(C(F)(F)F)cc3)cc1C(=O)C2=O]

2,7-Bis-(4-trifluoromethylbenzoyl)-benzo[1,2-b:6,5-b′]dithiophene-4,5-bis(1,3-dioxolane) (9c) (1.23 mmol, 0.80 g) was mixed with acetic acid (100 mL), and the resulting mixture was heated to reflux. HCl (˜5 mL) was added to a bright yellow solution, and it became darker in color, and then precipitate formed. After reflux for ˜5 h, reaction mixture was cooled to room temperature, and red solid was separated by vacuum filtration (0.42 g, 60.9% crude yield).

Material (500 mg) obtained from the deprotection reactions was purified by sublimation (6.5×10⁻⁷ torr, 250-285° C.; 0.238 g, 47.6% recovery). Anal. Calcd. for C₂₆H₁₀F₆O₄S₂: C, 55.32; H, 1.79. Found: C, 55.51; H, 1.73.

### Example 47

### 2,7-Bis-(3,5-bistrifluoromethyl-benzoyl)-benzo[1,2-b:6,5-b′]dithiophene-4,5-dione

### Step 1. 2,7-Bis-(3,5-bistrifluoromethyl-benzoyl)-benzo[1,2-b:6,5-b′]dithiophene-4,5-bis-(1,3-dioxolane)

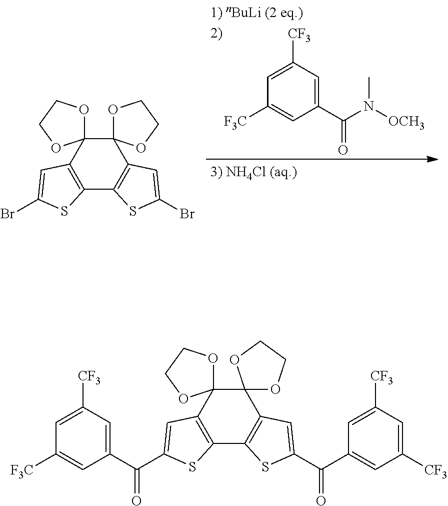 [SMILES: Brc1cc2c(s1)-c1sc(Br)cc1C1(OCCO1)C21OCCO1 ; CON(C)C(=O)c1cc(C(F)(F)F)cc(C(F)(F)F)c1 ; O=C(c1cc(C(F)(F)F)cc(C(F)(F)F)c1)c1cc2c(s1)-c1sc(C(=O)c3cc(C(F)(F)F)cc(C(F)(F)F)c3)cc1C1(OCCO1)C21OCCO1]

2,7-Dibromo-benzo[1,2-b:6,5-b′]dithiophene-4,5-bis-(1,3-dioxolane) (5.0 mmol, 2.33 g) was dissolved in anhydrous THF (150 mL) under nitrogen atmosphere, and the resulting solution was cooled in acetone/dry ice bath. n-Butyllithium (2.85 M in hexanes, 10.0 mmol, 3.5 mL) was added dropwise, and the yellowish solution became colorless suspension. The reaction mixture was stirred for 20 minutes, and N-methoxy-N-methyl-3,5-bis(trifluoromethyl)benzamide (11d) (2.1 eq., 10.5 mmol, 3.16 g) was added. After 10 minutes of stirring clear yellow solution was allowed to warm to room temperature. The reaction mixture was treated with aqueous ammonium chloride, yellow organic phase was separated, and aqueous phase was extracted with hexanes:dichloromethane. Combined organic phases were dried over anhydrous magnesium sulfate, the drying agent was filtered off, and the solvents were removed by rotary evaporation to give crude product, which was purified by column chromatography (silica gel, chloroform as eluant). Fractions with pure product were combined, the solvent was removed and yellow solid was obtained (1.90 g). Fractions with slightly contaminated product were kept separately (1.58 g). ¹H NMR (CDCl₃, 400 MHz): δ8.31 (s, 4H), 8.14 (s, 2H), 7.57 (s, 2H), 4.27 (m, 4H), 4.17 (m, 4H); ¹³C{¹H}NMR (CDCl₃, 100 MHz): 6184.30, 142.20, 141.73, 140.39, 139.28, 132.65 (CH), 132.54, 132.20, 128.90 (m, CH), 125.76 (m, CH), 122.82 (q, J=272 Hz, CF₃), 106.91, 66.87 (CH). ¹⁹F NMR (CDCl₃, 376.3 MHz): δ −62.9 (s, 12F) (1,1,2-trichlorotrifluoroethane was used as internal reference with δ at −71.75 ppm (t)). HRMS (EI) calculated for C₃₂H₁₆F₁₂O₆S₂ 788.0197; found 788.0187. Anal. Cacld. for C₃₂H₁₆F₁₂O₆S₂: C, 48.74; H, 2.05. Found: C, 48.55; H, 1.96.

Step 2.

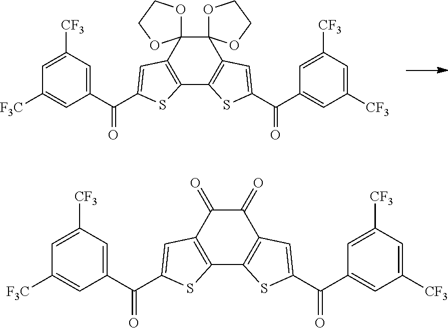 [SMILES: O=C(c1cc(C(F)(F)F)cc(C(F)(F)F)c1)c1cc2c(s1)-c1sc(C(=O)c3cc(C(F)(F)F)cc(C(F)(F)F)c3)cc1C1(OCCO1)C21OCCO1 ; O=C(c1cc(C(F)(F)F)cc(C(F)(F)F)c1)c1cc2c(s1)-c1sc(C(=O)c3cc(C(F)(F)F)cc(C(F)(F)F)c3)cc1C(=O)C2=O]

2,7-Bis-(3,5-ditrifluoromethylbenzoyl)-benzo[1,2-b:6,5-b′]dithiophene-4,5-(1,3-dioxolane) (2.0 mmol, 1.58 g) (9d) was dissolved in boiling acetic acid (200 mL), and to a bright yellow solution HCl (5-10 mL) was added. The reaction mixture became organge, then orange-red. After refluxing for ˜4 h dark red reaction mixture was cooled to room temperature, and shiny orange-red plates were separated by vacuum filtration (1.20 g, 85.7% crude yield). This crude product (˜1.1 g) was purified by column chromatography (silica gel, dichloromethane as eluant). Combined fractions were subjected to rotary evaporation, the residue was heated with 2-propanol and some dichloromethane, and cooled to room temperature. Shiny red solid was separated by vacuum filtration (0.88 g). Mother liquor was subjected to rotary evaporation, the residue was dissolved in dichloromethane, and solution was left for slow concentration to grow single crystals (0.146 g). ¹H NMR (CDCl₃, 400 MHz): δ 8.32 (s, 4H), 8.20 (s, 2H), 7.98 (s, 2H) (CH₂Cl₂ at 5.31 ppm was detected, indicating that the material traps dichloromethane (˜2.8 to 1 ratio); ¹³C {¹H} NMR (CDCl₃, 100 MHz): δ 184.3, 173.3, 148.0, 144.0, 137.9, 137.1, 133.4, 132.9 (q, J=34 Hz), 128.9 (d), 126.7 (m), 124.0. ¹⁹F NMR (CDCl₃, 376.3 MHz): δ −62.9 (12F). HRMS (EI) calculated for C₂₈H₈F₁₂O₄S₂ 699.9672; found 699.9688. Anal. Calcd. for C₂₈H₈F₁₂O₄S₂: C, 48.01; H, 1.15. Found: C, 48.10; H, 1.01 (for the sublimed material).

### Example 48

### 2,7-Bis-(pentafluorobenzoyl-thiophen-2-yl)-benzo[1,2-d:4,3-d]bis(thiazole)-4,5-dione (28b)

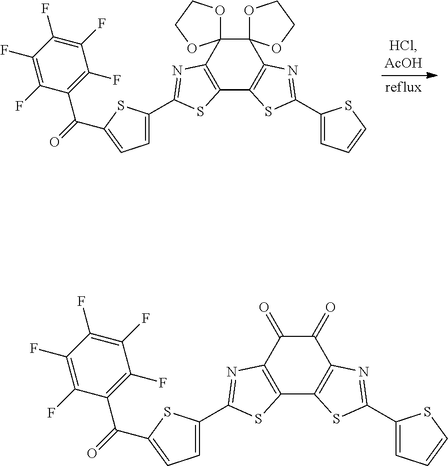 [SMILES: O=C(c1ccc(-c2nc3c(s2)-c2sc(-c4cccs4)nc2C2(OCCO2)C32OCCO2)s1)c1c(F)c(F)c(F)c(F)c1F ; O=C1C(=O)c2nc(-c3ccc(C(=O)c4c(F)c(F)c(F)c(F)c4F)s3)sc2-c2sc(-c3cccs3)nc21]

2-(5-Pentafluorobenzoyl-thiophene-2-yl)-benzo[1,2-d:4,3-d]bis(thiazole)-4,5-bis-(1,3-dioxolane) (0.135 mmol, 0.091 g) was mixed with acetic acid (25 mL), and the resulting mixture was heated to reflux. HCl (˜5 mL) was added dropwise to a bright orange solution, and the mixture became brown, and then precipitate formed. After reflux for about 0.5 h the reaction mixture was cooled to room temperature, treated with water, brown solid was separated by vacuum filtration, washed with water, ethanol, and then dried (0.061 g, 77.2% yield, sample was pure based on ¹H NMR analysis). ¹H NMR (CDCl₃, 400 MHz): δ7.73 (d, J=4.1 Hz, 1H), 7.70 (dd, J=3.8 Hz, 1.0 Hz, 1H), 7.61 (dd, J=5.0 Hz, 1.0 Hz, 1H), 7.18 (dd, J=5.0 Hz, 3.8 Hz, 1H); DEPT-135 (CDCl₃): δ135.67 (CH), 131.38 (CH), 129.70 (CH), 129.19 (CH), 128.53 (CH) (the material was not sufficiently soluble in CDCl₃ to record ¹³C{¹H} NMR spectrum). HRMS (EI) calculated for C₂₃H₅F₅N₂O₃S 4579.9103, found 579.9119 (M+2H (581.9253) was also detected). Anal. Calcd. for C₂₃H₅F₅N₂O₃S₄: C, 47.58; H, 0.87; N, 4.83. Found: C, 47.31; H, 0.68; N, 4.71.

### Condensation of 2,7-bis-trimethylsilyl-benzo[1,2-b: 6,5-b′]dithiophene-4,5-dione with diamine

2,7-Bis-trimethylsilyl-benzo[1,2-b:6,5-b′]dithiophene-4,5-dione (1) was tested in the condensation with diaminomaleonitrile, a diamine bearing two strong electron-withdrawing cyano groups. Under the conditions used (ethanol:acetic acid) two major products, 6,9-bis(trimethylsilyl)dithieno[3,2-f:2′,3′-h]quinoxaline-2,3-dicarbonitrile (S3) (11% yield) and 2,5,9,12-tetrakis(trimethylsilyl)tetrathieno[3,2-a:2′,3′-c:3″,2″-h:2′″,3′″-j]phenazine (S4) (25% yield), were isolated (Scheme S7).

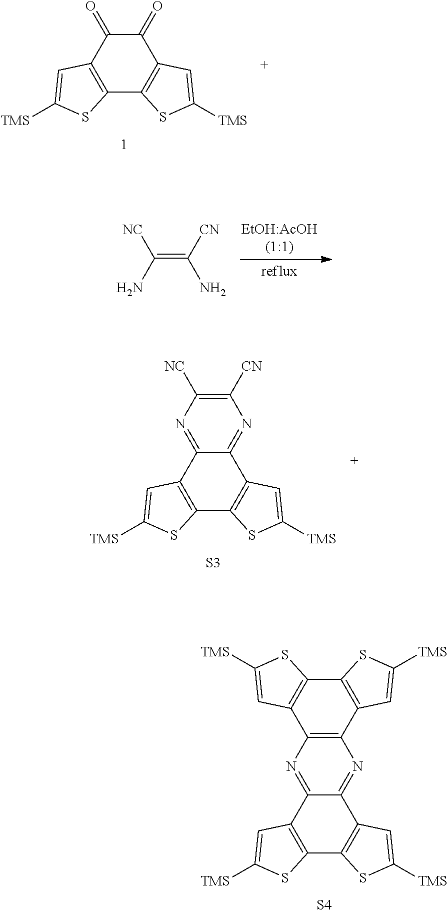

Scheme S7. Condensation of 2,7-bis-trimethylsilyl-benzo[1,2-b:6,5-b′]dithiophene-4,5-dione (1) with diaminomaleonitrile.

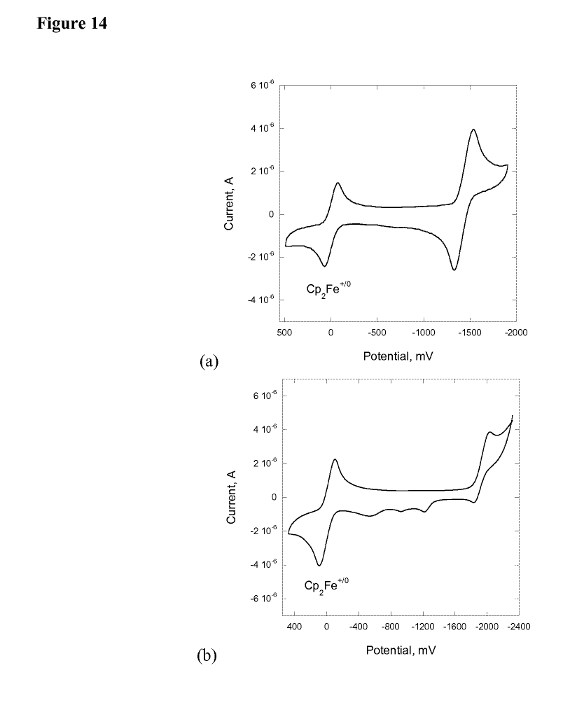

FIG. 14 CV analyses (0.1 M ⁿBu₄NPF₆ in THF, Cp₂Fe internal standard at 0 V, 50 mV rate) of (a) 6,9-bis(trimethylsilyl)dithieno[3,2-f:2′,3′-h]quinoxaline-2,3-dicarbonitrile (S3): E_{1/2}^{0/1-}=−1.43 V (partially reversible) and (b) 2,5,9,12-tetrakis(trimethylsilyl)tetrathieno[3,2-a:2′,3′-c:3″,2″-h:2′″,3′″-j]phenazine (S4): E_{1/2}^{0/1-}=−1.93 V (partially reversible).

2,6-Bis-trimethylsilyl-benzo[1,2-b:6,5-b′]dithiophene-4,5-dione (1) (0.50 mmol, 0.182 g) was mixed with diaminomaleonitrile (0.50 mmol, 0.054 g) in a 100 mL-round bottom flask. Ethanol (20 mL) and acetic acid (2 mL) were added, and the dark red solution was heated to reflux. After 1.5 h of reflux 18 mL of acetic acid was added, and the mixture was refluxed overnight. TLC analysis (hexanes:dichloromethane (4:1) showed the presence of two new materials and a small amount of starting material, and additional amount of diaminomaleonitrile (0.08 mmol, 0.009 g) was added. The mixture was heated for additional 0.5 h, cooled to room temperature, and ethanol was removed by the rotary evaporation. The residue was treated with water, the organic matter was extracted with diethyl ether several times, and the combined organic phases were dried over anhydrous magnesium sulfate. The residue was purified by the column chromatography (silica gel, dichloromethane as eluant). First three fractions (bright yellow spot on TLC under visible light) were combined, the solvents were removed by rotary evaporation, and the yellow solid was obtained (S4, 0.044 g, 25% yield). The solvents were removed from combined fractions, brownish-yellow solid S3 was obtained (0.051 g), and was further purified by column chromatography (silica gel, dichloromethane as eluant; then silica gel, chloroform:hexanes (1:1) as eluant). The solvents were removed from combined fractions, and the residue (yellow solid with a small amount of brownish impurities) was recrystallized from 2-propanol:chloroform, and bright yellow-orange material S3 was obtained after vacuum filtration (0.024 g, 11.0% yield).

S3: ¹H NMR (CDCl₃, 400 MHz): δ8.40 (s, 2H), 0.50 (s, 18H); ¹³C{¹H} NMR (CDCl₃, 100 MHz): 6144.90 (quaternary C), 144.08 (quaternary C), 138.35 (quaternary C), 134.26 (quaternary C), 131.15 (CH), 128.69 (quaternary C), 114.28 (quaternary C), ˜0.23 (CH₃) (assignment of CH and CH₃ signals was made based on the DEPT-135 experiment). HRMS (EI) calculated for C₂₀H₂₀N₄S₂Si₂ 436.0668; found 436.0682. Anal. Calcd. for C₂₀H₂₀N₄S₂Si₂: C, 55.01; H, 4.62; N, 12.83. Found: C, 54.95; H, 4.62; N, 12.58.

S4: ¹H NMR (CDCl₃, 400 MHz): δ8.70 (s, 2H), 0.54 (s, 18H); ¹³C {¹H} NMR (CDCl₃, 100 MHz): 6140.82 (quaternary C), 139.56 (quaternary C), 137.83 (quaternary C), 136.21 (quaternary C), 131.33 (CH), 0.01 (CH₃ of TMS group) (assignment of the CH and CH₃ signals was made based on the DEPT-135 experiment). MS (EI) calculated for C₃₂H₄₀N₂S₄Si₄ 692.1151; found 692.1.

### Example 49

### Reaction of 4-(3,4,5-tris(dodecyloxy)phenyl)-4H-diselenopheno[3,2-b:2′,3′-d]pyrrole with TCNE

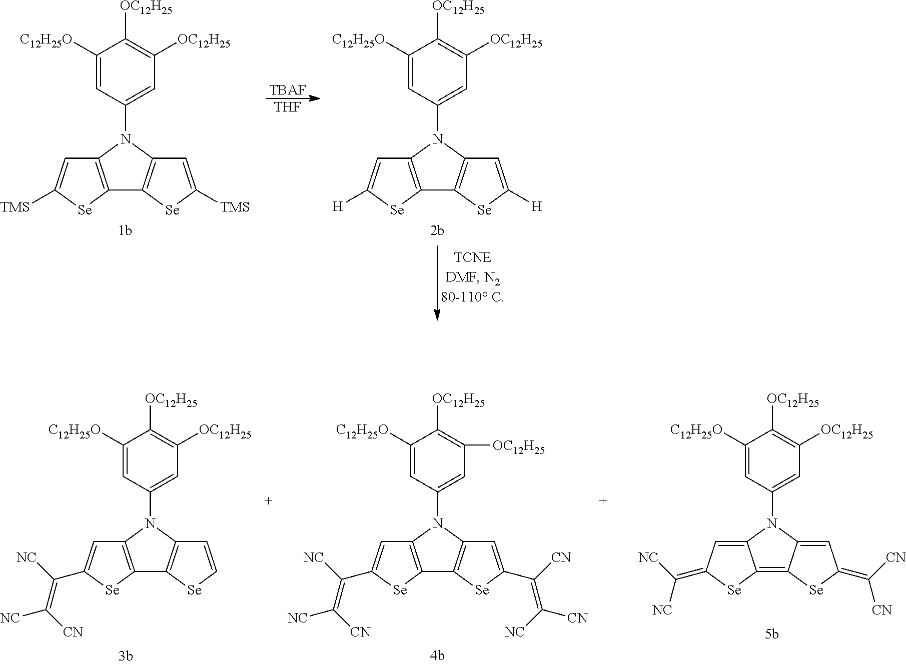

4-(3,4,5-Tris(dodecyloxy)phenyl)-4H-diselenopheno[3,2-b:2′,3′-d]pyrrole (2b) (2.00 mmol, 1.80 g) and TCNE (4.00 mmol, 1.03 g) were mixed in a flask under nitrogen atmosphere. Anhydrous DMF (25 mL) was added, and the solution became purple within a minute. The reaction mixture was initially heated to 117° C., and then stirred at 102° C. overnight. The reaction was monitored by TLC in hexanes:dichloromethane (1:1), and after consumption of the starting material the dark blue mixture was cooled to room temperature and treated with water (50 mL). The organic matter was extracted with dichloromethane (four times) and then with chloroform, and combined organic phases were dried over anhydrous magnesium sulfate. The drying agent was filtered off, the organic solvents were removed by rotary evaporation, and the crude product was column chromatographed (silica gel, hexanes:dichloromethane (2:1) as eluant). First fractions containing mono-substituted product 3b were combined, the solvents were removed by rotary evaporation, and the residue was further purified pre-packed Biotage columns (chloroform as eluant) (0.29 g, 14.6% yield). The next fractions containing di-substituted product 4b came out with dichloromethane as eluant. The dark blue pure fractions were combined, and the solvents were removed by rotary evaporation to give product as dark blue film, which was further purified using pre-packed Biotage columns (chloroform as eluant) (0.99 g, 44%). The next fractions containing slightly contaminated 5b (dichloromethane as eluant) were combined, the solvents were removed by rotary evaporation, and the residue was further purified by Biotage column chromatography (chloroform as eluant) (0.14 g, 6.9% yield).

3b: ¹H NMR (400 MHz, CDCl₃): δ 8.23 (m, 2H), 7.35 (d, J=5.9 Hz, 1H), 6.64 (s, 2H), 4.06 (t, J=6.5 Hz, 2H), 3.98 (t, J=6.4 Hz, 4H), 1.84 (m, 6H), 1.49 (m, 6H), 1.26 (m, 48H), 0.90 (m, 9H); ¹³C{¹H} NMR (400 MHz, CDCl₃): δ 154.17, 153.82, 145.84, 138.30 (CH), 134.07, 133.54, 132.69, 126.42 (CH), 118.70, 115.49 (CH), 113.99, 113.14, 103.13 (CH), 76.15, 73.76 (CH₂), 69.51 (CH₂), 31.96 (CH₂), 31.93 (CH₂), 30.40 (CH₂), 29.79 (CH₂), 29.77 (CH₂), 29.71 (CH₂), 29.67 (CH₂), 29.64 (CH₂), 29.40 (CH₂), 29.38 (CH₂), 29.29 (CH₂), 26.13 (CH₂), 26.07 (CH₂), 22.70 (CH₂), 14.13 (CH₃) (assignment of the CH, CH₂ and CH₃ carbons was made based on DEPT-135 experiment). HRMS (MALDI) calculated for (C₅₅H₈₀N₄O₃Se₂+H) 1005.4639; found 1005.4592. Anal. Calcd. For C₅₅H₈₀N₄O₃Se₂: C, 65.85; H, 8.04; N, 5.58. Found: C, 66.02; H, 8.14; N, 5.43.

4b: ¹H NMR (400 MHz, CDCl₃): δ 8.28 (s, 2H), 6.63 (s, 2H), 4.08 (t, J=6.6 Hz, 2H), 3.98 (t, J=6.4 Hz, 4H), 1.82 (m, 6H), 1.50 (m, 6H), 1.27 (48H), 0.90 (m, 9H). ¹³C{¹H} NMR (400 MHz, CDCl₃): δ 154.63, 149.77, 139.47, 139.14, 135.13, 131.33, 128.90, 125.81 (CH), 112.66, 112.50, 111.76, 103.12 (CH), 83.91, 77.36, 77.04, 76.72, 73.86 (CH₂), 69.65 (CH₂), 31.96 (CH₂), 31.93 (CH₂), 30.43 (CH₂), 29.77 (CH₂), 29.72 (CH₂), 29.68 (CH₂), 29.65 (CH₂), 29.41 (CH₂), 29.39 (CH₂), 29.27 (CH₂), 26.12 (CH₂), 26.06 (CH₂), 22.70 (CH₂), 14.13 (CH₃). HRMS (MALDI) calculated for (C₆₀H₇₉N₇O₃Se₂+H) 1106.4653; found 1106.4667. Anal. Calcd. for calculated for C₆₀H₇₉N₇O₃Se₂: C, 65.26; H, 7.21; N, 8.88. Found: C, 65.34; H, 7.20; N, 8.82 (for material prior to the purification by Biotage column chromatography). Found: C, 65.20; H, 7.12; N, 8.72 (for material after the purification by the Biotage column chromatography).

5b: ¹H NMR (400 MHz, CDCl₃): δ 6.53 (s, 2H), 6.48 (s, 2H), 4.05 (t, J=6.6 Hz, 2H), 3.96 (t, J=6.4 Hz, 4H), 1.82 (m, 6H) 1.49 (m, 6H), 1.27 (m, 48H), 0.89 (t, J=6.7 Hz, 9H). ¹³C{¹H} NMR (400 MHz, CDCl₃): δ 174.52, 165.80, 154.43, 139.52, 131.54, 129.37, 113.71, 112.36, 105.50 (CH), 103.40 (CH), 75.97, 73.84 (CH₂), 69.60 (CH₂), 31.91 (CH₂), 30.35 (CH₂), 29.76 (CH₂), 29.70 (CH₂), 29.69 (CH₂), 29.65 (CH₂), 29.61 (CH₂), 29.38 (CH₂), 29.36 (CH₂), 29.23 (CH₂), 26.04 (CH₂), 22.68 (CH₂), 14.11 (CH₃) (12 alkyl carbon signals are missing due to overlap) (assignment of the CH, CH₂ and CH₃ carbons was made based on DEPT-135 experiment). MS (MALDI) calculated for (C₅₆H₇₉N₅O₃Se₂+H) 1030.4592; found 1030.4478. Anal. Calcd. for C₅₆H₇₉N₅O₃Se₂ C, 65.42; H, 7.74; N, 6.81. Found: C, 65.55; H, 7.58; N, 6.76.

Materials with cyclopenta[1,2-b:5,4-b′]dithiophen-4-one core.

### Example 50

### 2,6-Bis-(thiophen-2-yl)-3,5-di-n-hexyl-4H-cyclopenta[1,2-b:5,4-b]dithiophen-4-one

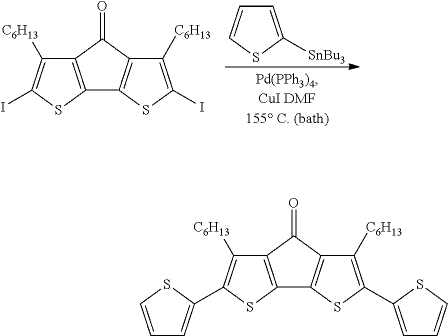

2,6-Diiodo-3,5-di-n-hexyl-4H-cyclopenta[1,2-b:5,4-b′]dithiophen-4-one (3.0 mmol, 1.837 g) and 2-tri-n-butylstannylthiophene (2.2 eq., 6.6 mmol, 2.46 g) were mixed in an oven-dried flask. Catalyst Pd(PPh₃)₄ (0.05 mol %, 0.15 mmol, 0.173 g), CuI (0.015 mol %, 0.045 mmol, 8.6 mg) and anhydrous DMF (30 mL) were added, and the mixture was heated up to reflux (155° C. bath temperature). The mixture changed color from purple to bluish-black. TLC analysis (hexanes:dichloromethane (1:1)) showed the complete consumption of the starting diiodide, and clean formation of the desired product. The mixture was cooled to room temperature, treated with water, and organic phase was extracted with hexanes. Dark blue-purple organic phase was dried over anhydrous magnesium sulfate and KF, and the solvent was removed by rotary evaporation to give product as dark blue-black soft matter. This crude product was purified by column chromatography (hexanes as eluant). Fractions containing the desired product were combined, the solvent was removed, and product was obtained as very dark solid (1.45 g, 92.4% yield). ¹H NMR (CDCl₃, 400 MHz): δ7.32 (dd, J=5.0 Hz, 0.54 Hz, 2H), 7.11 (poorly resolved dd, 2H), 7.06 (dd, J=5.0 Hz, 4.05 Hz, 2H), 2.18 (t, J=7.9 Hz, 4H), 1.65 (m, 4H), 1.39 (m, 4H), 1.31 (m, 8H), 0.90 (t, J=6.2 Hz, 6H); ¹³C{¹H} NMR (CDCl₃, 100 MHz): 6184.39, 146.67, 140.84, 137.10, 135.12, 133.96, 127.49, 126.10, 125.83, 31.55, 30.11, 29.31, 26.76, 22.64, 14.07. HRMS (EI) calculated for C₂₉H₃₂OS₄ 524.1236; found 524.1329. Anal. Calcd. for C₂₉H₃₂OS₄: C, 66.37; H, 6.15. Found: C, 66.45; H, 6.31.

### Example 51

### 2,5-Bis-(5-n-nonylthiophen-2-yl)-3,5-di-n-hexyl-4H-cyclopenta[1,2-b:5,4-b′]dithiophen-4-one

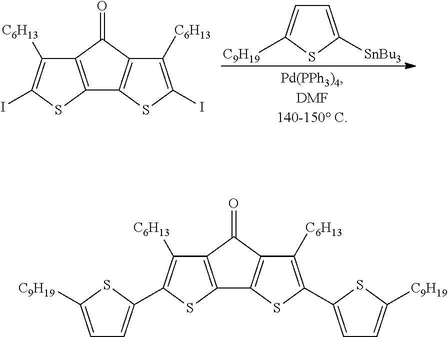

2,6-Diiodo-3,5-di-n-hexyl-4H-cyclopenta[1,2-b:5,4-b′]dithiophen-4-one (8c) (0.144 mmol, 0.088 g) was mixed with 2-n-nonyl-5-tri-n-butylstannylthiophene (2.1 eq., 0.302 mmol, 0.15 g) and Pd(PPh₃)₄ (5 mol % based on aryl diiodide, 7.19×10⁻³ mmol, 0.008 g). Anhydrous DMF (5 mL) was added under nitrogen atmosphere, and the resulting mixture was heated up to ˜140-150° C. for several minutes. The dark purple mixture became dark blue in color. TLC analysis (hexanes:ethyl acetate (a drop) as eluant) showed complete consumption of the starting aryl diiodide 8c, and the mixture was cooled to room temperature, and treated with water (10 mL). The organic matter was extracted with hexanes several times, the dark blue combined organic phases were dried over anhydrous magnesium sulfate, the drying agent was filtered off and the solvents were removed by rotary evaporation to give dark blue product as a film on the sides of the flask. This material was purified by column chromatography (silica gel, hexanes, then hexanes:ethyl acetate (300:1, 30:1) as eluants). Solvents were removed from combined organic phases, and the product was isolated as dark blue matter (0.073 g, 65.8% yield). ¹H NMR (CDCl₃, 400 MHz): δ6.88 (d, J=3.5 Hz, 2H), 6.69 (d, J=3.6 Hz, 2H), 2.79 (m, 8H), 1.70-1.55 (m, 8H), 1.45-1.20 (m, 36H), 0.87 (m, 12H); ¹³C{¹H} NMR (CDCl₃ 100 MHz): 6184.52, 146.63, 146.12, 140.59, 136.29, 134.37, 132.35, 125.56, 124.27, 31.74, 31.45, 31.43, 30.00, 29.97, 29.38, 29.22, 29.17, 28.99, 26.60, 22.54, 22.53, 13.98 (two alkyl carbon signals are missing due to overlap). HRMS (EI) calculated for C₄₇H₆₈OS₄ 776.4153, found 776.4153. Anal. Calcd. for C₄₇H₆₈OS₄: C, 72.62; H, 8.82; S, 16.50. Found: C, 72.66; H, 8.97.

### Example 52

### 2,6-Bis-(5-perfluorobenzoyl-thiophen-2-yl)-3,5-di-n-hexyl-4H-cyclopenta[1,2-b:5,4-b′]dithiophen-4-one (31a) and 2-(5-perfluorobenzoyl-thiophen-2-yl)-3,5-di-n-hexyl-6-(thiophen-2-yl)-4H-cyclopenta[1,2-b:5,4-b′]dithiophen-4-one (31b)

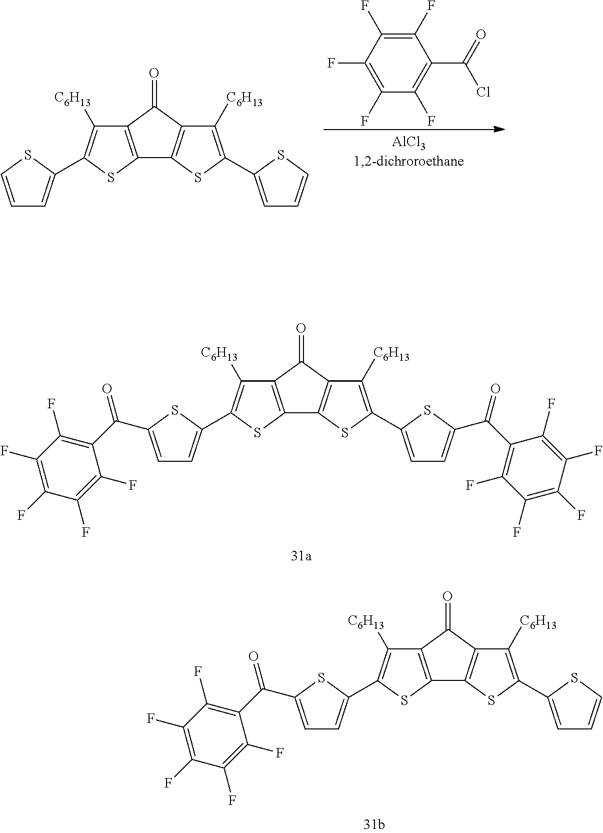

In a round bottom flask AlCl₃ (4 eq., 8.0 mmol, 1.07 g) was mixed with anhydrous 1,2-dichloroethane (20 mL), 2,3,4,5,6-pentafluorobenzoyl chloride (3 eq., 6 mmol, 1.38 g) was added under nitrogen atmosphere, and yellow suspension was stirred for a few minutes (ice-water bath). Dark blue solution of 2,6-bis-(thiophen-2-yl)-3,5-di-n-hexyl-4H-cyclopenta[1,2-b:5,4-b′]dithiophen-4-one (30a) (2.0 mmol, 1.050 g) in anhydrous 1,2-dichloroethane (10 mL) was added dropwise, and the reaction mixture became dark brown. After stirring for 15 minutes three materials were detected by TLC (chloroform as eluant): starting material, mono- and disubstituted products. The cooling bath was removed, the mixture was stirred for 2.5 h, analyzed by TLC (hexanes:chloroform as eluant), and starting material was detected. The reaction mixture was stirred overnight, analyzed by TLC (starting material was still present), and additional amount of AlCl₃ (˜2 g) was added followed by the addition of 2,3,4,5,6-pentafluorobenzoyl chloride (˜0.6 g). After stirring for 2.5 h only trace amount of the starting material was detected, and the mixture was stirred for additional 4 h. TLC analysis showed the complete consumption of the starting material, and two new byproducts. The reaction mixture was treated with water (exotherm), the organic matter was extracted with diethyl ether, and combined organic phases were dried over anhydrous magnesium sulfate. The drying agent was filtered off, the solvents were removed by rotary evaporation, and the residue was purified by column chromatography (silica gel, hexanes:chloroform (350:150 mL) to remove traces amounts of starting material (0.032 g, 3% recovery), and then chloroform to elute two products. Fractions contacting mono-substituted product 31b were combined, subjected to rotary evaporation and mono-substituted product was obtained as dark brown film on the sides of the vial (0.36 g, 25.0%). Fractions with the disubstituted product 31a were subjected to rotary evaporation, and the product was obtained as dark brown matter (0.31 g, 16.9%). Both materials 31a and 31b were further purified by column chromatography (silica gel, chloroform as eluant).

31a: ¹H NMR (CDCl₃, 400 MHz): δ7.45 (d, J=4.1 Hz, 2H), 7.19 (d, J=4.1 Hz, 2H), 2.97 (t, J=7.9 Hz, 4H), 1.68 (m, 4H), 1.45 (m, 4H), 1.34 (m, 8H), 0.90 (t, J=6.9 Hz, 6H); ¹³C{¹H} NMR (CDCl₃, 100 MHz): 6182.92, 175.77, 147.98, 147.13, 142.07, 141.49, 139.86, 136.40 (CH), 133.82, 126.24 (CH), 31.50 (CH₂), 29.90 (CH₂), 29.31 (CH₂), 27.09 (CH₂), 22.60 (CH₂), 14.03 (CH₃) (4 carbon signals of pentafluorophenyl group are missing due to coupling to fluorine). HRMS (EI) calculated for C₄₃H₃₀F₁₀O₃S₄ 912.0918, found 912.0854. Anal. Calcd. for C₄₃H₃₀F₁₀O₃S₄: C, 56.57; H, 3.31. Found: C, 56.83; H, 3.49.

31b: ¹H NMR (CDCl₃, 400 MHz): δ7.43 (d, J=4.1 Hz, 1H), 7.37 (dd, J=5.1 Hz, 1.1 Hz, 1H), 7.16 (d, J=4.2 Hz, 1H), 7.14 (dd, J=3.6 Hz, 1.10 Hz, 1H), 7.09 (dd, J=5.1 Hz, 3.7 Hz, 1H), 2.96 (t, J=7.9 Hz, 2H), 2.84 (t, J=7.9 Hz, 2H), 1.70-1.60 (m, 4H), 1.50-1.35 (m, 4H), 1.35-1.25 (m, 8H), 0.95-0.80 (m, 6H); ¹³C{¹H} NMR (CDCl₃, 100 MHz): δ 183.63, 175.64, 149.18, 147.76, 145.56, 141.80, 141.28, 140.94, 139.80, 137.30, 136.47 (CH), 135.72, 134.75, 132.38, 127.62 (CH), 126.45 (CH), 126.29 (CH), 125.78 (CH), 31.53 (CH₂), 30.10 (CH₂), 29.87 (CH₂), 29.33 (CH₂), 29.30 (CH₂), 27.11 (CH₂), 26.76 (CH₂), 22.63 (CH₂), 22.62 (CH₂), 14.06 (CH₃), 14.04 (CH₃) (4 carbon signals of pentafluorophenyl group are missing due to coupling to fluorine). HRMS (EI) calculated for C₃₆H₃₁F₅O₂S₄ 718.1127, found 718.1130. Anal. Calcd. for C₃₆H₃₁F₅O₂S₄: C, 60.15; H, 4.35. Found: C, 60.34; H, 4.51.

The above specification, examples and data provide exemplary description of the manufacture and use of the various compositions and devices of the inventions, and methods for their manufacture and use. In view of those disclosures, one of ordinary skill in the art will be able to envision many additional embodiments of the inventions disclosed and claimed herein to be obvious, and that they can be made without departing from the spirit and scope of the invention. The claims hereinafter appended define some of those embodiments.

### Additional Embodiments

### Embodiment 1a

A method for synthesizing a fused tricyclic compound comprising the structure

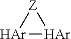

wherein

HAr a five or six membered heteroaryl group,

Z is C═C(CN)₂, or [C═C(CN₂)]₂,

the method comprising:

providing an optionally substituted precursor compound comprising a halo-heteroaryl ring having an Hal substituent at a first position on the HAr ring;

treating the precursor compound with a strongly basic compound to induce the isomerization of the precursor compound to produce an intermediate compound wherein the Hal atom is bound to a different position on the HAr ring;

treating the intermediate compound with an oxidizing agent so as to form a carbon-carbon bond between two intermediate compounds and thereby form the bishalo-bisheteroaryl compound.

optionally treating the bishalo-bisheteroaryl compound with an organometallic compound to exchange a metal for the Hal substituents, and form a bismetallo-bisheteroaryl compound, and

reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

### Embodiment 2a

The method of Embodiment 1a, wherein the organometallic compound is an alkyl lithium compound or lithium diorganoamide.

### Embodiment 3a

The method of Embodiments 1a-2a, wherein the organometallic compound is a transition metal compound.

### Embodiment 4a

The method of Embodiments 1a-3a, wherein the fused tricyclic compound has the structure

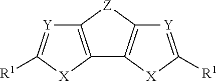

wherein

R¹ is hydrogen, a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;

X is O, S, Se, or NR³ wherein R³ is a C₁-C₁₈ alkyl, perfluoroalkyl, aryl, or heteroaryl; and

Y is CH, CR⁴, or N, wherein R⁴ is a C₁-C₁₈ alkyl, aryl, or heteroaryl.

### Embodiment 5a

A composition represented by at least one of:

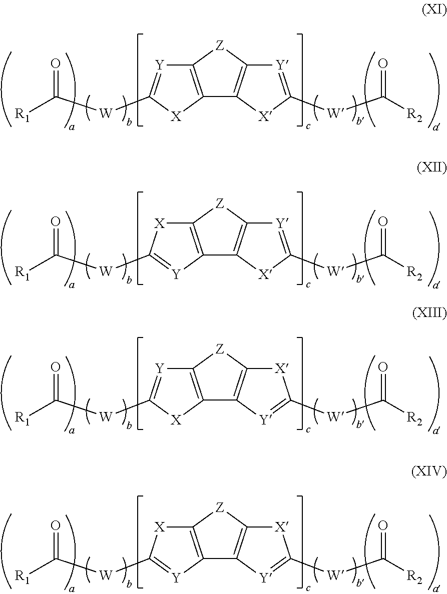

wherein independently a is 0 or 1, and a′ is 0 or 1;

wherein R₁ and R₂ independently are alkyl, fluoroalkyl, aryl, fluoroaryl, heteroaryl, arylalkyl, or heteroarylalkyl;

wherein W and W′ independently comprise at least one heteroarylene group;

wherein b and b′ independently are 0, 1, 2, 3, or 4;

wherein c is 1, 2, 3, or 4;

wherein X and X′ independently are O, S, Se, NR³, PR³, or Si(R³)₂, wherein R³ is alkyl, heteroalkyl, or alkylaryl;

wherein Y and Y′ independently are N, P, CH, CR⁴, or SiR⁴. wherein R⁴ is H, alkyl, fluorinated alkyl, aryl, fluorinated aryl, or heteroaryl;

wherein Z is C═C(CN)₂, or [C═C(CN₂)]₂.

### Embodiment 6a

The composition of Embodiment 5, wherein the compound is selected from formula XI.

### Embodiment 7a

The composition of Embodiments 5a-6a, wherein Z is C═C(CN)₂.

### Embodiment 8a

The composition of Embodiments 5a-7a, wherein Z is [C═C(CN₂)]₂.

### Embodiment 9a

A composition comprising at least one tricyclic fused aromatic compound represented by:

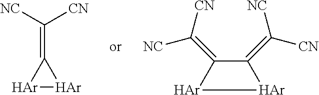

wherein HAr represent a five- or six-membered heteroarylene ring.

### Embodiment 10a

The composition of Embodiment 9a, wherein the compound is represented by:

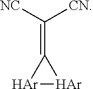

### Embodiment 11a

The composition of Embodiments 9a-10a, wherein the compound is represented by:

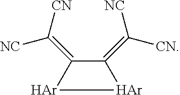

### Embodiment 12a

A device comprising at least one field-effect transistor comprising at least one organic semiconducting active layer which demonstrates a field-effect and comprises at least one of the compositions of any of Embodiments 5s-10s.

### Embodiment 13a

The device of Embodiment 12a, wherein the device charge mobility is at least 1×10⁻⁴ cm²/Vs.

1. A method for synthesizing a fused tricyclic compound comprising the structure 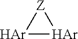
wherein
HAr a five or six membered heteroaryl group,
Z is C═C(CN)₂, or [C═C(CN₂)]₂,
the method comprising:
providing an optionally substituted precursor compound comprising a halo-heteroaryl ring having an Hal substituent at a first position on the HAr ring;
treating the precursor compound with a strongly basic compound to induce the isomerization of the precursor compound to produce an intermediate compound wherein the Hal atom is bound to a different position on the HAr ring;
treating the intermediate compound with an oxidizing agent so as to form a carbon-carbon bond between two intermediate compounds and thereby form the bishalo-bisheteroaryl compound;
optionally treating the bishalo-bisheteroaryl compound with an organometallic compound to exchange a metal for the Hal substituents, and form a bismetallo-bisheteroaryl compound, and
reacting the bismetallo-bisheteroaryl compound with a suitable electrophile, or reacting the bishalo-bisheteroaryl compound or bismetallo-bisheteroaryl compound with a nucleophile, to introduce the Z group, or a precursor thereof suitable for forming the fused tricyclic compound.

2. The method of claim 1, wherein the organometallic compound is an alkyl lithium compound or lithium diorganoamide.

3. The method of claim 1, wherein the organometallic compound is a transition metal compound.

4. The method of claim 1, wherein the fused tricyclic compound has the structure 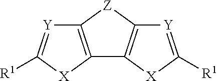
wherein
R¹ is hydrogen, a halide, or a C₁-C₃₀ organic radical selected from optionally substituted alkyl, alkynyl, aryl, and heteroaryl, or —Sn(R²)₃, —Si(R²)₃, Si(OR²)₃ or —B(—OR²¹)₂ wherein each R² is an independently selected alkyl or aryl, and each R²¹ is an independently selected alkyl or aryl, or the R²¹ groups together form an optionally substituted alkylene group bridging the oxygen atoms;
X is O, S, Se, or NR³ wherein R³ is a C₁-C₁₈ alkyl, perfluoroalkyl, aryl, or heteroaryl; and
Y is CH, CR⁴, or N, wherein R⁴ is a C₁-C₁₈ alkyl, aryl, or heteroaryl.

5. A composition comprising a compound represented by at least one of: 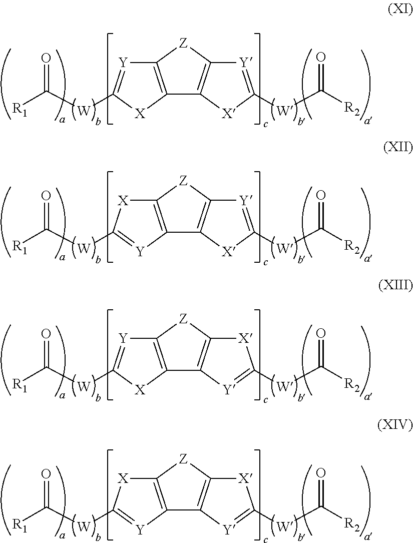
wherein independently a is 0 or 1, and a′ is 0 or 1;
wherein R₁ and R₂ independently are alkyl, fluoroalkyl, aryl, fluoroaryl, heteroaryl, arylalkyl, or heteroarylalkyl;
wherein W and W′ independently comprise at least one heteroarylene group;
wherein b and b′ independently are 0, 1, 2, 3, or 4;
wherein c is 1, 2, 3, or 4;
wherein X and X′ independently are O, S, Se, NR³, PR³, or Si(R³)₂, wherein R³ is alkyl, heteroalkyl, or alkylaryl;
wherein Y and Y′ independently are N, P, CH, CR⁴, or SiR⁴. wherein R⁴ is H, alkyl, fluorinated alkyl, aryl, fluorinated aryl, or heteroaryl;
wherein Z is C═C(CN)₂, or [C═C(CN₂)]₂.

6. The composition of claim 5, wherein the compound is selected from formula XI.

7. The composition of claim 5, wherein Z is C═C(CN)₂.

8. The composition of claim 5, wherein Z is [C═C(CN₂)]₂.

9. A composition comprising at least one tricyclic fused aromatic compound represented by: 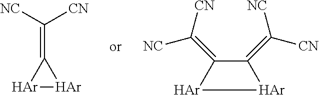
wherein HAr represent a five- or six-membered heteroarylene ring.

10. The composition of claim 9, wherein the compound is represented by:

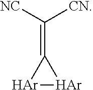

11. The composition of claim 9, wherein the compound is represented by:

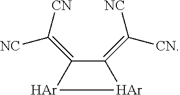

12. A compound produced by the process claim 1.

13. A composition comprising one or more of the compounds of claim 12.

14. A device comprising at least one field-effect transistor comprising at least one organic semiconducting active layer which demonstrates a field-effect and comprises at least one of the compositions according to claim 5.

15. The device of claim 14, wherein the device charge mobility is at least 1×10⁻⁴ cm²/Vs.

16. A device comprising at least one field-effect transistor comprising at least one organic semiconducting active layer which demonstrates a field-effect and comprises at least one of the compositions according to claim 9.

17. The device of claim 16, wherein the device charge mobility is at least 1×10⁻⁴ cm²/Vs.

18. A device comprising at least one field-effect transistor comprising at least one organic semiconducting active layer which demonstrates a field-effect and comprises at least one of the compounds according to claim 12.

19. The device of claim 18, wherein the device charge mobility is at least 1×10⁻⁴ cm²/Vs.
